(19) United States
(12) Patent Application Publication
(10) Pub. No.: US 2023/0320215 A1
(43) Pub. Date: Oct. 5, 2023

(54) LIGHT EMITTING DEVICE AND FUSED POLYCYCLIC COMPOUND FOR THE LIGHT EMITTING DEVICE

(71) Applicant: Samsung Display Co., Ltd., Yongin-si (KR)

(72) Inventors: SUN YOUNG PAK, Suwon-si (KR); SERAN KIM, Suwon-si (KR); JUNHA PARK, Gwacheon-si (KR); JANG YEOL BAEK, Yongin-si (KR); MinJae SUNG, Hwaseong-si (KR); MUN-KI SIM, Seoul (KR); MINJUNG JUNG, Hongcheon-gun (KR)

(21) Appl. No.: 18/109,194

(22) Filed: Feb. 13, 2023

(30) Foreign Application Priority Data
Apr. 4, 2022 (KR) 10-2022-0041493

(51) Int. Cl. H10K 85/60; H10K 85/40; H10K 85/30; C07F 5/02

(52) U.S. Cl. CPC H10K 85/658; H10K 85/40; H10K 85/346; C07F 5/027; H10K 50/12

(57) ABSTRACT

A light emitting device includes a first electrode, a second electrode facing the first electrode, and an emission layer disposed between the first electrode and the second electrode, wherein the emission layer includes a first compound represented by Formula 1 below:

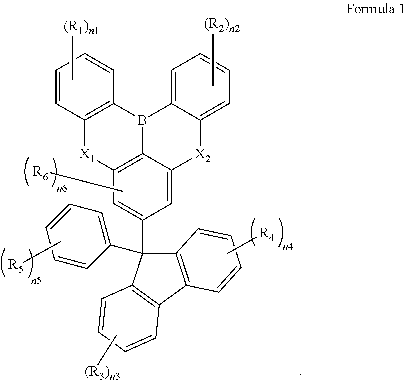

### CROSS-REFERENCE TO RELATED APPLICATION

This application claims priority to and the benefit of Korean Patent Application No. 10-2022-0041493, filed on Apr. 4, 2022, in the Korean Intellectual Property Office, the entire content of which is hereby incorporated by reference.

### BACKGROUND

### 1. Field

The present disclosure herein relates to a light emitting device and a fused polycyclic compound for the light emitting device.

### 2. Description of Related Art

Recently, the development of an organic electroluminescence display apparatus as an image display apparatus is being actively conducted. Unlike liquid crystal display apparatuses and/or the like, the organic electroluminescence display apparatus is a so-called self-luminescent display apparatus in which holes and electrons injected from a first electrode and a second electrode recombine in an emission layer, and thus a luminescent material including an organic compound in the emission layer emits light to implement display (e.g., to display an image).

In the application of an organic electroluminescence device to a display apparatus, there is a demand for an organic electroluminescence device having a low driving voltage, a high luminous efficiency, and a long service life, and the development on materials, for an organic electroluminescence device, capable of stably attaining such characteristics is being continuously pursued.

In recent years, particularly in order to implement a highly efficient organic electroluminescence device, technologies pertaining to phosphorescence emission (utilizing triplet state energy) or delayed fluorescence (utilizing triplet-triplet annihilation (TTA) in which singlet excitons are generated by collision of triplet excitons) are being developed, and thermally activated delayed fluorescence (TADF) materials utilizing delayed fluorescence phenomenon are being developed.

### SUMMARY

An aspect according to embodiments of the present disclosure is directed toward a light emitting device in which luminous efficiency and a device service life are improved.

An aspect according to embodiments of the present disclosure is directed toward a fused polycyclic compound capable of improving luminous efficiency and a device service life of a light emitting device.

Additional aspects will be set forth in part in the description which follows and, in part, will be apparent from the description, or may be learned by practice of the presented embodiments of the disclosure.

According to an embodiment of the present disclosure, a light emitting device includes a first electrode, a second electrode facing the first electrode, and an emission layer between the first electrode and the second electrode, wherein the emission layer includes a first compound represented by Formula 1:

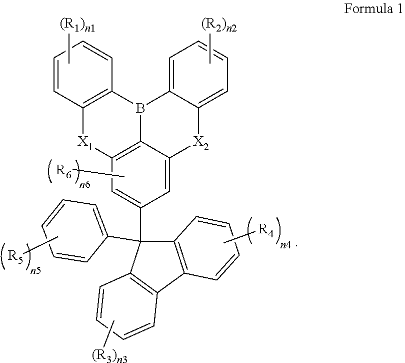

In Formula 1, X₁ and X₂ may each independently be NR₇, O, or S, R₁ to R₇ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, n1 to n4 may each independently be an integer of 0 to 4, n5 may be an integer of 0 to 5, and n6 may be an integer of 0 to 2.

In an embodiment, in Formula 1 above, R₁ to R₇ may each independently be a hydrogen atom, a deuterium atom, a fluorine atom, a cyano group, a substituted or unsubstituted amine group, a substituted or unsubstituted oxy group, a substituted or unsubstituted t-butyl group, a substituted or unsubstituted phenyl group, a substituted or unsubstituted biphenyl group, a substituted or unsubstituted terphenyl group, a substituted or unsubstituted naphthyl group, a substituted or unsubstituted carbazole group, a substituted or unsubstituted dibenzofuran group, or a substituted or unsubstituted dibenzothiophene group, and/or bonded to an adjacent group to form a ring.

In an embodiment, the first compound represented by Formula 1 may be represented by any one selected from among Formula 2a to Formula 2c:

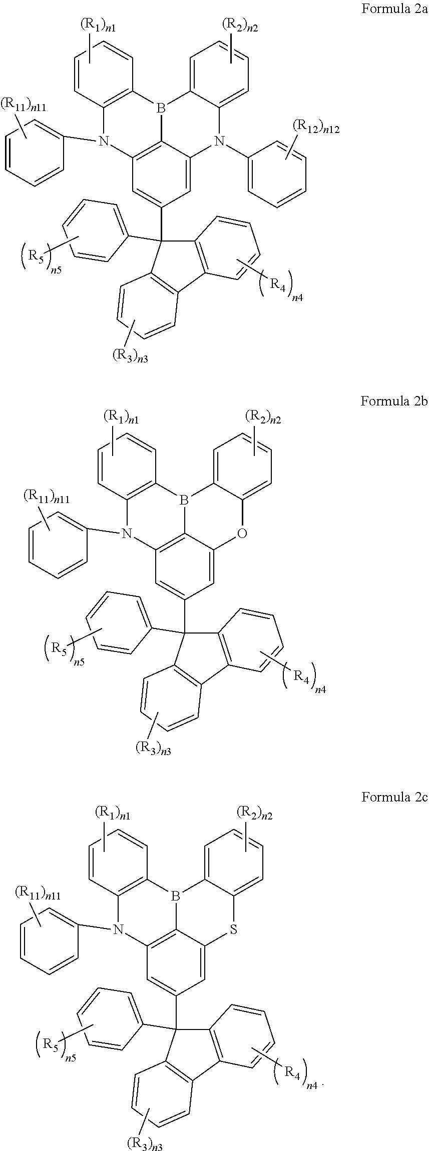

In Formula 2a to Formula 2c, R₁₁ and R₁₂ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and n11 and n12 may each independently be an integer of 0 to 5.

In Formula 2a to Formula 2c, the same as defined in Formula 1 are applied to R₁ to R₅, and n1 to n5.

In an embodiment, the first compound represented by Formula 2a may be represented by any one selected from among Formula 2-1 to Formula 2-5:

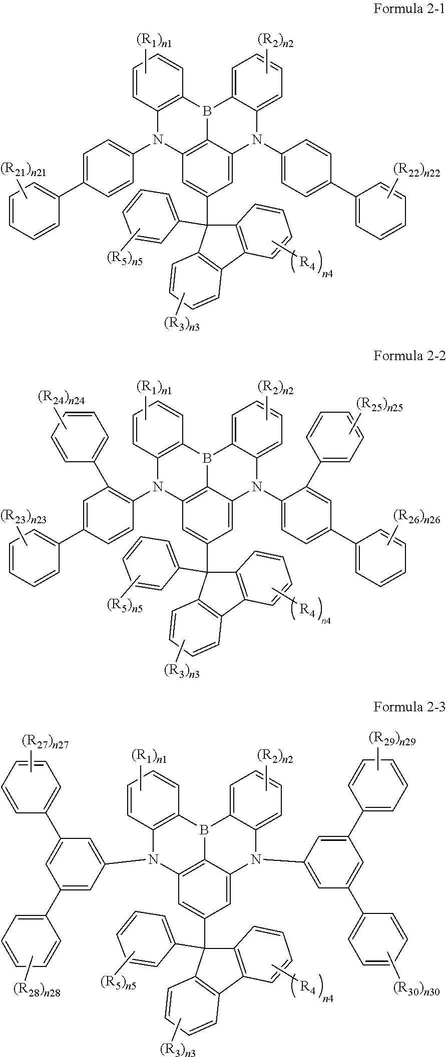

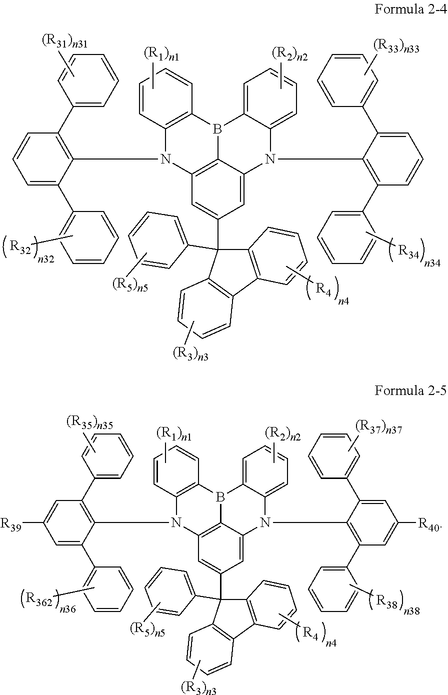

In Formula 2-1 to Formula 2-5, R₂₁ to R₃₈ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, R₃₉ and R₄₀ may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and n21 to n38 may each independently be an integer of 0 to 5.

In Formula 2-1 to Formula 2-5, the same as defined in Formula 1 are applied to R₁ to R₅, and n1 to n5.

In an embodiment, in Formula 2-1 to Formula 2-5, R₂₁ to R₃₈ may each independently be a hydrogen atom, a deuterium atom, a cyano group, a substituted or unsubstituted oxy group, a substituted or unsubstituted methyl group, a substituted or unsubstituted vinyl group, a substituted or unsubstituted t-butyl group, or a substituted or unsubstituted phenyl group, and/or bonded to an adjacent group to form a ring, and R₃₉ and R₄₀ may each independently be a deuterium atom, a cyano group, a substituted or unsubstituted methyl group, a substituted or unsubstituted t-butyl group, or a substituted or unsubstituted phenyl group.

In an embodiment, the first compound represented by Formula 1 may be represented by anyone selected from among Formula 3-1 to Formula 3-4:

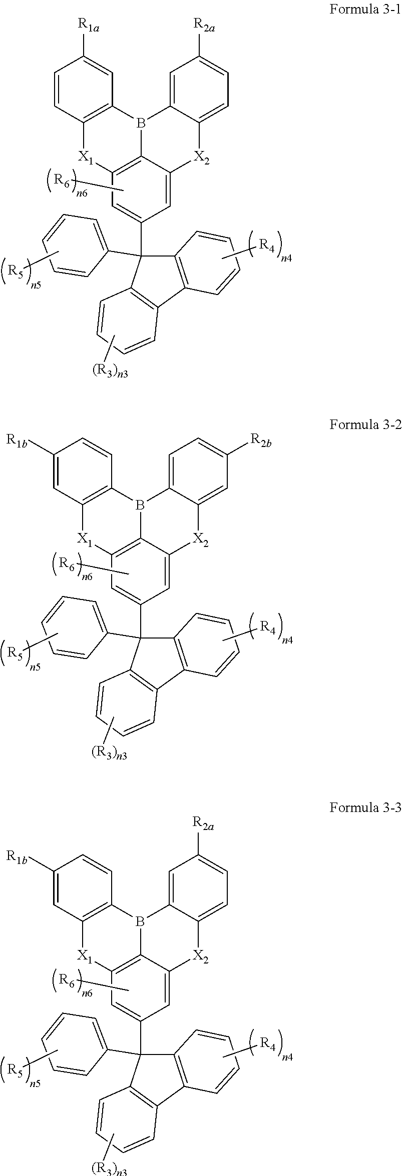

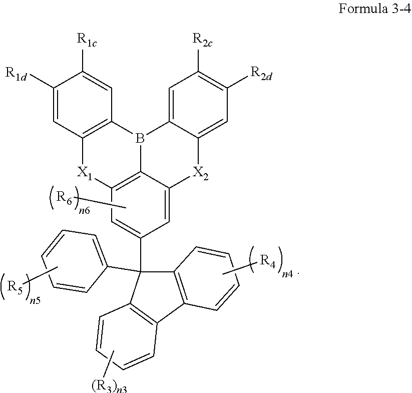

In Formula 3-1 to Formula 3-4, R₁ₐ, R_{1b}, R₂ₐ, and R_{2b} may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, R_{1c}, R_{1d}, R_{2c}, and R_{2d} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula 3-1 to Formula 3-5, the same as defined in Formula 1 are applied to X₁, X₂, R₃ to R₆, and n3 to n6.

In an embodiment, the first compound represented by Formula 1 above may be represented by any one selected from among Formula 4-1 to Formula 4-5:

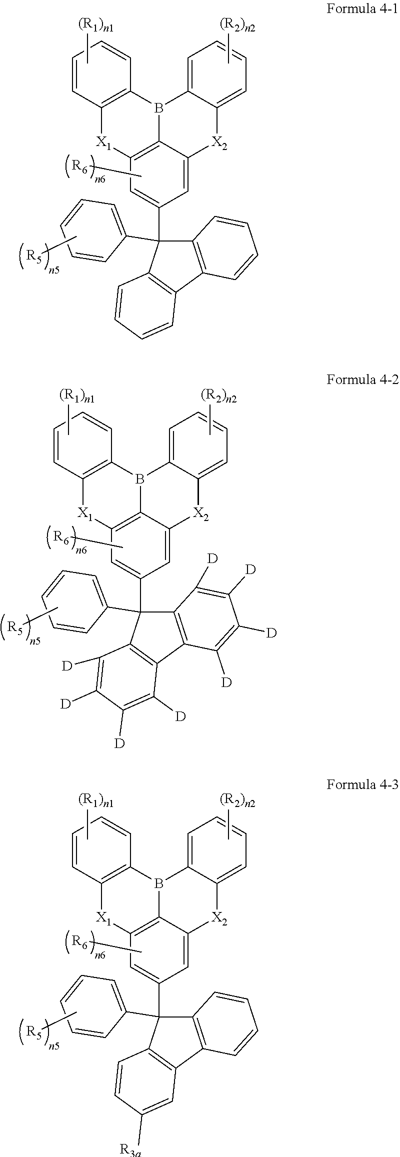

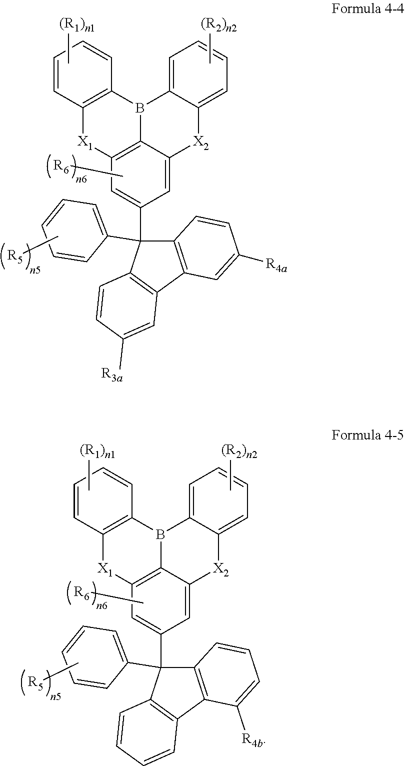

In Formula 4-1 to Formula 4-5, R₃ₐ, R₄ₐ, and R_{4b} may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and D represents a deuterium atom.

In Formula 4-1 to Formula 4-5, the same as defined in Formula 1 are applied to X₁, X₂, R₁, R₂, R₅, R₆, n1, n2, n5 and n6.

In an embodiment, the first compound represented by Formula 1 may be represented by any one selected from among Formula 5-1 to Formula 5-6:

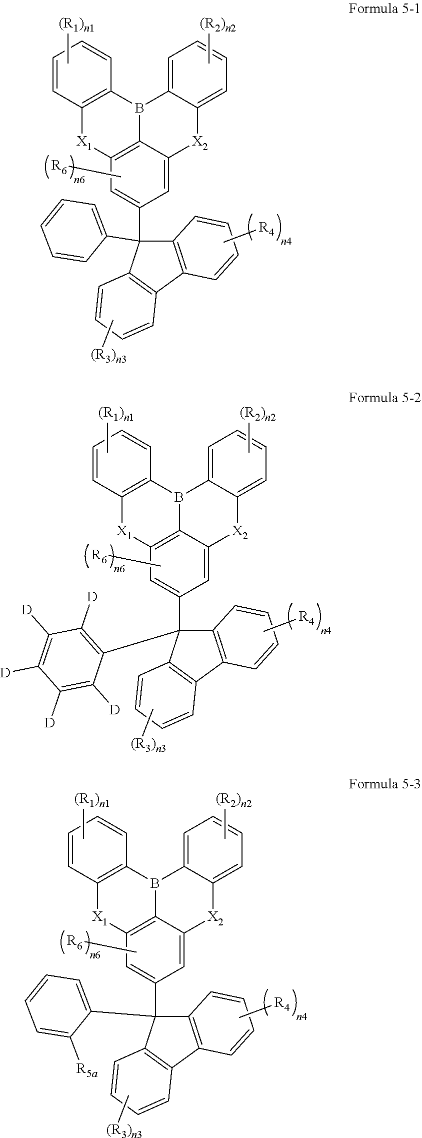

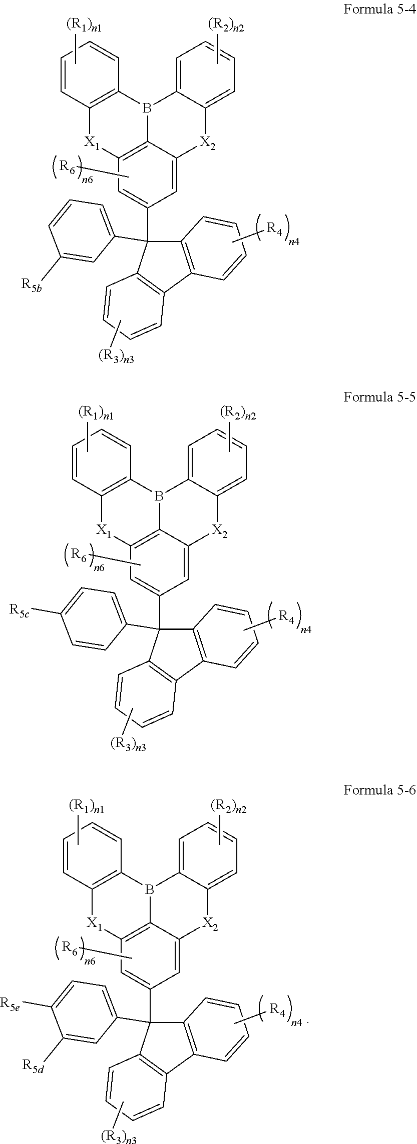

In Formula 5-1 to Formula 5-6, R₅ₐ, R_{5b}, and R_{5c} may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R_{5d} and R₅ₑ may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and D represents a deuterium atom.

In Formula 5-1 to Formula 5-6, the same as defined in Formula 1 are applied to X₁, X₂, R₁ to R₄, R₆, n1 to n4, and n6.

In an embodiment, the emission layer may further include a second compound represented by Formula H-1:

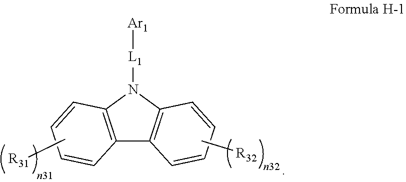

In Formula H-1, L₁ may be a direct linkage, a substituted or unsubstituted arylene group having 6 to 30 ring-forming carbon atoms, or a substituted or unsubstituted heteroarylene group having 2 to 30 ring-forming carbon atoms, An may be a substituted or unsubstituted aryl group having 6 to 30 ring-forming carbon atoms, or a substituted or unsubstituted heteroaryl group having 2 to 30 ring-forming carbon atoms, R₃₁ and R₃₂ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and n31 and n32 may each independently be an integer of 0 to 4.

In an embodiment, the emission layer may further include a third compound represented by Formula H-2:

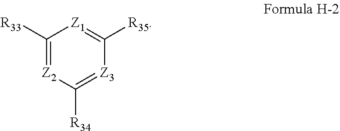

In Formula H-2, Z₁ to Z₃ may each independently be N or CR₃₆, at least one selected from among Z₁ to Z₃ may be N, and R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In an embodiment, the emission layer may further include a fourth compound represented by Formula D-1:

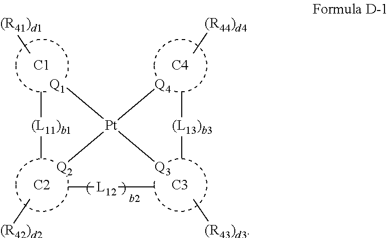

In Formula D-1, Q₁ to Q₄ may each independently be C or N, C1 to C4 may each independently be a substituted or unsubstituted hydrocarbon ring having 5 to 30 ring-forming carbon atoms, or a substituted or unsubstituted heterocycle having 2 to 30 ring-forming carbon atoms, L₁₁ to L₁₃ may each independently be a direct linkage,

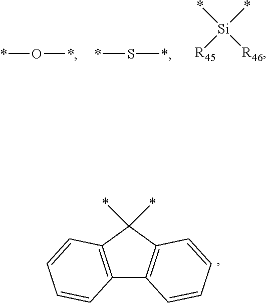

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b1 to b3 may each independently be 0 or 1, R₄₁ to R₄₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and d1 to d4 may each independently be an integer of 0 to 4.

In an embodiment of the present disclosure, a fused polycyclic compound is represented by Formula 1 above.

### BRIEF DESCRIPTION OF THE DRAWINGS

The accompanying drawings are included to provide a further understanding of the present disclosure, and are incorporated in and constitute a part of this specification. The drawings illustrate example embodiments of the present disclosure and, together with the description, serve to explain principles of the present disclosure.

In the drawings:

FIG. 1 is a plan view of a display apparatus according to an embodiment of the present disclosure;

FIG. 2 is a cross-sectional view of a display apparatus according to an embodiment of the present disclosure;

FIG. 3 is a cross-sectional view schematically illustrating a light emitting device according to an embodiment of the present disclosure;

FIG. 4 is a cross-sectional view schematically illustrating a light emitting device according to an embodiment of the present disclosure;

FIG. 5 is a cross-sectional view schematically illustrating a light emitting device according to an embodiment of the present disclosure;

FIG. 6 is a cross-sectional view schematically illustrating a light emitting device according to an embodiment of the present disclosure;

FIG. 7 is a cross-sectional view of a display apparatus according to an embodiment of the present disclosure;

FIG. 8 is a cross-sectional view of a display apparatus according to an embodiment of the present disclosure;

FIG. 9 is a cross-sectional view illustrating a display apparatus according to an embodiment of the present disclosure; and

FIG. 10 is a cross-sectional view illustrating a display apparatus according to an embodiment of the present disclosure.

### DETAILED DESCRIPTION

The present disclosure may be modified in many alternate forms, and thus specific embodiments will be shown in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

When explaining each of the drawings, like reference numbers are used for referring to like elements. In the accompanying drawings, the dimensions of each structure may be exaggeratingly illustrated for clarity of the present disclosure. It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. The terms of a singular form may include plural forms unless the context clearly indicates otherwise.

In the present application, it will be understood that the terms “include,” “have” and/or the like specify the presence of features, numbers, steps, operations, components, parts, or combinations thereof disclosed in the present disclosure, but do not exclude the presence or addition of one or more other features, numbers, steps, operations, components, parts, or combinations thereof.

In the present application, when a layer, a film, a region, or a plate is referred to as being “above” or “on an upper portion of” another layer, film, region, or plate, it can be not only “directly on” the layer, film, region, or plate, but intervening layers, films, regions, or plates may also be present. In contrast, when a part such as a layer, a film, a region, or a plate is referred to as being “under” or “on a lower portion of” another part, it can be not only “directly under” the other part, but an intervening part may also be present. In addition, it will be understood that when a part is referred to as being “on” another part, it can be disposed above the other part, or disposed under the other part.

In the present disclosure, the term “substituted or unsubstituted” may refer to a functional group that is substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the substituents exemplified above may be substituted or unsubstituted. For example, a biphenyl group may be interpreted as an aryl group or a phenyl group substituted with a phenyl group.

In the present disclosure, the phrase “bonded to an adjacent group to form a ring” may indicate that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by adjacent groups being bonded to each other may be connected to another ring to form a spiro structure.

In the present disclosure, the term “adjacent group” may refer to a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the present disclosure, examples of the halogen atom may include a fluorine atom, a chlorine atom, a bromine atom, or an iodine atom.

In the present disclosure, the alkyl group may be linear or branched. The number of carbon atoms in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but the embodiment of the present disclosure is not limited thereto.

In the present disclosure, a cycloalkyl group may refer to a cyclic alkyl group. The number of carbon atoms in the cycloalkyl group may be 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but the embodiment of the present disclosure is not limited thereto.

In the description, an alkenyl group refers to a hydrocarbon group including at least one carbon-carbon double bond in the middle and/or at the terminal end of an alkyl group having 2 or more carbon atoms. The alkenyl group may be linear or branched. The number of carbon atoms in the alkenyl group is not specifically limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but the embodiment of the present disclosure is not limited thereto.

In the present disclosure, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysene group, etc., but the embodiment of the present disclosure is not limited thereto.

In the present disclosure, the heteroaryl group may include at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but the embodiment of the present disclosure is not limited thereto.

In the present disclosure, the above description of the aryl group may be applied to an arylene group except that the arylene group is a divalent group. The above description of the heteroaryl group may be applied to a heteroarylene group except that the heteroarylene group is a divalent group.

In the present disclosure, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but the embodiment of the present disclosure is not limited thereto.

In the present disclosure, the thio group may include an alkylthio group and an arylthio group. The thio group may refer to that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but the embodiment of the present disclosure is not limited thereto.

In the present disclosure, an oxy group may refer to that an oxygen atom is bonded to the alkyl group or the aryl group as defined above. The oxy group may include an alkoxy group and an aryl oxy group. The alkoxy group may be a linear chain, a branched chain or a ring (e.g., cyclic) chain. The number of carbon atoms in the alkoxy group is not specifically limited, but may be, for example, 1 to 20 or 1 to 10. Examples of the oxy group may include a methoxy group, a ethoxy group, an n-propoxy group, an isopropoxy group, a butoxy group, a pentyloxy group, a hexyloxy group, an octyloxy group, a nonyloxy group, a decyloxy group, a benzyloxy group, etc., but the embodiment of the present disclosure is not limited thereto.

The boron group as used herein may refer to that a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, etc., but the embodiment of the present disclosure is not limited thereto.

In the present disclosure, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but the embodiment of the present disclosure is not limited thereto.

In the present disclosure, a direct linkage may refer to a single bond.

Hereinafter, embodiments of the present disclosure will be described with reference to the accompanying drawings.

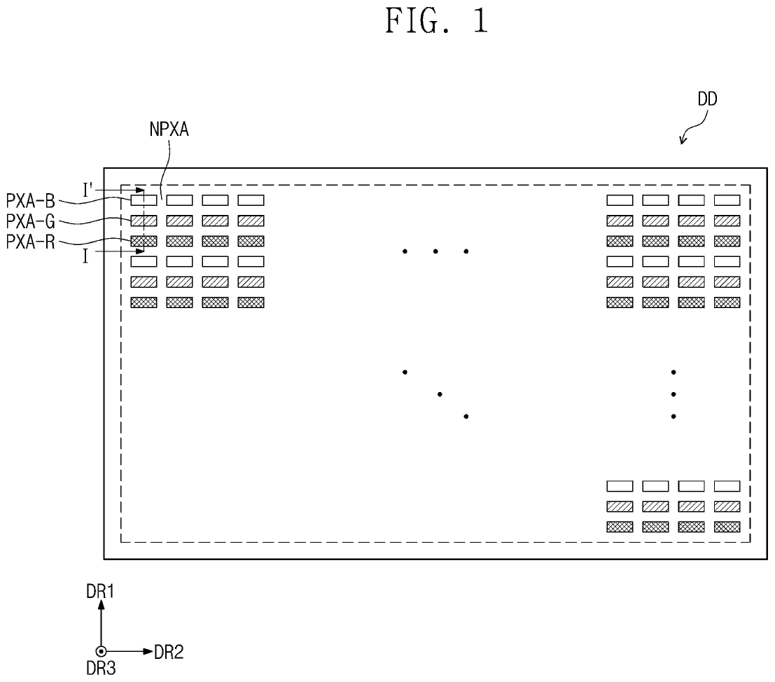

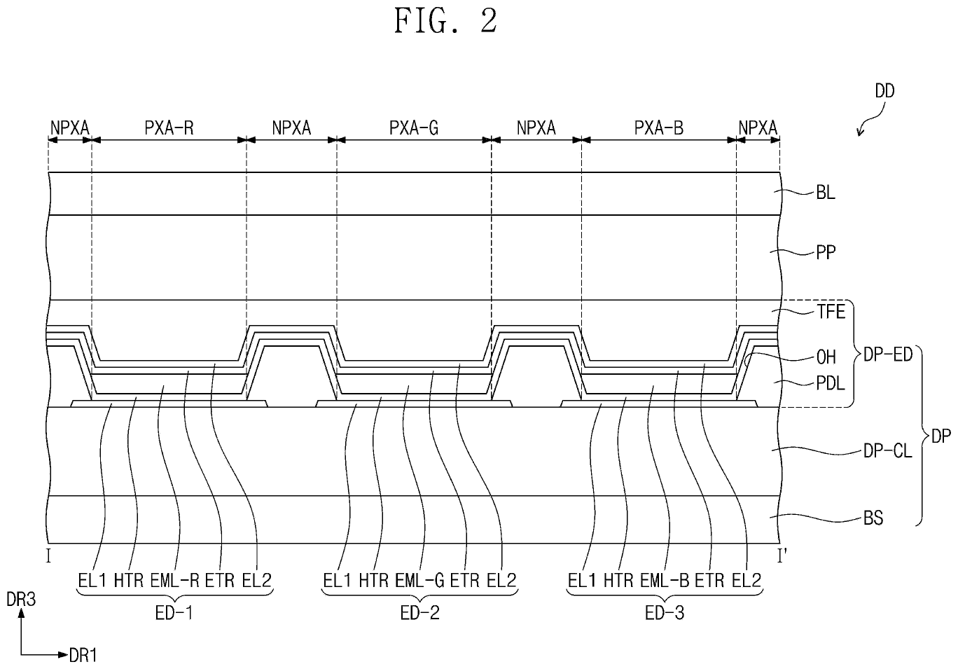

FIG. 1 is a plan view illustrating an embodiment of a display apparatus DD. FIG. 2 is a cross-sectional view of the display apparatus DD of the embodiment. FIG. 2 is a cross-sectional view illustrating a part taken along the line I-I′ of FIG. 1.

The display apparatus DD may include a display panel DP and an optical layer PP disposed on the display panel DP. The display panel DP includes light emitting devices ED-1, ED-2, and ED-3. The display apparatus DD may include a plurality of light emitting devices ED-1, ED-2, and ED-3. The optical layer PP may be disposed on the display panel DP to control reflection of external light at the display panel DP. The optical layer PP may include, for example, a polarization layer and/or a color filter layer. In some embodiments, unlike the configuration illustrated in the drawings, the optical layer PP may not be provided in the display apparatus DD of an embodiment.

A base substrate BL may be disposed on the optical layer PP. The base substrate BL may be a member which provides a base surface on which the optical layer PP is disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, the base substrate BL may not be provided.

The display apparatus DD according to an embodiment may further include a filling layer. The filling layer may be disposed between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 disposed between portions of the pixel defining film PDL, and an encapsulation layer TFE disposed on the light emitting devices ED-1, ED-2, and ED-3.

The base layer BS may be a member which provides a base surface on which the display device layer DP-ED is disposed. The base layer BS may be a glass substrate, a metal substrate, a plastic substrate, etc. However, the embodiment is not limited thereto, and the base layer BS may be an inorganic layer, an organic layer, or a composite material layer.

In an embodiment, the circuit layer DP-CL is disposed on the base layer BS, and the circuit layer DP-CL may include a plurality of transistors. Each of the transistors may include a control electrode, an input electrode, and an output electrode.

For example, the circuit layer DP-CL may include a switching transistor and a driving transistor for driving the light emitting devices ED-1, ED-2, and ED-3 of the display device layer DP-ED.

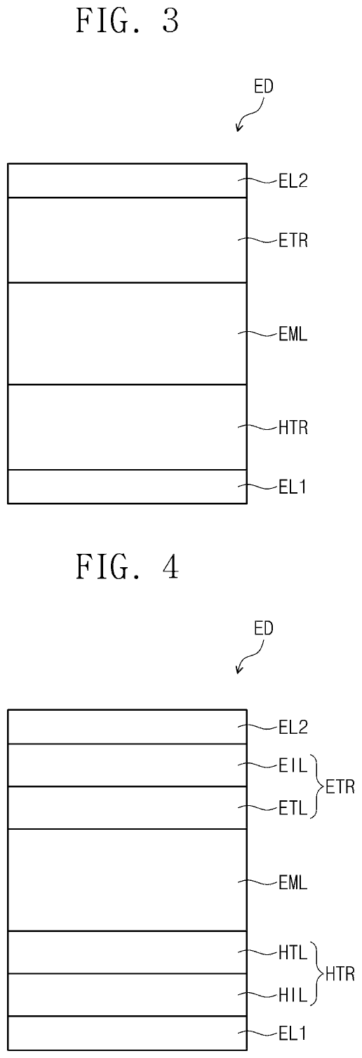

Each of the light emitting devices ED-1, ED-2, and ED-3 may have a structure of a light emitting device ED of an embodiment according to FIGS. 3 to 6, which will be described in more detail later. Each of the light emitting devices ED-1, ED-2, and ED-3 may include a first electrode EL1, a hole transport region HTR, emission layer(s) EML-R, EML-G, and EML-B (e.g., a corresponding one of the emission layer EML-R, the emission layer EML-G, or the emission layer EML-B), an electron transport region ETR, and a second electrode EL2.

FIG. 2 illustrates an embodiment in which the emission layers EML-R, EML-G, and EML-B of the light emitting devices ED-1, ED-2, and ED-3 are disposed in openings OH defined in the pixel defining film PDL, and the hole transport region HTR, the electron transport region ETR, and the second electrode EL2 are provided as common layers in the entire light emitting devices ED-1, ED-2, and ED-3. However, the embodiment of the present disclosure is not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in an embodiment may be provided and patterned through an inkjet printing method.

The encapsulation layer TFE may cover the light emitting devices ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but the embodiment of the present disclosure is not particularly limited thereto. The encapsulation-organic film may include an acrylic-based compound, an epoxy-based compound, and/or the like. The encapsulation-organic film may include a photopolymerizable organic material, but the embodiment of the present disclosure is not particularly limited thereto.

The encapsulation layer TFE may be disposed on the second electrode EL2 and may be disposed to fill the opening OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2, and ED-3 is emitted. The light emitting regions PXA-R, PXA-G, and PXA-B may be spaced apart from each other on a plane (e.g., in a plan view).

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In some embodiments, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be disposed in openings OH defined in the pixel defining film PDL and separated from each other.

The light emitting regions PXA-R, PXA-G, and PXA-B may be divided into a plurality of groups according to the color of light generated from the light emitting devices ED-1, ED-2, and ED-3. In the display apparatus DD of an embodiment illustrated in FIGS. 1 and 2, three light emitting regions PXA-R, PXA-G, and PXA-B, which emit red light, green light, and blue light, respectively, are illustrated as an example. For example, the display apparatus DD of an embodiment may include the red light emitting region PXA-R, the green light emitting region PXA-G, and the blue light emitting region PXA-B that are separated from each other.

In the display apparatus DD according to an embodiment, the plurality of light emitting devices ED-1, ED-2 and ED-3 may be to emit light (e.g., light beams) having wavelengths different from each other. For example, in an embodiment, the display apparatus DD may include a first light emitting device ED-1 that emits red light, a second light emitting device ED-2 that emits green light, and a third light emitting device ED-3 that emits blue light. For example, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, the embodiment of the present disclosure is not limited thereto, and the first to third light emitting devices ED-1, ED-2, and ED-3 may be to emit light (e.g., light beams) in substantially the same wavelength range or at least one light emitting device may be to emit light (e.g., a light beam) in a wavelength range different from the others. For example, the first to third light emitting devices ED-1, ED-2, and ED-3 may all emit blue light.

The light emitting regions PXA-R, PXA-G, and PXA-B in the display apparatus DD according to an embodiment may be arranged in a stripe form. Referring to FIG. 1, the plurality of red light emitting regions PXA-R may be arranged with each other along a second directional axis DR2, the plurality of green light emitting regions PXA-G may be arranged with each other along the second directional axis DR2, and the plurality of blue light emitting regions PXA-B may be arranged with each other along the second directional axis DR2. In some embodiments, the red light emitting region PXA-R, the green light emitting region PXA-G, and the blue light emitting region PXA-B may be alternately arranged in this stated order along a first directional axis DR1.

FIGS. 1 and 2 illustrate that all the light emitting regions PXA-R, PXA-G, and PXA-B have similar area, but the embodiment of the present disclosure is not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may refer to areas when viewed on a plane defined by the first directional axis DR1 and the second directional axis DR2 (e.g., in a plan view).

In some embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in one or more suitable combinations according to the characteristics of display quality required in the display apparatus DD. For example, the arrangement form of the light emitting regions PXA-R, PXA-G, and PXA-B may be a pentile (PENTILE®) arrangement form or a diamond (Diamond Pixel™) arrangement form. PENTILE® and Diamond Pixel™ are trademarks of Samsung Display Co., Ltd.

In some embodiments, the areas of the light emitting regions PXA-R, PXA-G, and PXA-B may be different from each other. For example, in an embodiment, the area of the green light emitting region PXA-G may be smaller than that of the blue light emitting region PXA-B, but the embodiment of the present disclosure is not limited thereto.

Hereinafter, FIGS. 3 to 6 are cross-sectional views schematically illustrating light emitting devices according to embodiments. Each of the light emitting devices ED according to embodiments may include a first electrode EL1, a hole transport region HTR, an emission layer EML, an electron transport region ETR, and a second electrode EL2 that are sequentially stacked.

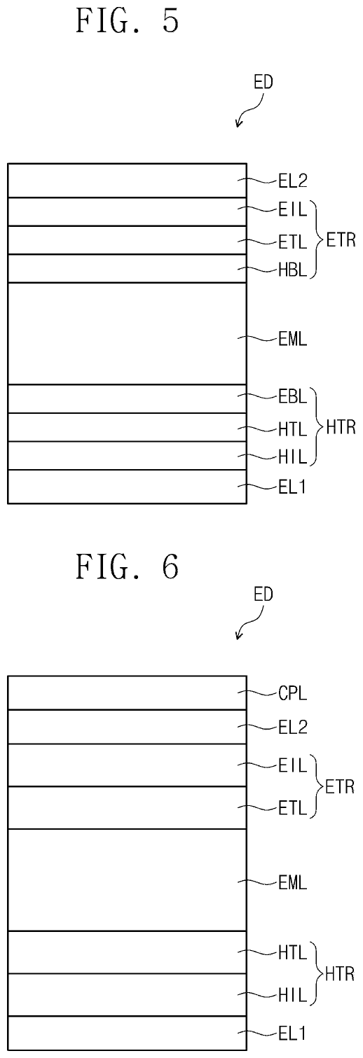

Compared with FIG. 3, FIG. 4 illustrates a cross-sectional view of a light emitting device ED of an embodiment, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting device ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting device ED of an embodiment including a capping layer CPL disposed on a second electrode EL2.

The first electrode EL1 has conductivity (e.g., is a conductor). The first electrode EL1 may be formed of a metal material, a metal alloy, or a conductive compound. The first electrode EL1 may be an anode or a cathode. However, the embodiment of the present disclosure is not limited thereto. In some embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

When the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). When the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but the embodiment of the present disclosure is not limited thereto. In some embodiments, the first electrode EL1 may include one or more of the above-described metal materials, combinations of at least two metal materials of the above-described metal materials, oxides of the above-described metal materials, and/or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer, an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In some embodiments, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in in the respective stated order from the first electrode EL1, but the embodiment of the present disclosure is not limited thereto.

The hole transport region HTR may be formed utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-3:

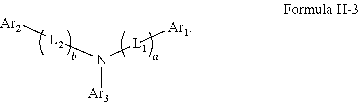

In Formula H-3 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-3, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-3, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-3 above may be a monoamine compound (e.g., a compound including a single amine group). In some embodiments, the compound represented by Formula H-3 above may be a diamine compound in which at least one selected from among Ar₁ to Ar₃ includes the amine group as a substituent. In some embodiments, the compound represented by Formula H-3 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-3 may be represented by any one of the compounds of Compound Group H. However, the compounds listed in Compound Group H are examples, and the compounds represented by Formula H-3 are not limited to those represented by Compound Group H:

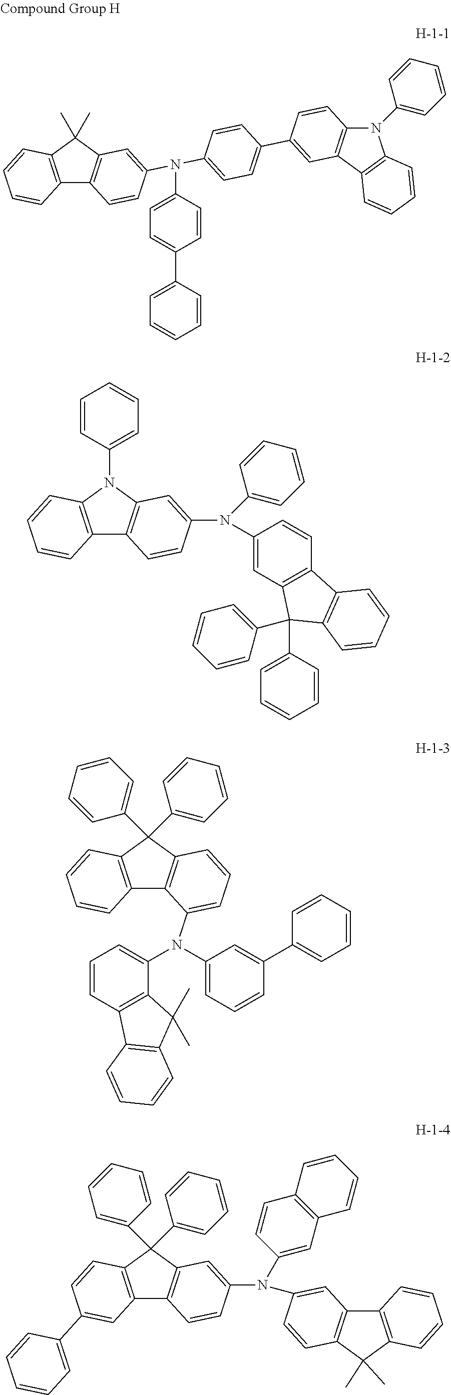 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

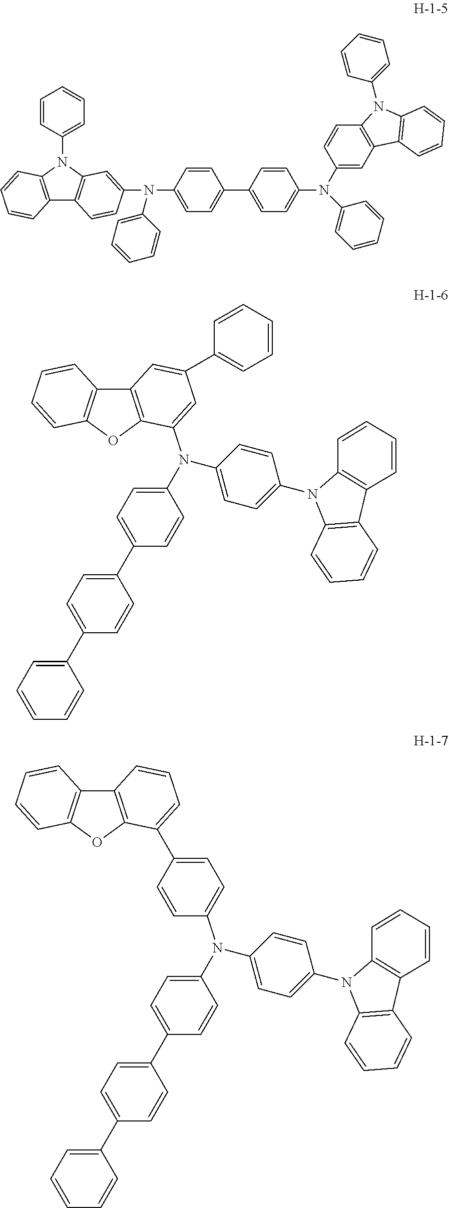 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

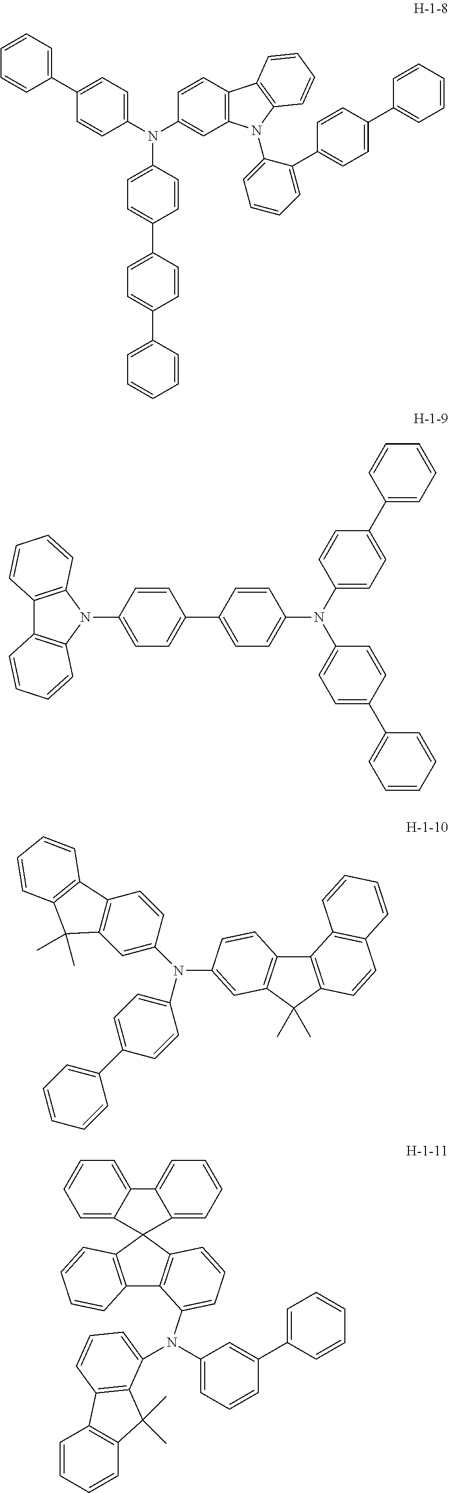

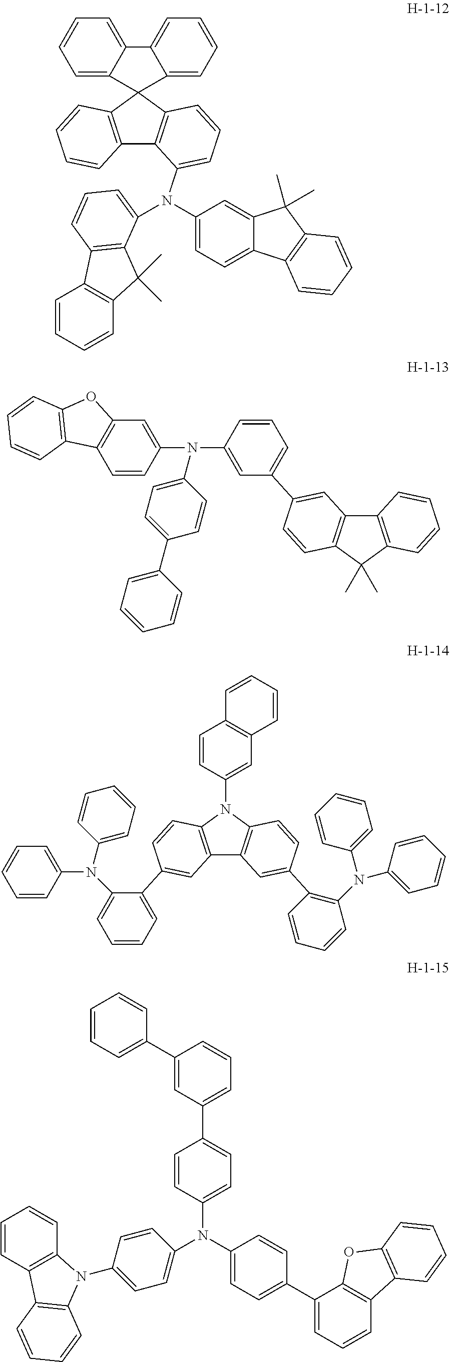 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

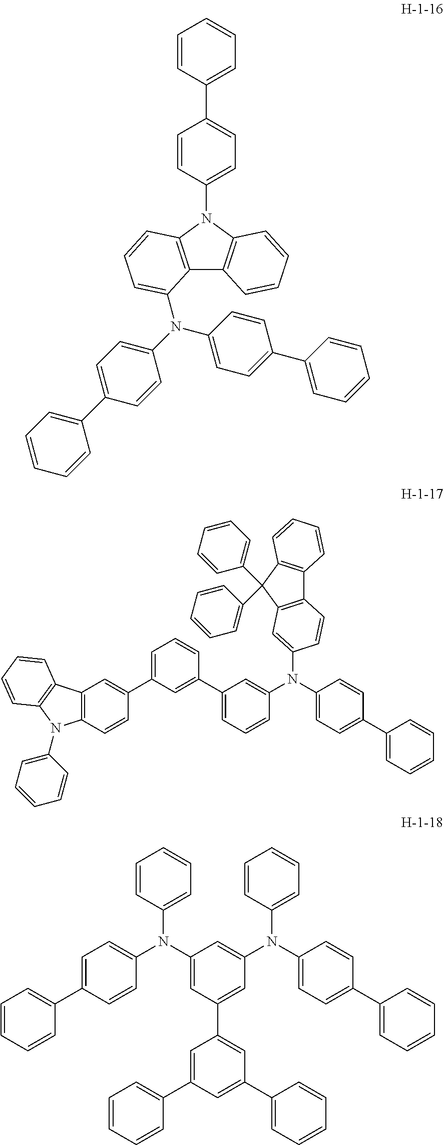 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

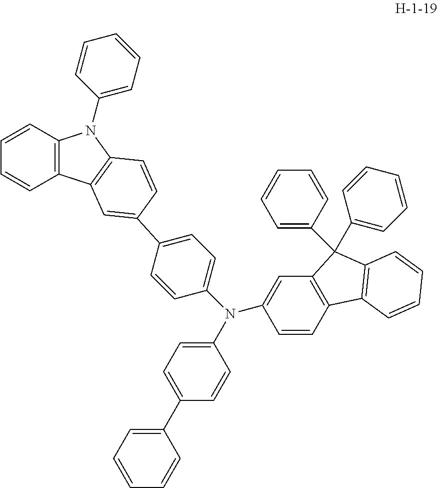 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCfN), etc.

The hole transport region HTR may include a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalene-I-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. When the thicknesses of the hole transport region HTR, the hole injection layer HIL, the hole transport layer HTL and the electron blocking layer EBL satisfy the above-described ranges, satisfactory hole transport properties may be achieved without a substantial increase in driving voltage.

The hole transport region HTR may further include a charge generating material to increase conductivity in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but the embodiment of the present disclosure is not limited thereto. For example, the p-dopant may include a metal halide compound such as CuI and/or RbI, a quinone derivative such as tetracyanoquinodimethane (TCNQ) and/or 2,3,5,6-tetrafluoro-7,7′8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but the embodiment of the present disclosure is not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be contained in the hole transport region HTR may be utilized as a material to be contained in the buffer layer. The electron blocking layer EBL is a layer that serves to prevent or reduce the electron injection from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML in the light emitting device ED according to an embodiment may include a fused polycyclic compound of an embodiment. In an embodiment, the emission layer EML may include the fused polycyclic compound of an embodiment as a dopant. The fused polycyclic compound of an embodiment may be a dopant material of the emission layer EML.

The fused polycyclic compound of an embodiment may include a core structure in which a plurality of aromatic rings are fused via at least one boron atom and at least two (e.g., two additional) heteroatoms. For example, the fused polycyclic compound of an embodiment may include a structure in which the first to third aromatic rings are fused via one boron atom, a first heteroatom, and a second heteroatom. The first aromatic ring and the second aromatic ring may be symmetric with respect to the boron atom in the fused ring structure. In some embodiments, the first heteroatom and the second heteroatom may each independently be a nitrogen atom, an oxygen atom, or a sulfur atom.

The fused polycyclic compound of an embodiment may include a first substituent that is a steric hindrance substituent bonded to the core structure as described above. The first substituent may be a substituent having a fluorene moiety. The first substituent may be bonded to the core structure of the fused polycyclic compound of an embodiment at carbon 9 of the fluorene moiety, and a substituted or unsubstituted phenyl group may be additionally bonded at carbon 9. The first substituent may be bonded at the para-position with respect to a boron atom contained in the above-described core structure.

In the present disclosure, the carbon number of the fluorene moiety is as represented by Formula A:

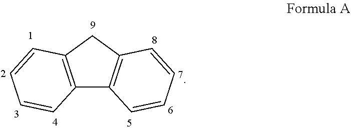 [SMILES: c1ccc2c(c1)Cc1ccccc1-2]

The fused polycyclic compound of an embodiment may be represented by Formula 1:

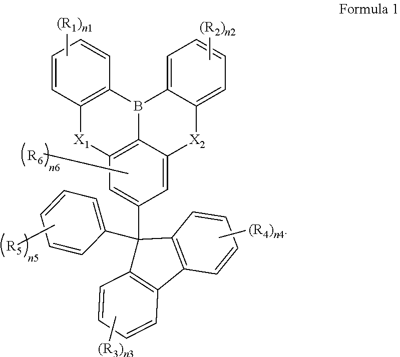

In Formula 1, X₁ and X₂ may each independently be NR₇, O, or S. X₁ and X₂ may be the same. For example, both X₁ and X₂ may (e.g., simultaneously) be NR₇. In Formula 1, X₁ and X₂ may correspond to the first heteroatom and the second heteroatom, respectively, as described above.

In Formula 1, R₁ to R₇ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₁ to R₇ may be bonded to an adjacent group to form a ring. For example, R₁ to R₇ may each independently be a hydrogen atom, a deuterium atom, a fluorine atom, a cyano group, a substituted or unsubstituted amine group, a substituted or unsubstituted oxy group, a substituted or unsubstituted t-butyl group, a substituted or unsubstituted phenyl group, a substituted or unsubstituted biphenyl group, a substituted or unsubstituted terphenyl group, a substituted or unsubstituted naphthyl group, a substituted or unsubstituted carbazole group, or a substituted or unsubstituted dibenzofuran group. In some embodiments, each of R₁, R₂ and R₅ may be bonded to an adjacent group to form an aromatic ring. In some embodiments, in Formula 1, the fluorene substituent at which R₃ and R₄ are substituted may correspond to the above-described first substituent.

In some embodiments, in Formula 1 above, when at least one of X₁ or X₂ is NR₇, R₇ may be represented by any one selected from among Formula a1 to Formula a5:

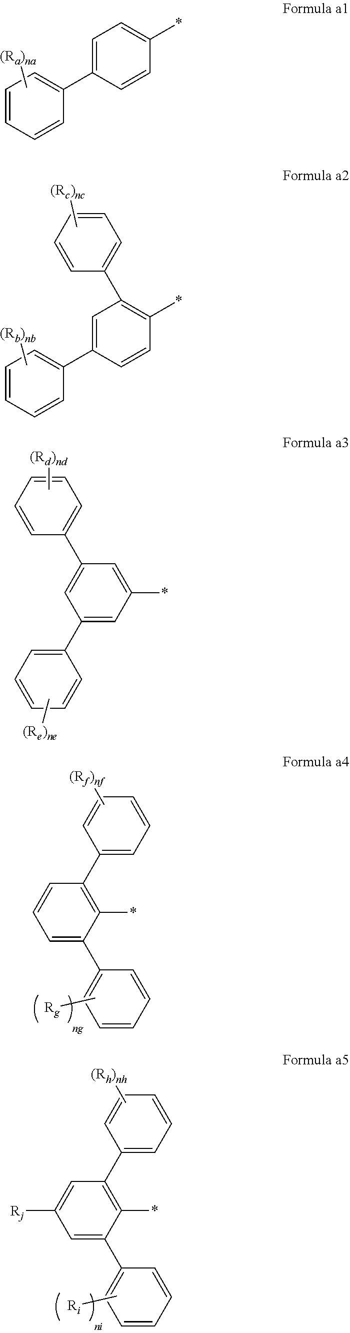

In Formula a1 to Formula a5, Rₐ to Rᵢ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of Rₐ to Rᵢ may be bonded to an adjacent group to form a ring. For example, Rₐ to Rᵢ may each independently be a hydrogen atom, a deuterium atom, a cyano group, a substituted or unsubstituted oxy group, a substituted or unsubstituted methyl group, a substituted or unsubstituted vinyl group, a substituted or unsubstituted t-butyl group, or a substituted or unsubstituted phenyl group. In some embodiments, each of Rₐ to Rᵢ may be bonded to an adjacent group to form an aromatic ring.

In Formula a1 to Formula a5, Rⱼ may be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R; may be a deuterium atom, a cyano group, a substituted or unsubstituted methyl group, a substituted or unsubstituted t-butyl group, or a substituted or unsubstituted phenyl group.

In Formula a1 to Formula a5, na to ni may each independently be an integer of 0 to 5. When each of na to ni is 0, the fused polycyclic compound of an embodiment may not be substituted with each of Rₐ to Rᵢ. The case where each of na to ni is 5 and Rₐ's to Rᵢ's each are hydrogen atoms may be the same as the case where each of na to ni is 0. When each of na to ni is an integer of 2 or more, a plurality of Rₐ's to Rᵢ's may each be the same or at least one selected from among the plurality of Rₐ's to Rᵢ's may be different from the others.

In Formula a1 to Formula a5, “-*” represents a part linked to the nitrogen atom in NR₇.

In Formula 1, n1 to n4 may each independently be an integer of 0 to 4. When each of n1 to n4 is 0, the fused polycyclic compound of an embodiment may not be substituted with each of R₁ to R₄. The case where each of n1 to n4 is 4 and R₁'s to R₄'s each are hydrogen atoms may be the same as the case where each of n1 to n4 is 0. When each of n1 to n4 is an integer of 2 or more, a plurality of R₁'s to R₄'s may each be the same or at least one selected from among the plurality of R₁'s to R₄'s may be different from the others.

In Formula 1, n5 may be an integer of 0 to 5. When n5 is 0, the fused polycyclic compound of an embodiment may not be substituted with R₅. The case where n5 is 5 and R₅'s are all hydrogen atoms may be the same as the case where n5 is 0. When n5 is an integer of 2 or more, a plurality of R₅'s may all be the same, or at least one selected from among the plurality of R₅'s may be different from the others.

In Formula 1, n6 may be an integer of 0 to 2. When n6 is 0, the fused polycyclic compound of an embodiment may not be substituted with R₆. The case where n6 is 2 and R₆'s are all hydrogen atoms may be the same as the case where n6 is 0. When n6 is 2, of the two R₆'s may be the same as or different from each other.

In an embodiment, R₁ to R₆ may each be deuterium atoms, and the sum of n1 to n6 may be 1 to 23. For example, the fused polycyclic compound represented by Formula 1 of an embodiment may include a structure in which at least one deuterium atom is substituted at the core structure and/or the first substituent.

In an embodiment, the fused polycyclic compound represented by Formula 1 may be represented by Formula 2a to Formula 2c:

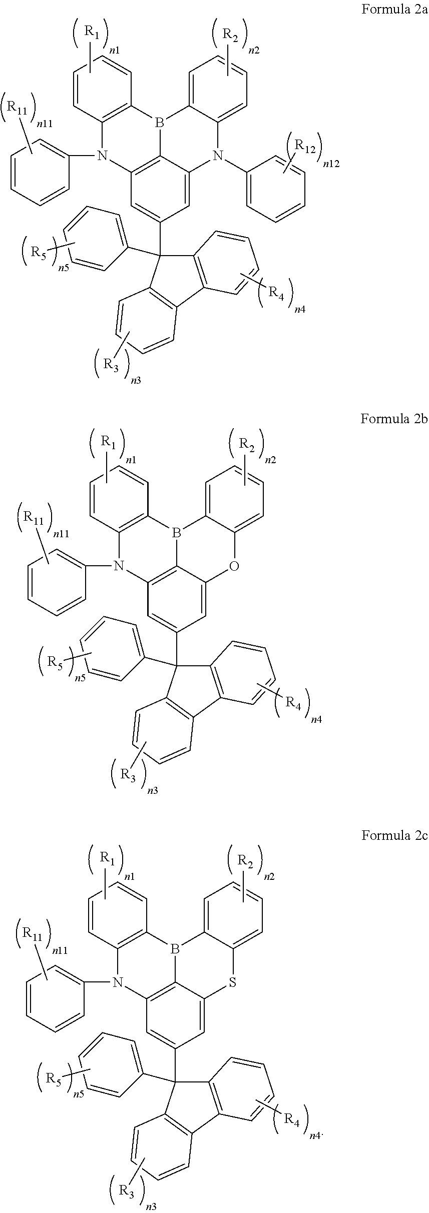

Formula 2a to Formula 2c represent the cases where n6, R₇, X₁, and X₂ in Formula 1 are specified. Formula 2a represents the case where both X₁ and X₂ are (e.g., simultaneously) NR₇, and R₇ is a substituted or unsubstituted phenyl group in Formula 1. Formula 2b represents the case where X₁ is NR₇, R₇ is a substituted or unsubstituted phenyl group, and X₂ is O in Formula 1. Formula 2c represents the case where X₁ is NR₇, R₇ is a substituted or unsubstituted phenyl group, and X₂ is S in Formula 1. In addition, Formula 2a to Formula 2c represent the cases where n6 is 0.

In Formula 2a to Formula 2c, R₁₁ and R₁₂ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₁₁ and R₁₂ may be bonded to an adjacent group to form a ring. For example, R₁₁ and R₁₂ may each independently be a hydrogen atom, a deuterium atom, a cyano group, a substituted or unsubstituted amine group, a substituted or unsubstituted oxy group, a substituted or unsubstituted t-butyl group, a substituted or unsubstituted phenyl group, a substituted or unsubstituted biphenyl group, a substituted or unsubstituted terphenyl group, a substituted or unsubstituted naphthyl group, a substituted or unsubstituted carbazole group, or a substituted or unsubstituted dibenzofuran group. In some embodiments, each of R₁₁ and R₁₂ may be bonded to an adjacent group to form an aromatic ring. In Formula 2a to Formula 2c, n11 and n12 may each independently be an integer of 0 to 5. When each of n11 and n12 is 0, the fused polycyclic compound of an embodiment may not be substituted with each of R₁₁ and R₁₂. The case where each of n11 and n12 is 5 and R₁₁'s and R₁₂'s each are hydrogen atoms may be the same as the case where each of n11 and n12 is 0. When each of n11 and n12 is an integer of 2 or more, a plurality of R₁₁'s and R₁₂'s may each be the same or at least one selected from among the plurality of R₁₁'s and R₁₂'s may be different from the others.

In Formula 2a to Formula 2c, the same as described in Formula 1 above may be applied to R₁ to R₅, and n1 to n5.

In an embodiment, the fused polycyclic compound represented by Formula 2a may be represented by any one selected from among Formula 2-1 to Formula 2-5:

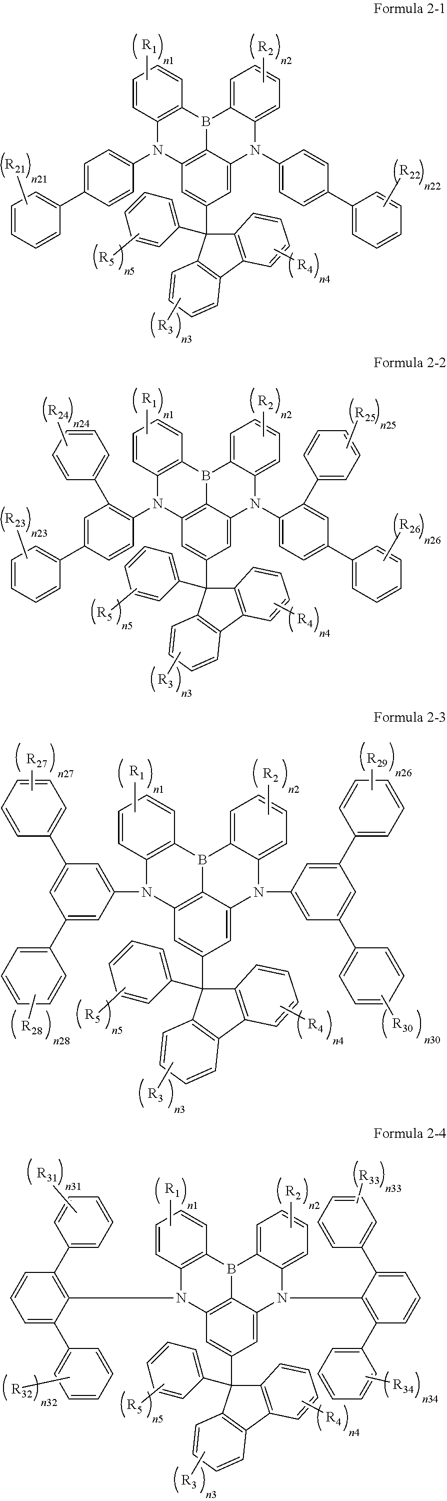

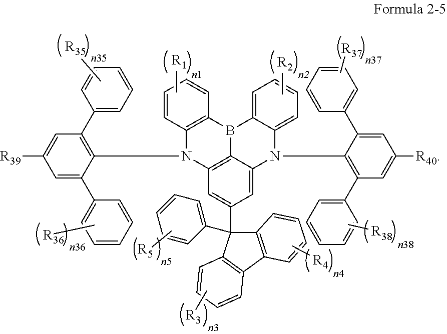

Formula 2-1 to Formula 2-5 represent the cases where the types (kinds), bonding position, and bonding number of substituents represented by R₁₁ and R₁₂ in Formulae 2a to 2c are specified.

In Formula 2-1 to Formula 2-5, R₂₁ to R₃₈ may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₂₁ to R₃₈ may be bonded to an adjacent group to form a ring. For example, R₂₁ to R₃₈ may each independently be a hydrogen atom, a deuterium atom, a cyano group, a substituted or unsubstituted oxy group, a substituted or unsubstituted methyl group, a substituted or unsubstituted vinyl group, a substituted or unsubstituted t-butyl group, or a substituted or unsubstituted phenyl group. In some embodiments, each of R₂₁ to R₃₈ may be bonded to an adjacent group to form an aromatic ring.

In Formula 2-1 to Formula 2-5, R₃₉ and R₄₀ may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃₉ and R₄₀ may each independently be a deuterium atom, a cyano group, a substituted or unsubstituted methyl group, a substituted or unsubstituted t-butyl, or a substituted or unsubstituted phenyl group.

In Formula 2-1 to Formula 2-5, n21 to n38 may each independently be an integer of 0 to 5. When each of n21 to n38 is 0, the fused polycyclic compound of an embodiment may not be substituted with each of R₂₁ to R₃₈. The case where each of n21 to n38 is 5 and R₂₁'s to R₃₈'s each are hydrogen atoms may be the same as the case where each of n21 to n38 is 0. When each of n21 to n38 is an integer of 2 or more, a plurality of R₂₁'s to R₃₈'s may each be the same or at least one selected from among the plurality of R₂₁'s to R₃₈'s may be different from the others.

In Formula 2-1 to Formula 2-5, the same as described in Formula 1 above may be applied to R₁ to R₅, and n1 to n5.

In an embodiment, the fused polycyclic compound represented by Formula 1 may be represented by any one selected from among Formula 3-1 to Formula 3-4:

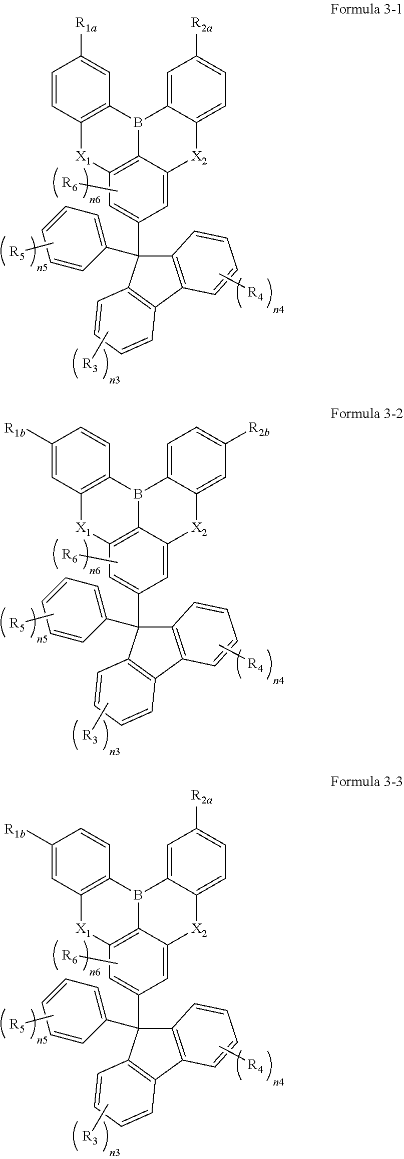

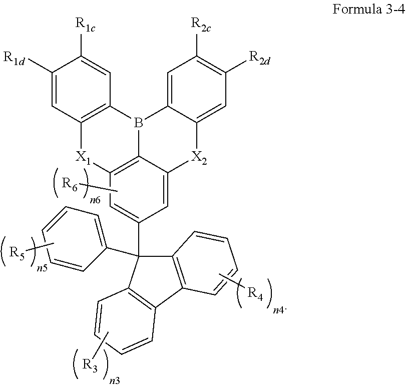

Formula 3-1 to Formula 3-4 represent the cases where substituted positions of substituents substituted to the first aromatic ring and the second aromatic ring in the fused polycyclic compound of an embodiment are specified. For example, Formula 3-1 to Formula 3-4 represent the cases where substituted positions of R₁ and R₂ in Formula 1 are specified.

In Formula 3-1 to Formula 3-4, R₁ₐ, R_{1b}, R₂ₐ, and R_{2b} may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁ₐ and R_{1b} may each independently be a deuterium atom, a fluorine atom, a cyano group, a substituted or unsubstituted methyl group, a substituted or unsubstituted ethyl group, a substituted or unsubstituted isopropyl group, a substituted or unsubstituted t-butyl group, a substituted or unsubstituted phenyl group, a substituted or unsubstituted biphenyl group, a substituted or unsubstituted terphenyl group, a substituted or unsubstituted carbazole group, or a substituted or unsubstituted dibenzofuran group.

In Formula 3-1 to Formula 3-4, R_{1c}, R_{1d}, R_{2c}, and R_{2d} may each independently be a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R_{1c}, R_{1d}, R_{2c}, and R_{2d} may be bonded to an adjacent group to form a ring. For example, R_{1c}, R_{1d}, R_{2c}, and R_{2d} may each independently be a hydrogen atom, a deuterium atom, a cyano group, a substituted or unsubstituted oxy group, a substituted or unsubstituted methyl group, a substituted or unsubstituted vinyl group, a substituted or unsubstituted t-butyl group, or a substituted or unsubstituted phenyl group. In some embodiments, each of R_{1c}, R_{1d}, R_{2c}, and R_{2d} may be bonded to an adjacent group to form an aromatic ring. In some embodiments, R_{1c} and R_{1d} may be bonded to each other to form an aromatic hydrocarbon ring or an aromatic heterocycle. In some embodiments, R_{2c} and R_{2d} may be bonded to each other to form an aromatic hydrocarbon ring or an aromatic heterocycle.

In Formula 3-1 to Formula 3-4, the same as described in Formula 1 above may be applied to X₁, X₂, R₃ to R₆, and n3 to n6.

In an embodiment, the fused polycyclic compound represented by Formula 1 may be represented by any one selected from among Formula 4-1 to Formula 4-5:

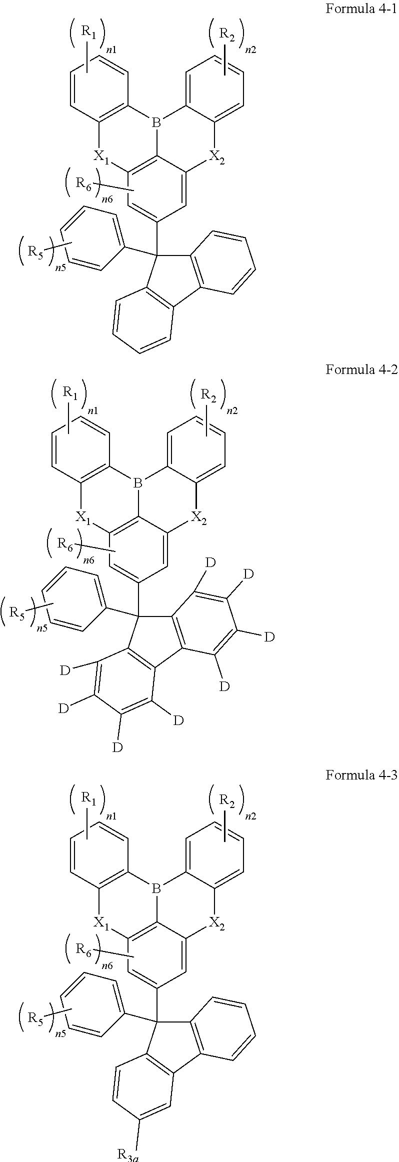

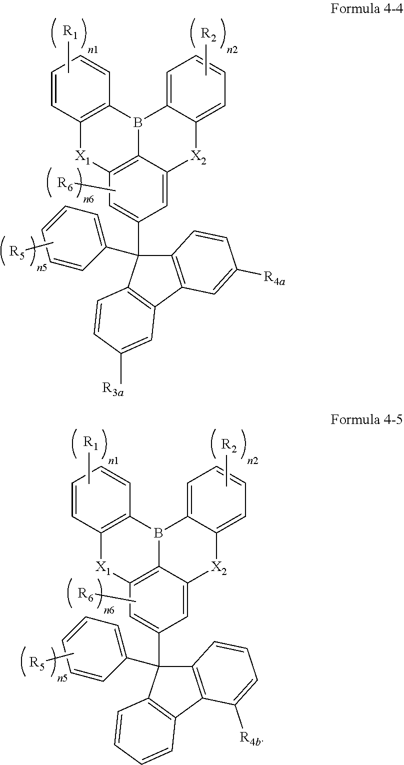

Formula 4-1 to Formula 4-5 represent the cases where types (kinds) and substituted positions of substituents substituted to the fluorene moiety that is the first substituent in the fused polycyclic compound of an embodiment are specified. For example, Formula 4-1 to Formula 4-5 represent the cases where the substituent types (kinds) and substituted positions of each of R₃ and R₄ in Formula 1 are specified.

In Formula 4-1 to Formula 4-5, D represents a deuterium atom.

In Formula 4-1 to Formula 4-5, R₃ₐ, R₄ₐ, and R_{4b} may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃ₐ, R₄ₐ, and R_{4b} may each independently be a deuterium atom, a fluorine atom, a cyano group, a substituted or unsubstituted methyl group, a substituted or unsubstituted ethyl group, a substituted or unsubstituted isopropyl group, a substituted or unsubstituted t-butyl group, a substituted or unsubstituted phenyl group, a substituted or unsubstituted biphenyl group, a substituted or unsubstituted terphenyl group, a substituted or unsubstituted carbazole group, or a substituted or unsubstituted dibenzofuran group.

In Formula 4-1 to Formula 4-5, the same as described in Formula 1 above may be applied to X₁, X₂, R₁, R₂, R₅, R₆, n1, n2, n5, and n6.

In an embodiment, the fused polycyclic compound represented by Formula 1 may be represented by any one selected from among Formula 5-1 to Formula 5-6:

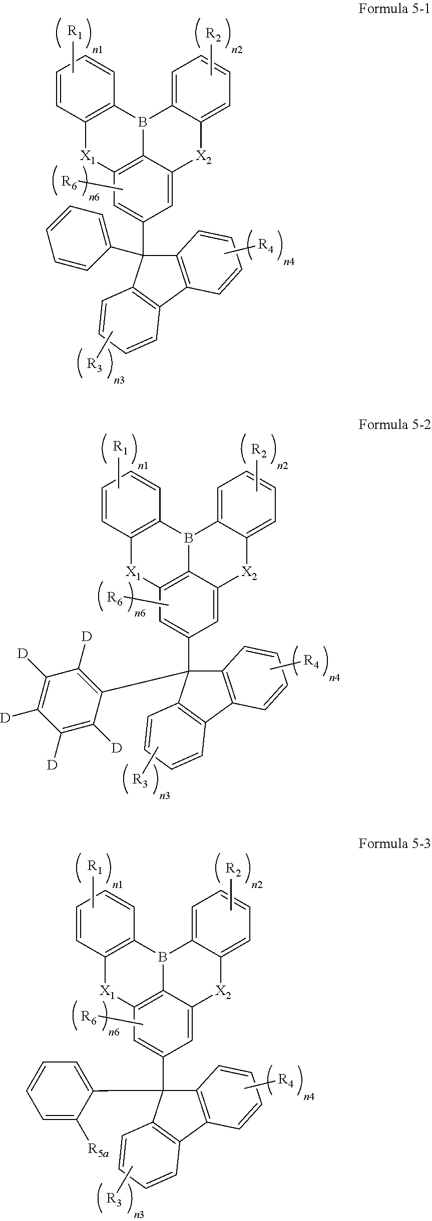

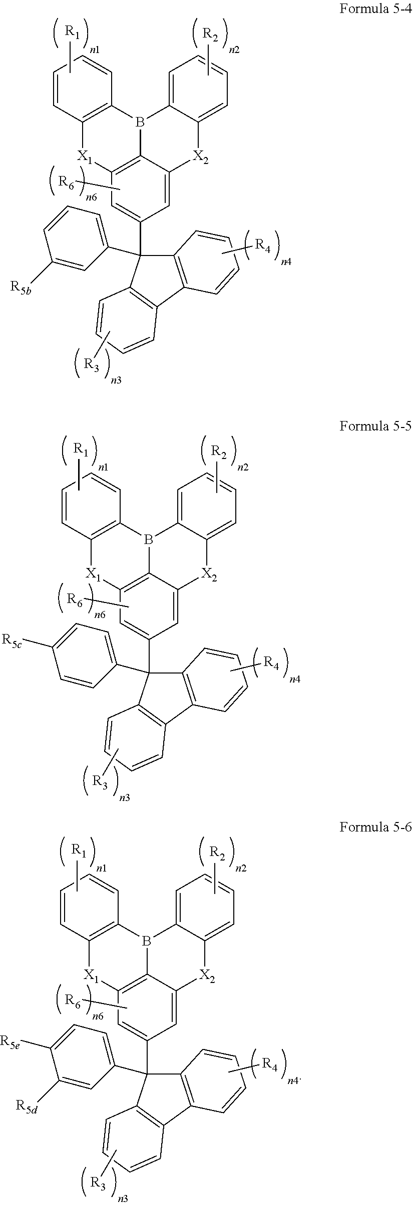

Formula 5-1 to Formula 5-6 represent the cases where types (kinds) and substituted positions of substituents substituted to the additional phenyl group which is linked at carbon 9 of the fluorene moiety that is the first substituent in the fused polycyclic compound of an embodiment are specified. For example, Formula 5-1 to Formula 5-6 represent the cases where a type or kind and substituted position of R₅ in Formula 1 are specified.

In Formula 5-1 to Formula 5-6, D represents a deuterium atom.

In Formula 5-1 to Formula 5-6, R₅ₐ, R_{5b}, and R_{5c} may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₅ₐ, R_{5b}, and R_{5c} may each independently be a deuterium atom, a fluorine atom, a cyano group, a substituted or unsubstituted methyl group, a substituted or unsubstituted ethyl group, a substituted or unsubstituted isopropyl group, a substituted or unsubstituted t-butyl group, a substituted or unsubstituted phenyl group, a substituted or unsubstituted biphenyl group, a substituted or unsubstituted terphenyl group, a substituted or unsubstituted carbazole group, or a substituted or unsubstituted dibenzofuran group.

In Formula 5-1 to Formula 5-6, R_{5d} and R₅ₑ may each independently be a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R_{5d} and R₅ₑ may be bonded to an adjacent group to form a ring. For example, R_{5d} and R₅ₑ may each independently be a deuterium atom, a cyano group, a substituted or unsubstituted oxy group, a substituted or unsubstituted methyl group, a substituted or unsubstituted vinyl group, a substituted or unsubstituted t-butyl group, or a substituted or unsubstituted phenyl group. In some embodiments, each of R_{5d} and R₅ₑ may be bonded to an adjacent group to form an aromatic ring. In some embodiments, R_{5d} and R₅ₑ may be bonded to each other to form an aromatic hydrocarbon ring or an aromatic heterocycle.

In Formula 5-1 to Formula 5-6, the same as described in Formula 1 above may be applied to X₁, X₂, R₁ to R₄, R₆, n1 to n4, and n6.

The fused polycyclic compound of an embodiment may be any one selected from among the compounds represented by Compound Group 1. The light emitting device ED of an embodiment may include at least one fused polycyclic compound selected from among the compounds represented by Compound Group 1 in the emission layer EML.

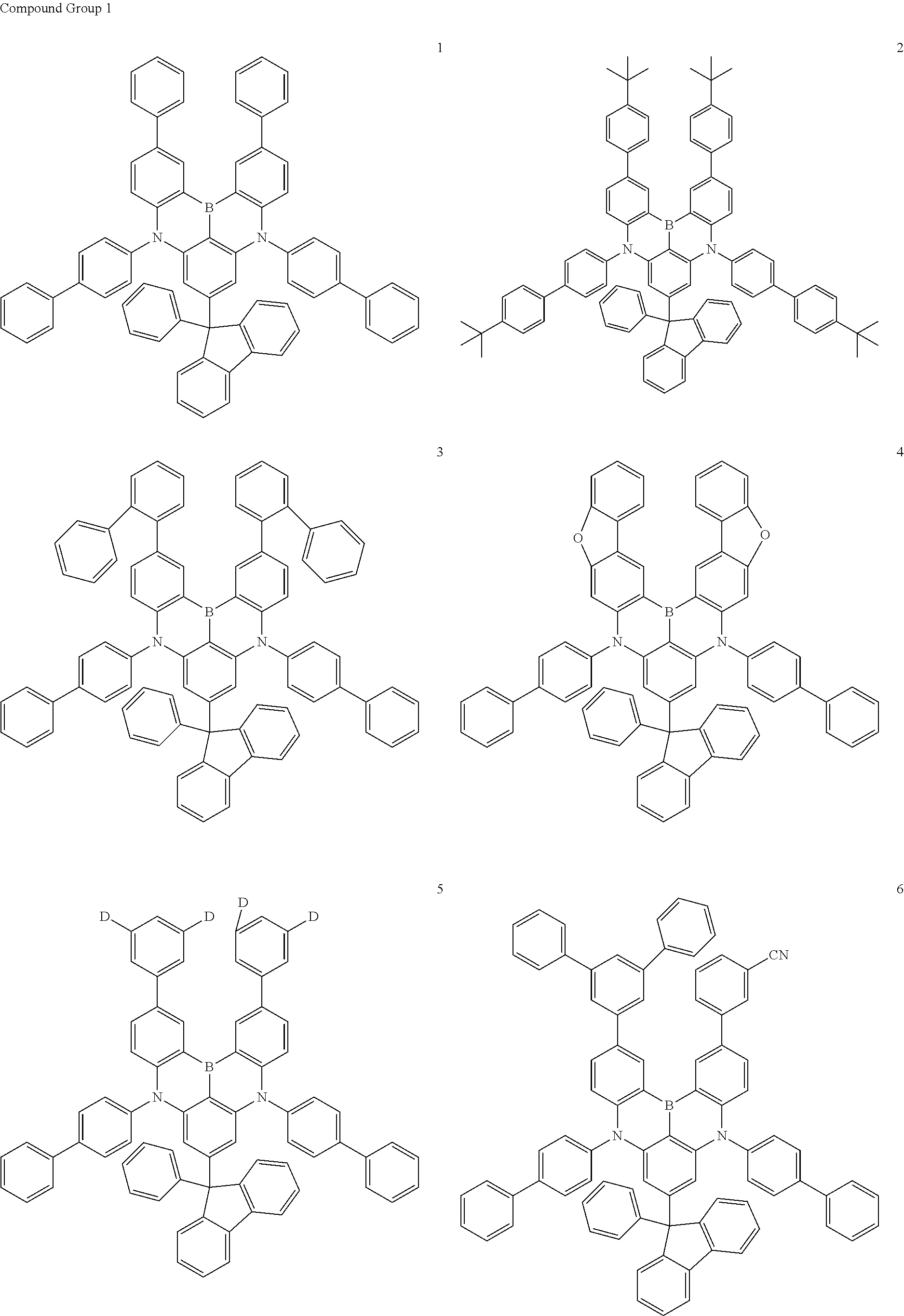

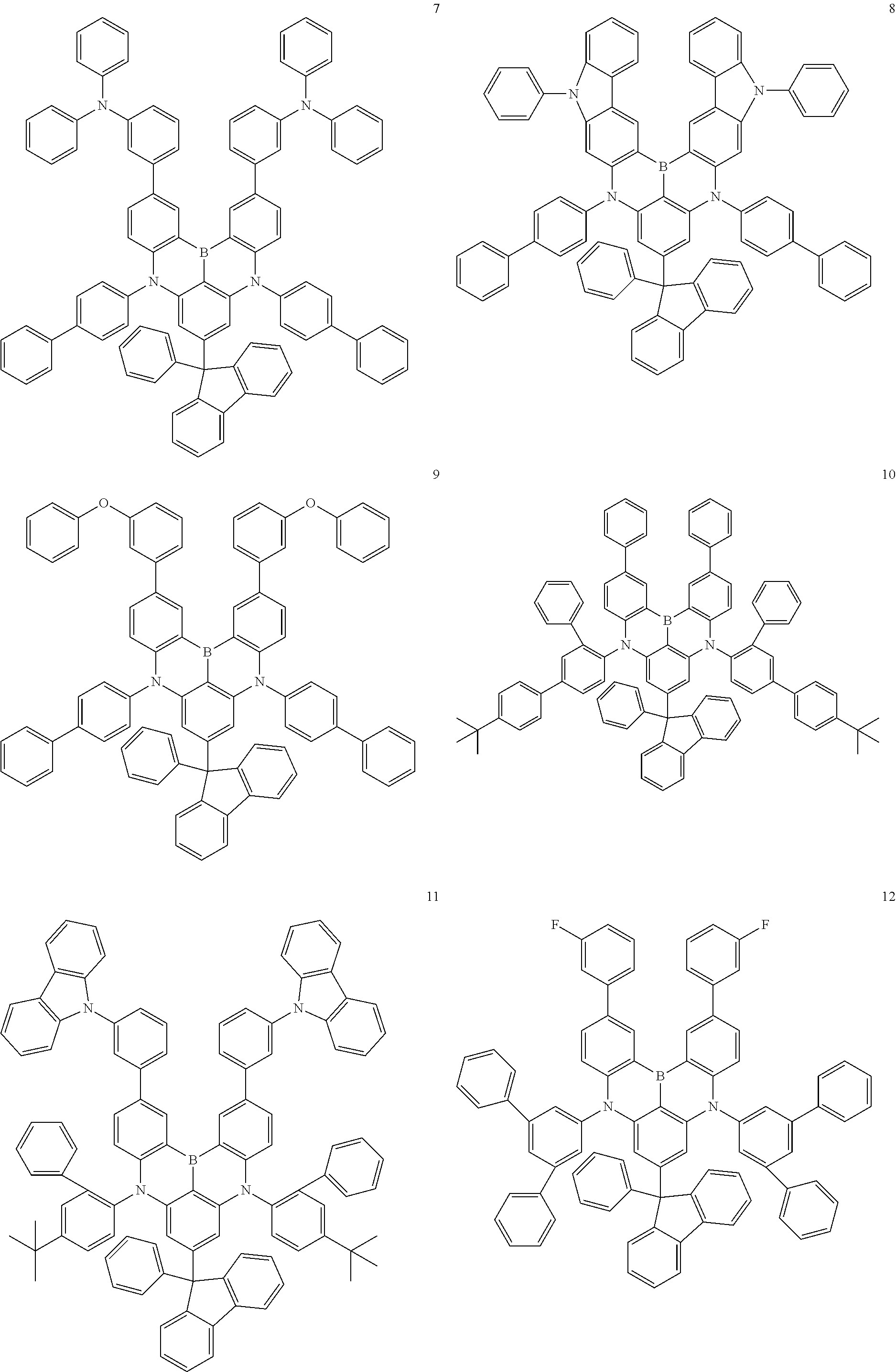

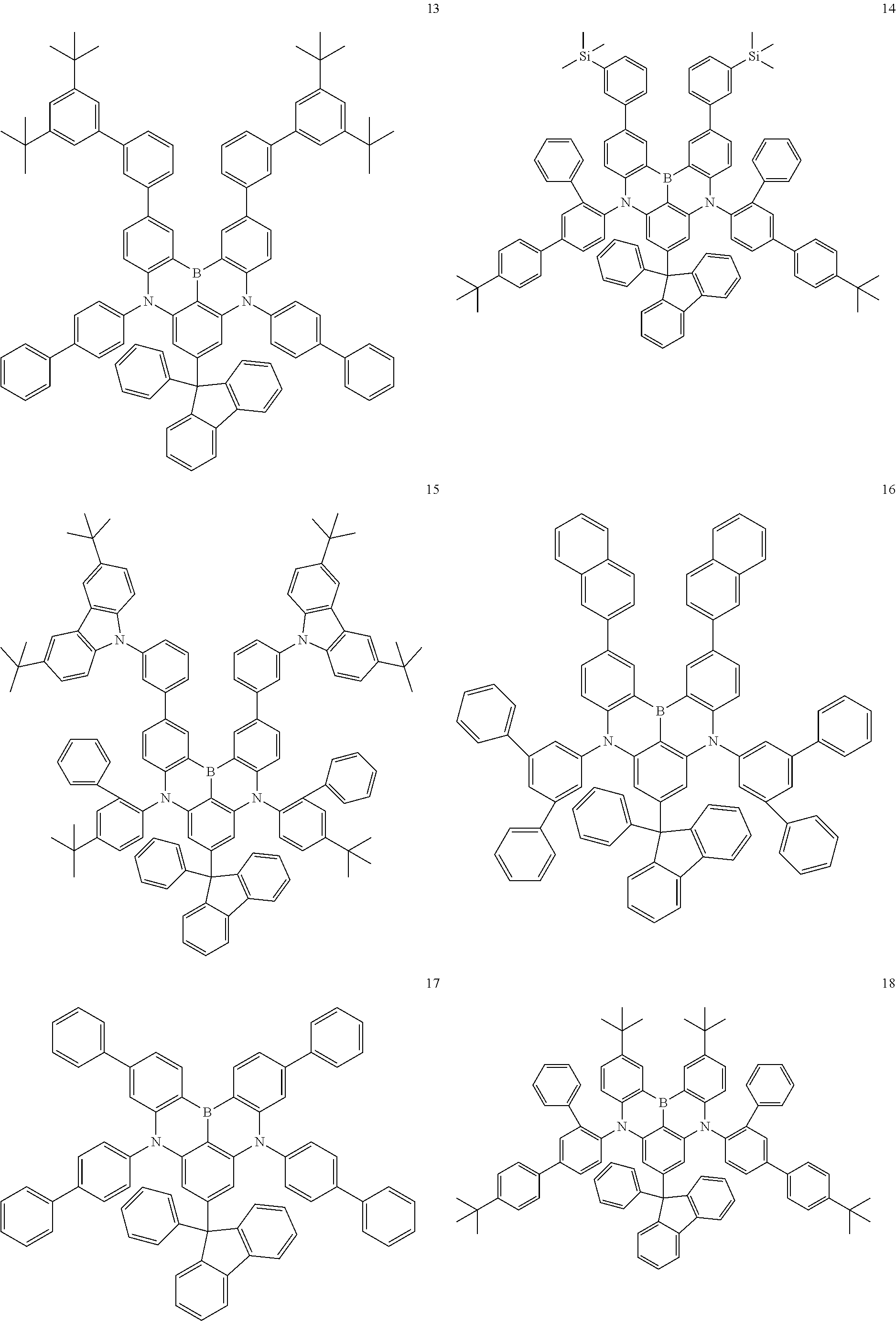

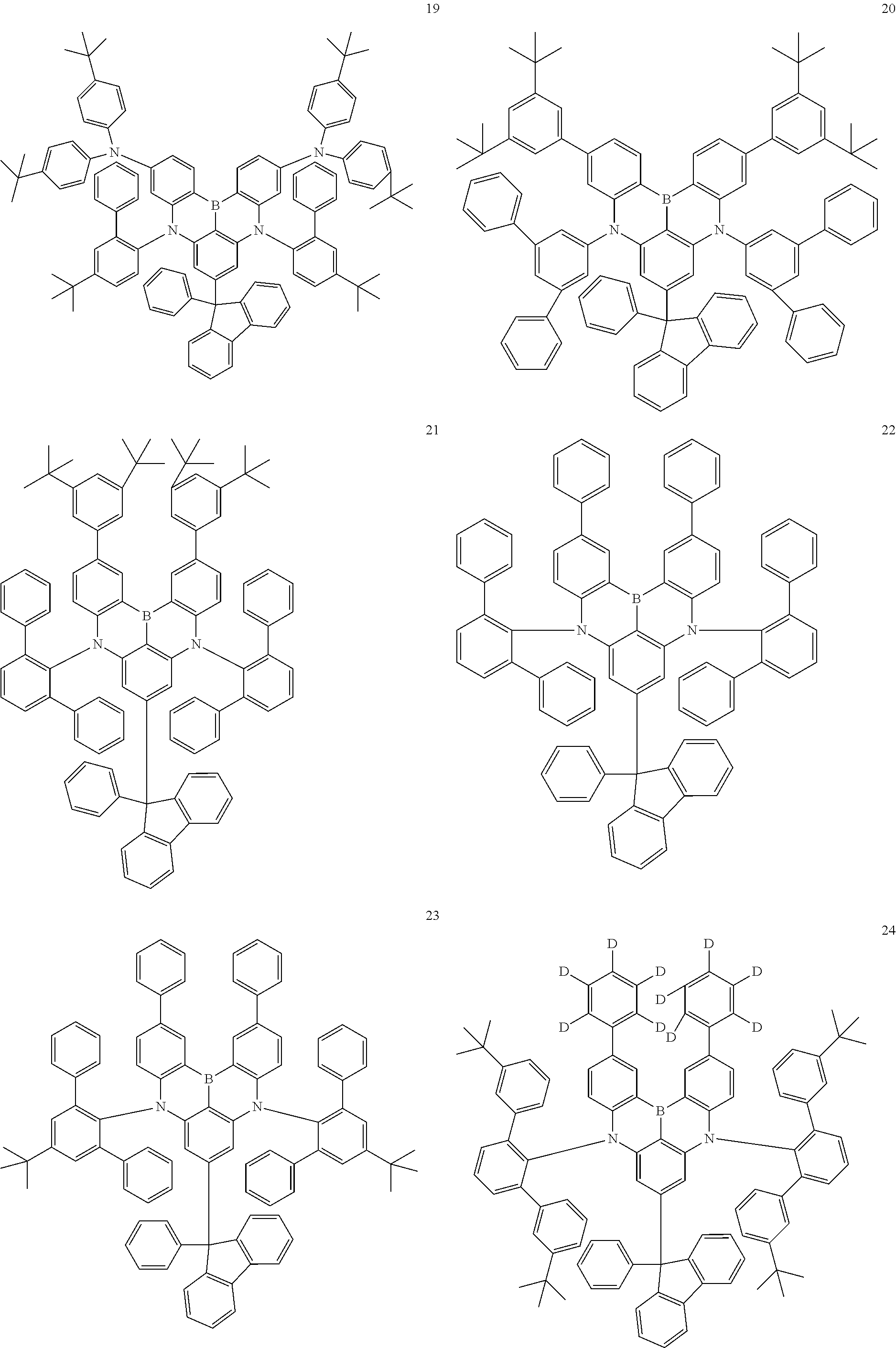

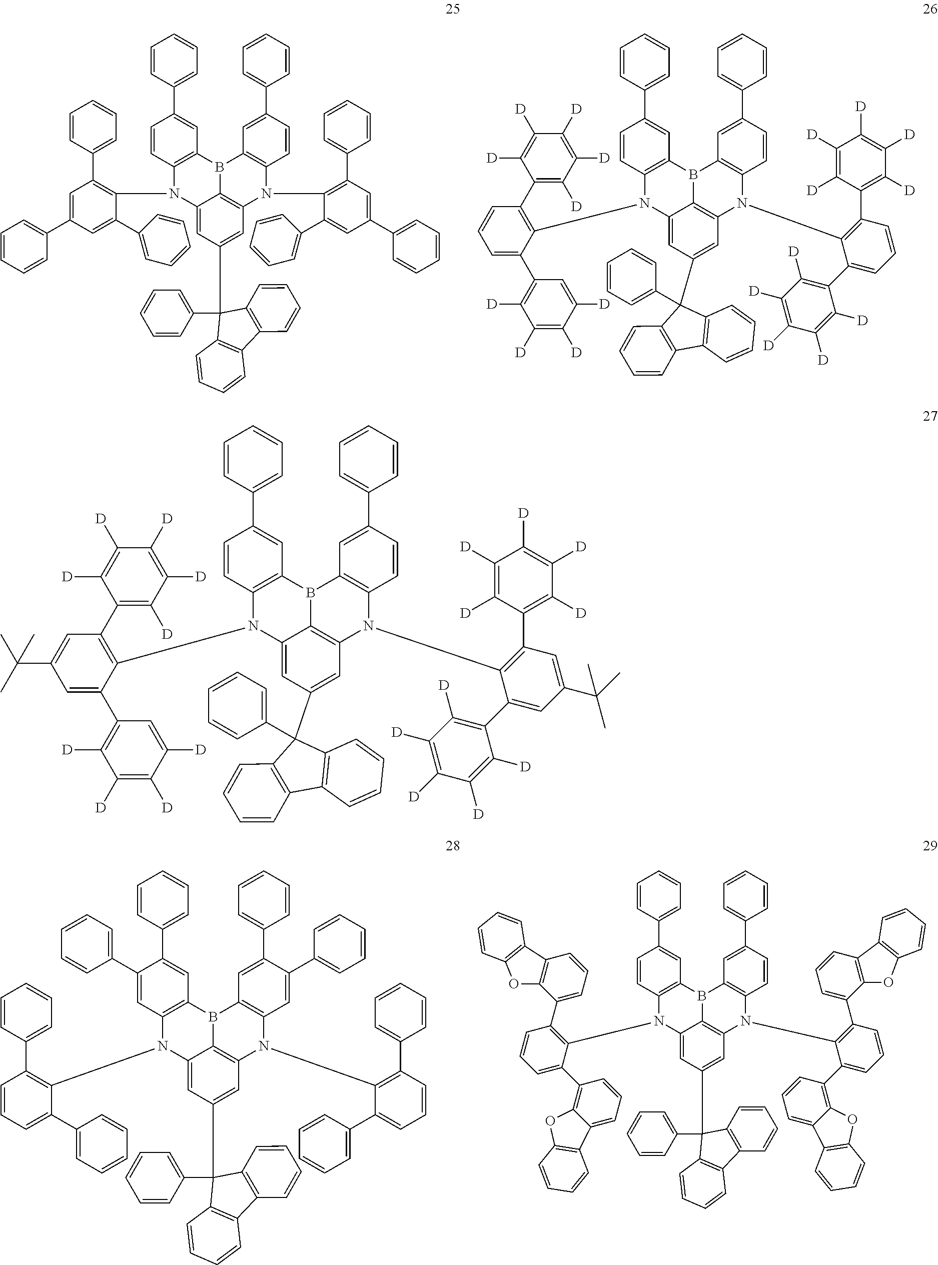

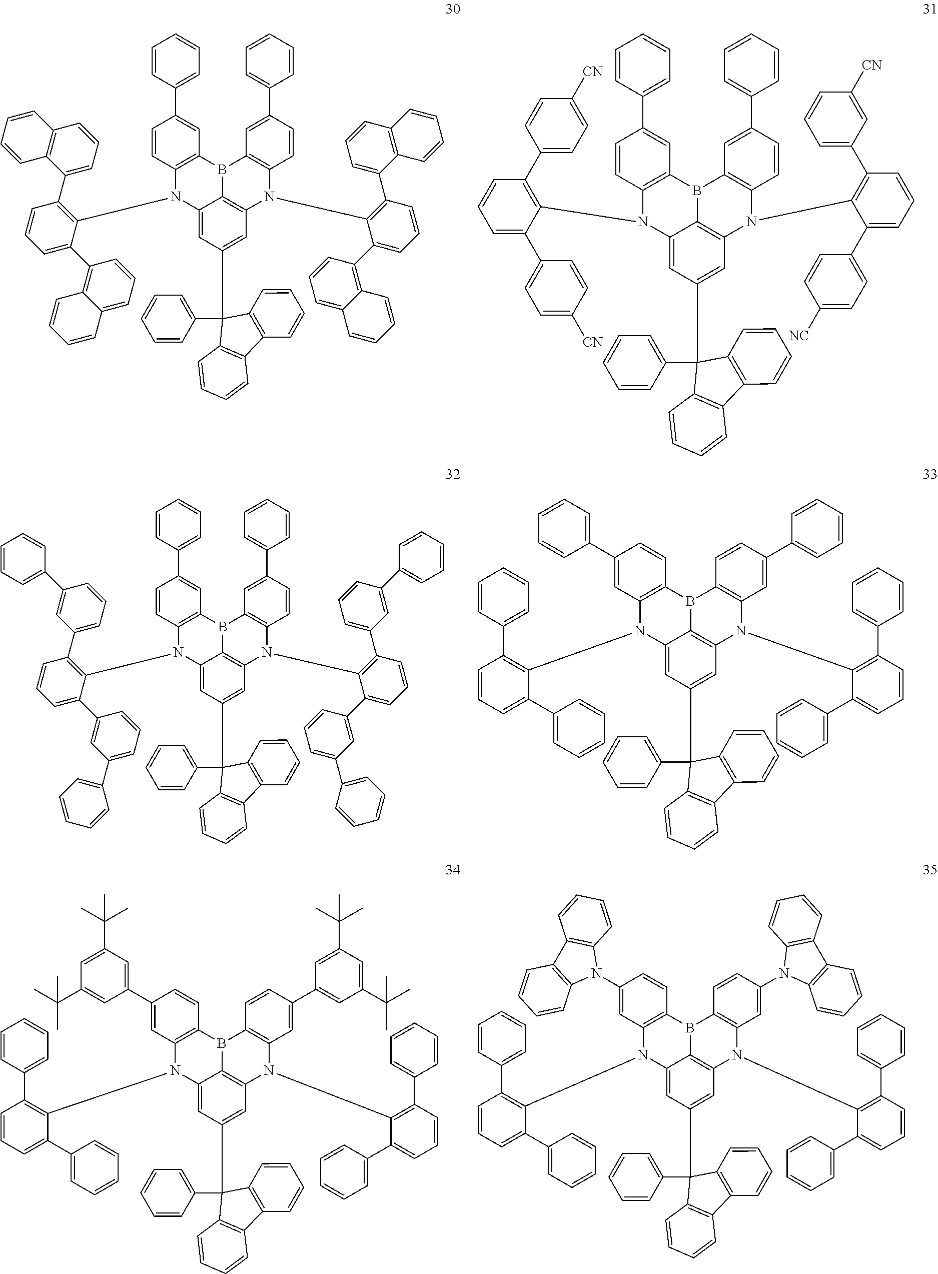

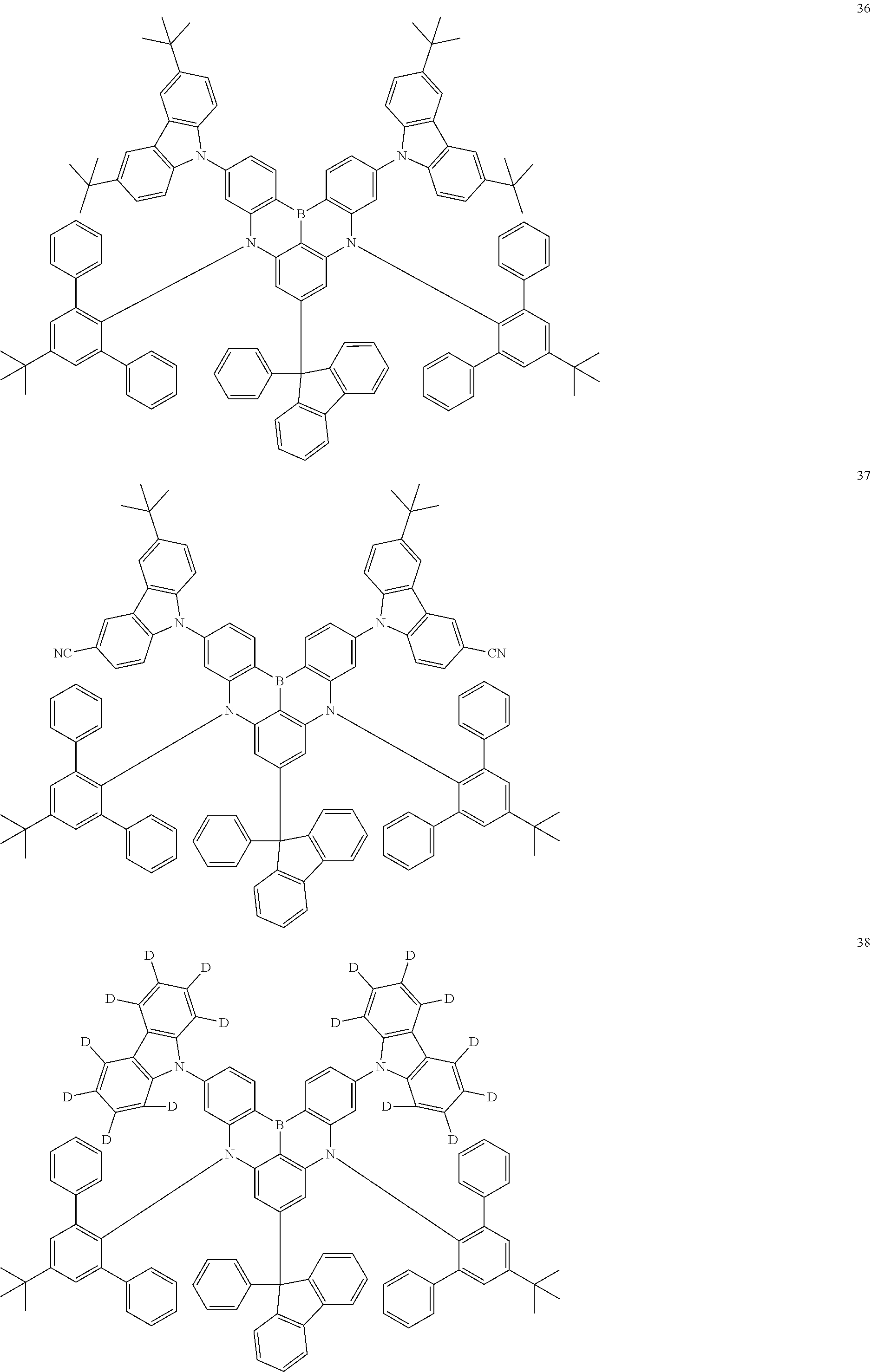

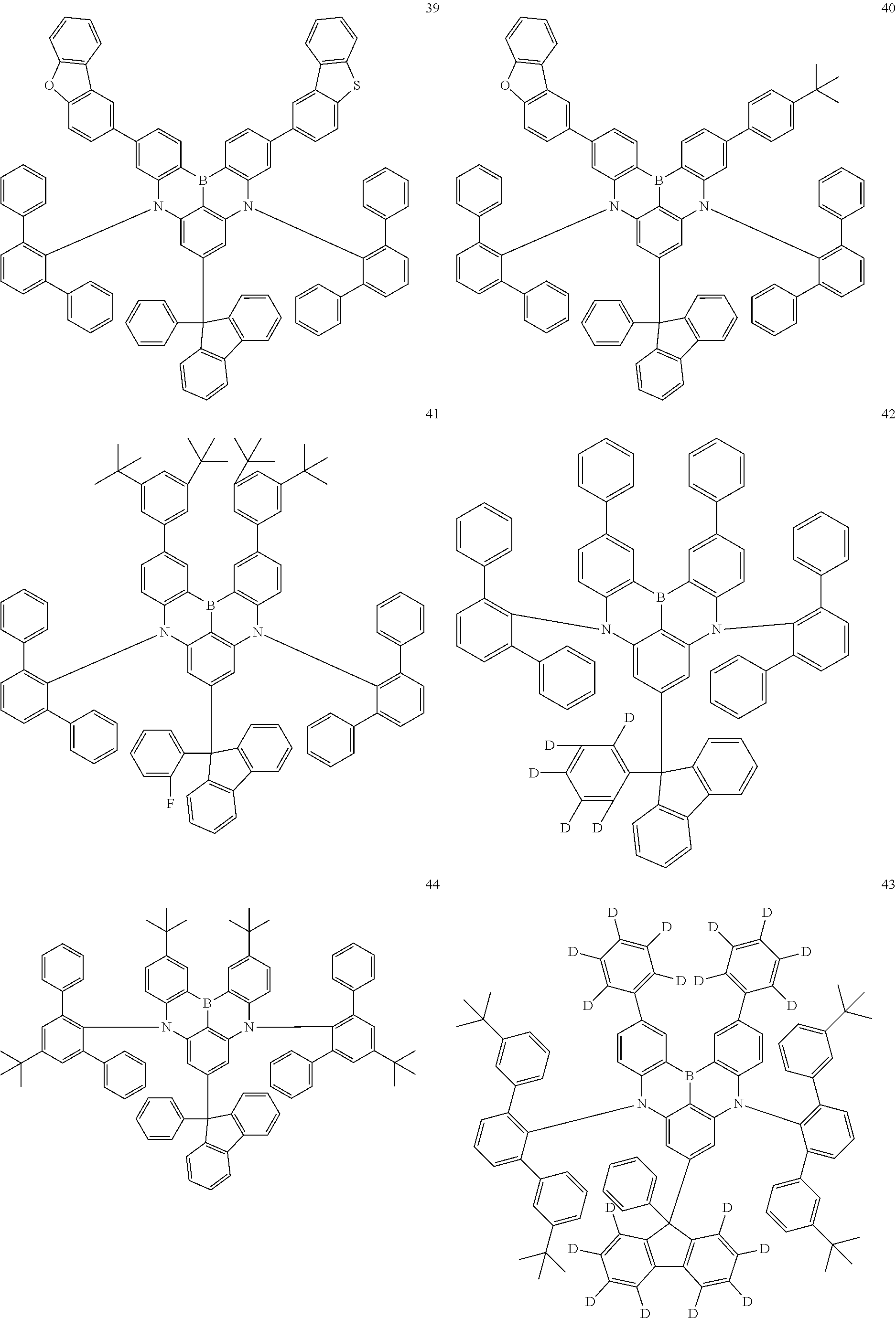

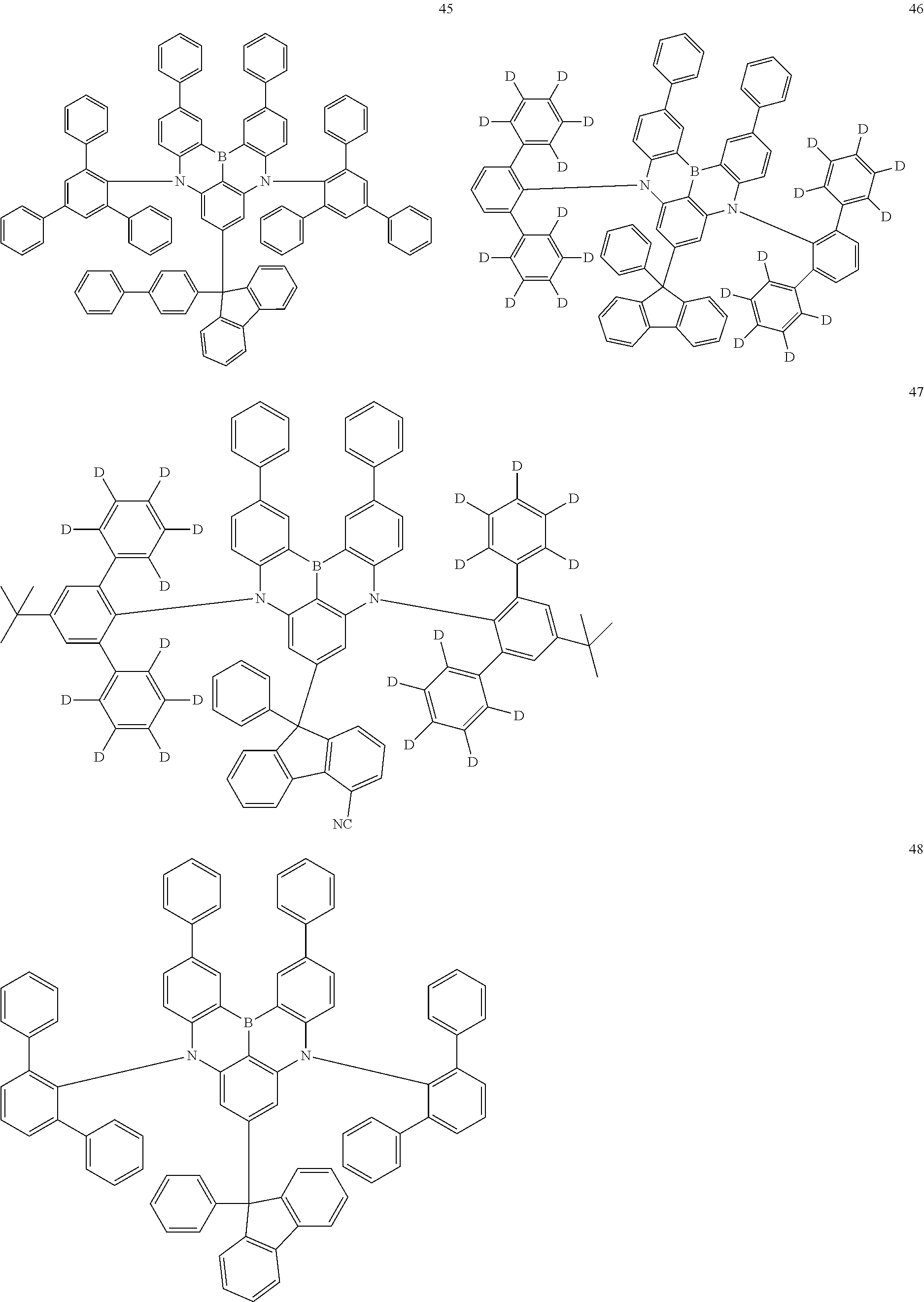

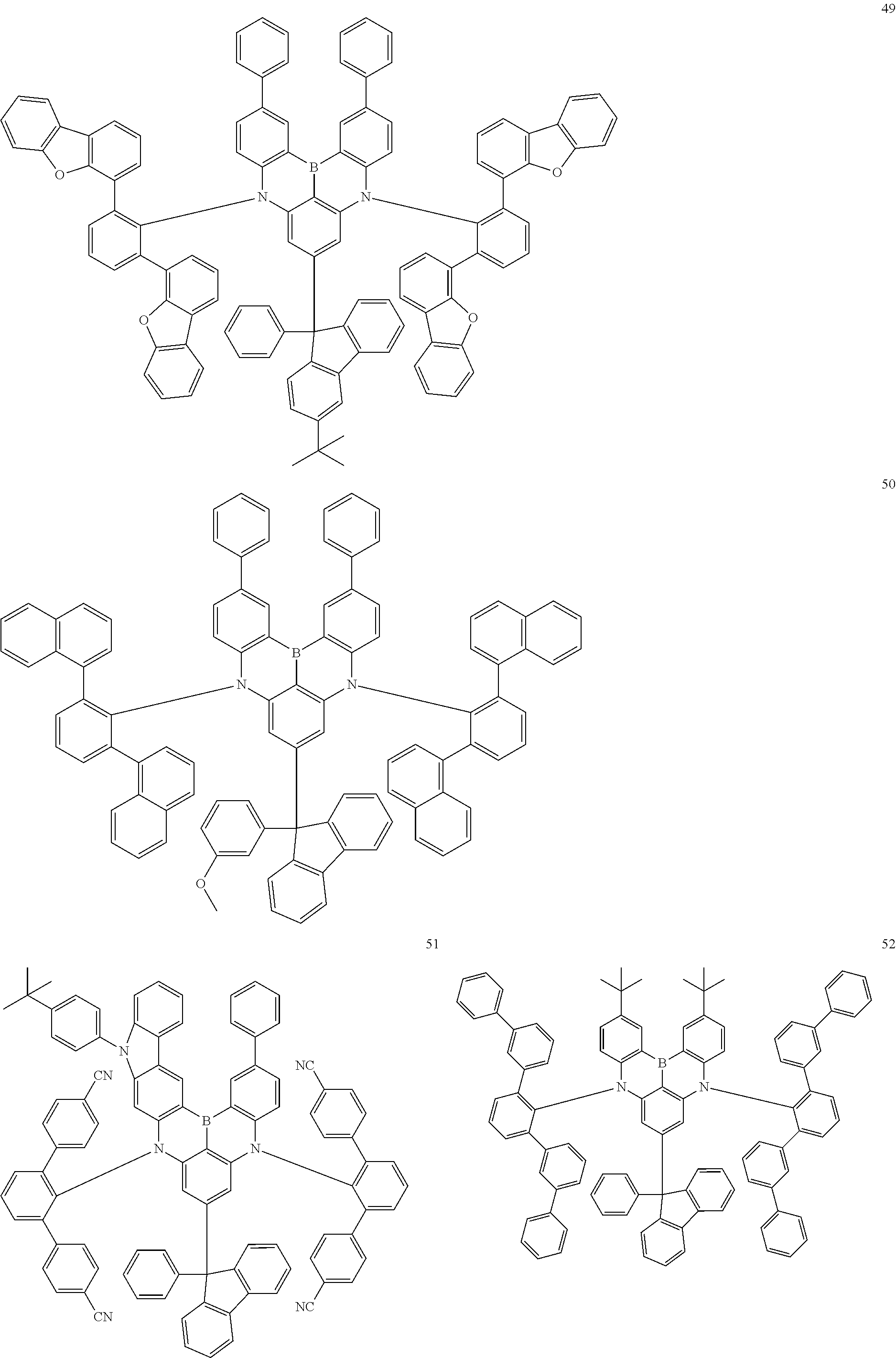

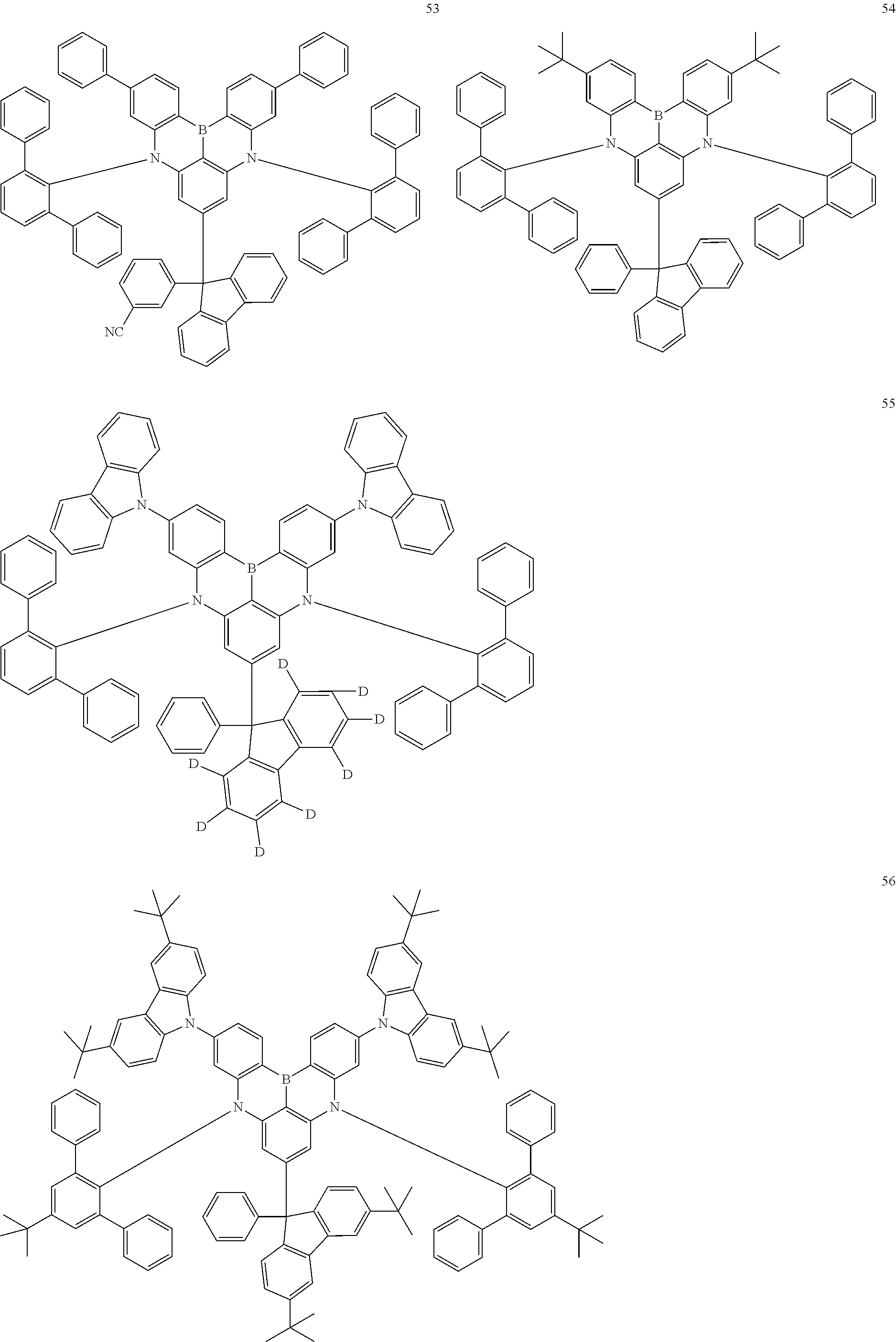

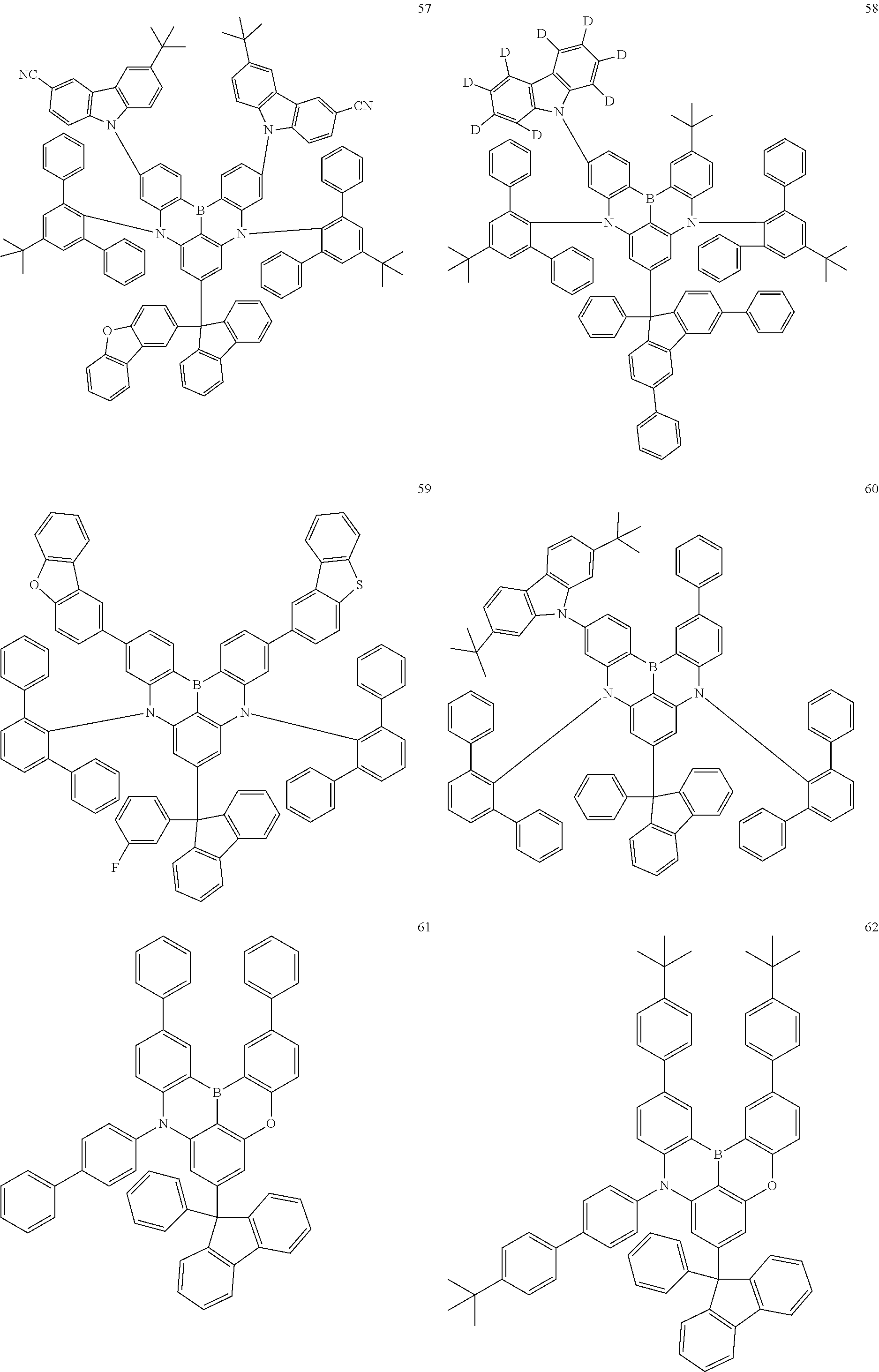

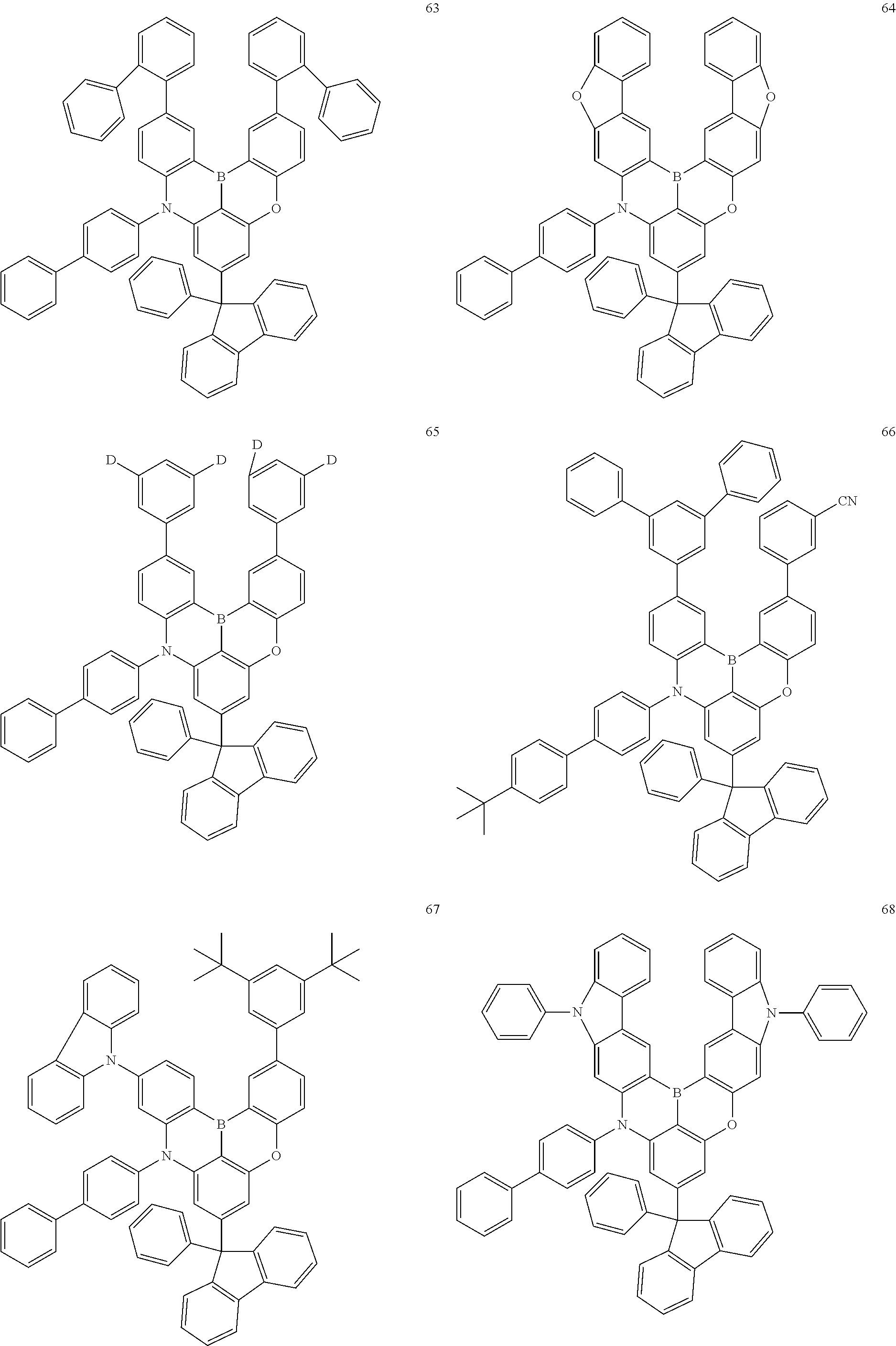

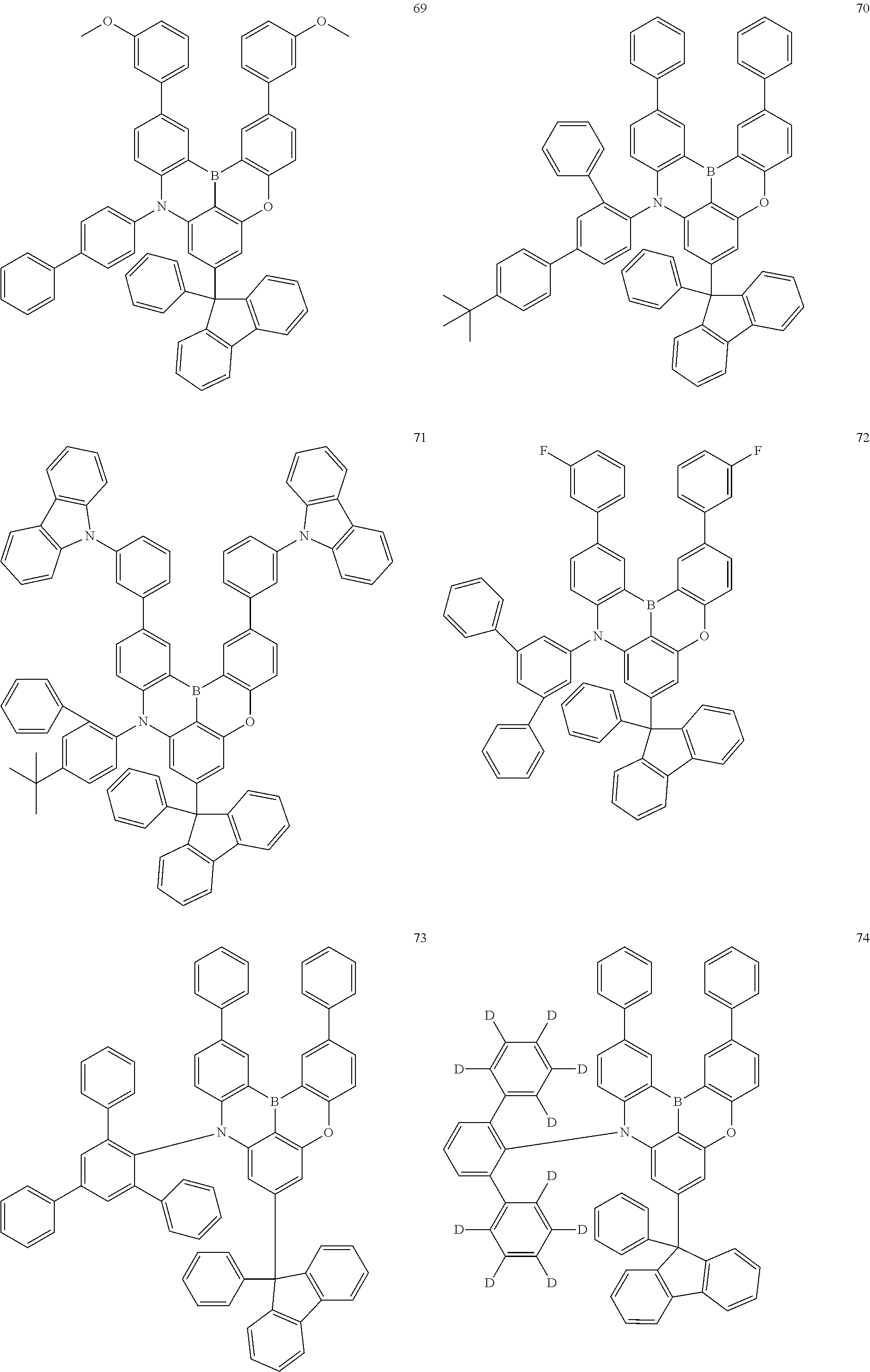

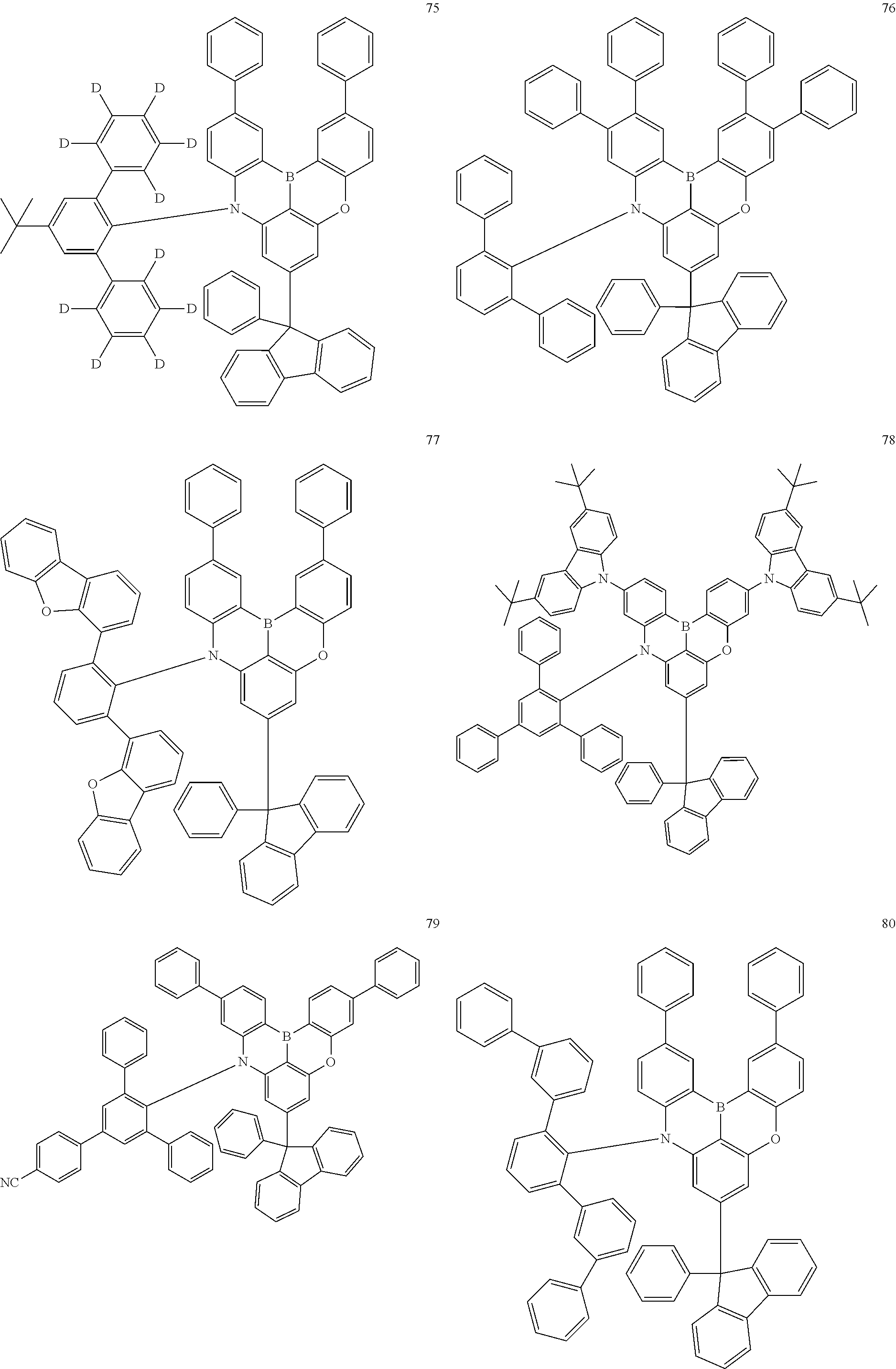

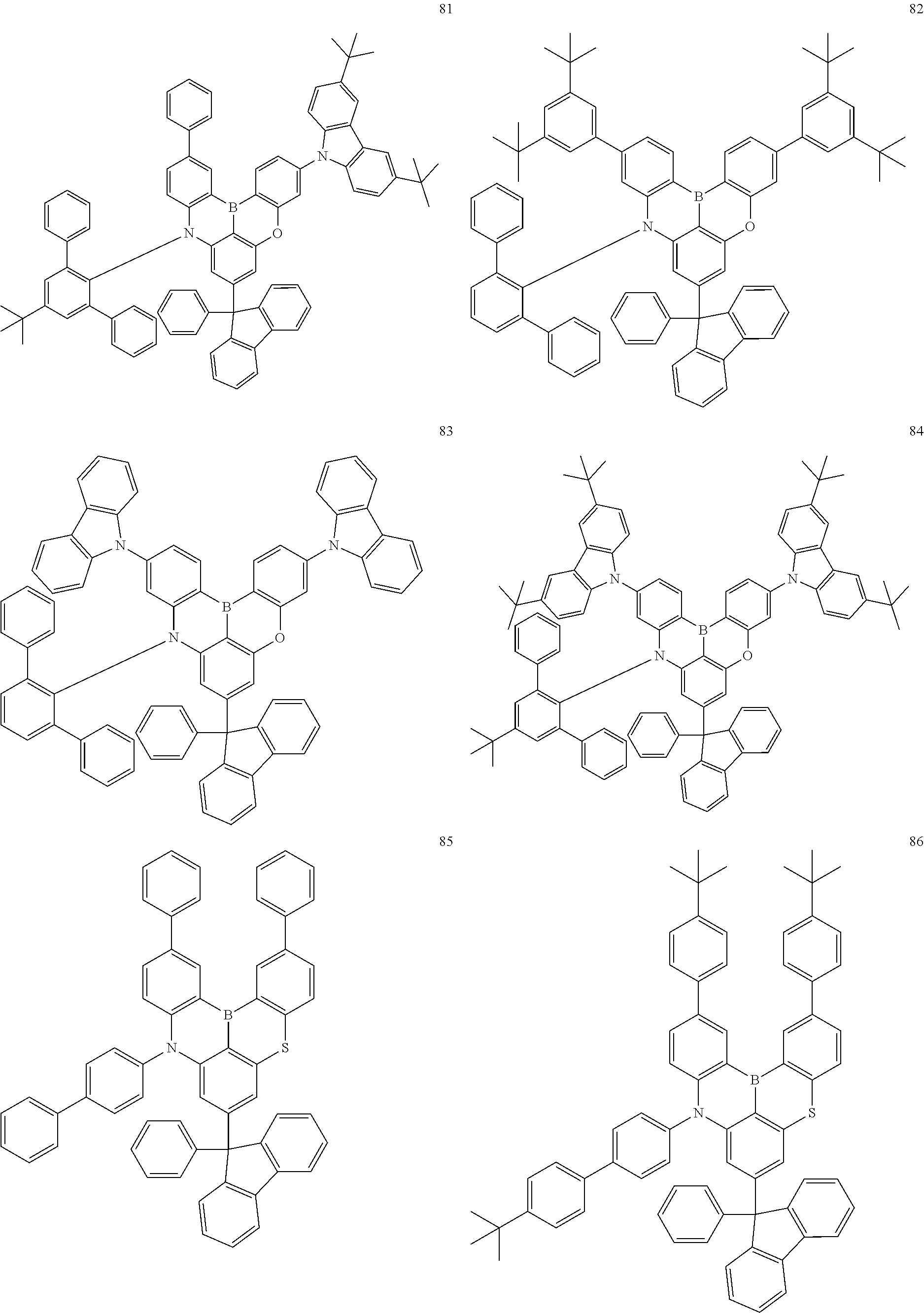

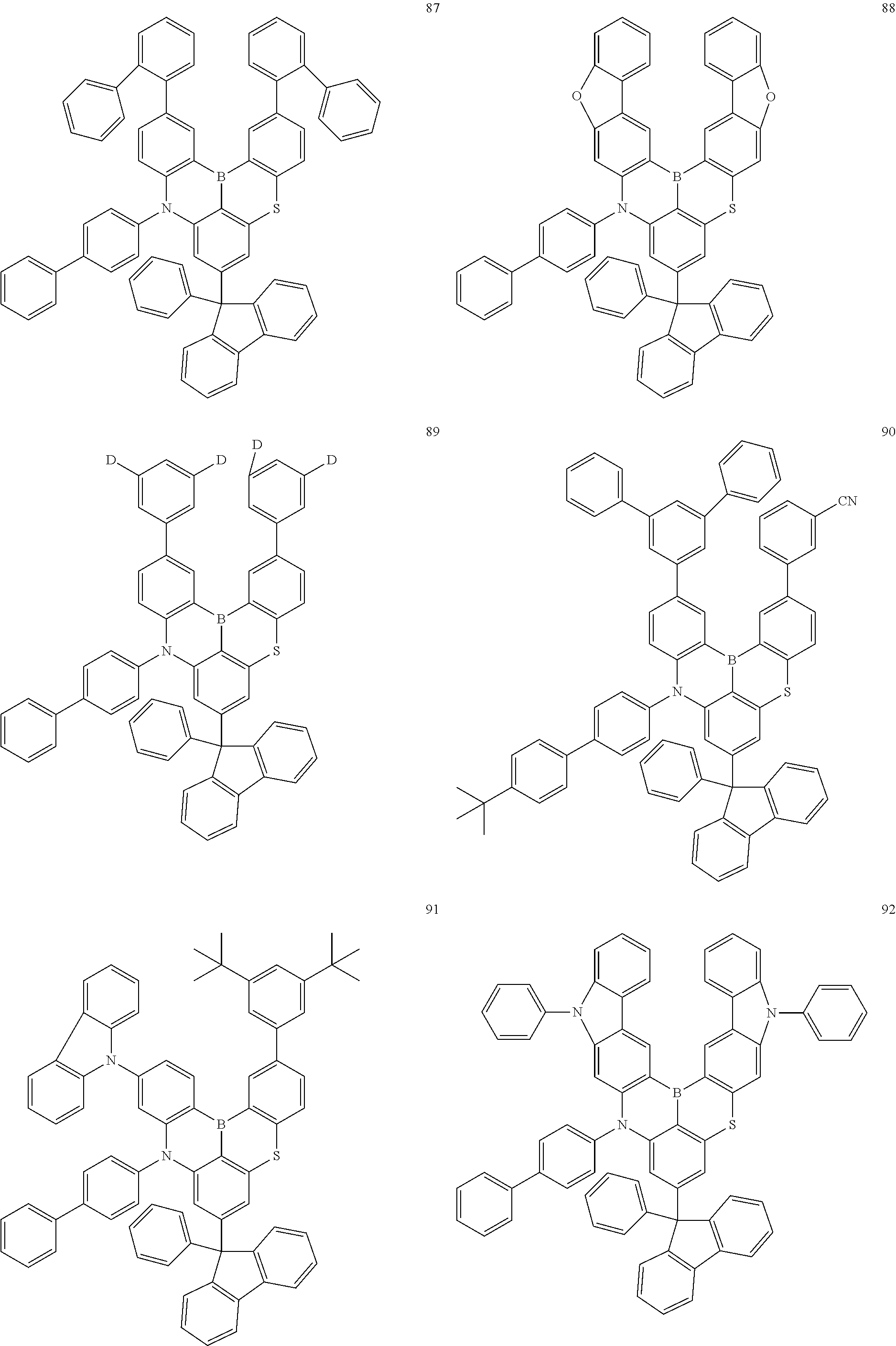

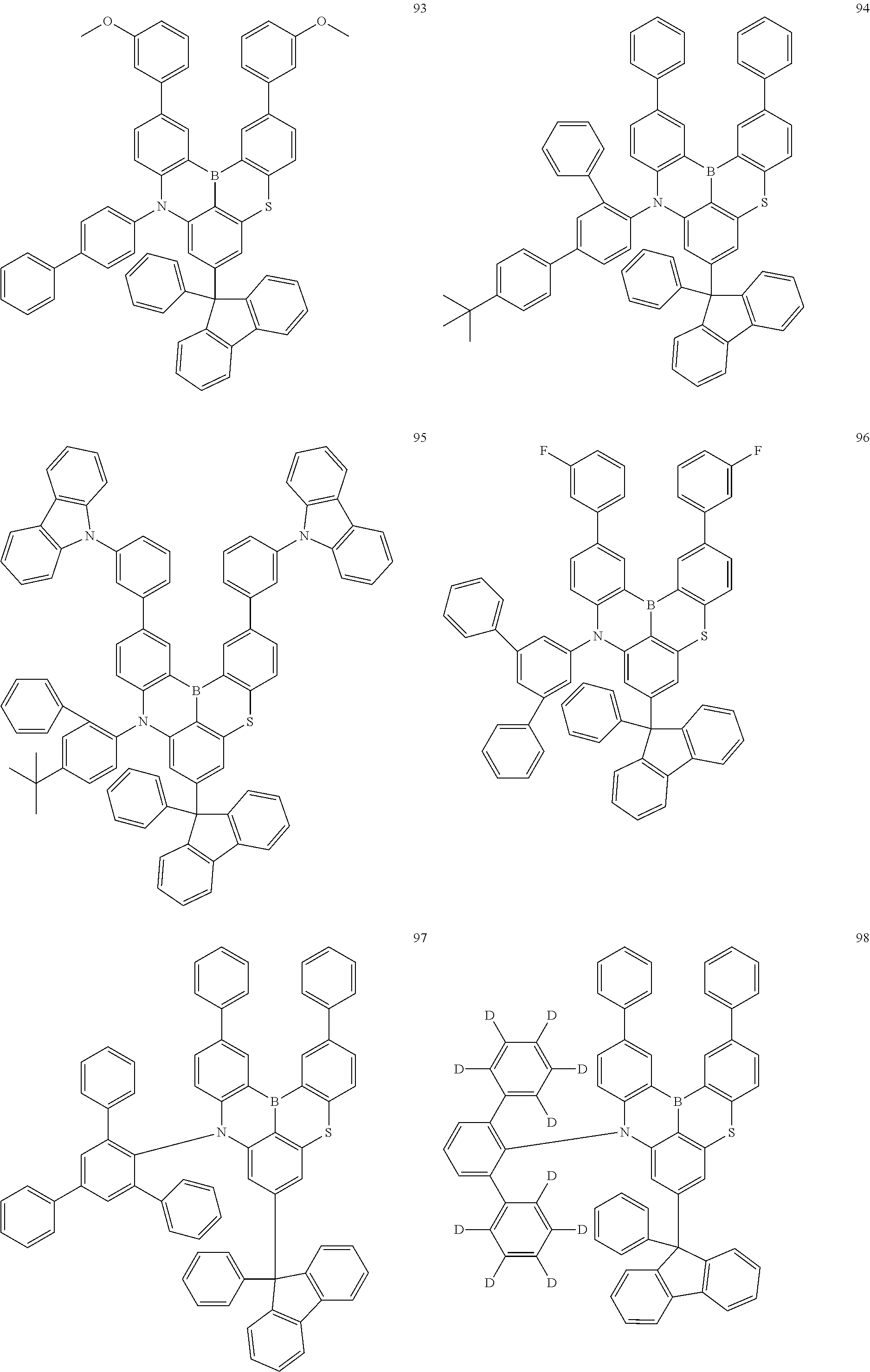

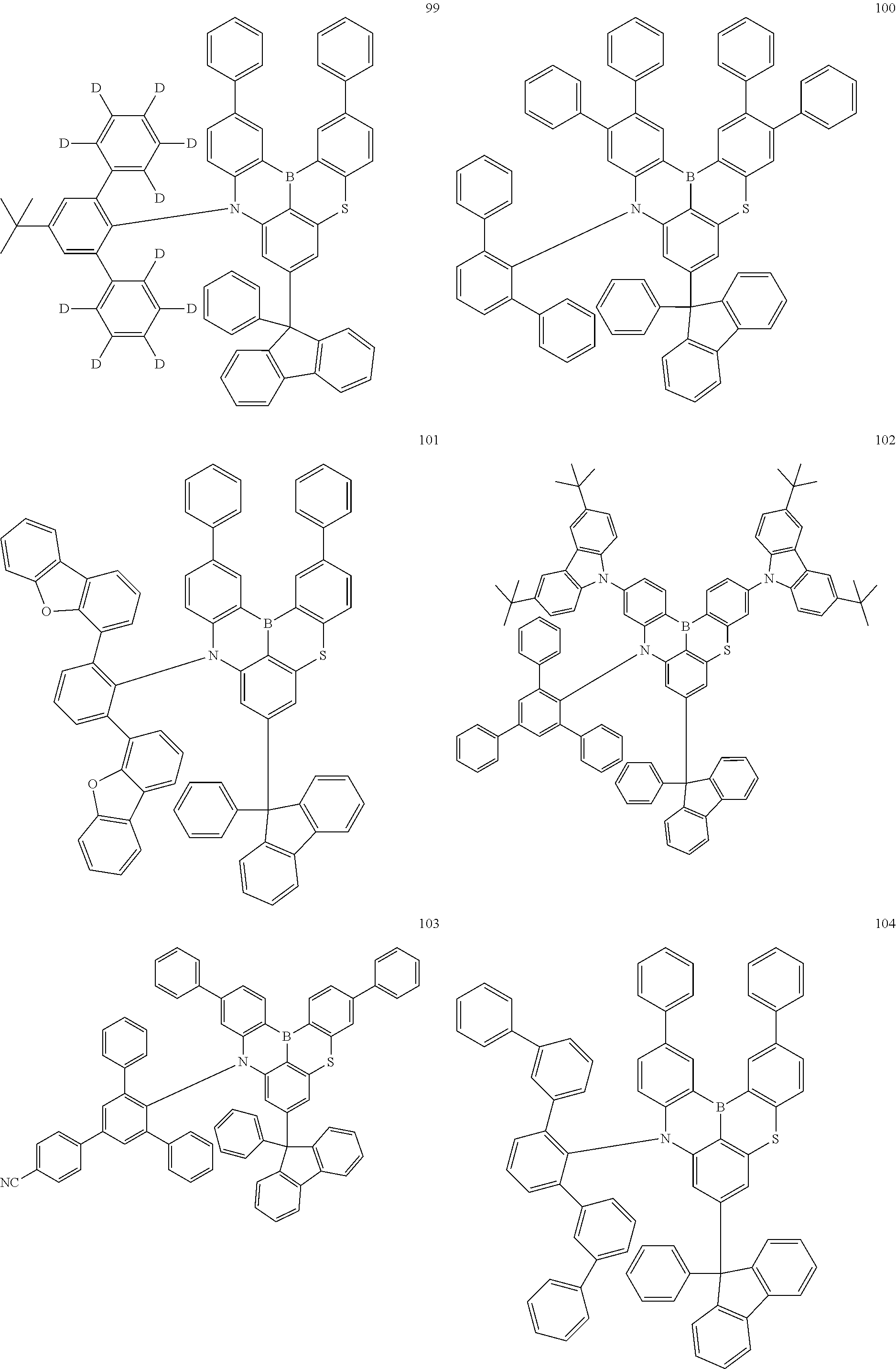

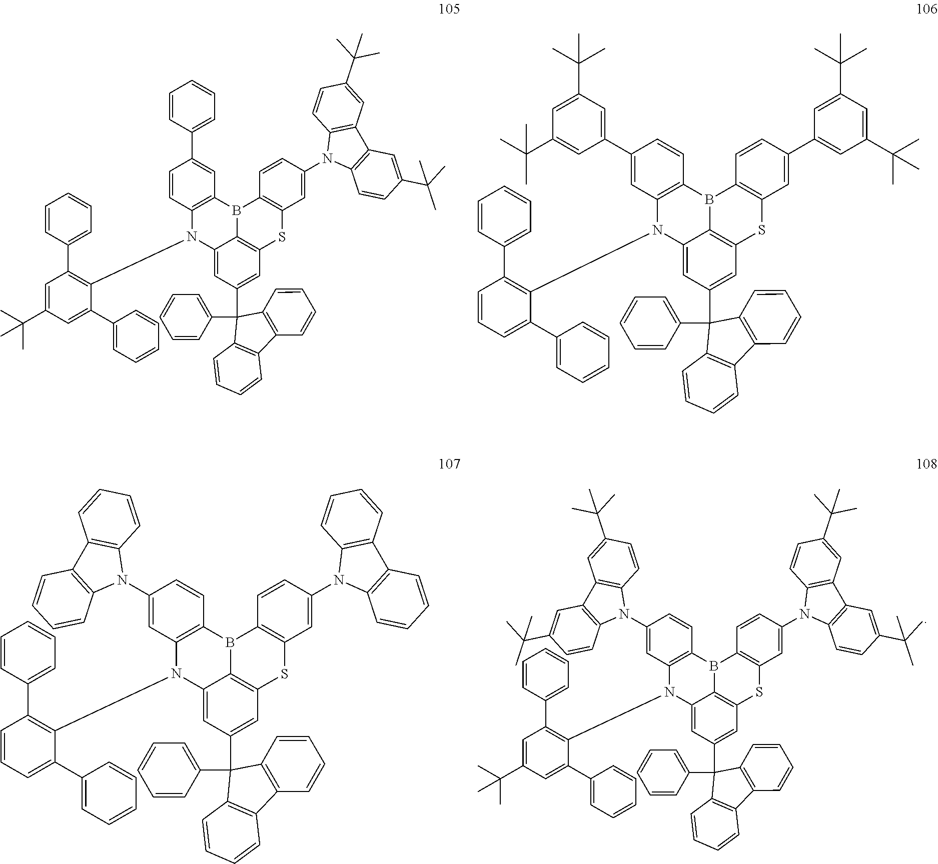

In the embodiment compounds presented in Compound Group 1, “D” represents a deuterium atom.

The fused polycyclic compound represented by Formula 1 according to an embodiment includes the first substituent that is a steric hindrance substituent, and thus high luminous efficiency and long service life may be achieved.

The fused polycyclic compound of an embodiment has a structure in which the first to third aromatic rings are fused by one boron atom, the first heteroatom, and the second heteroatom, and necessarily includes, as a substituent, the first substituent which is bonded at the para-position with the boron atom. The first substituent may have a fluorene moiety, and may be bonded to the core structure of the fused polycyclic compound of an embodiment at carbon 9 of the fluorene moiety, and a substituted or unsubstituted phenyl group may be additionally bonded at carbon 9. The fused polycyclic compound of an embodiment having such a structure may effectively maintain a trigonal planar structure of the boron atom through the steric hindrance effect due to the first substituent. The boron atom may have electron deficiency characteristics by an empty p-orbital, thereby form a bond with other nucleophiles, and thus be changed into a tetrahedral structure, which may cause deterioration of the device. According to the present disclosure, the fused polycyclic compound represented by Formula 1 includes the first substituent and the second substituent having the steric hindrance structure, thereby may effectively protect the empty p-orbital of the boron atom, and thus may prevent or reduce the deterioration phenomenon due to the structural change.

In some embodiments, the fused polycyclic compound of an embodiment may have an increase in the luminous efficiency because the intermolecular interaction may be suppressed or reduced by the introduction of the first substituent, thereby controlling the formation of excimer or exciplex. The fused polycyclic compound represented by Formula 1 of an embodiment includes the first substituent, and thus the dihedral angle between the plane containing the fused ring core structure having the boron atom at the center and the plane containing the first substituent may be increased. For example, a first dihedral angle between a first plane containing the first to third aromatic rings and a second plane containing the first substituent may be increased. Thus, the intermolecular distance increases so that there is an effect of reducing Dexter energy transfer. The Dexter energy transfer is a phenomenon, in which a triplet exciton moves between molecules, and increases when the intermolecular distance is short, and may become a factor that increases a quenching phenomenon due to the increase of triplet concentration. According to the present disclosure, the fused polycyclic compound of an embodiment has an increase in the distance between adjacent molecules due to the large steric hindrance structure to thereby suppress or reduce the Dexter energy transfer, and thus may suppress or reduce the deterioration of service life due to the increase of triplet concentration. Therefore, when the fused polycyclic compound of an embodiment is applied to (e.g., utilized in) the emission layer EML of the light emitting device ED, the luminous efficiency may be increased and the device service life may also be improved. The fused polycyclic compound of an embodiment may have a decrease in the difference (ΔEst) between a lowest triplet exciton energy level (T1 level) and a lowest singlet exciton energy level (S1 level) by the structure described above, and accordingly, when the fused polycyclic compound is utilized as a material for emitting delayed fluorescence, luminous efficiency of the light emitting device may be improved.

In some embodiments, the fused polycyclic compound of an embodiment may be included in the emission layer EML. The fused polycyclic compound of an embodiment may be included as a dopant material in the emission layer EML. The fused polycyclic compound of an embodiment may be a thermally activated delayed fluorescence material. The fused polycyclic compound of an embodiment may be utilized as a thermally activated delayed fluorescence dopant. For example, in the light emitting device ED of an embodiment, the emission layer EML may include, as a thermally activated delayed fluorescence dopant, at least one selected from among the fused polycyclic compounds represented by Compound Group 1 as described above. However, a usage of the fused polycyclic compound of an embodiment is not limited thereto.

In an embodiment, the emission layer EML may include a plurality of compounds. The emission layer EML of an embodiment may include the fused polycyclic compound represented by Formula 1, i.e., the first compound, and at least one of the second compound represented by Formula H-1, the third compound represented by Formula H-2, or the fourth compound represented by Formula D-1:

In an embodiment, the second compound may be utilized as a hole transporting host material of the emission layer EML.

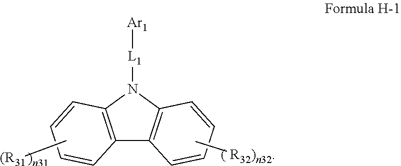

In Formula H-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but the embodiment of the present disclosure is not limited thereto.

In Formula H-1, An may be a substituted or unsubstituted aryl group having 6 to 30 ring-forming carbon atoms, or a substituted or unsubstituted heteroaryl group having 2 to 30 ring-forming carbon atoms. For example, An may be a substituted or unsubstituted carbazole group, a substituted or unsubstituted dibenzofuran group, a substituted or unsubstituted dibenzothiophene group, a substituted or unsubstituted biphenyl group, etc., but the embodiment of the present disclosure is not limited thereto.

In Formula H-1, R₃₁ and R₃₂ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₃₁ and R₃₂ may be bonded to an adjacent group to form a ring. For example, R₃₁ and R₃₂ may each independently be a hydrogen atom or a deuterium atom.

In Formula H-1, n31 and n32 may each independently be an integer of 0 to 4. When each of n31 and n32 is 0, the fused polycyclic compound of an embodiment may not be substituted with each of R₃₁ and R₃₂. The case where each of n31 and n32 is 4 and R₃₁'s and R₃₂'s are each hydrogen atoms may be the same as the case where each of n31 and n32 is 0. When each of n31 and n32 is an integer of 2 or more, a plurality of R₃₁'s and R₃₂'s may each be the same or at least one selected from among the plurality of R₃₁'s and R₃₂'s may be different from the others.

In an embodiment, the second compound represented by Formula 2 may be represented by any one selected from among the compounds represented by Compound Group 2. The emission layer EML may include at least one selected from among the compounds represented by Compound Group 2 as a hole transporting host material.

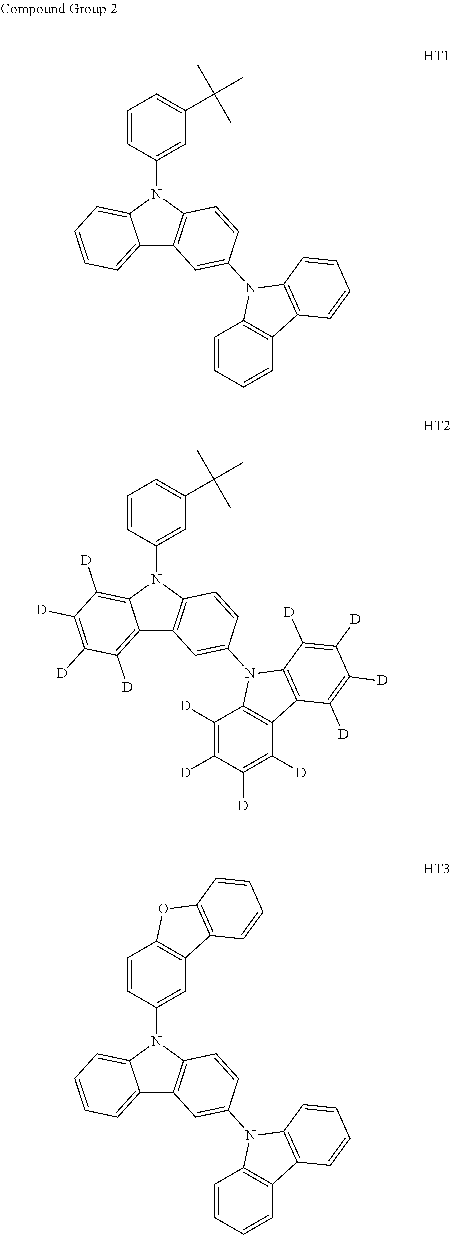 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

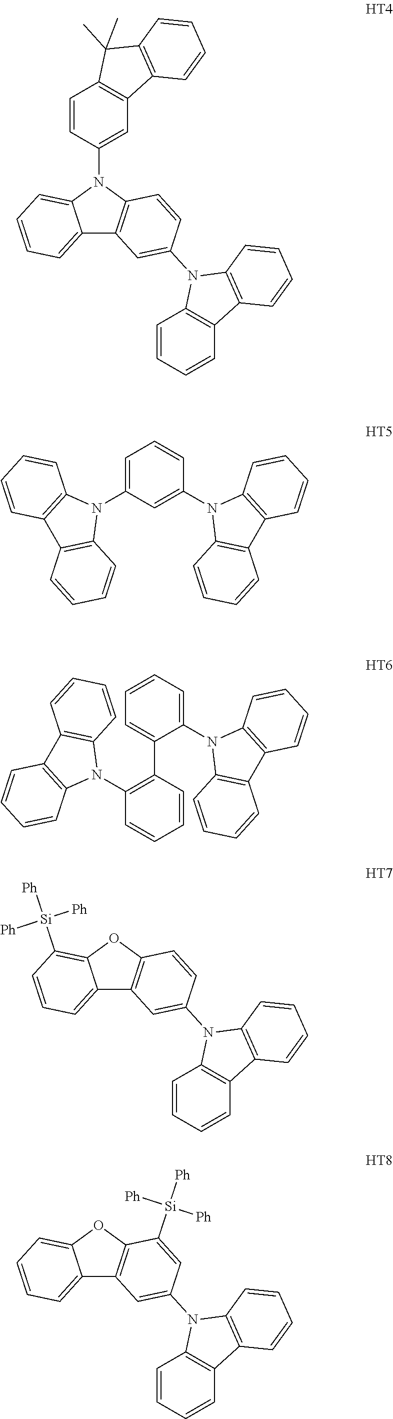 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

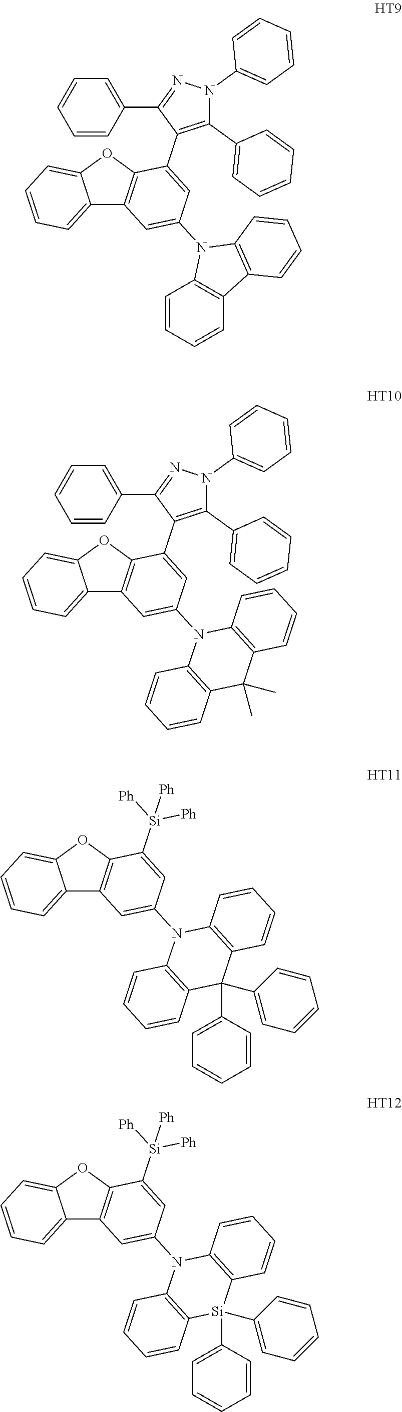 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

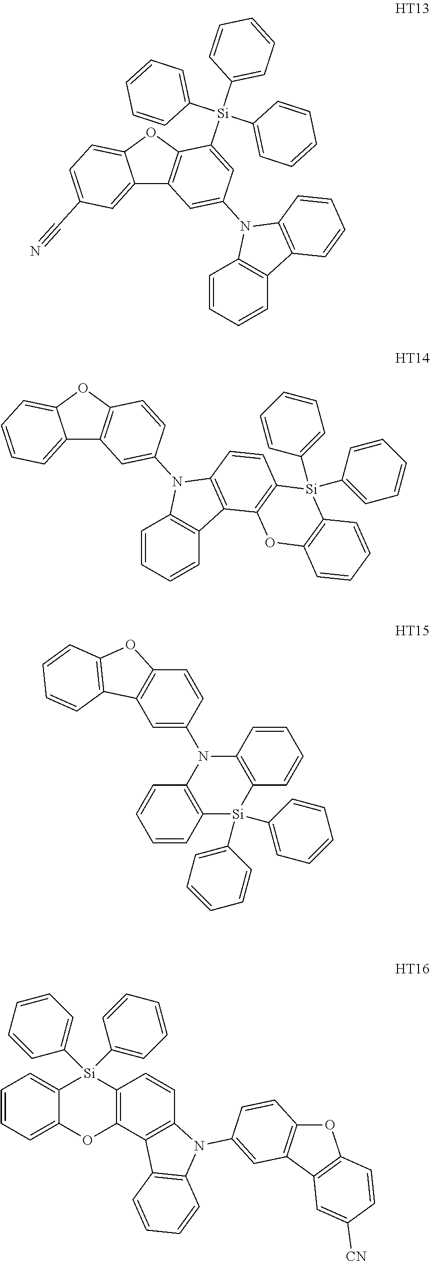 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

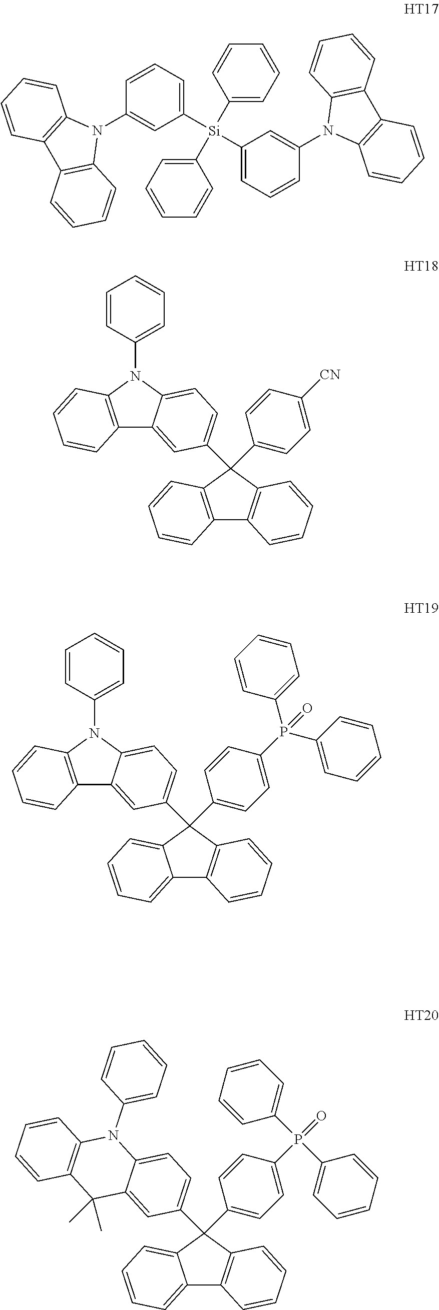 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

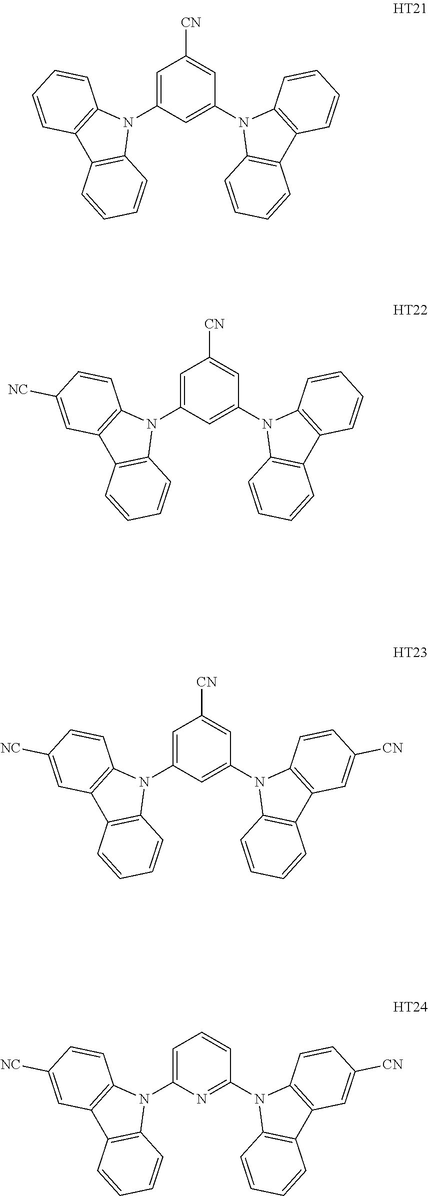 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

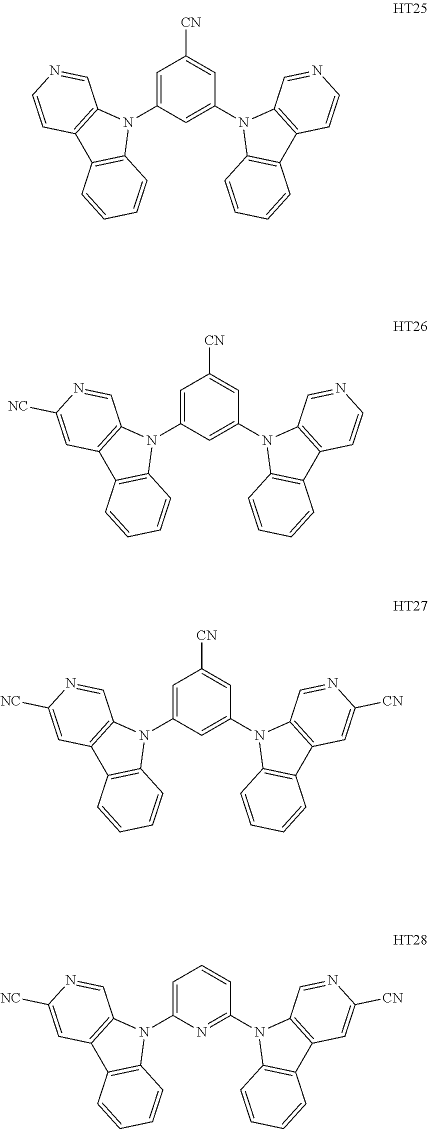 [SMILES: N#Cc1cc(-n2c3ccccc3c3ccncc32)cc(-n2c3ccccc3c3ccncc32)c1 ; N#Cc1cc(-n2c3ccccc3c3ccncc32)cc(-n2c3ccccc3c3cc(C#N)ncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

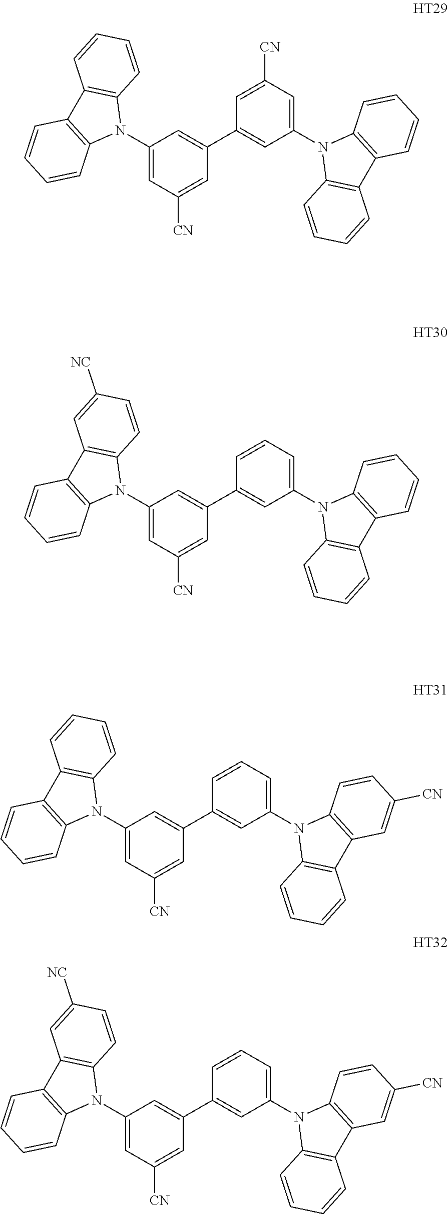 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

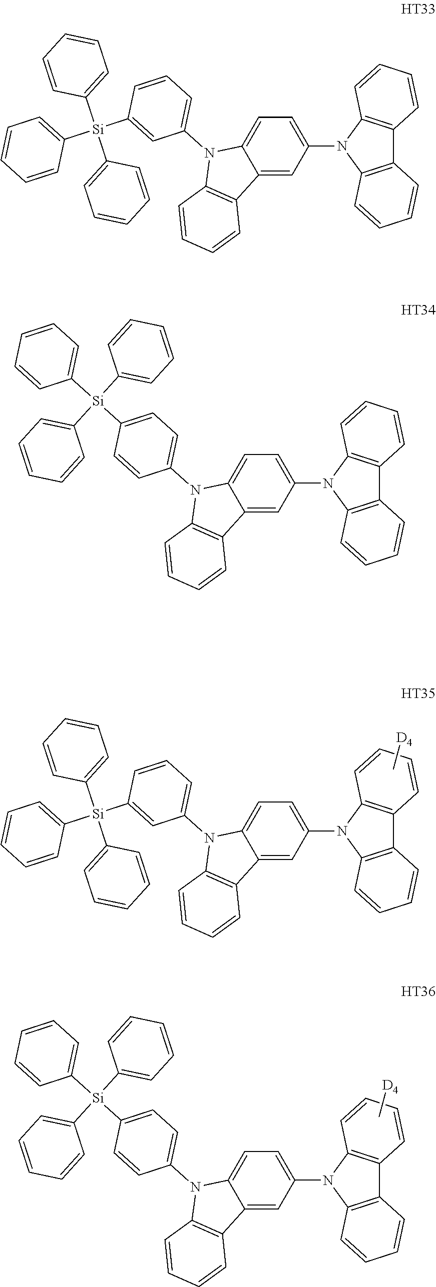

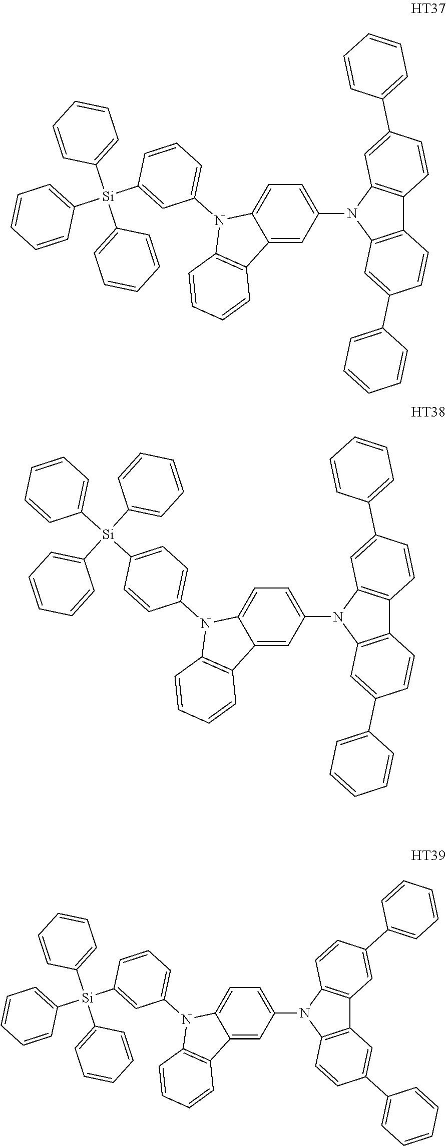

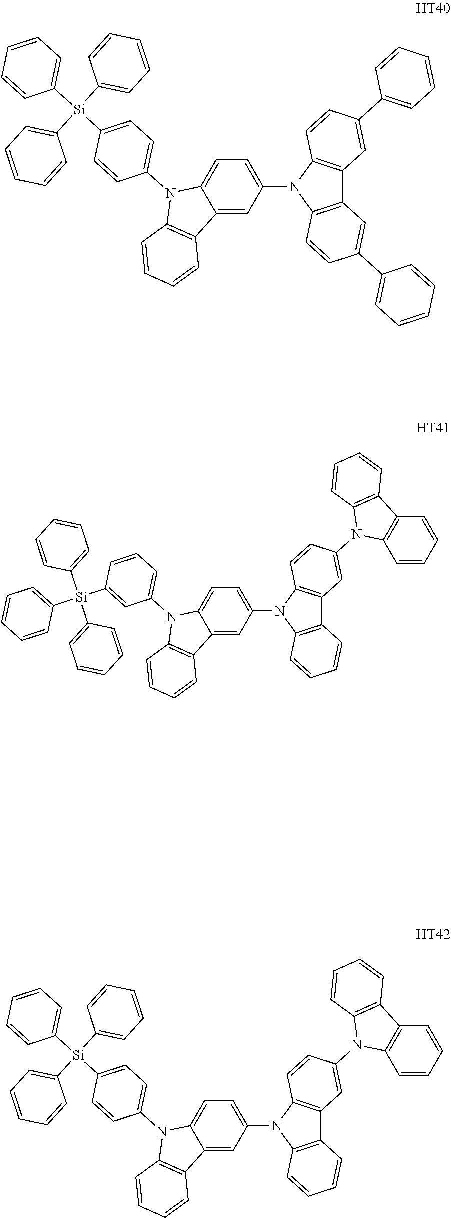 [SMILES: c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

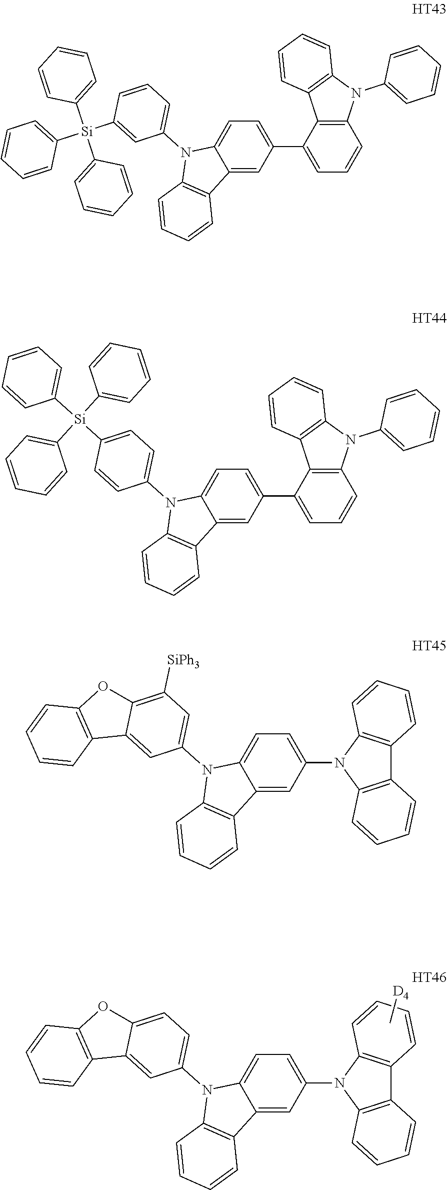

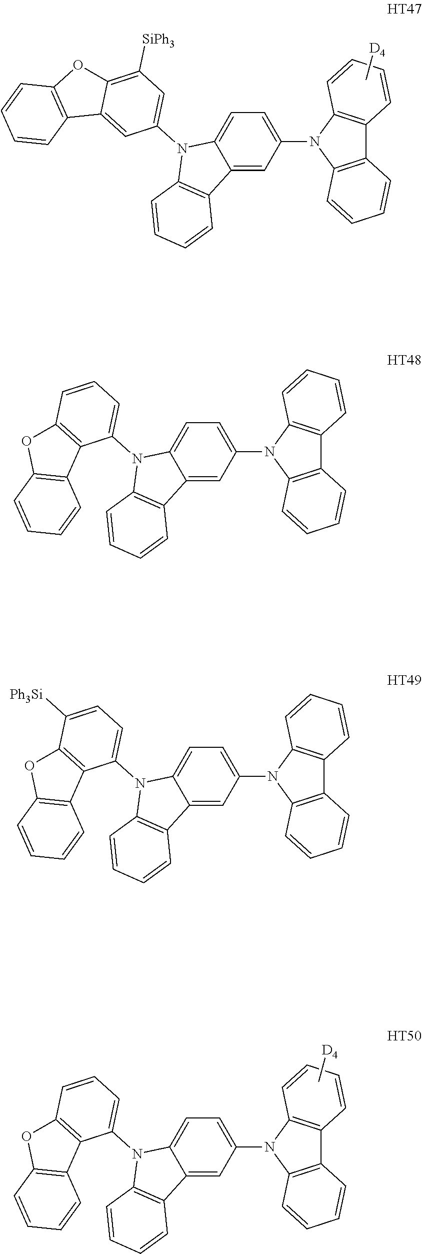

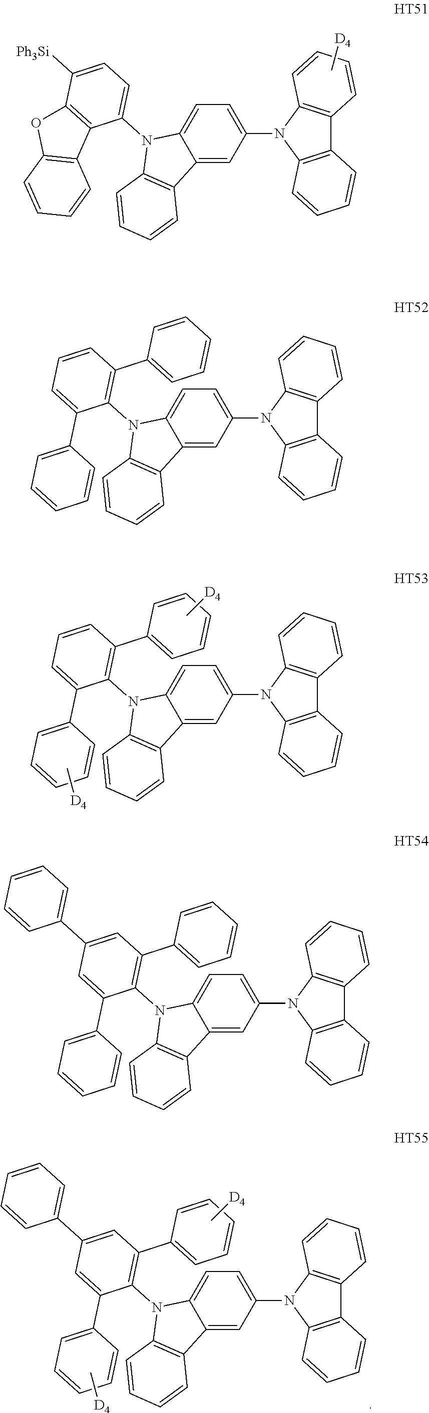

In embodiment compounds presented in Compound Group 2, “D” may represent a deuterium atom, and “Ph” may represent a substituted or unsubstituted phenyl group. For example, in embodiment compounds presented in Compound Group 2, “Ph” may represent an unsubstituted phenyl group.

In an embodiment, the emission layer EML may include the third compound represented by Formula H-2. For example, the third compound may be utilized as an electron transport host material of the emission layer EML.

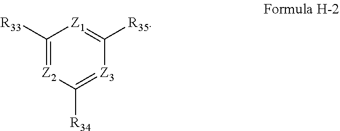

In Formula H-2, Z₁ to Z₃ may each independently be N or CR₃₆, and at least one selected from among Z₁ to Z₃ may be N.

In Formula H-2, R₃₃ to R₃₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₃₃ to R₃₆ may be bonded to an adjacent group to form a ring. For example, R₃₃ to R₃₆ may each independently be a substituted or unsubstituted phenyl group, a substituted or unsubstituted carbazole group, etc., but the embodiment of the present disclosure is not limited thereto.

In an embodiment, the third compound represented by Formula H-2 may be represented by any one selected from among the compounds represented by Compound Group 3. The emission layer EML may include at least one selected from among the compounds represented by Compound Group 3 as an electron transporting host material.

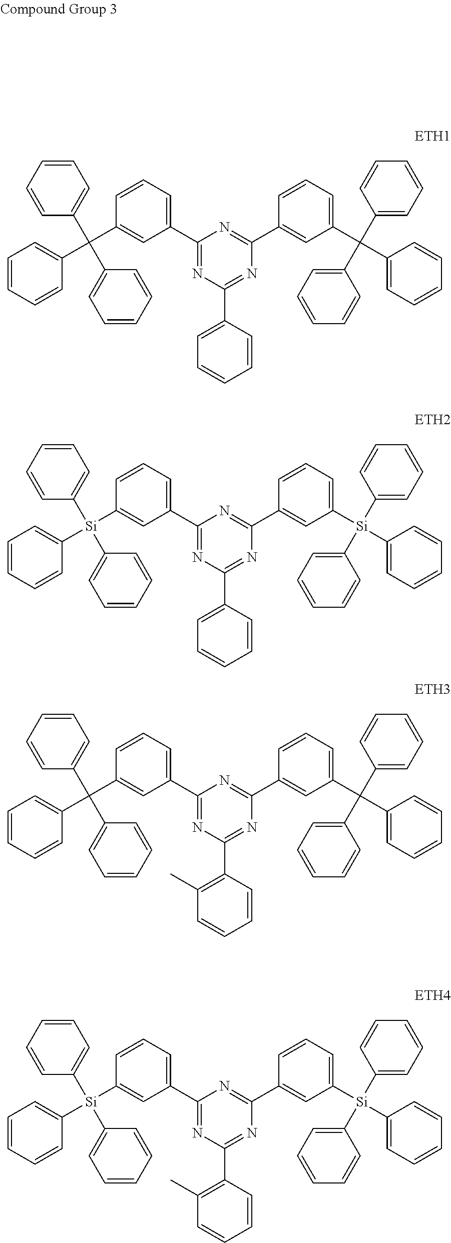 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

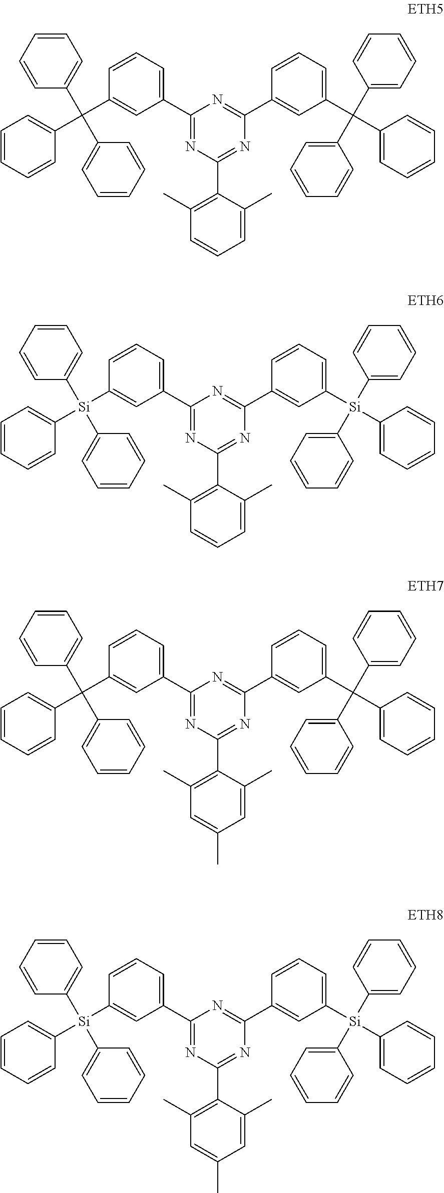 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

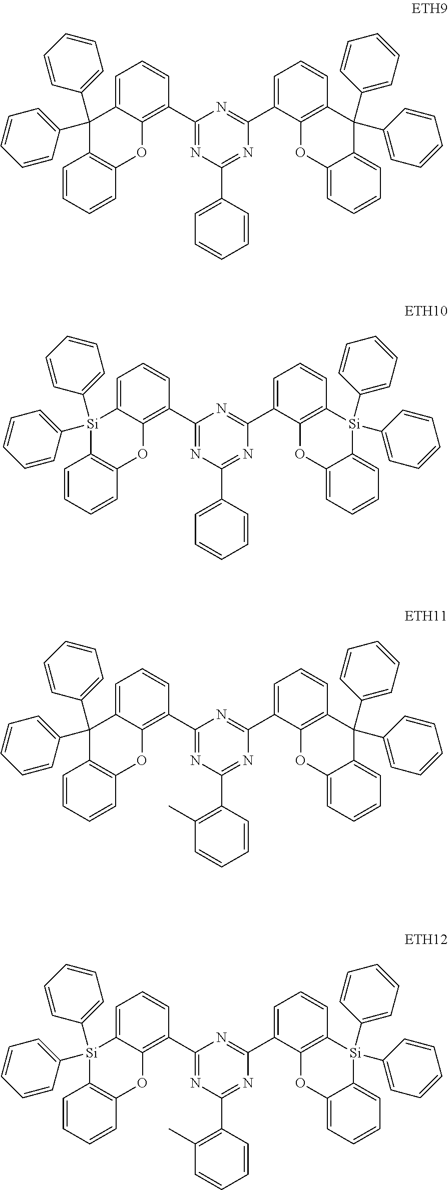 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

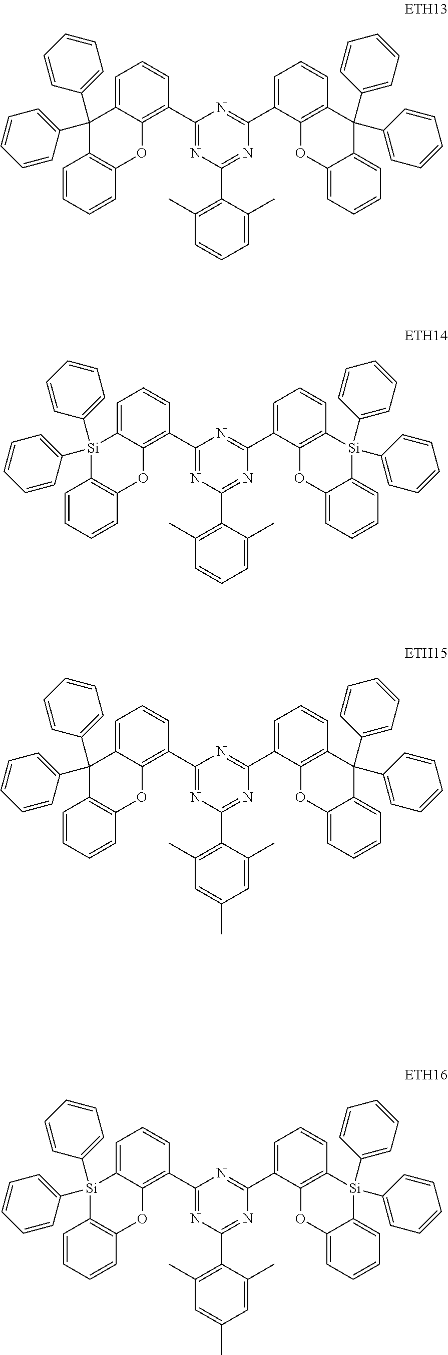 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

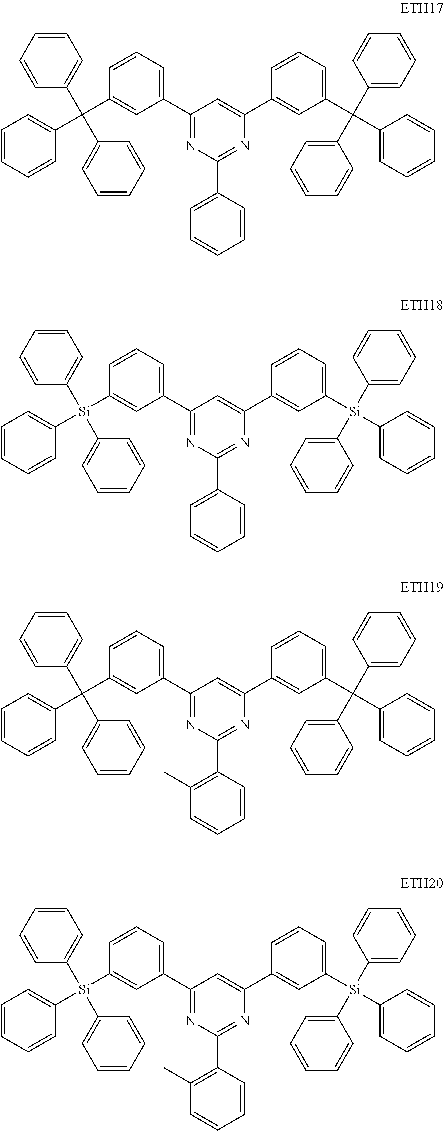 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

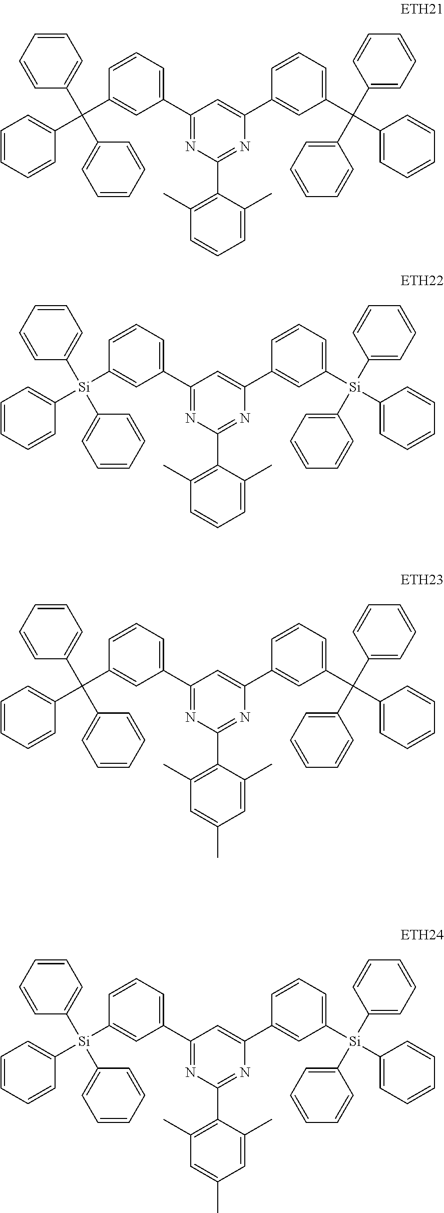 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

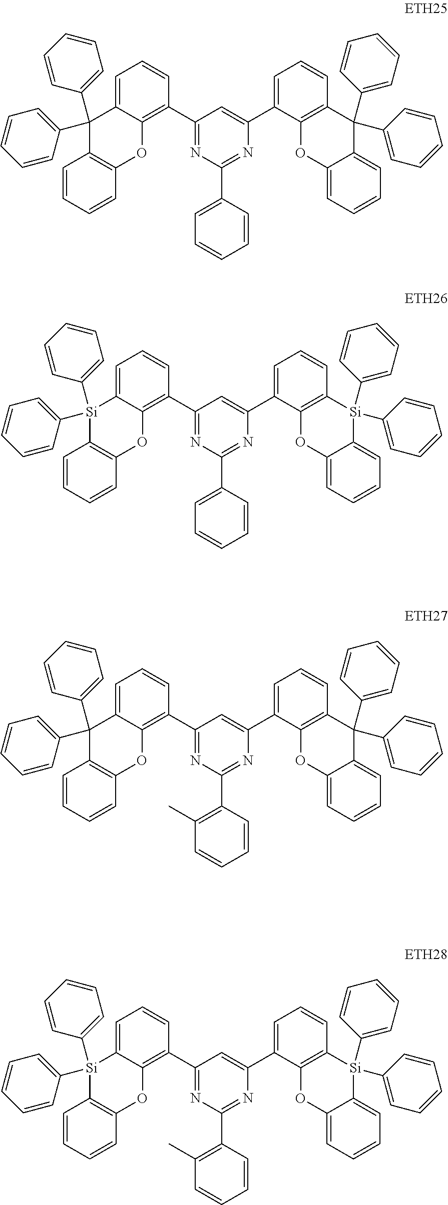 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

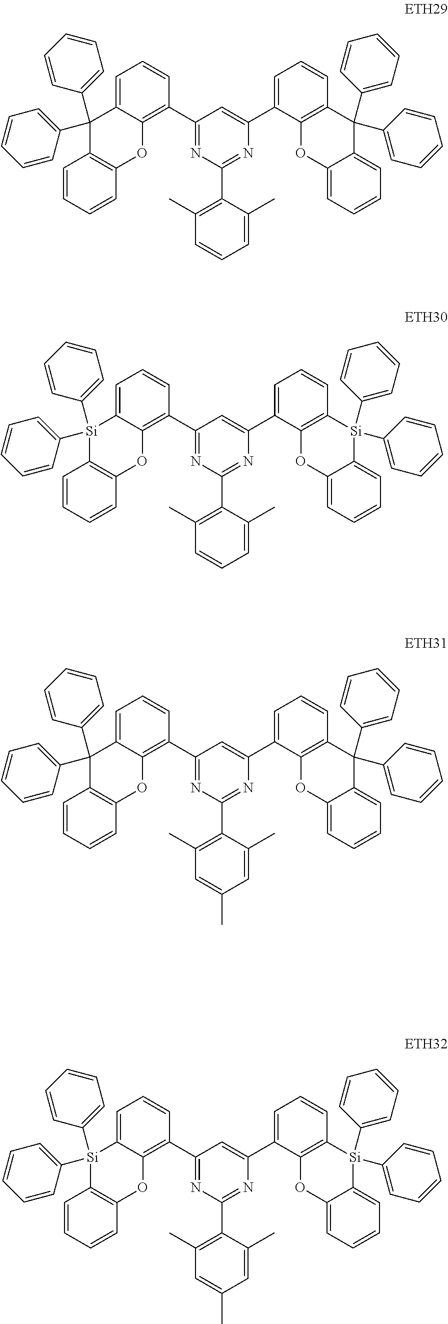 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

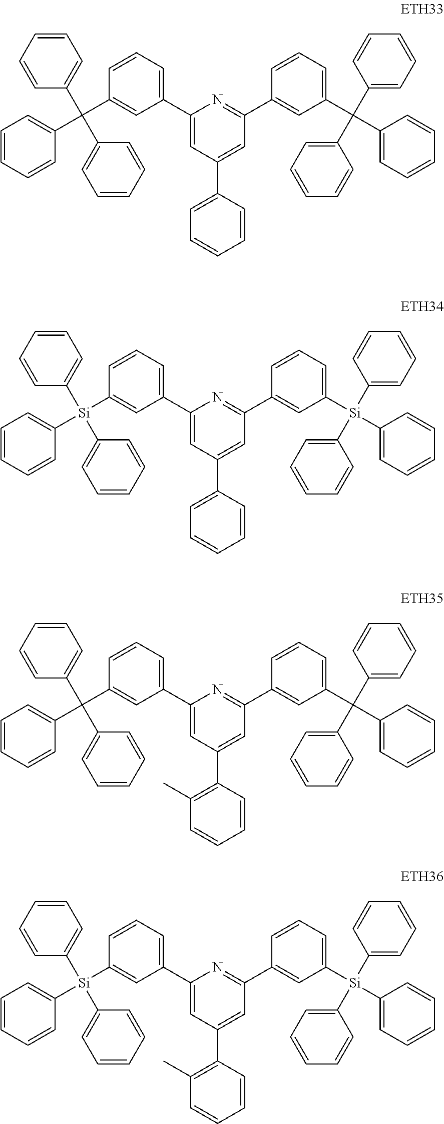 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

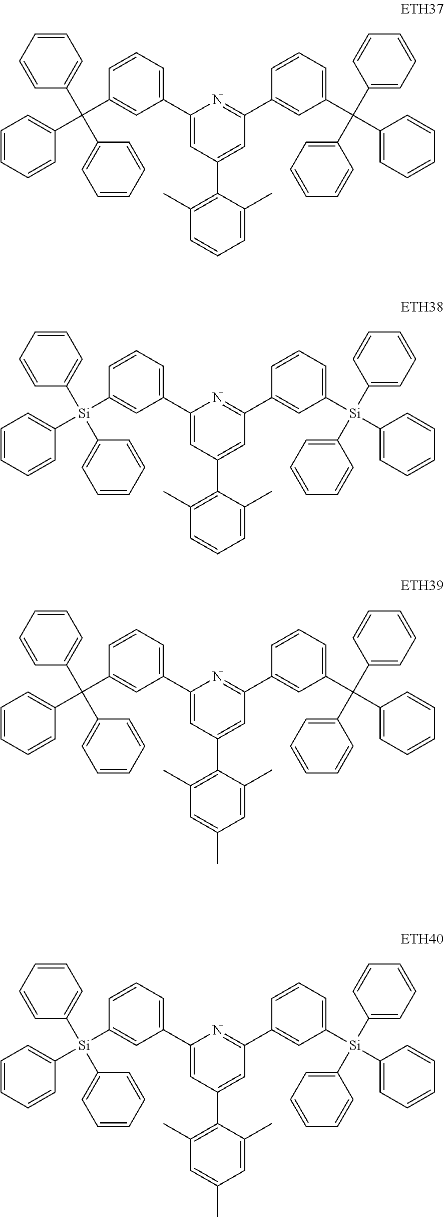 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

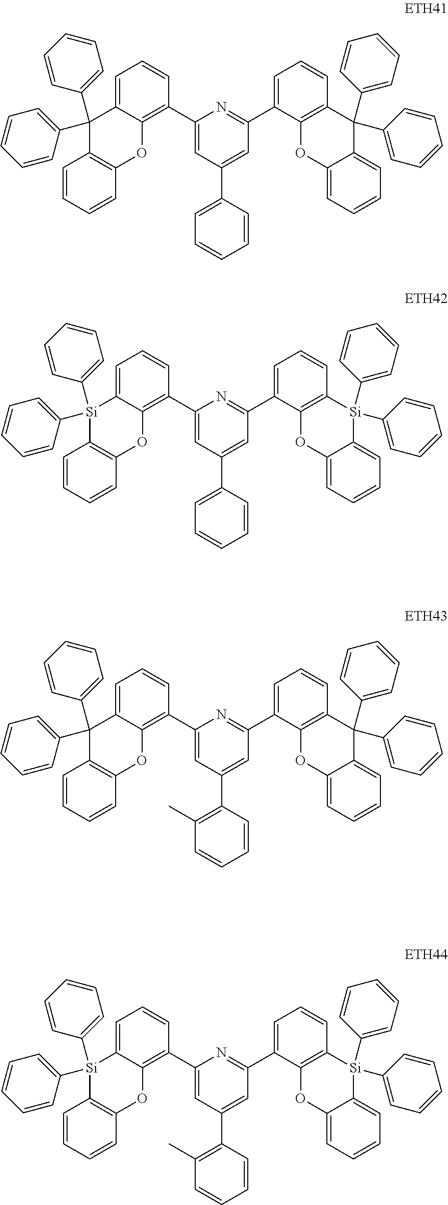 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

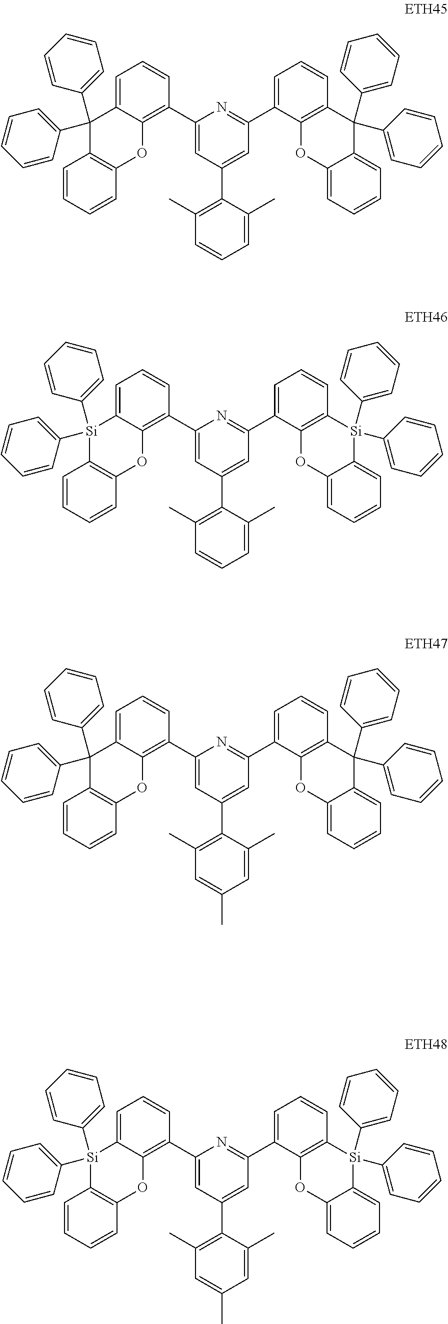 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

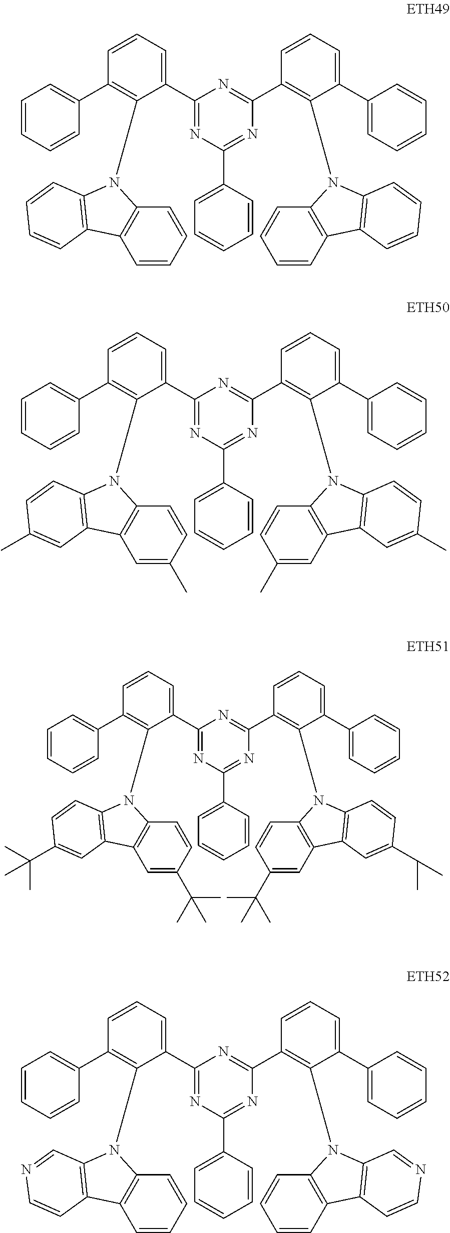

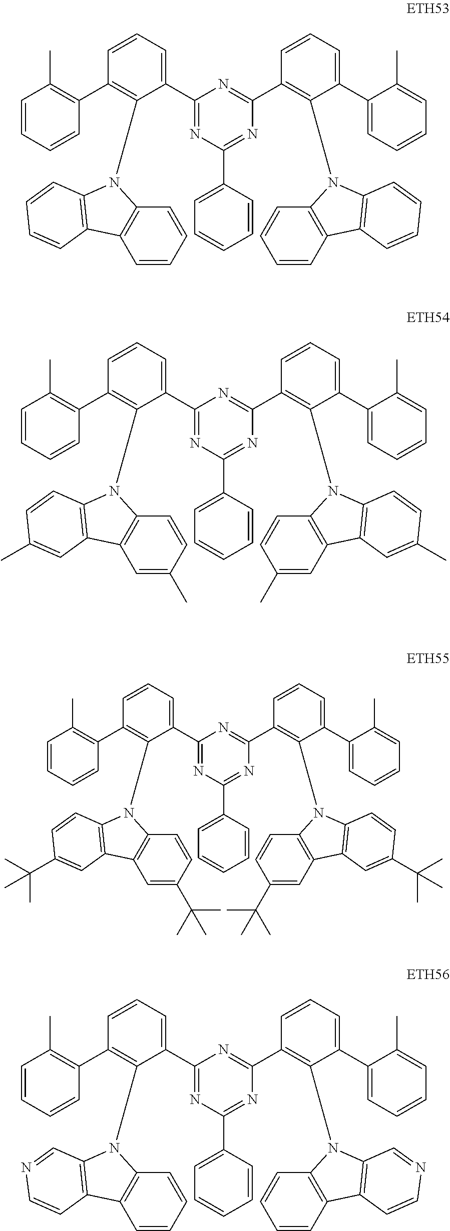

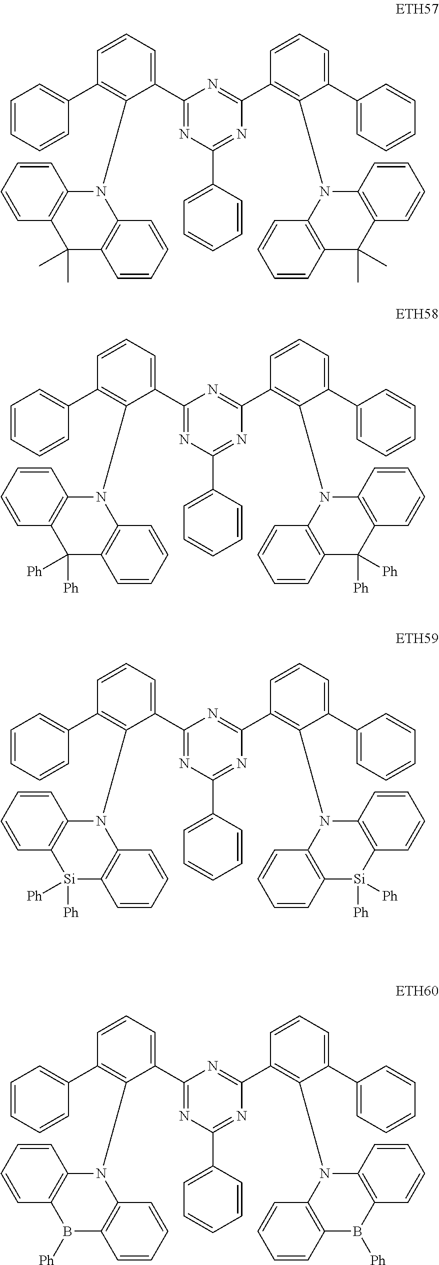

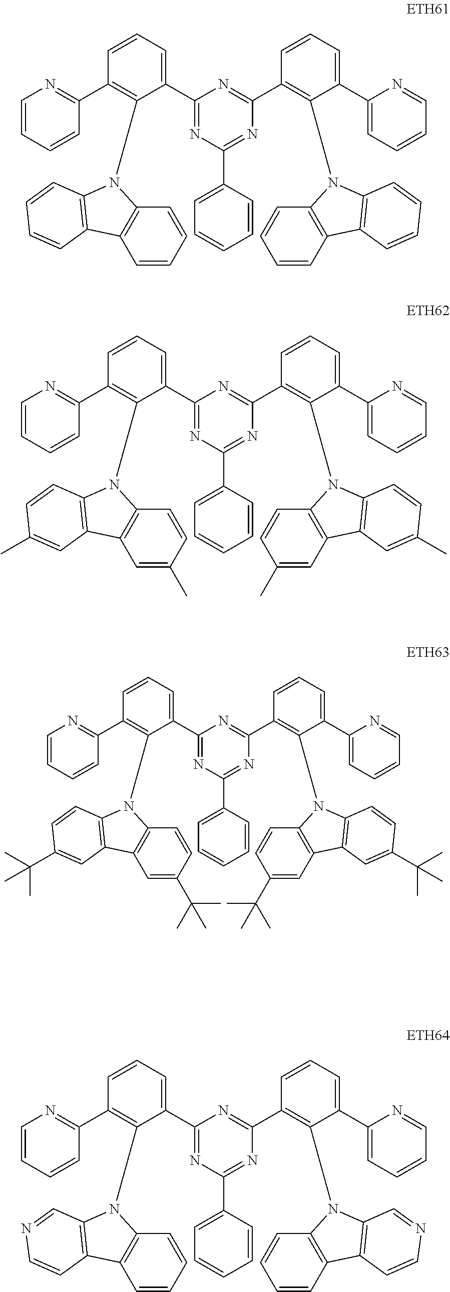

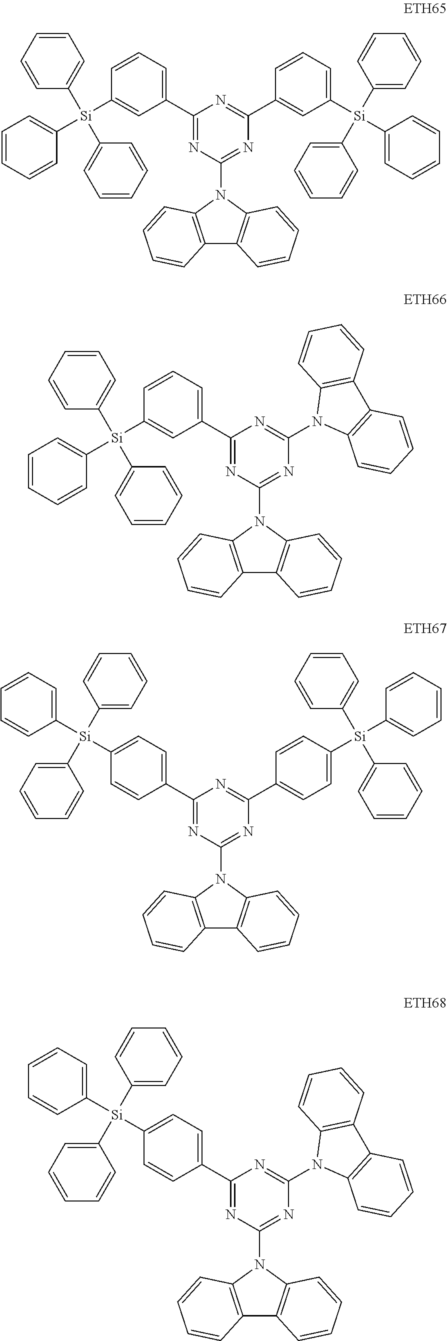 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

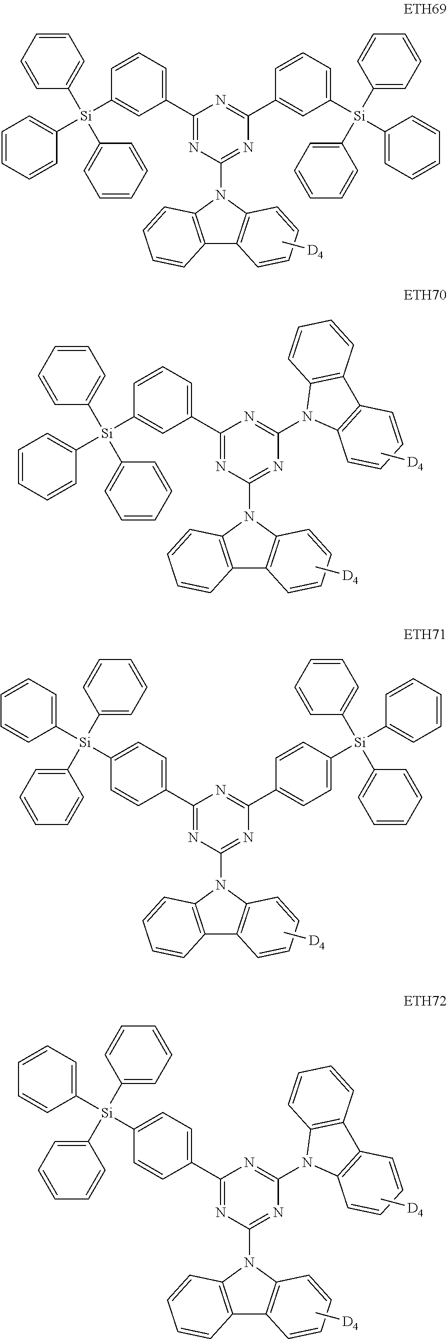

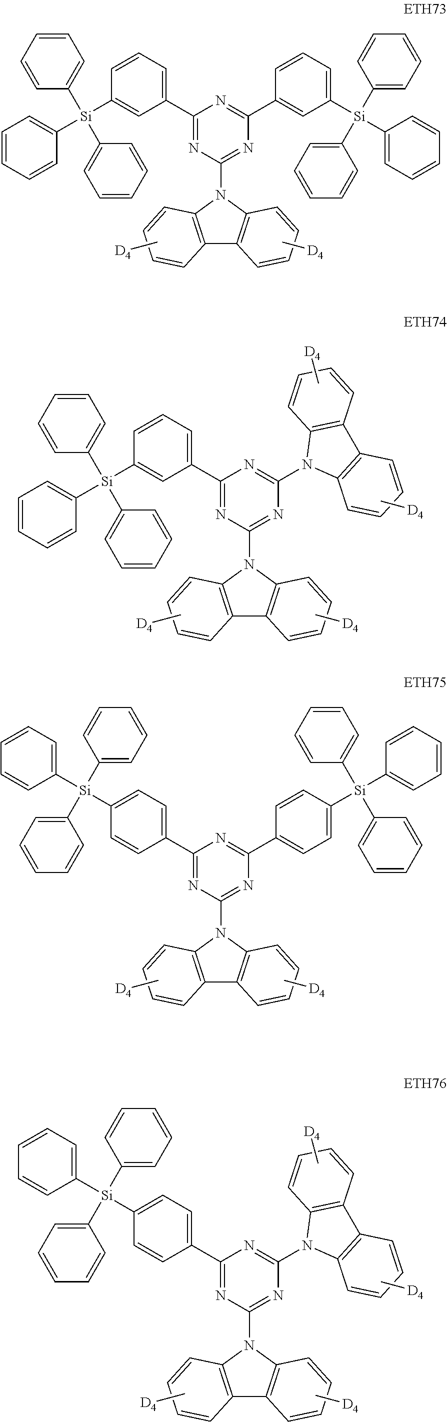

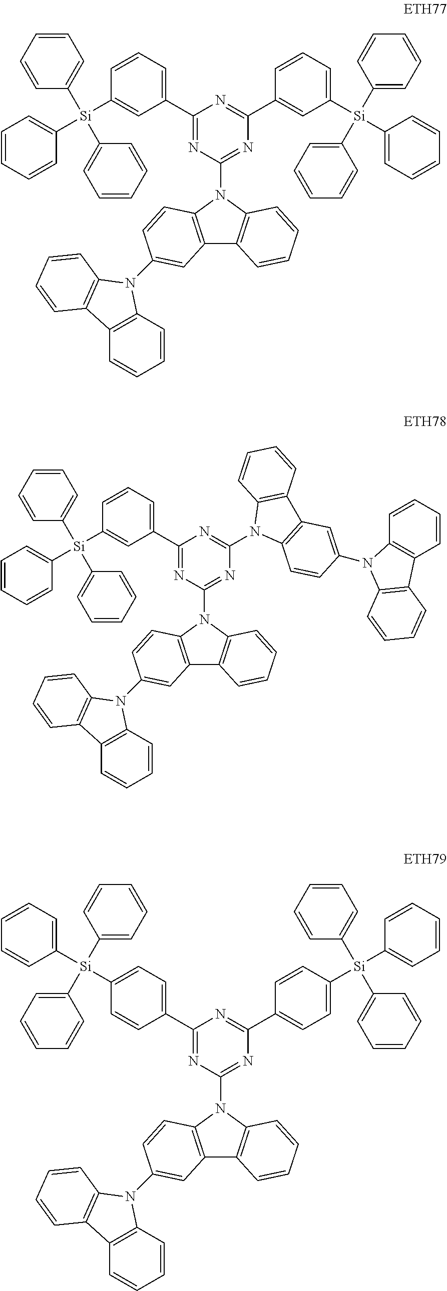 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

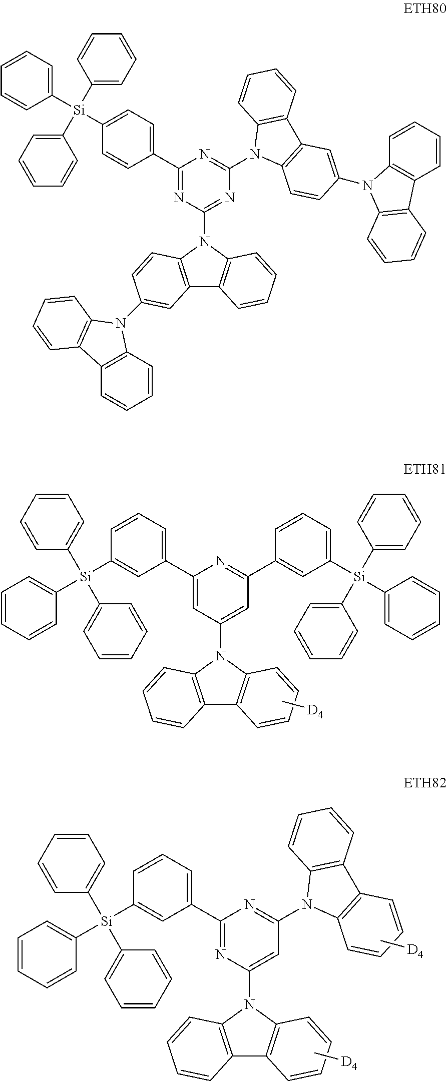

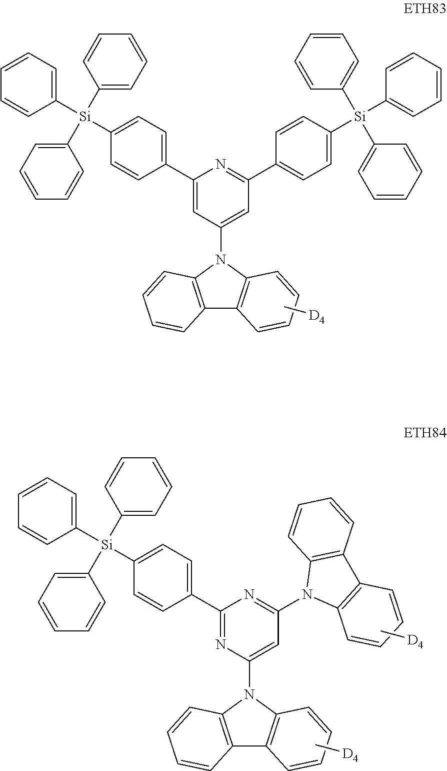

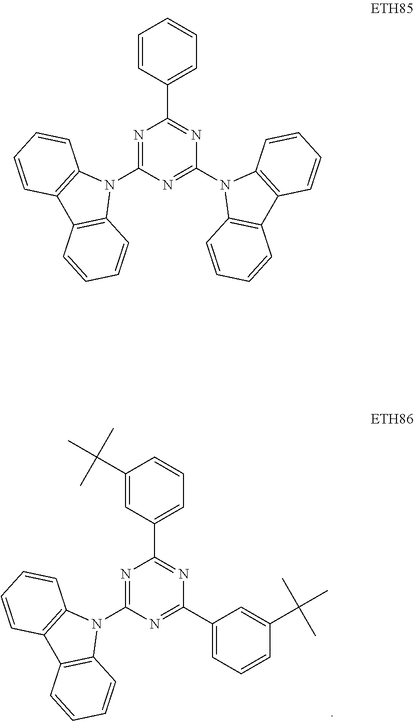 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In embodiment compounds presented in Compound Group 3, “D” may represent a deuterium atom, and “Ph” may represent an unsubstituted phenyl group.

The emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In some embodiments, the triplet energy of the exciplex may be a value smaller than an energy gap of each host material. The exciplex may have a triplet energy of about 3.0 eV or less that is an energy gap between the hole transporting host and the electron transporting host.

In an embodiment, the emission layer EML may include a fourth compound in addition to the first compound to the third compound. The fourth compound may be utilized as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting device ED of an embodiment may include, as the fourth compound, a compound represented by Formula D-1:

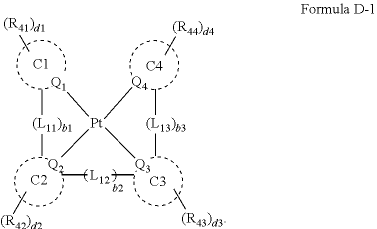

In Formula D-1, Q₁ to Q₄ may each independently be C or N.

In Formula D-1, C1 to C4 may each independently be a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may each independently be a direct linkage,

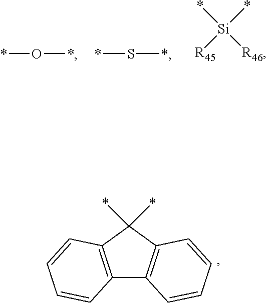

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] refers to a part linked to C1 to C4.

In Formula D-1, b1 to b3 may each independently be 0 or 1. When b1 is 0, C1 and C2 may not be linked to each other. When b2 is 0, C2 and C3 may not be linked to each other. When b3 is 0, C3 and C4 may not be linked to each other.

In Formula D-1, R₄₁ to R₄₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₄₁ to R₄₆ may be bonded to an adjacent group to form a ring. In some embodiments, R₄₁ to R₄₆ may each independently be a substituted or unsubstituted methyl group, or a substituted or unsubstituted t-butyl group.

In Formula D-1, d1 to d4 may each independently be an integer of 0 to 4. In Formula D-1, when each of d1 to d4 is 0, the fourth compound may not be substituted with each of R₄₁ to R₄₄. The case where each of d1 to d4 is 4 and R₄₁'s to R₄₄′ are each hydrogen atoms may be the same as the case where each of d1 to d4 is 0. When each of d1 to d4 is an integer of 2 or more, a plurality of R₄₁'s to R₄₄'s may each be the same or at least one selected from among the plurality of R₄₁'s to R₄₄'s may be different from the others.

In Formula D-1, C1 to C4 may each independently be a substituted or unsubstituted hydrocarbon ring or a substituted or unsubstituted heterocycle represented by any one selected from among Formulae C-1 to C-4:

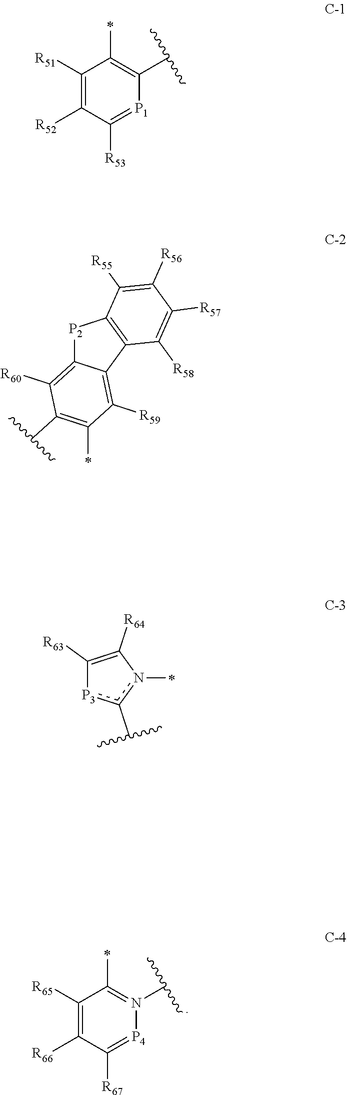

In Formulae C-1 to C-4 P₁ may be [symbol] or CR₅₄, P₂ may be [symbol] or NR₆₁, P₃ may be [symbol] or NR₆₂, and P₄ may be [symbol] or CR₆₈. R₅₁ to R₆₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In some embodiments, in Formulae C-1 to C-4, [symbol] corresponds to a part linked to Pt that is a central metal atom, and [symbol] corresponds to a part linked to a neighboring cyclic group (C1 to C4) or a linker (L₁₁ to L₁₄).

The emission layer EML of an embodiment may include the first compound, and at least one of the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In some embodiments, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In an embodiment, the fourth compound may be a sensitizer. The fourth compound included in the emission layer EML in the light emitting device ED of an embodiment may serve as a sensitizer to deliver energy from the host to the first compound that is a light emitting dopant. For example, the fourth compound serving as an auxiliary dopant accelerates energy delivery to the first compound that is a light emitting dopant, thereby increasing the emission ratio of the first compound. Therefore, the emission layer EML of an embodiment may improve luminous efficiency. In some embodiments, when the energy delivery to the first compound is increased, an exciton formed in the emission layer EML is not accumulated inside the emission layer EML and emits light rapidly, and thus deterioration of the element may be reduced. Therefore, the service life of the light emitting device ED of an embodiment may increase.

The light emitting device ED of an embodiment may include all of the first compound, the second compound, the third compound, and the fourth compound, and the emission layer EML may include the combination of two host materials and two dopant materials. In the light emitting device ED of an embodiment, the emission layer EML may concurrently (e.g., simultaneously) include two different hosts, the first compound that emits a delayed fluorescence, and the fourth compound including an organometallic complex, thereby exhibiting excellent or suitable luminous efficiency characteristics.

In an embodiment, the fourth compound represented by Formula D-1 may be at least one selected from among the compounds represented by Compound Group 4. The emission layer EML may include at least one selected from among the compounds represented by Compound Group 4 as a sensitizer material.

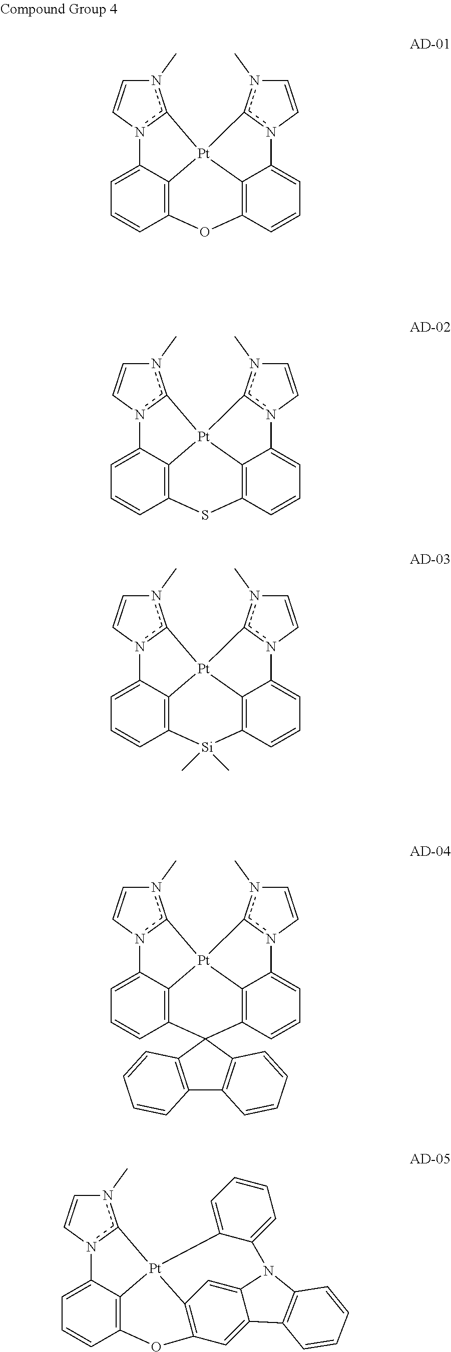

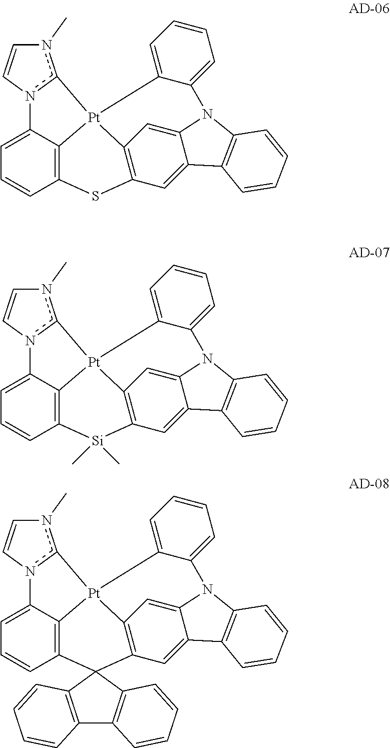

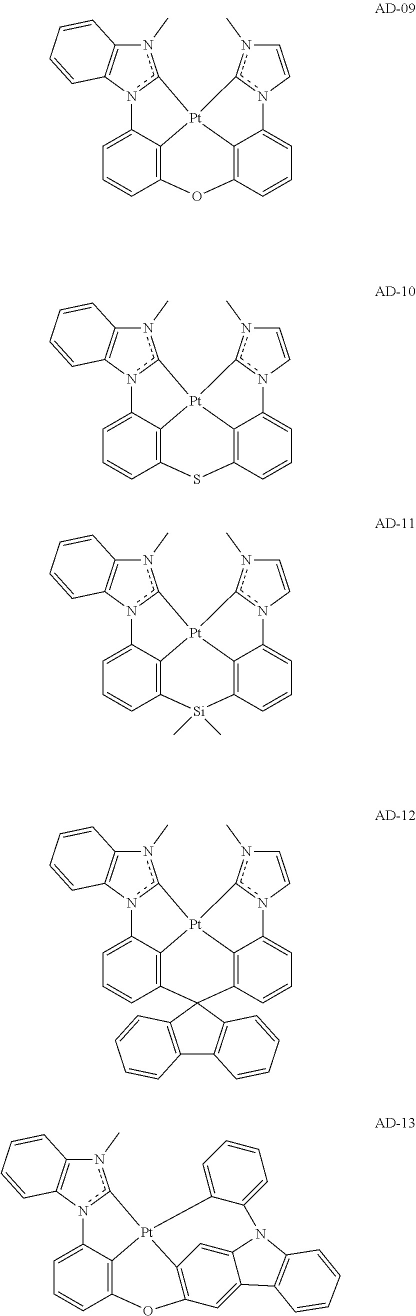

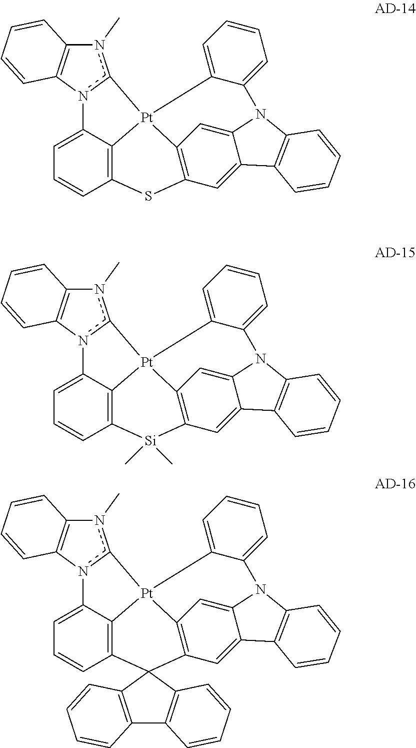

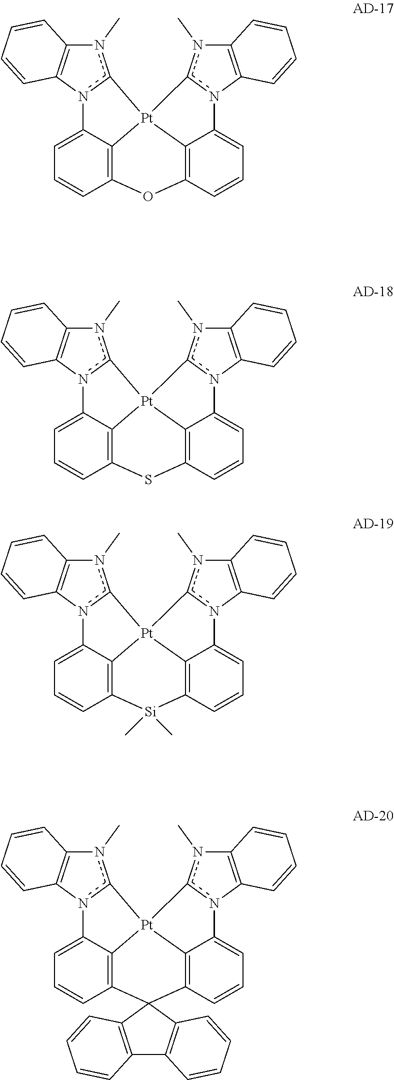

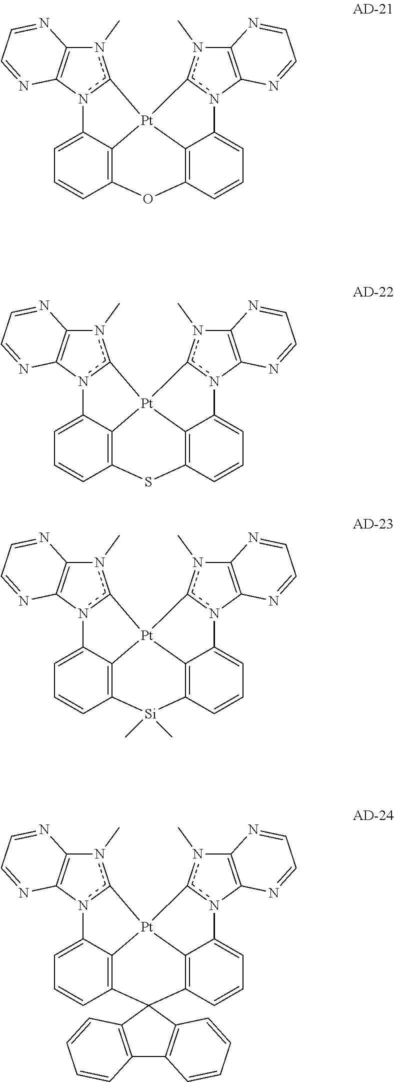

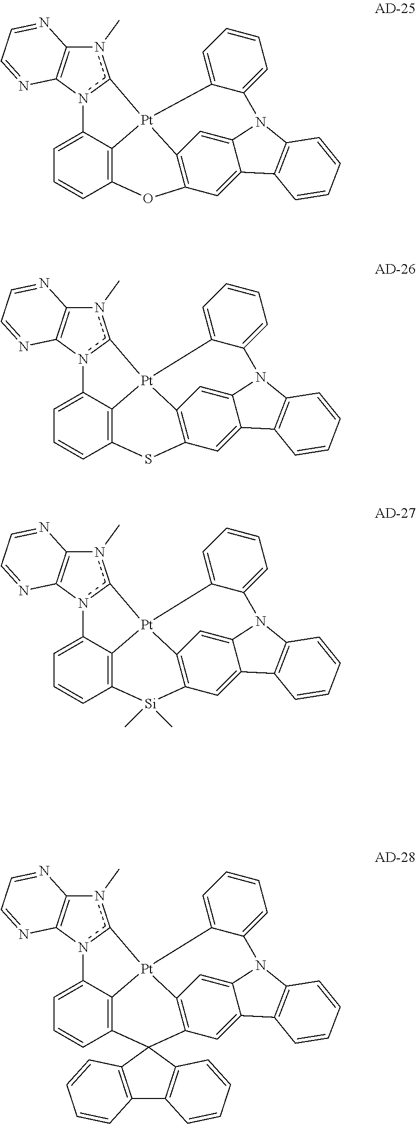

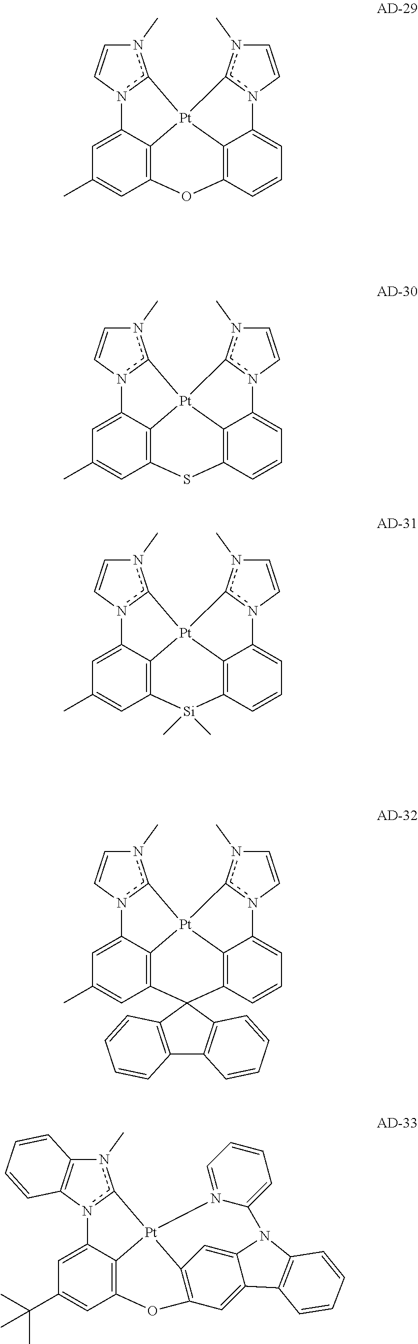

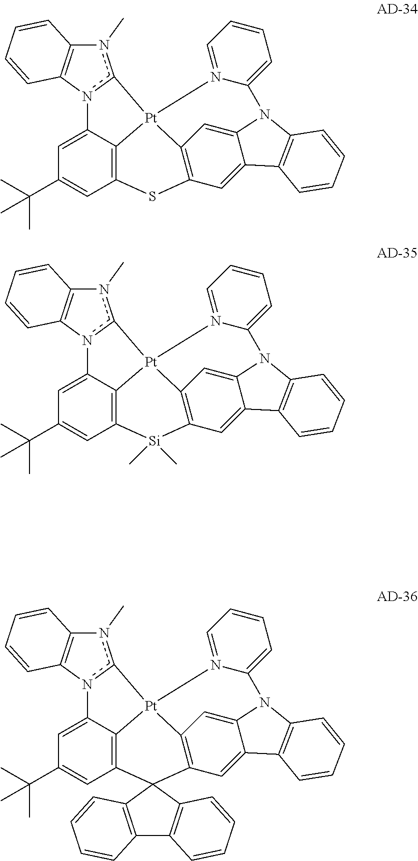

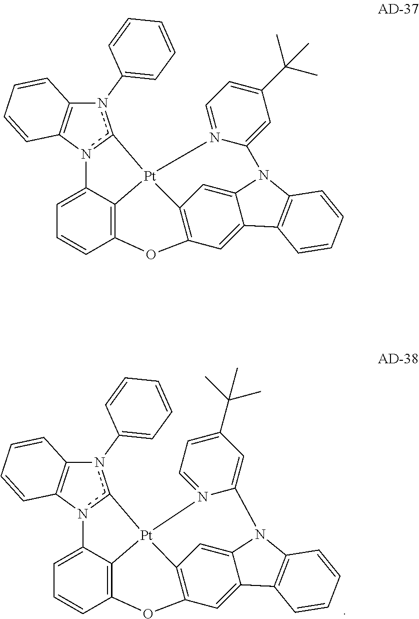

In some embodiments, the light emitting device ED of an embodiment may include a plurality of emission layers. The plurality of emission layers may be sequentially stacked and provided, and for example, the light emitting device ED including the plurality of emission layers may be to emit white light. The light emitting device including the plurality of emission layers may be a light emitting device having a tandem structure. When the light emitting device ED includes a plurality of emission layers, at least one emission layer EML may include the first compound represented by Formula 1 of an embodiment. In some embodiments, when the light emitting device ED includes the plurality of emission layers, at least one emission layer EML may include all of the first compound, the second compound, the third compound, and the fourth compound as described above.

When the emission layer EML in the light emitting device ED of an embodiment includes all of the first compound, the second compound, and the third compound, with respect to the total weight of the first compound, the second compound, and the third compound, the content (e.g., amount) of the first compound may be about 0.5 wt % to about 3 wt %. However, an embodiment of the present disclosure is not limited thereto. When the content (e.g., amount) of the first compound satisfy the above-described range, the energy transfer from the second compound and the third compound to the first compound may increase, and thus the luminous efficiency and device service life may increase.

The contents (e.g., amounts) of the second compound and the third compound in the emission layer EML may be the rest excluding the weight of the first compound. For example, the contents (e.g., amounts) of the second compound and the third compound in the emission layer EML may be about 20 wt % to about 90 wt % with respect to the total weight of the first compound, the second compound, and the third compound.

In the total weight of the second compound and the third compound, the weight ratio between the second compound and the third compound may be about 3:7 to about 7:3.

When the contents (e.g., amounts) of the second compound and the third compound satisfy the above-described ratio, a charge balance characteristic in the emission layer EML are improved, and thus the luminous efficiency and device service life may increase. When the contents (e.g., amounts) of the second compound and the third compound deviate from the above-described ratio range, a charge balance in the emission layer EML may be broken, and thus the luminous efficiency may be reduced and the device may be easily deteriorated.

When the first compound, the second compound, and the third compound included in the emission layer EML satisfies the above-described ratio ranges, excellent or suitable luminous efficiency and long service life may be achieved.

In the light emitting device ED of an embodiment, the emission layer EML may include an anthracene derivative, a pyrene derivative, a fluoranthene derivative, a chrysene derivative, a dehydrobenzanthracene derivative, and/or a triphenylene derivative. For example, the emission layer EML may include the anthracene derivative or the pyrene derivative.

In each light emitting device ED of embodiments illustrated in FIGS. 3 to 6, the emission layer EML may further include a suitable host and dopant besides the above-described host and dopant, and for example the emission layer EML may include a compound represented by Formula E-1. The compound represented by Formula E-1 may be utilized as a fluorescent host material.

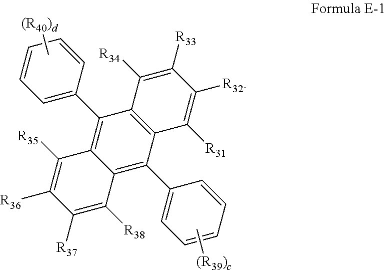

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In some embodiments, R₃1 to R₄₀ may be bonded to an adjacent group to form a saturated hydrocarbon ring or an unsaturated hydrocarbon ring, a saturated heterocycle, or an unsaturated heterocycle.

In Formula E-1, c and d may each independently be an integer of 0 to 5.

The compound represented by Formula E-1 may be represented by any one selected from among Compound E1 to Compound E19:

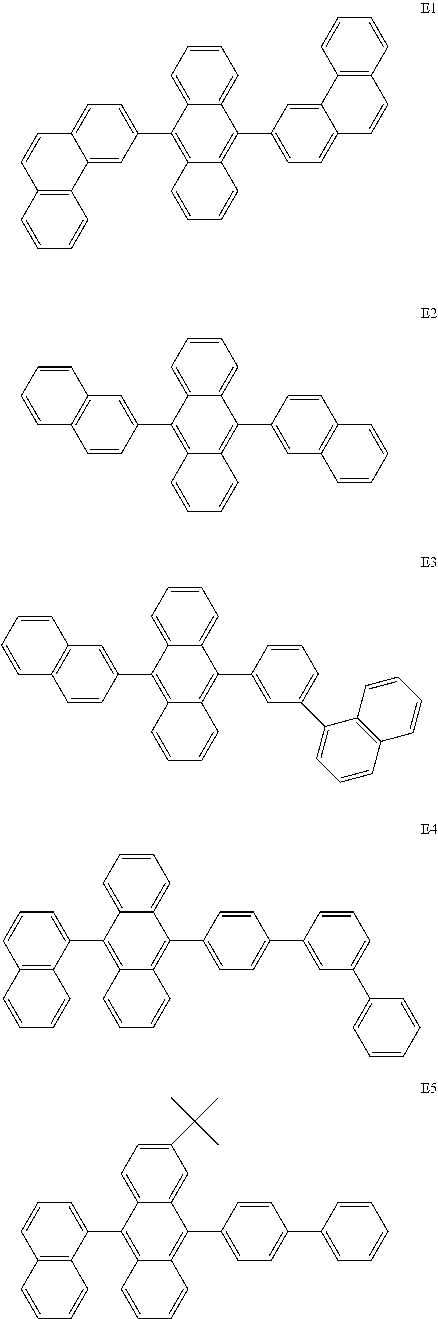

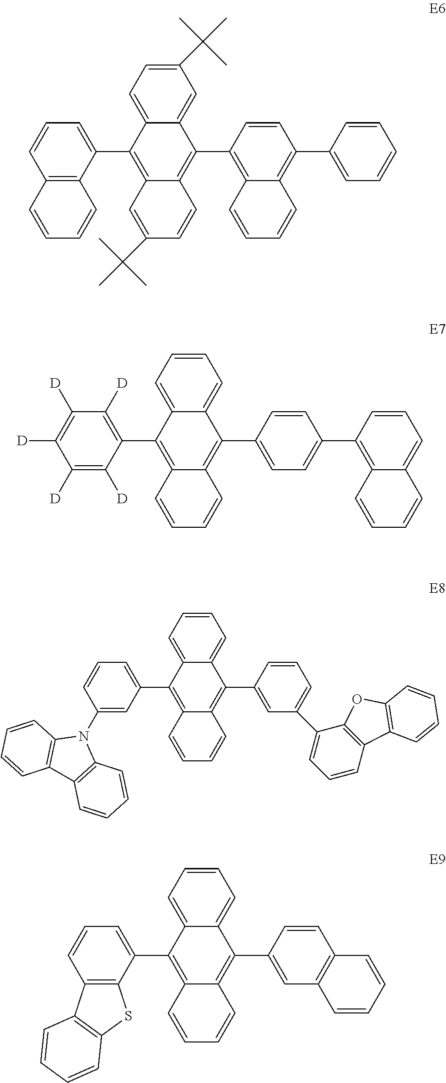

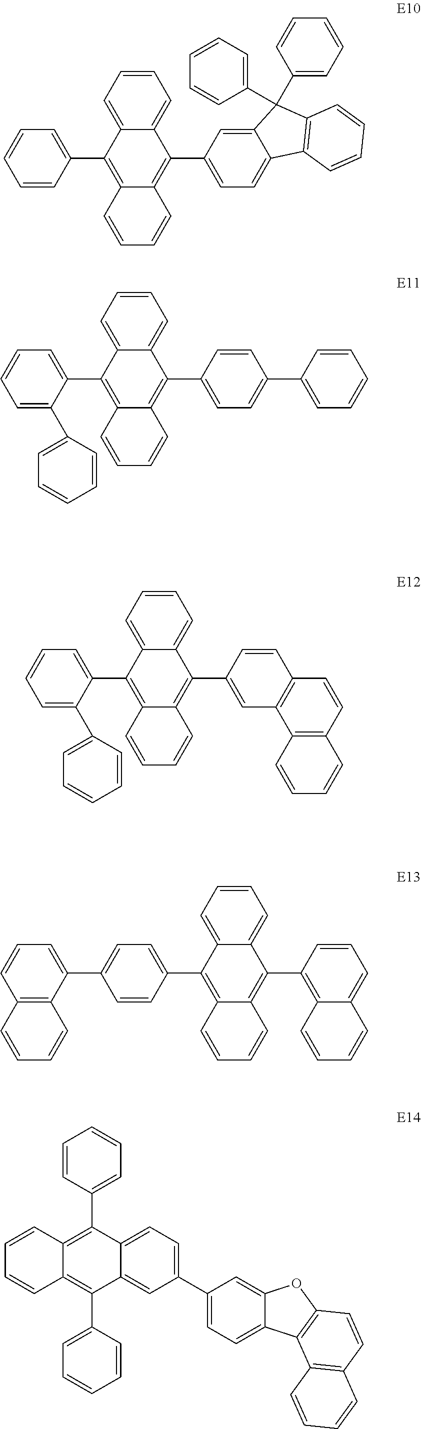

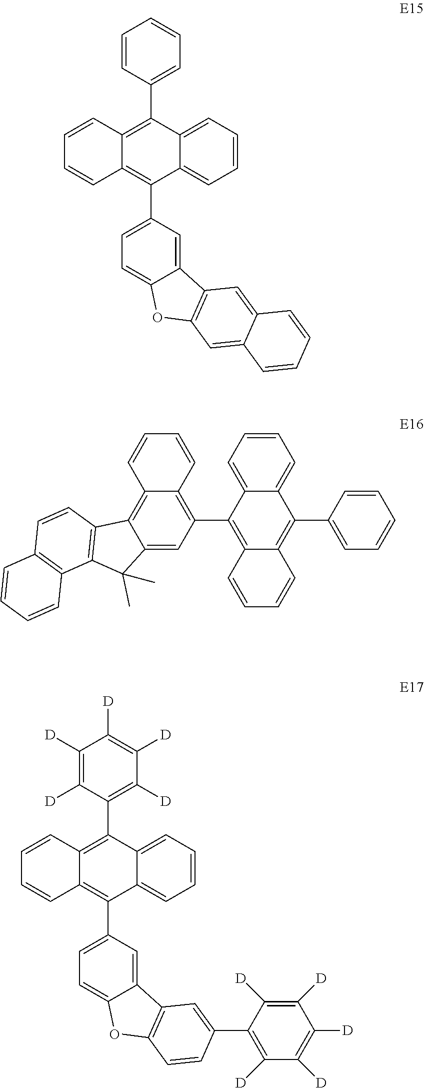

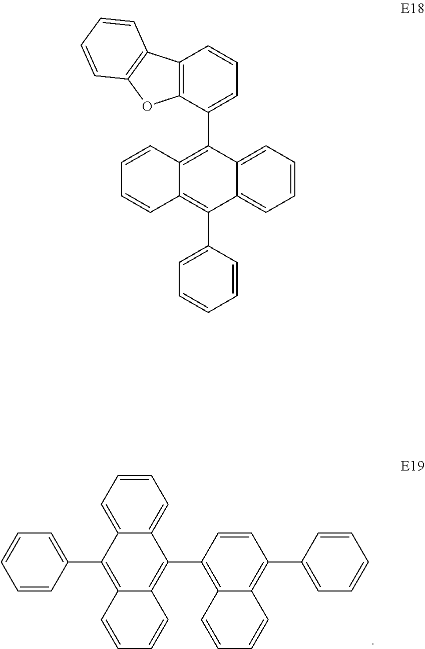

In an embodiment, the emission layer EML may include a compound represented by Formula E-2a or Formula E-2b. The compound represented by Formula E-2a or Formula E-2b may be utilized as a phosphorescent host material.

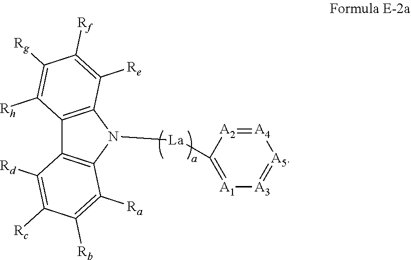

In Formula E-2a, a may be an integer of 0 to 10, Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or more, a plurality of Lₐ's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In some embodiments, Rₐ to Rᵢ may be bonded to an adjacent group to form a hydrocarbon ring or a heterocycle containing N, O, S, etc. as a ring-forming atom.

In some embodiments, in Formula E-2a, two or three selected from among A₁ to A₅ may be N, and any remainder thereof may be CRᵢ.

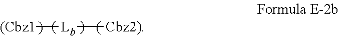

In Formula E-2b, Cbz1 and Cbz2 may each independently be an unsubstituted carbazole group, or a carbazole group substituted with an aryl group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, b may be an integer of 0 to 10, and when b is an integer of 2 or more, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2. However, the compounds listed in Compound Group E-2 are example, and the compound represented by Formula E-2a or Formula E-2b is not limited to those represented in Compound Group E-2.

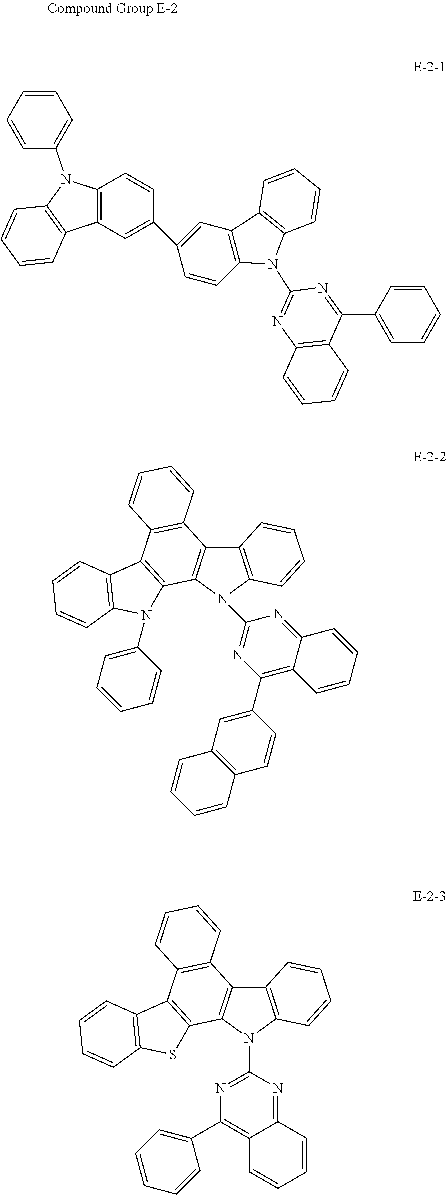 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

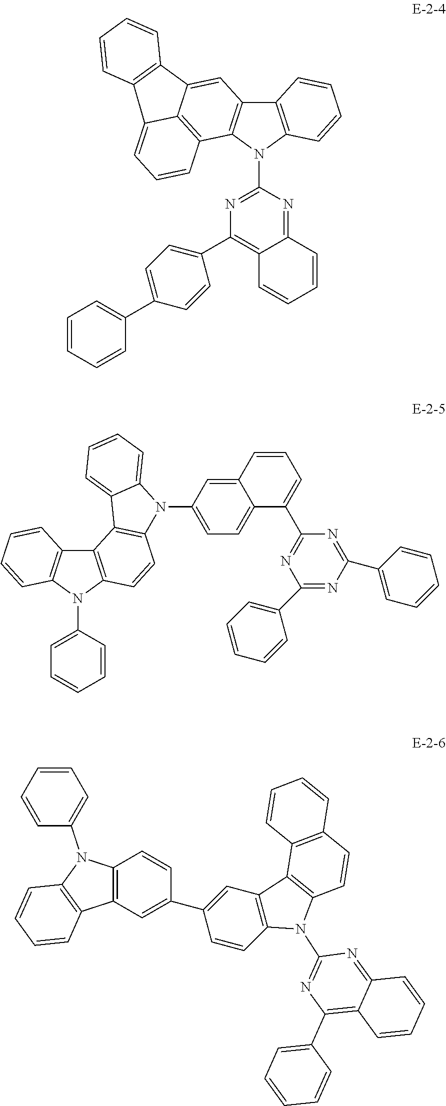 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

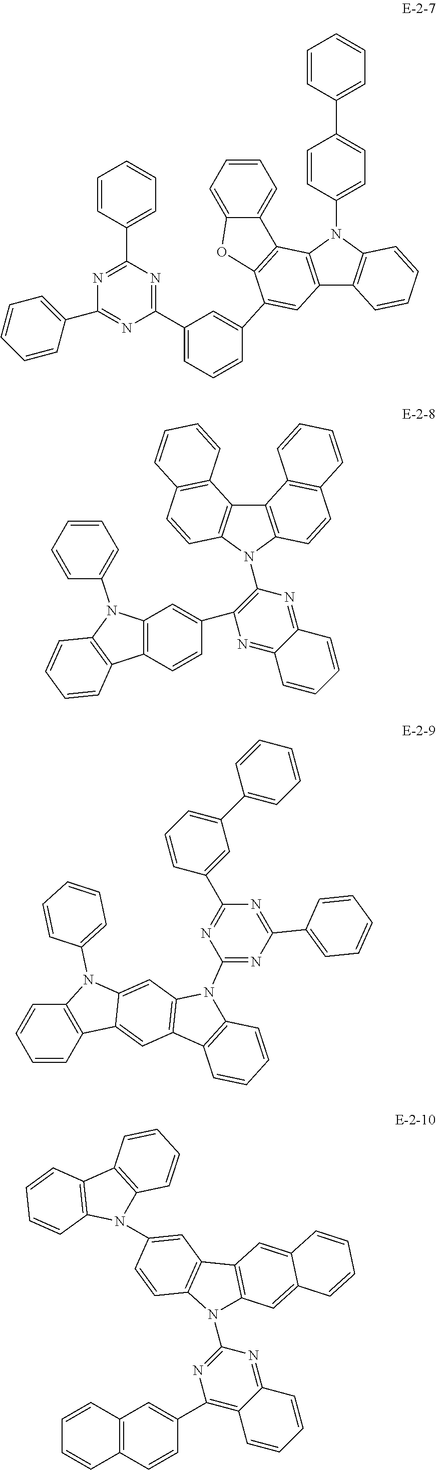 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1]

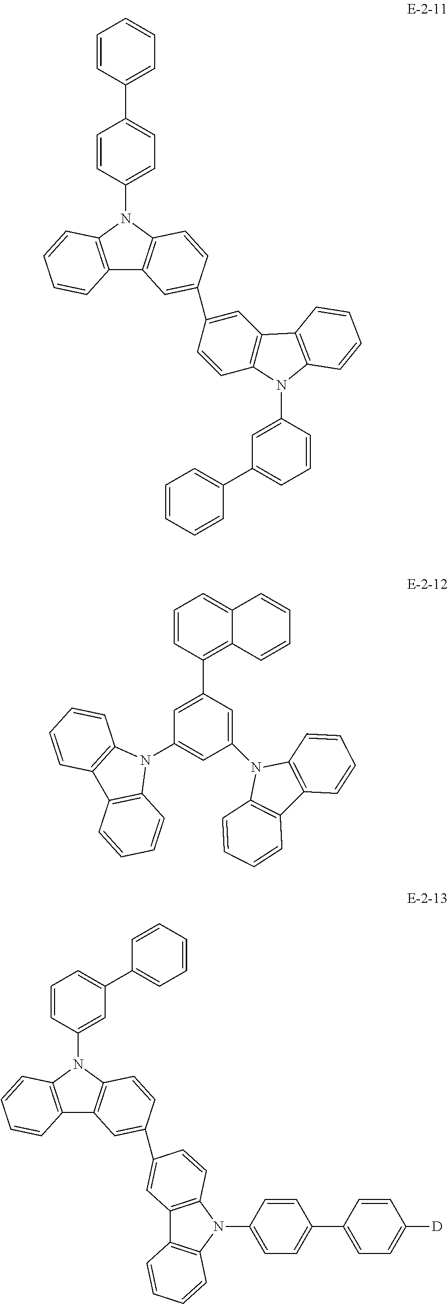 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1]

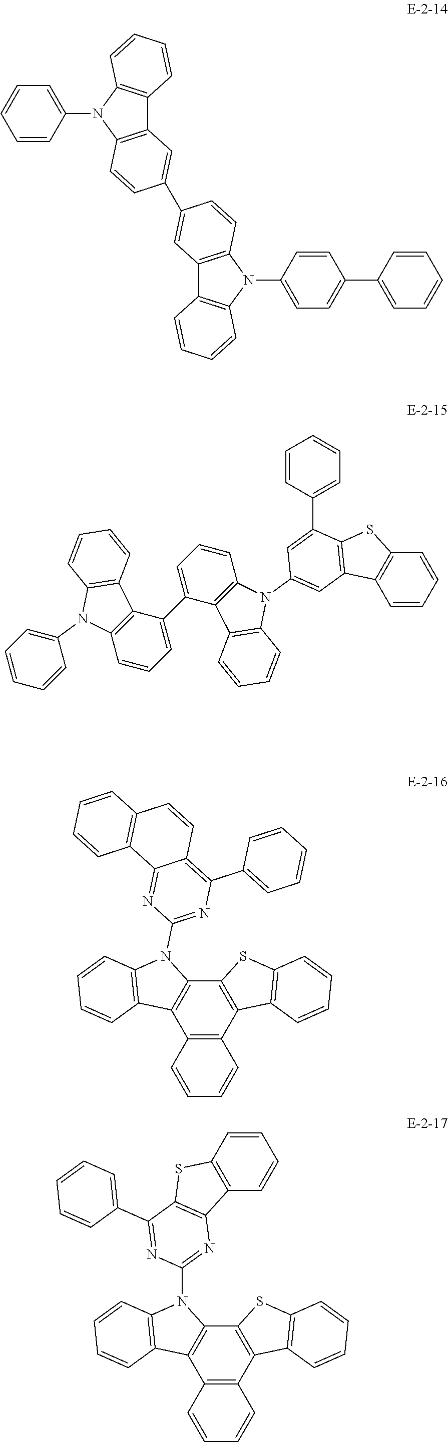

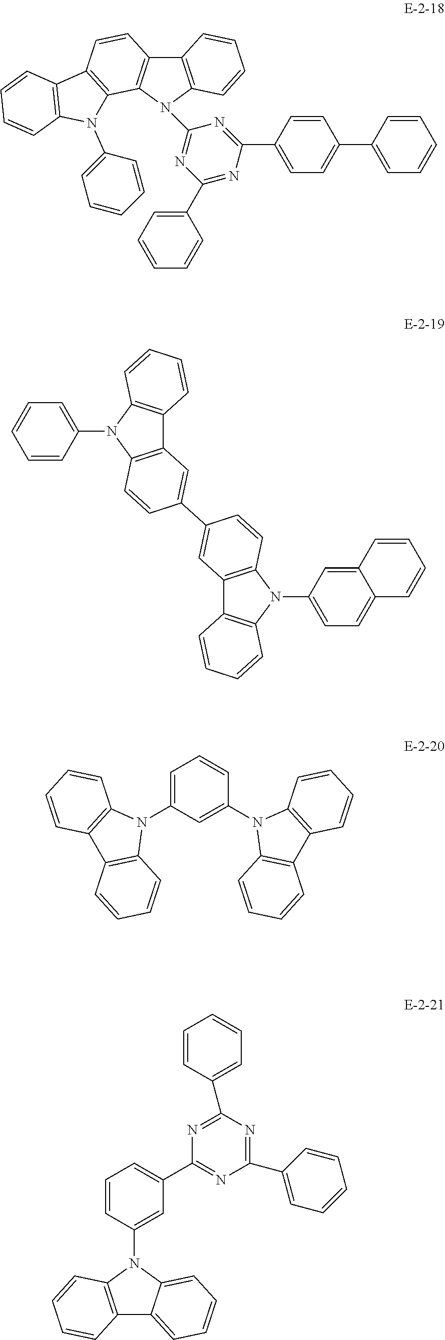 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

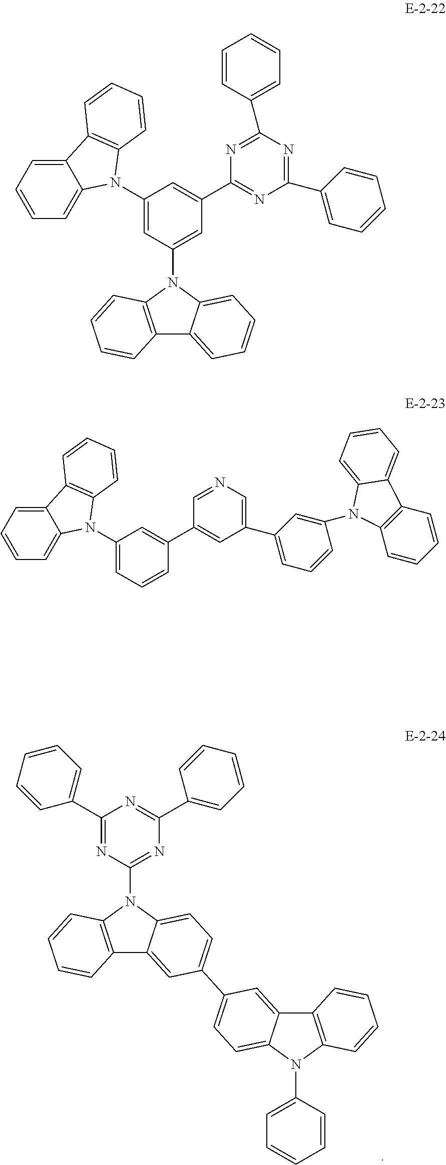 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include a general material suitable in the art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, the embodiment of the present disclosure is not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be utilized as a host material.

The emission layer EML may include the compound represented by Formula M-a. The compound represented by Formula M-a may be utilized as a phosphorescent dopant material.

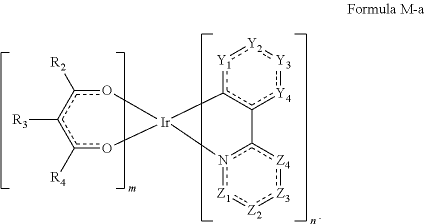

In Formula M-a above, Y₁ to Y₄ and Z₁ to Z₄ may each independently be CR₁ or N, R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In Formula M-a, m may be 0 or 1, and n may be 2 or 3. In Formula M-a, when m is 0, n is 3, and when m is 1, n is 2.

The compound represented by Formula M-a may be utilized as a phosphorescent dopant.

The compound represented by Formula M-a may be represented by any one selected from among Compound M-a1 to Compound M-a25. However, Compounds M-a1 to M-a25 are examples, and the compound represented by Formula M-a is not limited to those represented by Compounds M-a1 to M-a25.

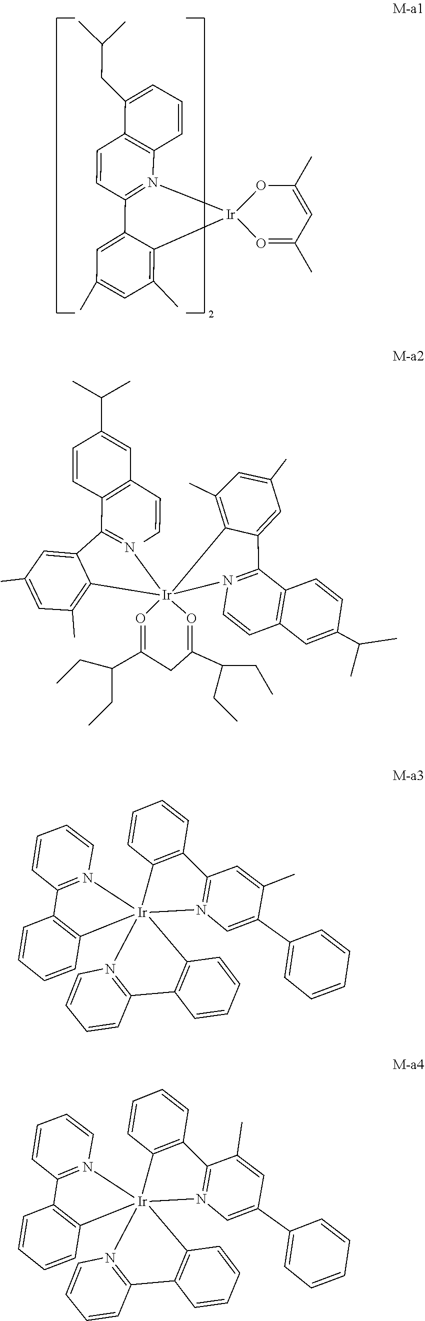

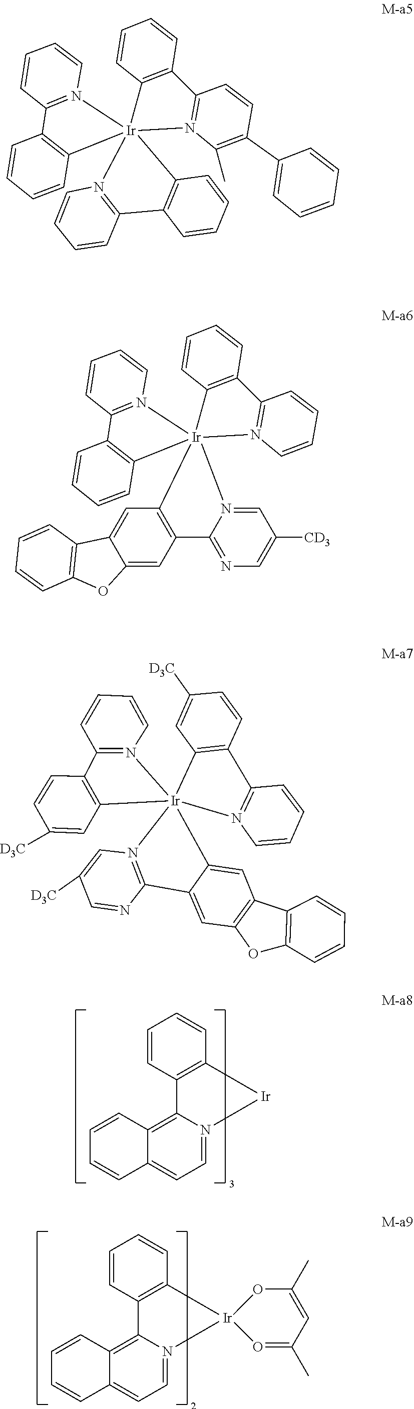

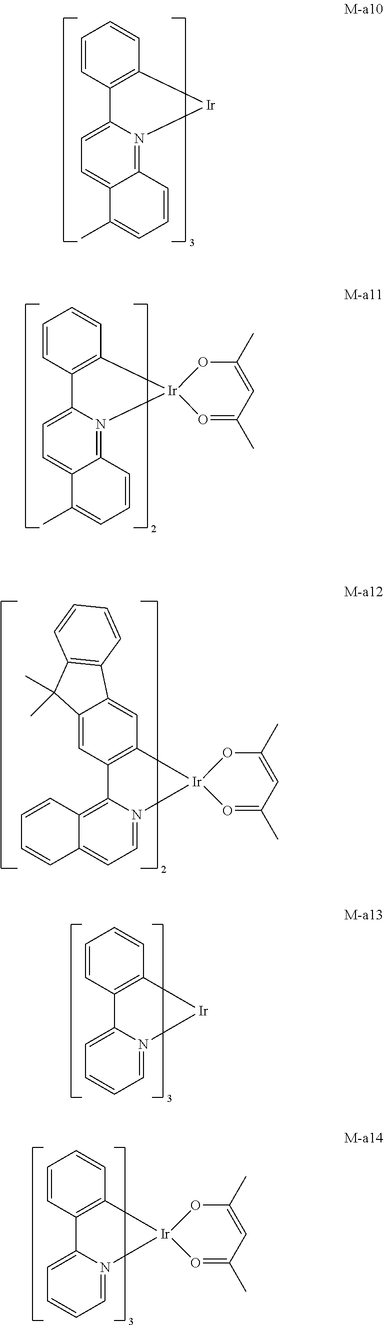

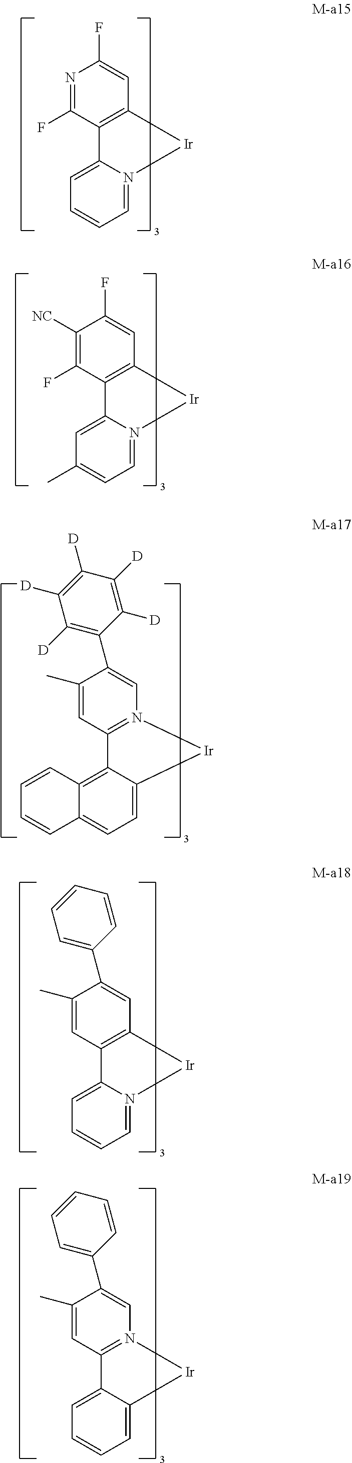

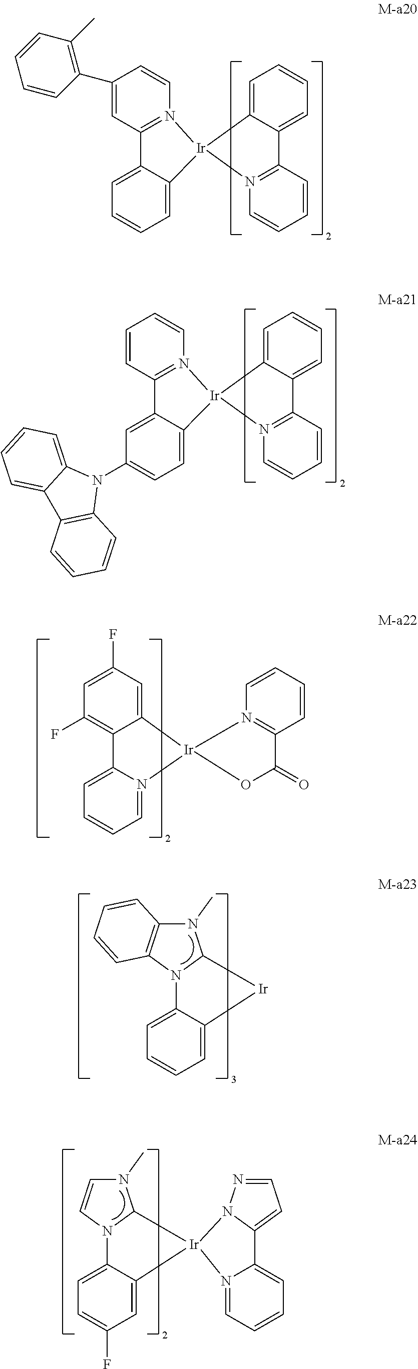

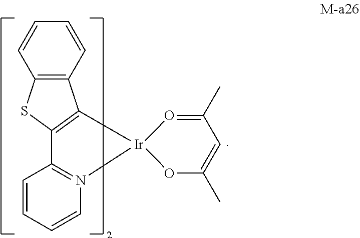

The emission layer EML may include a compound represented by any one selected from among Formula F-a to Formula F-c. The compound represented by Formula F-a or Formula F-c may be utilized as a fluorescence dopant material.

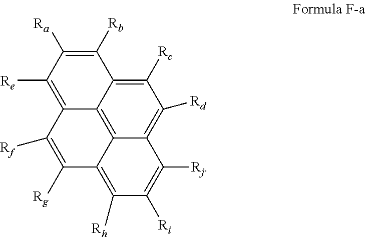

In Formula F-a above, two selected from among Rₐ to Rⱼ may each independently be substituted with [symbol] NAr₁Ar₂. Any remainder not substituted with [symbol] NAr₁Ar₂ selected from among Rₐ to Rⱼ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In [symbol] NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

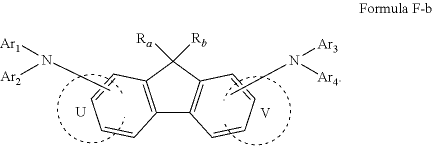

In Formula F-b above, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-b above, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b above, U and V may each independently be a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, when the number of U or V is 1, one ring indicated by U or V forms a fused ring at the designated part (e.g., a portion indicated by U or V), and when the number of U or V is 0, a ring indicated by U or V does not exist. For example, when the number of U is 0 and the number of V is 1, or when the number of U is 1 and the number of V is 0, the fused ring having a fluorene core in Formula F-b may be a cyclic compound having four rings. In some embodiments, when each number of U and V is 0, the fused ring in Formula F-b may be a cyclic compound having three rings. In some embodiments, when each number of U and V is 1, the fused ring having a fluorene core in Formula F-b may be a cyclic compound having five rings.

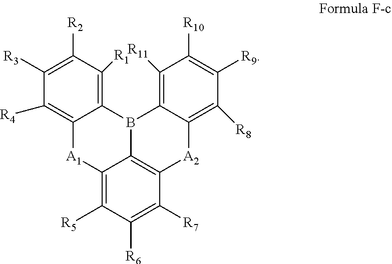

In Formula F-c, A₁ and A₂ may each independently be O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of an adjacent ring to form a condensed ring. For example, when A₁ and A₂ may each independently be NRₘ, A₁ may be bonded to R₄ or R₅ to form a ring. In some embodiments, A₂ may be bonded to R₇ or R₈ to form a ring.

In an embodiment, the emission layer EML may further include, as a suitable dopant material, one or more styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and/or N-(4-((E)-2-(6-((E)-4-(diphenylamino)styryl)naphthalen-2-yl)vinyl)phenyl)-N-phenylbenzenamine (N-BDAVBi)), 4,4′-bis[2-(4-(N,N-diphenylamino)phenyl)vinyl]biphenyl (DPAVBi), perylene and the derivatives thereof (e.g., 2,5,8,11-tetra-t-butylperylene (TBP)), pyrene and the derivatives thereof (e.g., 1,1-dipyrene, 1,4-dipyrenylbenzene, and/or 1,4-bis(N,N-diphenylamino)pyrene), etc.

The emission layer EML may further include a suitable phosphorescence dopant material. For example, a metal complex containing iridium (Ir), platinum (Pt), osmium (Os), gold (Au), titanium (Ti), zirconium (Zr), hafnium (Hf), europium (Eu), terbium (Tb), and/or thulium (Tm) may be utilized as a phosphorescent dopant. For example, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), and/or platinum octaethyl porphyrin (PtOEP) may be utilized as a phosphorescent dopant. However, the embodiment of the present disclosure is not limited thereto.

The emission layer EML may include a quantum dot material. The core of the quantum dot may be selected from among a Group II-VI compound, a Group III-VI compound, a Group I-III-IV compound, a Group III-V compound, a Group III—II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAIO₂, and a mixture thereof, or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, the binary compound, the ternary compound, and/or the quaternary compound may be present in a particle with a substantially uniform concentration distribution, or may be present in the same particle with a partially different concentration distribution. In some embodiments, the quantum dot may have a core/shell structure in which one quantum dot is around (e.g., surrounds) the other quantum dot. The core/shell structure may have a concentration gradient in which the concentration of elements present in the shell decreases toward the core.

In some embodiments, the quantum dot may have the above-described core/shell structure including a core containing nanocrystals and a shell around (e.g., surrounding) the core. The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An example of the shell of the quantum dot may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, CO₃O₄, and/or NiO, or a ternary compound such as MgAl₂O₄, CoFe₂O₄, NiFe₂O₄, and/or CoMn₂O₄, but the embodiment of the present disclosure is not limited thereto.

Also, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the embodiment of the present disclosure is not limited thereto.

The quantum dot may have a full width of half maximum (FWHM) of a light emitting wavelength spectrum of about 45 nm or less, about 40 nm or less, or about 30 nm or less. Within these ranges, color purity and/or color reproducibility may be improved. In some embodiments, light emitted through such a quantum dot is emitted in all directions, and thus a wide viewing angle may be obtained or improved.

In some embodiments, although the form of the quantum dot is not particularly limited as long as it is a form commonly utilized in the art, the quantum dot in the form of, for example, spherical, pyramidal, multi-arm, or cubic nanoparticles, nanotubes, nanowires, nanofibers, nanoplate particles, etc. may be utilized.

A quantum dot may control the color of emitted light according to the particle size thereof and thus the quantum dot may have one or more suitable light emission colors such as blue, red, and/or green.

In each light emitting device ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but the embodiment of the present disclosure is not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, or may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, or a hole blocking layer HBL/electron transport layer ETL/electron injection layer EIL are stacked in the respective stated order from the emission layer EML, but the embodiment of the present disclosure is not limited thereto. The electron transport region ETR may have a thickness, for example, from about 1,000 Å to about 1,500 Å.

The electron transport region ETR may be formed by utilizing one or more suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1:

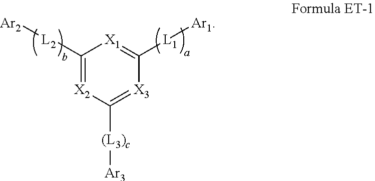

In Formula ET-1, at least one selected from among X₁ to X₃ may be N, and any remainder thereof may be CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are each an integer of 2 or more, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, the embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1, 10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAIq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

The electron transport region ETR may include at least one selected from among Compound ET1 to Compound ET36:

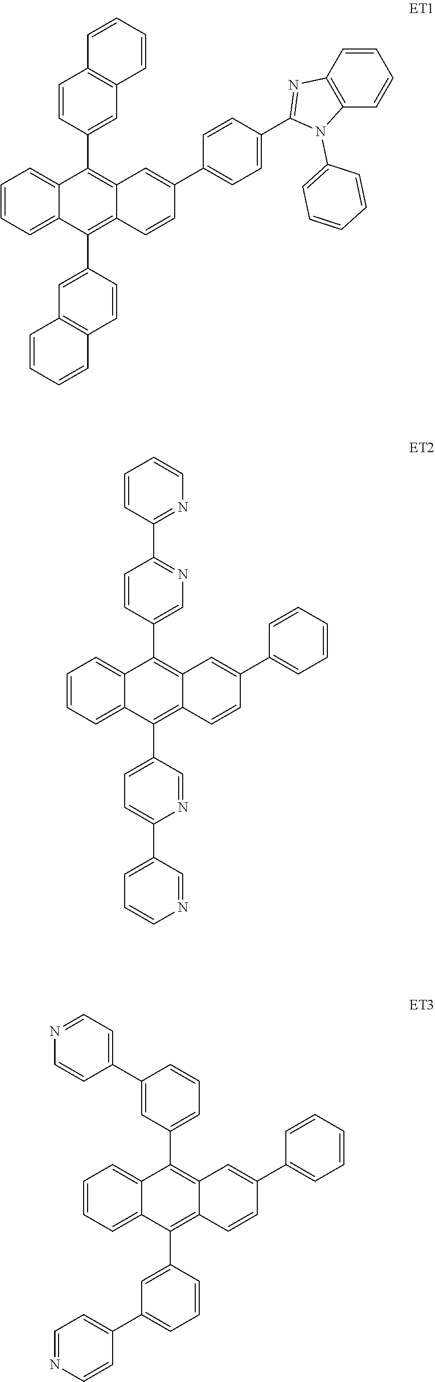 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5cccnc5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

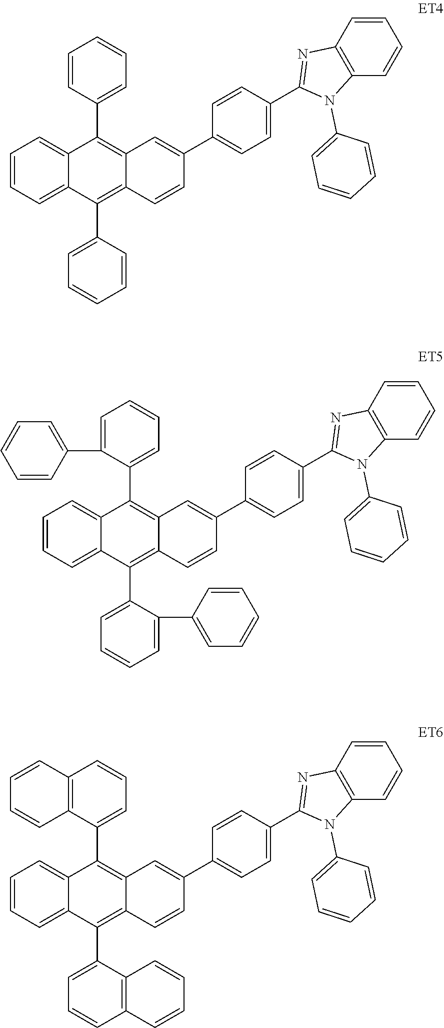 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

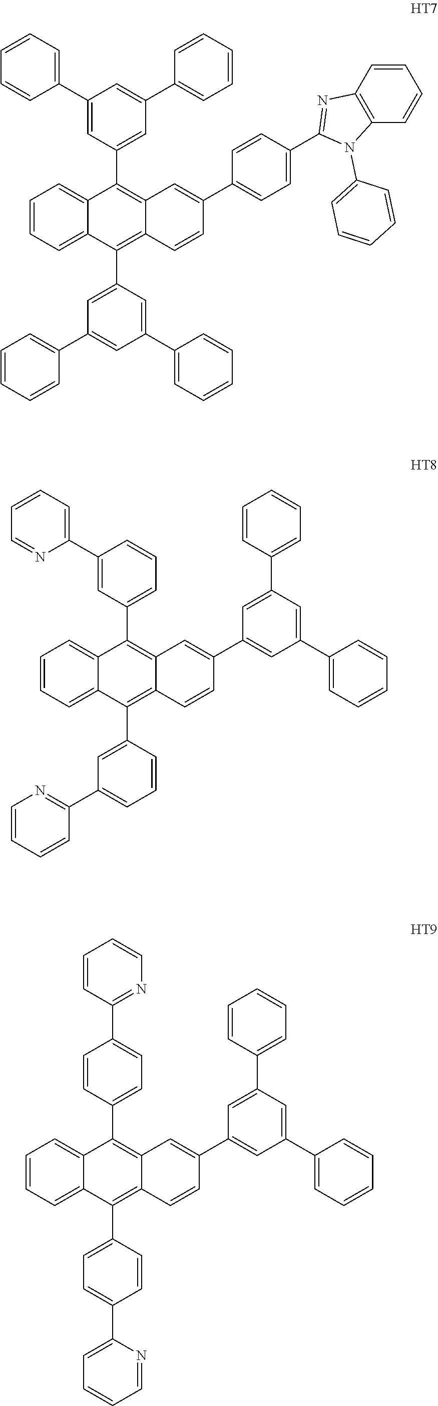 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

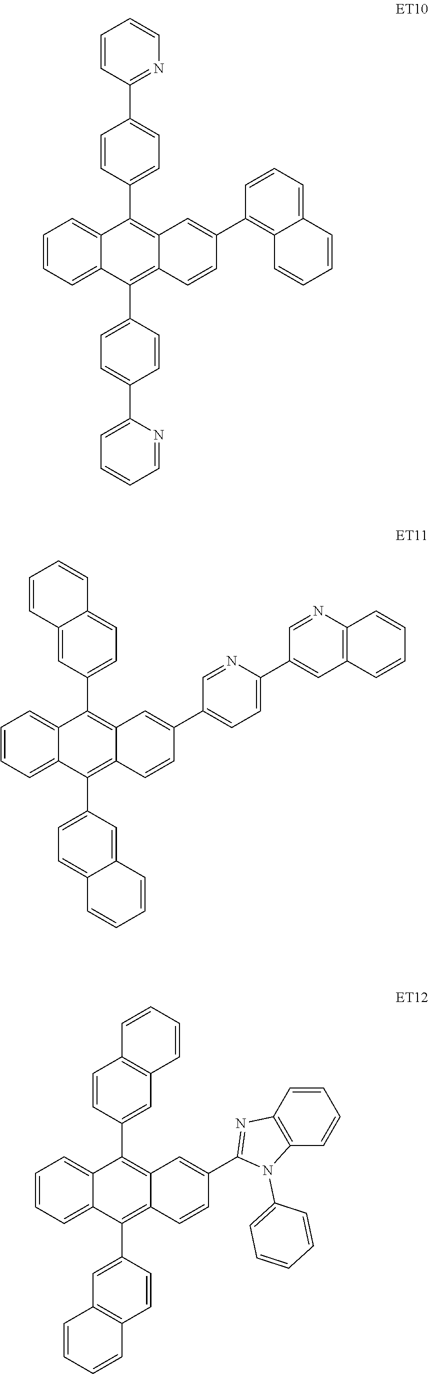 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

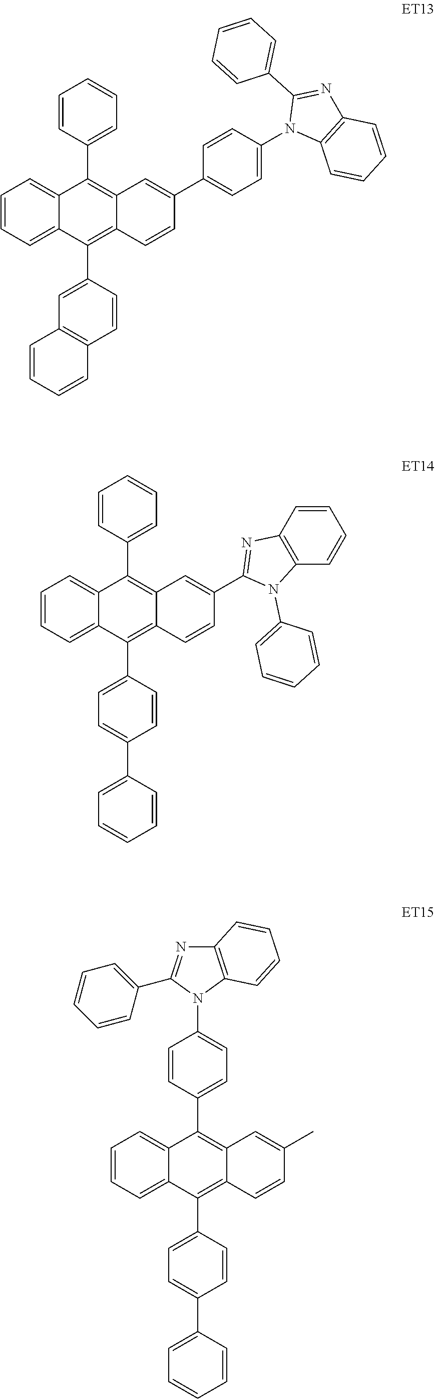 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccc(-c4ccccc4)cc3)c3ccccc3c(-c3ccc(-n4c(-c5ccccc5)nc5ccccc54)cc3)c2c1]

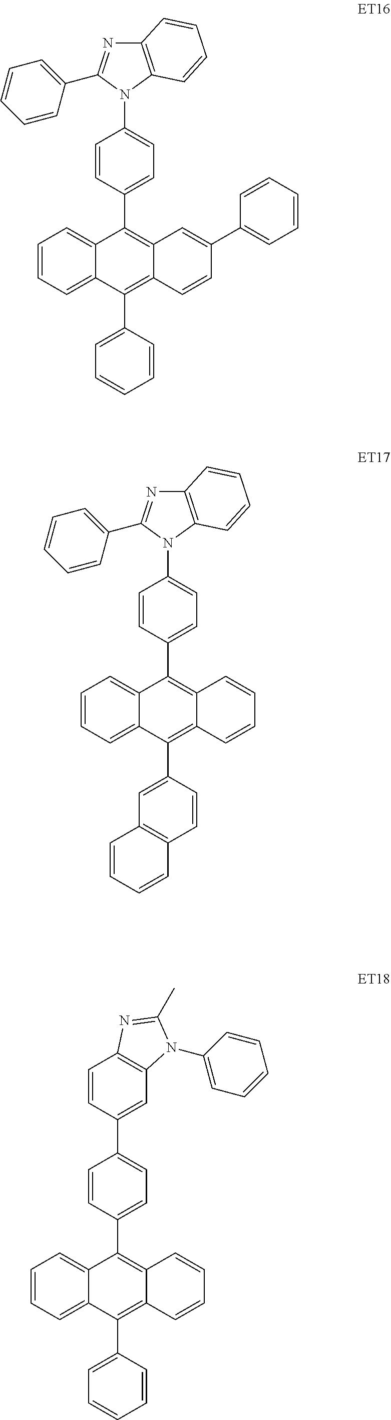 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

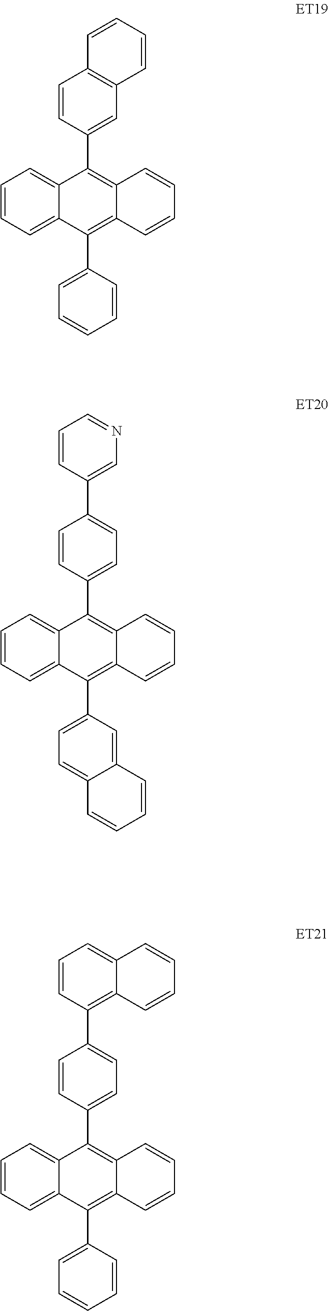

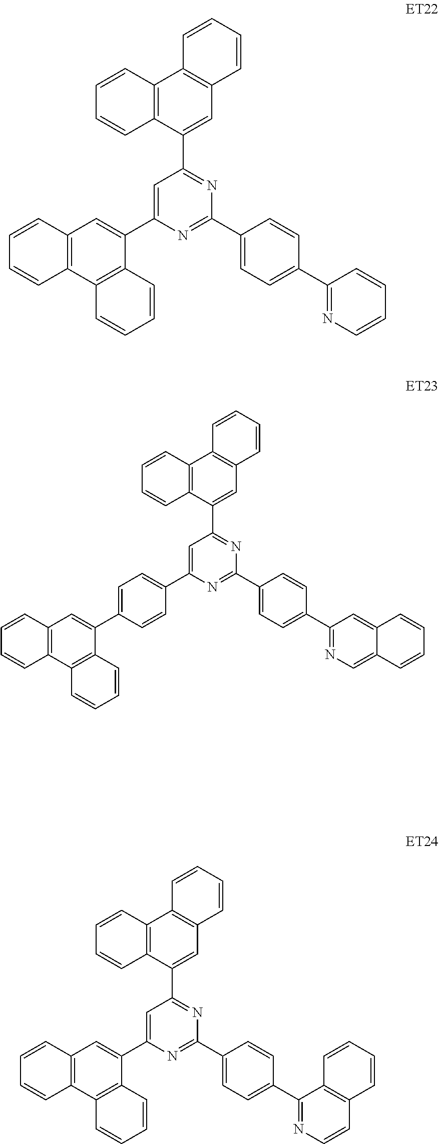 [SMILES: c1ccc(-c2ccc(-c3nc(-c4cc5ccccc5c5ccccc45)cc(-c4cc5ccccc5c5ccccc45)n3)cc2)nc1 ; c1ccc2cc(-c3ccc(-c4nc(-c5ccc(-c6cc7ccccc7c7ccccc67)cc5)cc(-c5cc6ccccc6c6ccccc56)n4)cc3)ncc2c1 ; c1ccc2c(-c3ccc(-c4nc(-c5cc6ccccc6c6ccccc56)cc(-c5cc6ccccc6c6ccccc56)n4)cc3)nccc2c1]

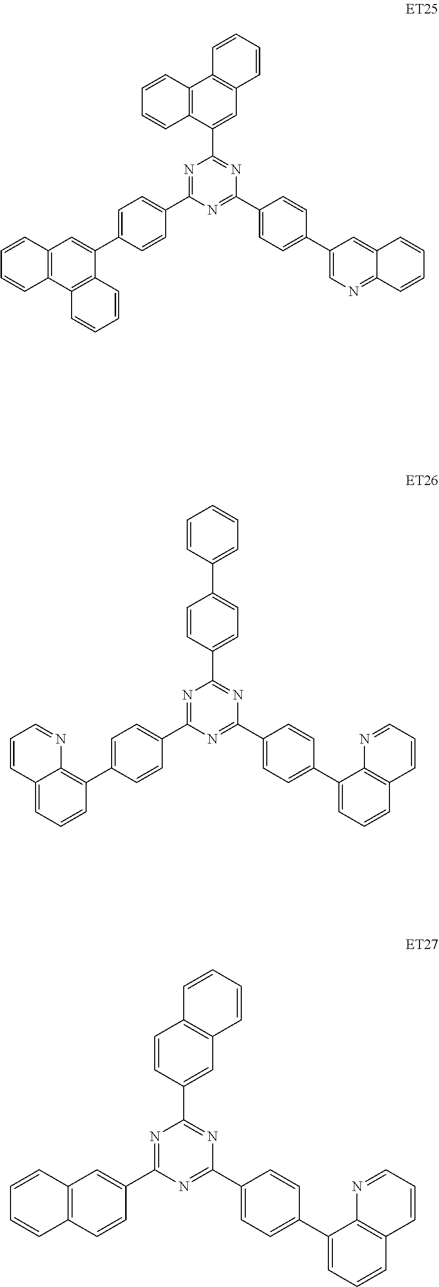 [SMILES: c1ccc2ncc(-c3ccc(-c4nc(-c5ccc(-c6cc7ccccc7c7ccccc67)cc5)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

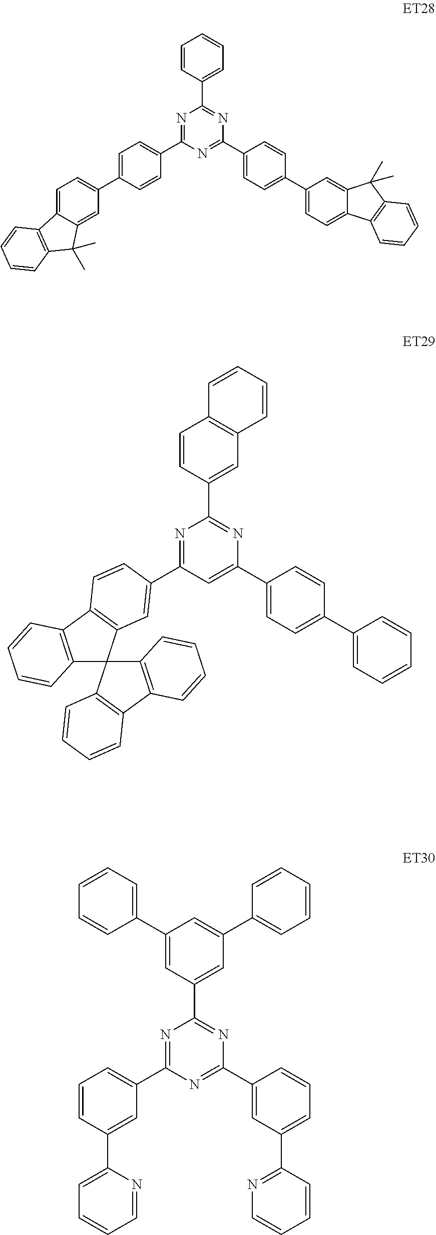 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

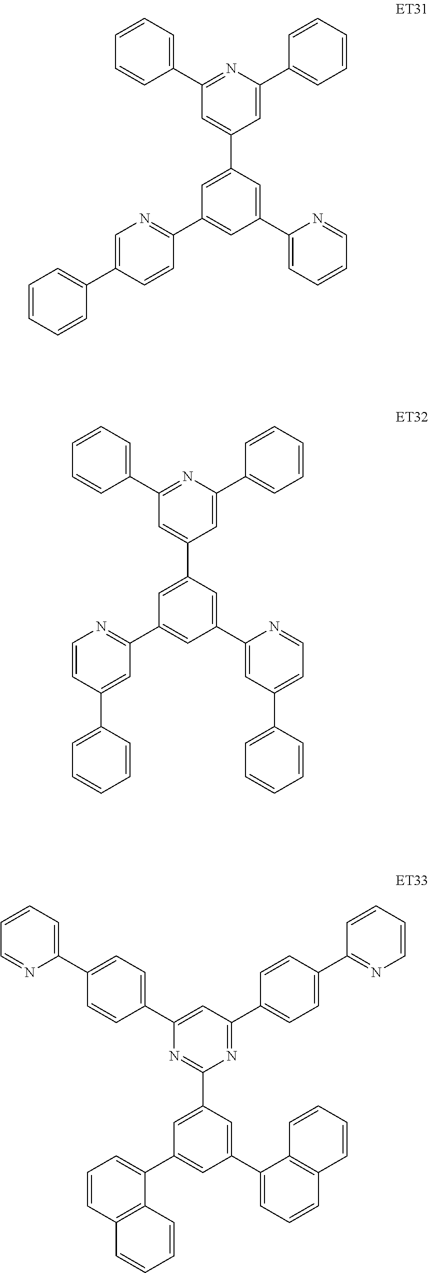 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

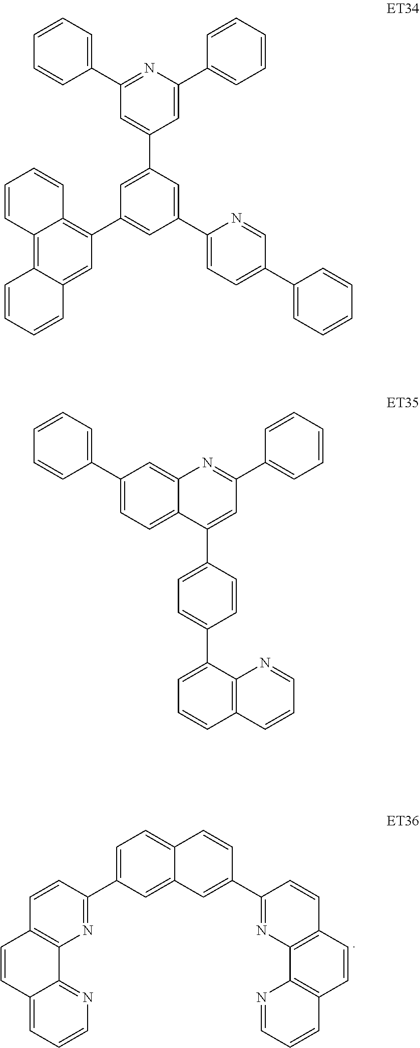 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccccc4)nc3c2)cc1 ; c1cnc2c(c1)ccc1ccc(-c3ccc4ccc(-c5ccc6ccc7cccnc7c6n5)cc4c3)nc12]

In some embodiments, the electron transport regions ETR may include a metal halide such as LiF, NaCl, CsF, RbCl, RbI, CuI, and/or KI, a lanthanide metal such as Yb, and/or a co-deposited material of the metal halide and the lanthanide metal. For example, the electron transport region ETR may include KI:Yb, RbI:Yb, LiF:Yb, etc. as a co-deposited material. In some embodiments, the electron transport region ETR may be formed utilizing a metal oxide such as Li₂O and/or BaO, and/or 8-hydroxyl-lithium quinolate (Liq), etc., but the embodiment of the present disclosure is not limited thereto. The electron transport region ETR may also be formed of a mixture material of an electron transport material and an insulating organometallic salt. The organometallic salt may be a material having an energy band gap of about 4 eV or more. For example, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1, 10-phenanthroline (BCP), diphenyl(4-(triphenylsilyl)phenyl)phosphine oxide (TSPO1), or 4,7-diphenyl-1, 10-phenanthroline (Bphen) in addition to the above-described materials, but the embodiment of the present disclosure is not limited thereto.

The electron transport region ETR may include the above-described compounds of the electron transport region ETR in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. When the thickness of the electron transport layer ETL satisfies the aforementioned ranges, satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but the embodiment of the present disclosure is not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, or a compound or mixture thereof (e.g., AgMg, AgYb, or MgAg). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include one or more of the above-described metal materials, combinations of at least two metal materials of the above-described metal materials, oxides of the above-described metal materials, and/or the like.

In some embodiments, the second electrode EL2 may be connected with an auxiliary electrode. When the second electrode EL2 is connected with the auxiliary electrode, the resistance of the second electrode EL2 may decrease.

In some embodiments, a capping layer CPL may be further disposed on the second electrode EL2 of the light emitting device ED of an embodiment. The capping layer CPL may include a multilayer or a single layer.

In an embodiment, the capping layer CPL may be an organic layer or an inorganic layer. For example, when the capping layer CPL contains an inorganic material, the inorganic material may include an alkali metal compound (for example, LiF), an alkaline earth metal compound (for example, MgF₂), SiON, SiNₓ, SiOy, etc.

For example, when the capping layer CPL contains an organic material, the organic material may include 2,2′-dimethyl-N,N′-di-[(1-naphthyl)-N,N′-diphenyl]-1,1′-biphenyl-4,4′-diamine(α-NPD), NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., and/or may include an epoxy resin, and/or an acrylate such as a methacrylate. However, the embodiment of the present disclosure is not limited thereto, and the capping layer CPL may include at least one selected from among Compounds P1 to P5:

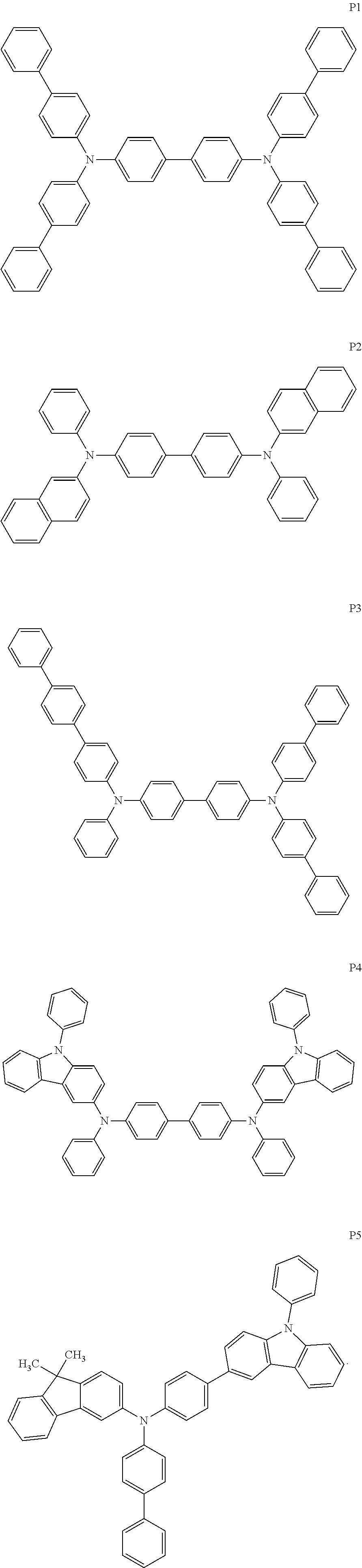 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In some embodiments, the refractive index of the capping layer CPL may be about 1.6 or more. For example, the refractive index of the capping layer CPL may be 1.6 or more with respect to light in a wavelength range of about 550 nm to about 660 nm.

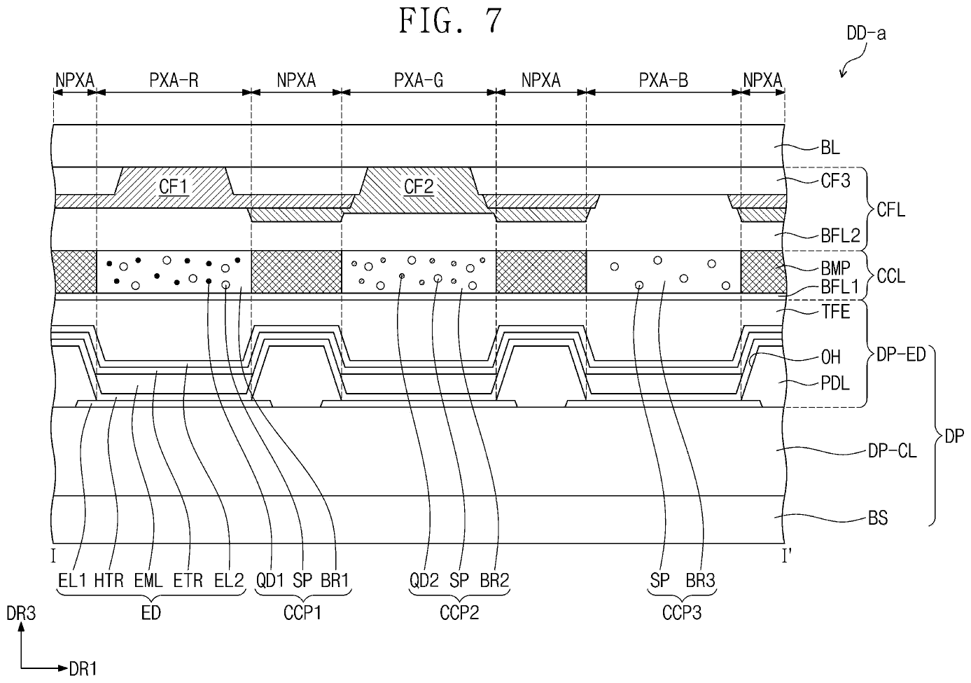

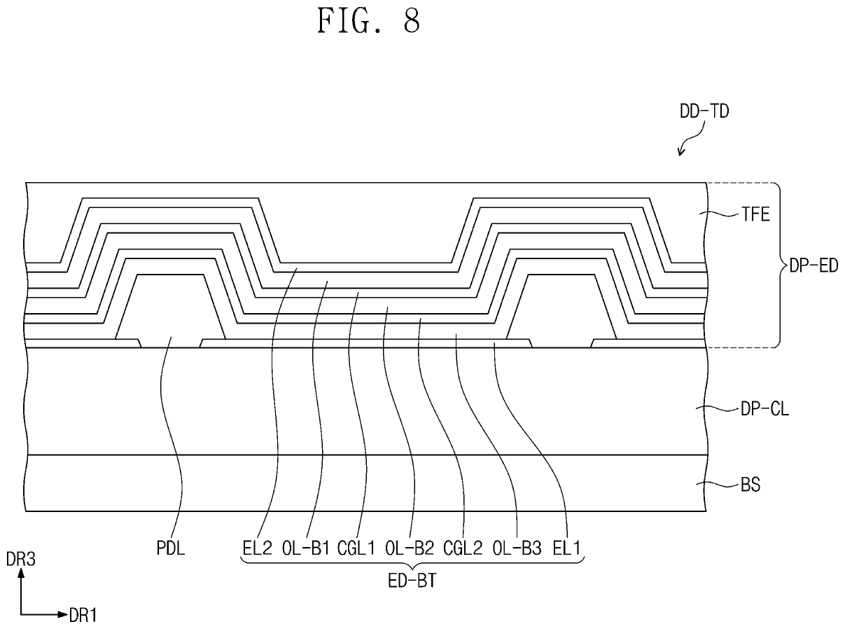

Each of FIGS. 7 and 8 is a cross-sectional view of a display apparatus according to an embodiment of the present disclosure. Hereinafter, in describing the display apparatuses of embodiments with reference to FIGS. 7 and 8, the duplicated features which have been described in FIGS. 1 to 6 are not described again, but their differences will be mainly described.

Referring to FIG. 7, the display apparatus DD-a according to an embodiment may include a display panel DP including a display apparatus layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In some embodiments, the structures of the light emitting devices of FIGS. 3 to 6 as described above may be equally applied to the structure of the light emitting device ED illustrated in FIG. 7.

The emission layer EML of the light emitting device ED included in the display apparatus DD-a according to an embodiment may include the above-described fused polycyclic compound of an embodiment.

Referring to FIG. 7, the emission layer EML may be disposed in an opening OH defined in a pixel defining film PDL. For example, the emission layer EML which is divided by the pixel defining film PDL and provided corresponding to each light emitting regions PXA-R, PXA-G, and PXA-B may be to emit light in substantially the same wavelength range. In the display apparatus DD of an embodiment, the emission layer EML may be to emit blue light. In some embodiments, unlike the configuration illustrated, the emission layer EML may be provided as a common layer in the entire light emitting regions PXA-R, PXA-G, and PXA-B.

The light control layer CCL may be disposed on the display panel DP. The light control layer CCL may include a light conversion body. The light conversion body may be a quantum dot, a phosphor, and/or the like. The light conversion body may convert the wavelength of provided light and emit the converted light. For example, the light control layer CCL may be a layer containing the quantum dot or a layer containing the phosphor.

The light control layer CCL may include a plurality of light control parts CCP1, CCP2 and CCP3. The light control parts CCP1, CCP2, and CCP3 may be spaced apart from each other.

Referring to FIG. 7, divided patterns BMP may be disposed between the light control parts CCP1, CCP2 and CCP3 which are spaced apart from each other, but the embodiment of the present disclosure is not limited thereto. FIG. 7 illustrates that the divided patterns BMP do not overlap the light control parts CCP1, CCP2 and CCP3, but in some embodiments, at least a portion of the edges of the light control parts CCP1, CCP2 and CCP3 may overlap the divided patterns BMP.

The light control layer CCL may include a first light control part CCP1 containing a first quantum dot QD1 which converts a first color light provided from the light emitting device ED into a second color light, a second light control part CCP2 containing a second quantum dot QD2 which converts the first color light into a third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described above may be applied with respect to the quantum dots QD1 and QD2.

In some embodiments, the light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include (e.g., may exclude) any quantum dot but may include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, or may be a mixture of at least two materials selected from among TiO₂, ZnO, Al₂O₃, SiO₂, and hollow sphere silica.

The first light control part CCP1, the second light control part CCP2, and the third light control part CCP3 may each include a corresponding one of the base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in the first base resin BR1, the second light control part CCP2 may include the second quantum dot QD2 and the scatterer SP dispersed in the second base resin BR2, and the third light control part CCP3 may include the scatterer SP dispersed in the a third base resin BR3. The base resins BR1, BR2, and BR3 are media in which the quantum dots QD1 and QD2 and the scatterer SP are dispersed, and may be formed of one or more suitable resin compositions, which may be generally referred to as a binder. For example, the base resins BR1, BR2, and BR3 may each independently be one or more of acrylic-based resins, urethane-based resins, silicone-based resins, epoxy-based resins, etc. The base resins BR1, BR2, and BR3 may each be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, referred to as ‘moisture/oxygen’). The barrier layer BFL1 may be disposed on the light control parts CCP1, CCP2, and CCP3 to block or reduce the exposure of the light control parts CCP1, CCP2 and CCP3 to moisture/oxygen. In some embodiments, the barrier layer BFL1 may cover the light control parts CCP1, CCP2, and CCP3. In some embodiments, a barrier layer BFL2 may be provided between the light control parts CCP1, CCP2, and CCP3 and filters CF1, CF2, and CF3.

The barrier layers BFL1 and BFL2 may include at least one inorganic layer. For example, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display apparatus DD-a of an embodiment, the color filter layer CFL may be disposed on the light control layer CCL. For example, the color filter layer CFL may be directly disposed on the light control layer CCL. In this case, the barrier layer BFL2 may not be provided.

The color filter layer CFL may include a light shielding part BM and color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment and/or dye. The first filter CF1 may include a red pigment and/or dye, the second filter CF2 may include a green pigment and/or dye, and the third filter CF3 may include a blue pigment and/or dye. In some embodiments, the embodiment of the present disclosure is not limited thereto, and the third filter CF3 may not include (e.g., may exclude) any pigment or dye. The third filter CF3 may include a polymeric photosensitive resin and may not include (e.g., may exclude) any pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated but be provided as one filter.

The light shielding part BM may be a black matrix. The light shielding part BM may include an organic light shielding material or an inorganic light shielding material containing a black pigment and/or dye. The light shielding part BM may prevent or reduce light leakage, and may separate boundaries between the adjacent filters CF1, CF2, and CF3. In some embodiments, the light shielding part BM may be formed of a blue filter.

The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may be a member which provides a base surface in which the color filter layer CFL, the light control layer CCL, and/or the like are disposed. The base substrate BL may be a glass substrate, a metal substrate, a plastic substrate, etc. However, the embodiment of the present disclosure is not limited thereto, and the base substrate BL may be an inorganic layer, an organic layer, or a composite material layer. In some embodiments, unlike the configuration illustrated, the base substrate BL may not be provided.

FIG. 8 is a cross-sectional view illustrating a portion of a display apparatus according to an embodiment. In the display apparatus DD-TD of an embodiment, the light emitting device ED-BT may include a plurality of light emitting structures OL-B1, OL-B2, and OL-B3. The light emitting device ED-BT may include a first electrode EL1 and a second electrode EL2 facing the first electrode EL1, and the plurality of light emitting structures OL-B1, OL-B2, and OL-B3 sequentially stacked in the stated order in the thickness direction between the first electrode EL1 and the second electrode EL2. The light emitting structures OL-B1, OL-B2, and OL-B3 may each include an emission layer EML (FIG. 7) and a hole transport region HTR and an electron transport region ETR disposed with the emission layer EML (FIG. 7) located therebetween.

For example, the light emitting device ED-BT included in the display apparatus DD-TD of an embodiment may be a light emitting device having a tandem structure and including a plurality of emission layers.

In an embodiment illustrated in FIG. 8, light (e.g., light beams) respectively emitted from the light emitting structures OL-B1, OL-B2, and OL-B3 may all be blue light. However, the embodiment of the present disclosure is not limited thereto, and the light (e.g., light beams) respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light (e.g., light beams) having wavelength ranges different from each other may be to emit white light.

Charge generation layers CGL1 and CGL2 may be respectively disposed between two of the neighboring light emitting structures OL-B1, OL-B2, and OL-B3. The charge generation layers CGL1 and CGL2 may include a p-type or kind charge generation layer and/or an n-type or kind charge generation layer.

At least one selected from among the light emitting structures OL-B1, OL-B2, and OL-B3 included in the display apparatus DD-TD of an embodiment may contain the above-described fused polycyclic compound of an embodiment. For example, at least one selected from among the plurality of emission layers included in the light emitting device ED-BT may include the fused polycyclic compound of an embodiment.

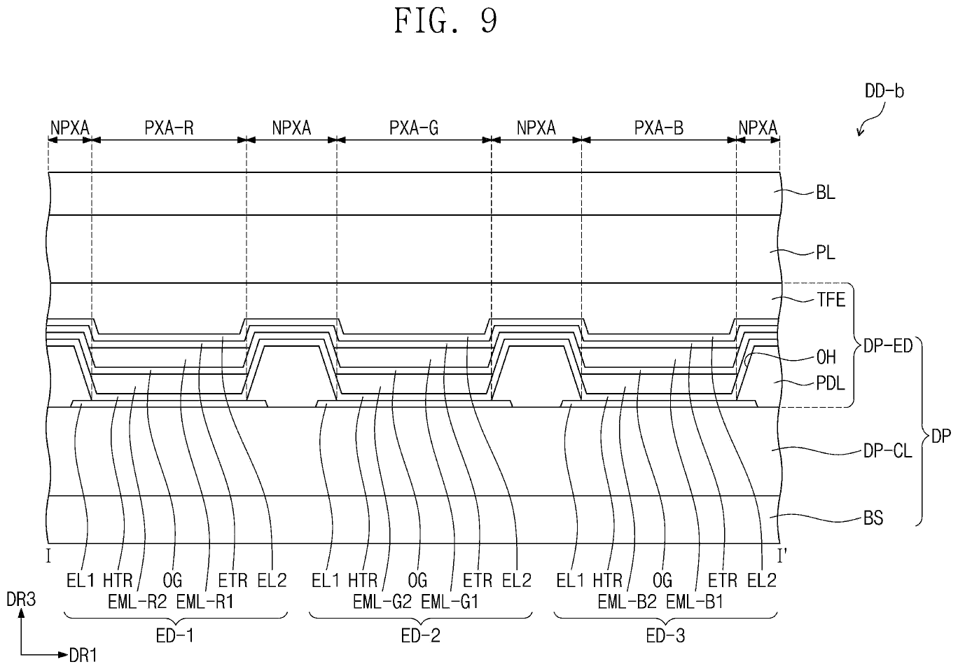

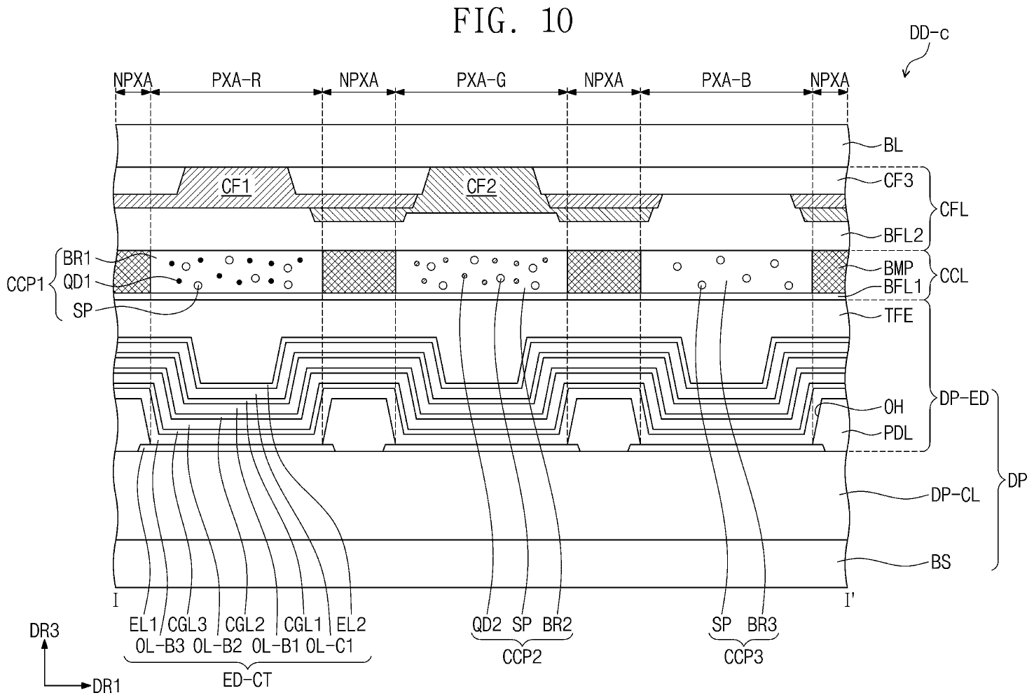

FIG. 9 is a cross-sectional view illustrating a display apparatus according to an embodiment of the present disclosure; and FIG. 10 is a cross-sectional view illustrating a display apparatus according to an embodiment of the present disclosure.

Referring to FIG. 9, the display apparatus DD-b according to an embodiment may include light emitting devices ED-1, ED-2, and ED-3, each formed by stacking two emission layers over each other. Compared with the display apparatus DD of an embodiment illustrated in FIG. 2, an embodiment illustrated in FIG. 9 has a difference in that the first to third light emitting devices ED-1, ED-2, and ED-3 each include two emission layers stacked in the thickness direction. In each of the first to third light emitting devices ED-1, ED-2, and ED-3, the two emission layers may be to emit light in substantially the same wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In some embodiments, the third light emitting device ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked in the stated order. The emission auxiliary part OG may be provided as a common layer in all (e.g., the whole) of the first to third light emitting devices ED-1, ED-2, and ED-3. However, the embodiment of the present disclosure is not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be disposed between the electron transport region ETR and the emission auxiliary part OG. The second red emission layer EML-R2, the second green emission layer EML-G2, and the second blue emission layer EML-B2 may be disposed between the emission auxiliary part OG and the hole transport region HTR.

For example, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked in the stated order. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked in the stated order. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked in the stated order.

In some embodiments, an optical auxiliary layer PL may be disposed on the display device layer DP-ED. The optical auxiliary layer PL may include a polarizing layer. The optical auxiliary layer PL may be disposed on the display panel DP and control reflected light in the display panel DP due to external light. Unlike the configuration illustrated, the optical auxiliary layer PL in the display apparatus according to an embodiment may not be provided.

At least one emission layer included in the display apparatus DD-b of an embodiment illustrated in FIG. 9 may include the above-described fused polycyclic compound of an embodiment. For example, in an embodiment, at least one of the first blue emission layer EML-B1 or the second blue emission layer may include the fused polycyclic compound of an embodiment.

Unlike FIGS. 8 and 9, FIG. 10 illustrates that a display apparatus DD-c includes four light emitting structures OL-B1, OL-B2, OL-B3, and OL-C1. A light emitting device ED-CT may include a first electrode EL1 and a second electrode EL2 facing the first electrode EL1, and first to fourth light emitting structures OL-B1, OL-B2, OL-B3, and OL-C1 that are sequentially stacked in the thickness direction between the first electrode EL1 and the second electrode EL2 in the stated order. Charge generation layers CGL1, CGL2, and CGL3 may be disposed between the first to fourth light emitting structures OL-B1, OL-B2, OL-B3, and OL-C1. From among the four light emitting structures, the first to third light emitting structures OL-B1, OL-B2, and OL-B3 may be to emit blue light, and the fourth light emitting structure OL-C1 may be to emit green light. However, the embodiment of the present disclosure is not limited thereto, and the first to fourth light emitting structures OL-B1, OL-B2, OL-B3, and OL-C1 may be to emit light (e.g., light beams) in different wavelength regions.

The charge generation layers CGL1, CGL2, and CGL3 disposed between adjacent light emitting structures OL-B1, OL-B2, OL-B3, and OL-C1 may include a p-type or kind charge generation layer and/or an n-type or kind charge generation layer.

At least one selected from among the light emitting structures OL-B1, OL-B2, OL-B3, and OL-C1 included in the display apparatus DD-c of an embodiment may contain the above-described fused polycyclic compound of an embodiment. For example, in an embodiment, at least one selected from among the first to third light emitting structures OL-B1, OL-B2, and OL-B3 may include the described-above fused polycyclic compound of an embodiment.

Hereinafter, with reference to Examples and Comparative Examples, a condensed polycyclic compound according to an embodiment of the present disclosure and a luminescence device of an embodiment of the present disclosure will be described in more detail. In addition, Examples described below are only illustrations to assist the understanding of the present disclosure, and the scope of the present disclosure is not limited thereto.

### EXAMPLES

### 1. Synthesis of Fused Polycyclic Compound

First, a synthetic method of the fused polycyclic compound according to the current embodiment will be described by illustrating a synthetic method of compounds 18, 20, 27, 36, 37, 55, 60, 81, and 102. In addition, the synthetic methods of the fused polycyclic compounds as described below are only examples, and the synthetic method of the fused polycyclic compound according to an embodiment of the present disclosure is not limited to the following examples.

### (1) Synthesis of Compound 18

Fused polycyclic Compound 18 according to an embodiment may be synthesized, for example, by the reaction below:

### Synthesis of Intermediate Compound 18-1

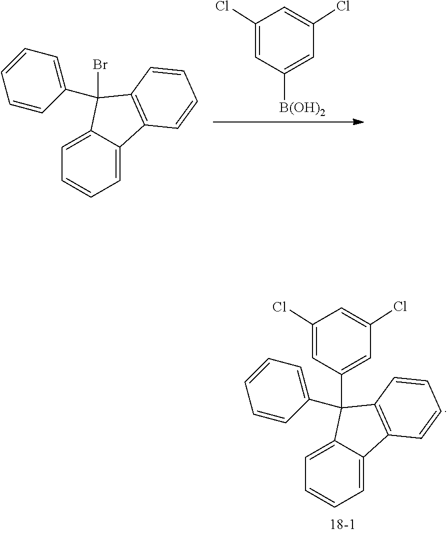 [SMILES: BrC1(c2ccccc2)c2ccccc2-c2ccccc21 ; OB(O)c1cc(Cl)cc(Cl)c1 ; Clc1cc(Cl)cc(C2(c3ccccc3)c3ccccc3-c3ccccc32)c1]

In an argon atmosphere, 9-bromo-9-phenyl-9H-fluorene (1 eq), (3,5-dichlorophenyl)boronic acid (1.5 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After being cooled, the resulting product was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate Compound 18-1. (yield: 82%)

### Synthesis of Intermediate Compound 18-2

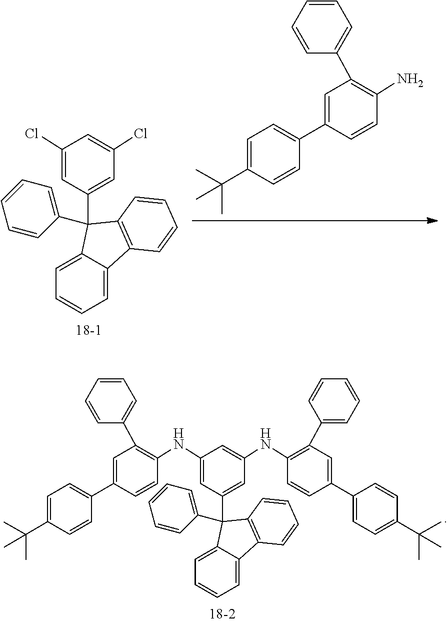

In an argon atmosphere, Compound 18-1 (1 eq), 4-(tert-butyl)-[1,1′:3′,1″-terphenyl]-4′-amine (1 eq), Pd₂dba₃ (0.05 eq), tris-tert-butyl phosphine (0.1 eq), and sodium tert-butoxide (1.5 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 18-2. (yield: 75%)

### Synthesis of Intermediate Compound 18-3

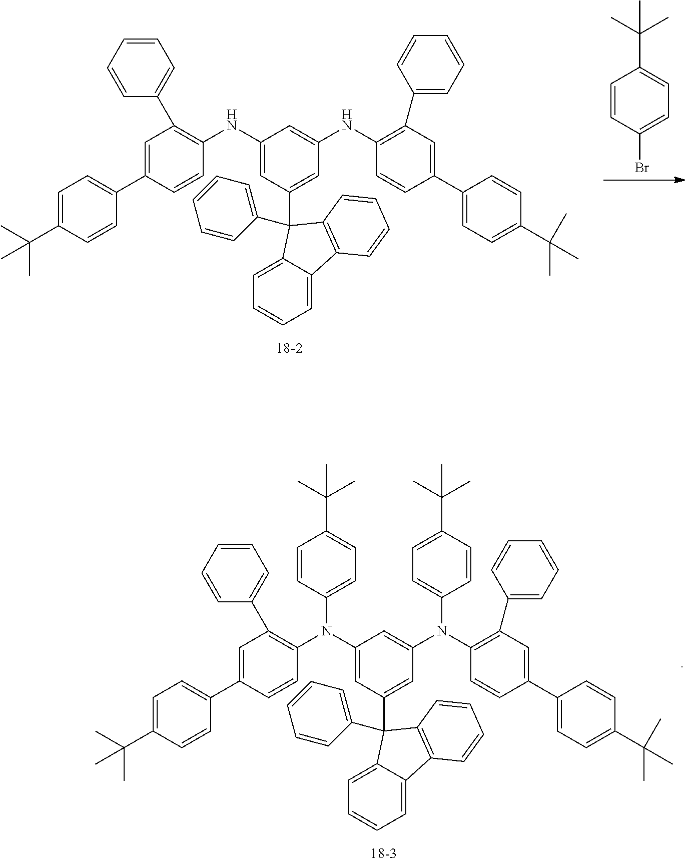

In an argon atmosphere, Compound 18-2 (1 eq), 1-bromo-4-(tert-butyl)benzene (10 eq), Pd₂dba₃ (0.5 eq), tris-tert-butyl phosphine (1 eq), and sodium tert-butoxide (4 eq) were added and dissolved in o-xylene, and then the reaction solution was stirred at about 160° C. for about 3 days. After being cooled, the reaction solution was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 18-3. (yield: 51%)

### Synthesis of Compound 18

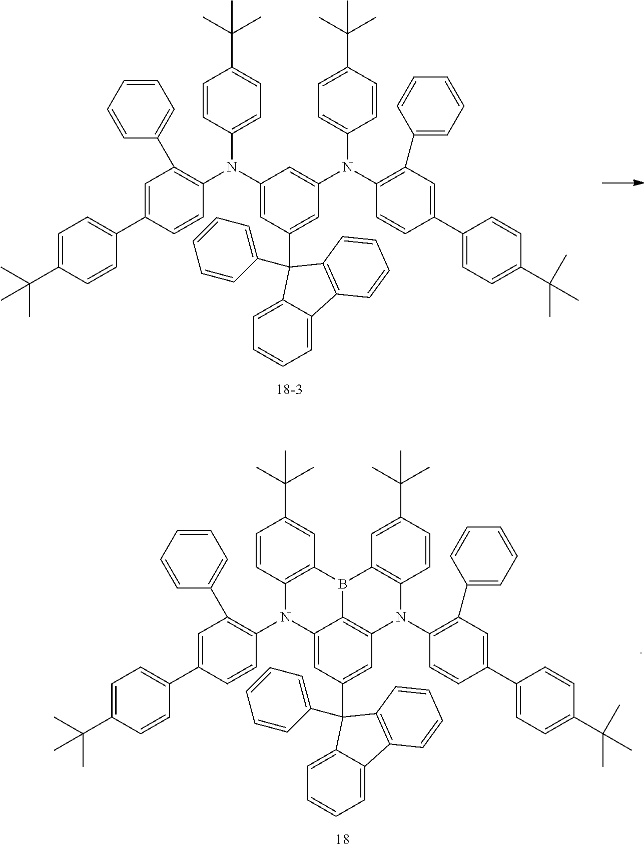

In an argon atmosphere, Compound 18-3 (1 eq) was dissolved in o-dichlorobenzene, then cooled utilizing water and ice, and BBr₃ (5 equiv.) was slowly added dropwise thereto, and then the reaction solution was stirred at about 180° C. for about 12 hours. After the resulting product was cooled, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 18. (yield: 34%)

### (2) Synthesis of Compound 20

Fused polycyclic Compound 20 according to an embodiment may be synthesized, for example, by the reaction below:

### Synthesis of Intermediate Compound 20-1

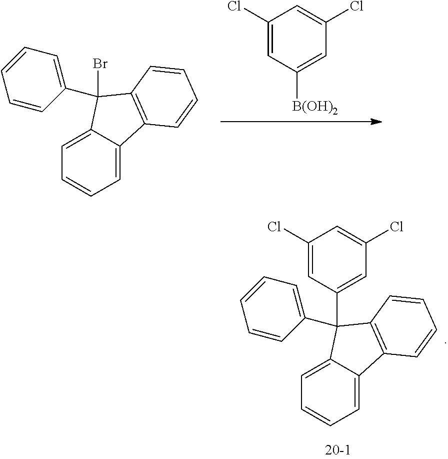 [SMILES: BrC1(c2ccccc2)c2ccccc2-c2ccccc21 ; OB(O)c1cc(Cl)cc(Cl)c1 ; Clc1cc(Cl)cc(C2(c3ccccc3)c3ccccc3-c3ccccc32)c1]

In an argon atmosphere, 9-bromo-9-phenyl-9H-fluorene (1 eq), (3,5-dichlorophenyl)boronic acid (1.5 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After being cooled, the resulting product was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate Compound 20-1. (yield: 82%)

### Synthesis of Intermediate Compound 20-2

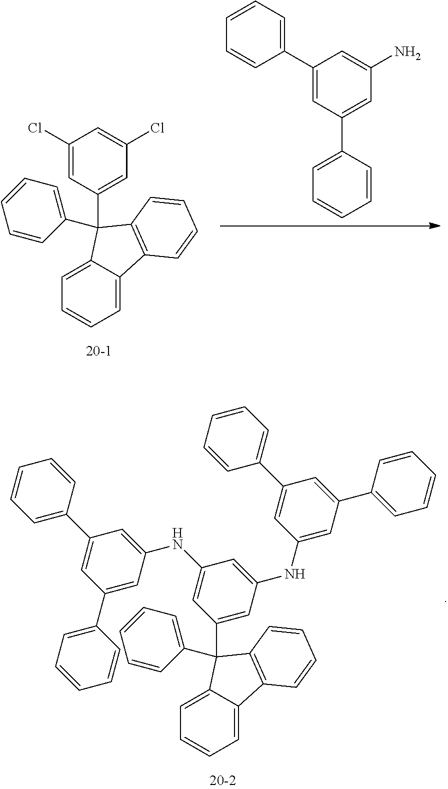 [SMILES: Clc1cc(Cl)cc(C2(c3ccccc3)c3ccccc3-c3ccccc32)c1 ; Nc1cc(-c2ccccc2)cc(-c2ccccc2)c1 ; c1ccc(-c2cc(Nc3cc(Nc4cc(-c5ccccc5)cc(-c5ccccc5)c4)cc(C4(c5ccccc5)c5ccccc5-c5ccccc54)c3)cc(-c3ccccc3)c2)cc1]

In an argon atmosphere, Intermediate Compound 20-1 (1 eq), [1,1:3,1″-terphenyl]-5′-amine (1 eq), Pd₂dba₃ (0.05 eq), tris-tert-butyl phosphine (0.1 eq), and sodium tert-butoxide (2 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 20-2. (yield: 82%)

### Synthesis of Intermediate Compound 20-3

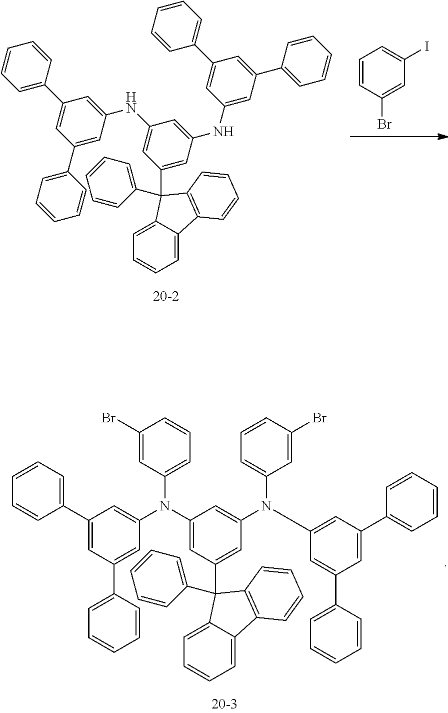

In an argon atmosphere, Intermediate Compound 20-2 (1 eq), 3-iodobromobenzene (10 eq), Pd₂dba₃ (0.5 eq), tris-tert-butyl phosphine (1 eq), and sodium tert-butoxide (4 eq) were added and dissolved in o-xylene, and then the reaction solution was stirred at about 160° C. for about 3 days. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 20-3. (yield: 62%)

### Synthesis of Intermediate Compound 20-4

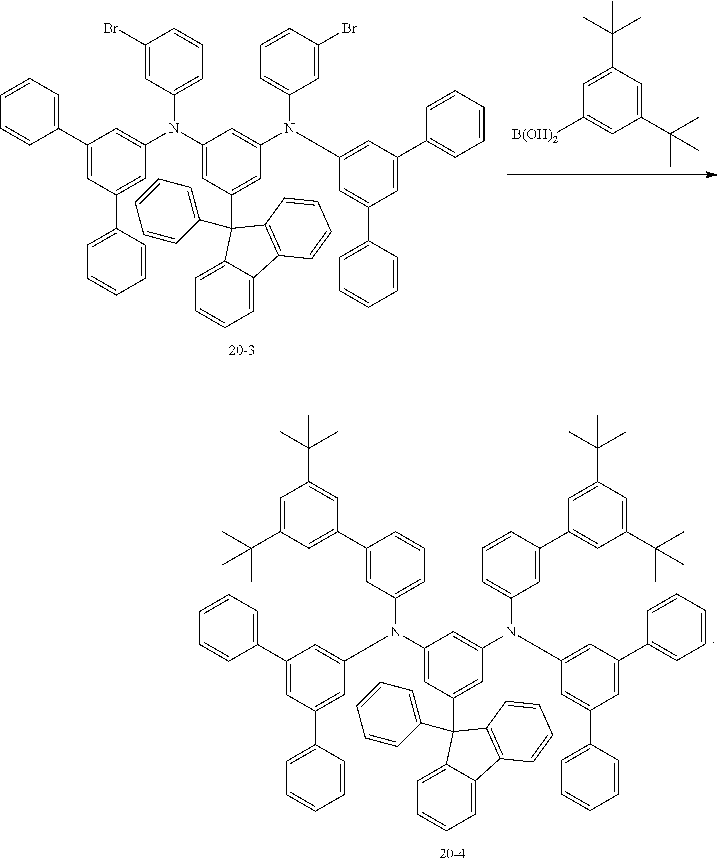 [SMILES: Brc1cccc(N(c2cc(-c3ccccc3)cc(-c3ccccc3)c2)c2cc(N(c3cccc(Br)c3)c3cc(-c4ccccc4)cc(-c4ccccc4)c3)cc(C3(c4ccccc4)c4ccccc4-c4ccccc43)c2)c1 ; CC(C)(C)c1cc(B(O)O)cc(C(C)(C)C)c1 ; CC(C)(C)c1cc(-c2cccc(N(c3cc(-c4ccccc4)cc(-c4ccccc4)c3)c3cc(N(c4cccc(-c5cc(C(C)(C)C)cc(C(C)(C)C)c5)c4)c4cc(-c5ccccc5)cc(-c5ccccc5)c4)cc(C4(c5ccccc5)c5ccccc5-c5ccccc54)c3)c2)cc(C(C)(C)C)c1]

In an argon atmosphere, Intermediate Compound 20-3 (1 eq), (3,5-di-tert-butylphenyl)boronic acid (2.3 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After being cooled, the resulting product was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate Compound 20-4. (yield: 66%)

### Synthesis of Compound 20

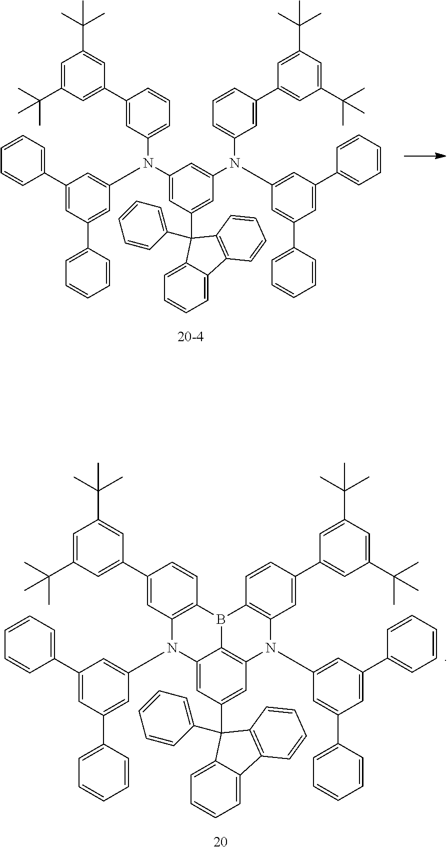 [SMILES: CC(C)(C)c1cc(-c2cccc(N(c3cc(-c4ccccc4)cc(-c4ccccc4)c3)c3cc(N(c4cccc(-c5cc(C(C)(C)C)cc(C(C)(C)C)c5)c4)c4cc(-c5ccccc5)cc(-c5ccccc5)c4)cc(C4(c5ccccc5)c5ccccc5-c5ccccc54)c3)c2)cc(C(C)(C)C)c1 ; CC(C)(C)c1cc(-c2ccc3c(c2)N(c2cc(-c4ccccc4)cc(-c4ccccc4)c2)c2cc(C4(c5ccccc5)c5ccccc5-c5ccccc54)cc4c2B3c2ccc(-c3cc(C(C)(C)C)cc(C(C)(C)C)c3)cc2N4c2cc(-c3ccccc3)cc(-c3ccccc3)c2)cc(C(C)(C)C)c1]

In an argon atmosphere, Intermediate Compound 20-4 (1 eq) was dissolved in o-dichlorobenzene, then cooled utilizing water and ice, and BBr₃ (5 equiv.) was slowly added dropwise thereto, and then the reaction solution was stirred at about 180° C. for about 12 hours. After the resulting product was cooled, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 20. (yield: 42%)

### (3) Synthesis of Compound 27

Fused polycyclic Compound 27 according to an embodiment may be synthesized, for example, by the reaction below:

### Synthesis of Intermediate Compound 27-1

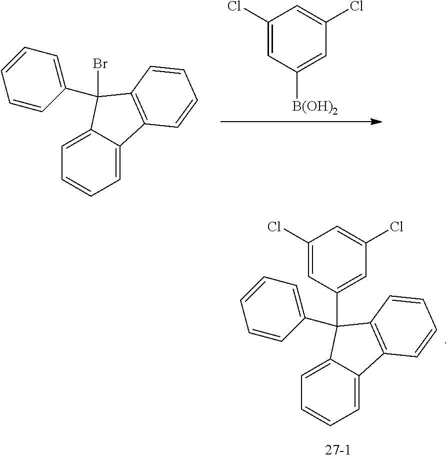 [SMILES: BrC1(c2ccccc2)c2ccccc2-c2ccccc21 ; OB(O)c1cc(Cl)cc(Cl)c1 ; Clc1cc(Cl)cc(C2(c3ccccc3)c3ccccc3-c3ccccc32)c1]

In an argon atmosphere, 9-bromo-9-phenyl-9H-fluorene (1 eq), (3,5-dichlorophenyl)boronic acid (1.5 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After being cooled, the resulting product was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate Compound 27-1. (yield: 82%)

### Synthesis of Intermediate Compound 27-2

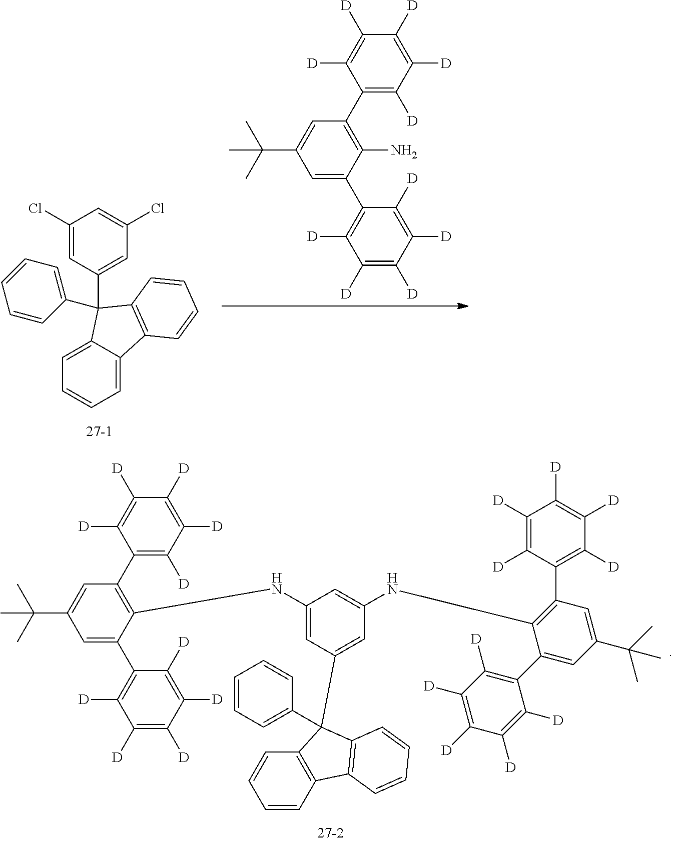 [SMILES: Clc1cc(Cl)cc(C2(c3ccccc3)c3ccccc3-c3ccccc32)c1 ; [2H]c1c([2H])c([2H])c(-c2cc(C(C)(C)C)cc(-c3c([2H])c([2H])c([2H])c([2H])c3[2H])c2N)c([2H])c1[2H] ; [2H]c1c([2H])c([2H])c(-c2cc(C(C)(C)C)cc(-c3c([2H])c([2H])c([2H])c([2H])c3[2H])c2Nc2cc(Nc3c(-c4c([2H])c([2H])c([2H])c([2H])c4[2H])cc(C(C)(C)C)cc3-c3c([2H])c([2H])c([2H])c([2H])c3[2H])cc(C3(c4ccccc4)c4ccccc4-c4ccccc43)c2)c([2H])c1[2H]]

In an argon atmosphere, Intermediate Compound 27-1 (1 eq), 5′-(tert-butyl)-[1,1′:3′,1″-terphenyl]-2,2″,3,3″,4,4″,5,5″,6,6″-d10-2′-amine (1 eq), Pd₂dba₃ (0.05 eq), tris-tert-butyl phosphine (0.1 eq), and sodium tert-butoxide (2 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 27-2. (yield: 75%)

### Synthesis of Intermediate Compound 27-3

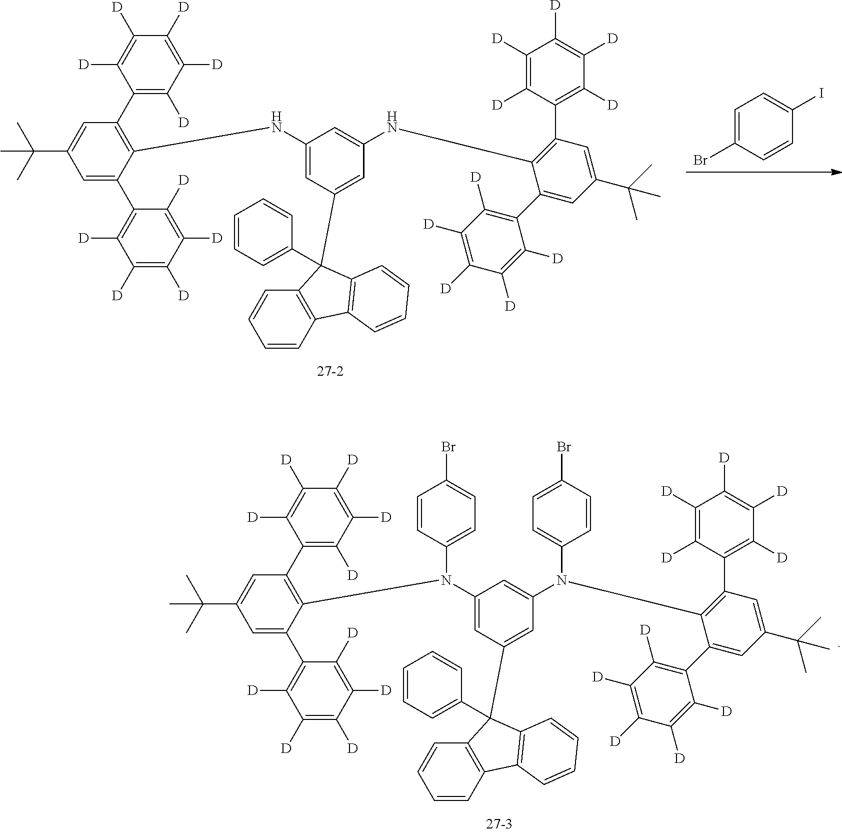

In an argon atmosphere, Intermediate Compound 27-2 (1 eq), 4-iodobromobenzene (10 eq), Pd₂dba₃ (0.5 eq), tris-tert-butyl phosphine (1 eq), and sodium tert-butoxide (4 eq) were added and dissolved in o-xylene, and then the reaction solution was stirred at about 160° C. for about 3 days. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 27-3. (yield: 68%)

### Synthesis of Intermediate Compound 27-4

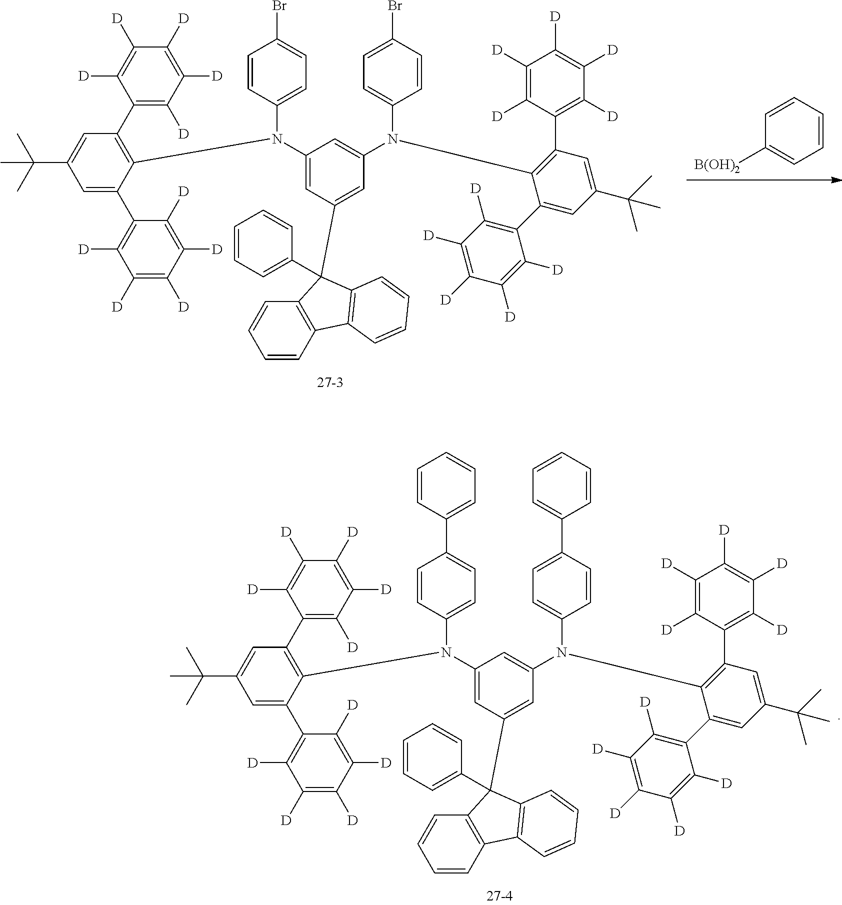

In an argon atmosphere, Intermediate Compound 27-3 (1 eq), phenylboronic acid (2.5 eq), Pd(PPh₃)₄ (0.05 eq), and potassium carbonate (2 eq) were added and dissolved in toluene/H₂O (3:1), and the reaction solution was stirred at about 100° C. for about 12 hours. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 27-4. (yield: 78%)

### Synthesis of Compound 27

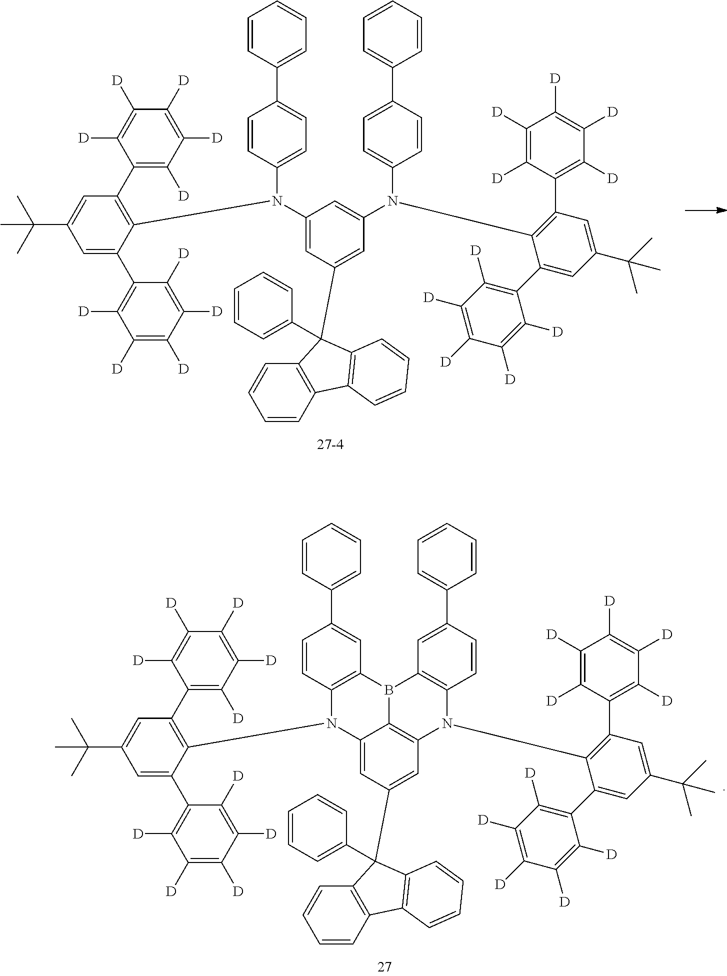

In an argon atmosphere, Intermediate Compound 27-4 (1 eq) was dissolved in o-dichlorobenzene, then cooled utilizing water and ice, and BBr₃ (5 equiv.) was slowly added dropwise thereto, and then the reaction solution was stirred at about 180° C. for about 12 hours. After the resulting product was cooled, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 27. (yield: 43%)

### (4) Synthesis of Compound 36

Fused polycyclic Compound 36 according to an embodiment may be synthesized, for example, by the reaction below:

### Synthesis of Intermediate Compound 36-1

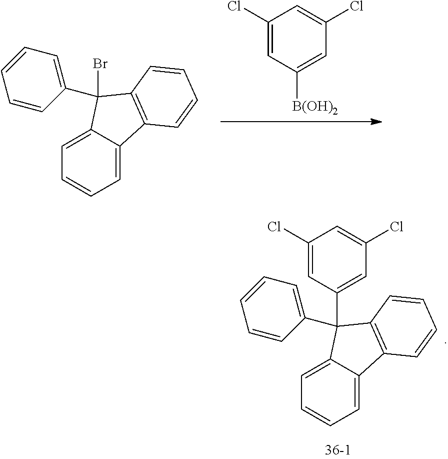 [SMILES: BrC1(c2ccccc2)c2ccccc2-c2ccccc21 ; OB(O)c1cc(Cl)cc(Cl)c1 ; Clc1cc(Cl)cc(C2(c3ccccc3)c3ccccc3-c3ccccc32)c1]

In an argon atmosphere, 9-bromo-9-phenyl-9H-fluorene (1 eq), (3,5-dichlorophenyl)boronic acid (1.5 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After being cooled, the resulting product was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate Compound 36-1. (yield: 82%)

### Synthesis of Intermediate (Compound 36-2

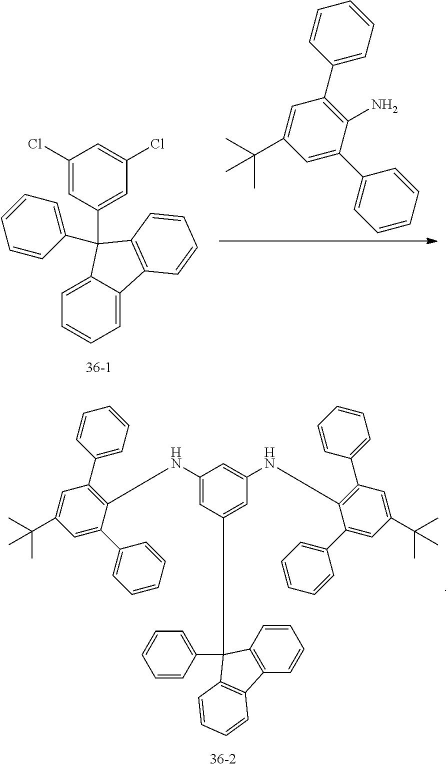 [SMILES: Clc1cc(Cl)cc(C2(c3ccccc3)c3ccccc3-c3ccccc32)c1 ; CC(C)(C)c1cc(-c2ccccc2)c(N)c(-c2ccccc2)c1 ; CC(C)(C)c1cc(-c2ccccc2)c(Nc2cc(Nc3c(-c4ccccc4)cc(C(C)(C)C)cc3-c3ccccc3)cc(C3(c4ccccc4)c4ccccc4-c4ccccc43)c2)c(-c2ccccc2)c1]

In an argon atmosphere, Intermediate Compound 20-1 (1 eq), 5′-(tert-butyl)-[1,1′:3′,1″-terphenyl]-2′-amine (1 eq), Pd₂dba₃ (0.05 eq), tris-tert-butyl phosphine (0.1 eq), and sodium tert-butoxide (2 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 36-2. (yield: 74%)

### Synthesis of Intermediate Compound 36-3

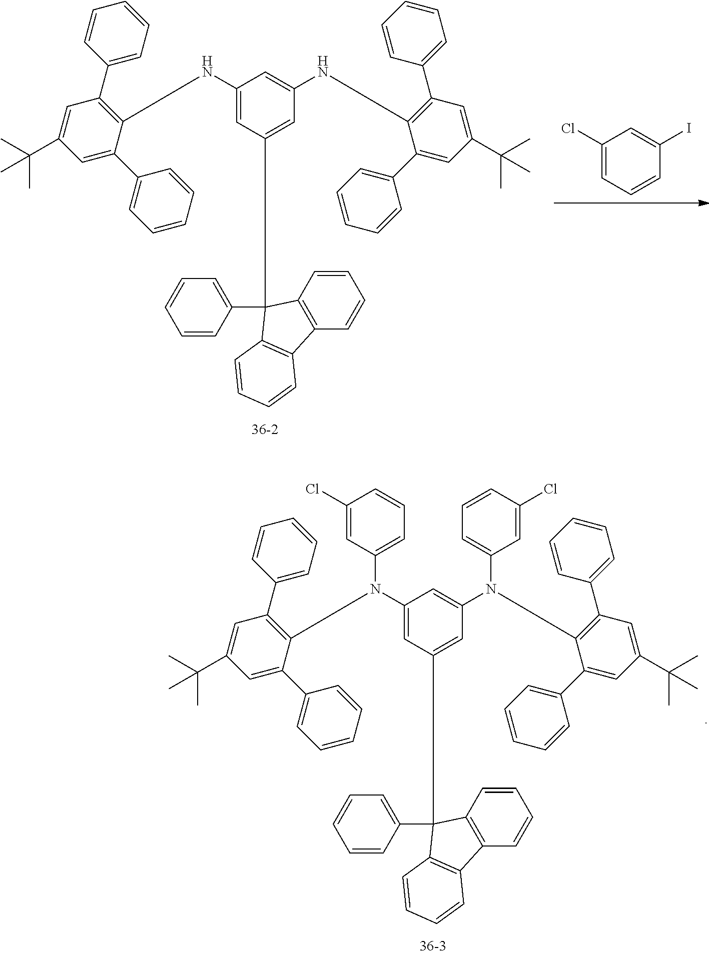

In an argon atmosphere, Intermediate Compound 36-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and then the reaction solution was stirred at about 160° C. for about 3 days. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 36-3. (yield: 66%)

### Synthesis of Intermediate Compound 36-4

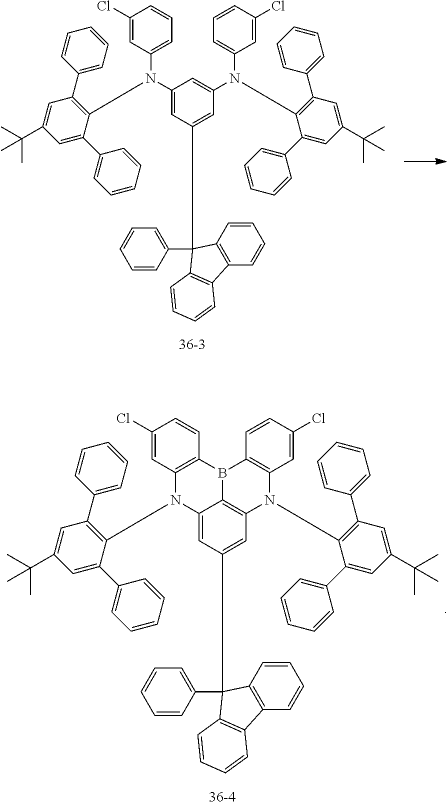

In an argon atmosphere, Intermediate Compound 36-3 (1 eq) was dissolved in o-dichlorobenzene, then cooled utilizing water and ice, and BBr₃ (5 equiv.) was slowly added dropwise thereto, and then the reaction solution was stirred at about 180° C. for about 12 hours. After the resulting product was cooled, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 36-4. (yield: 50%)

### Synthesis of Compound 36

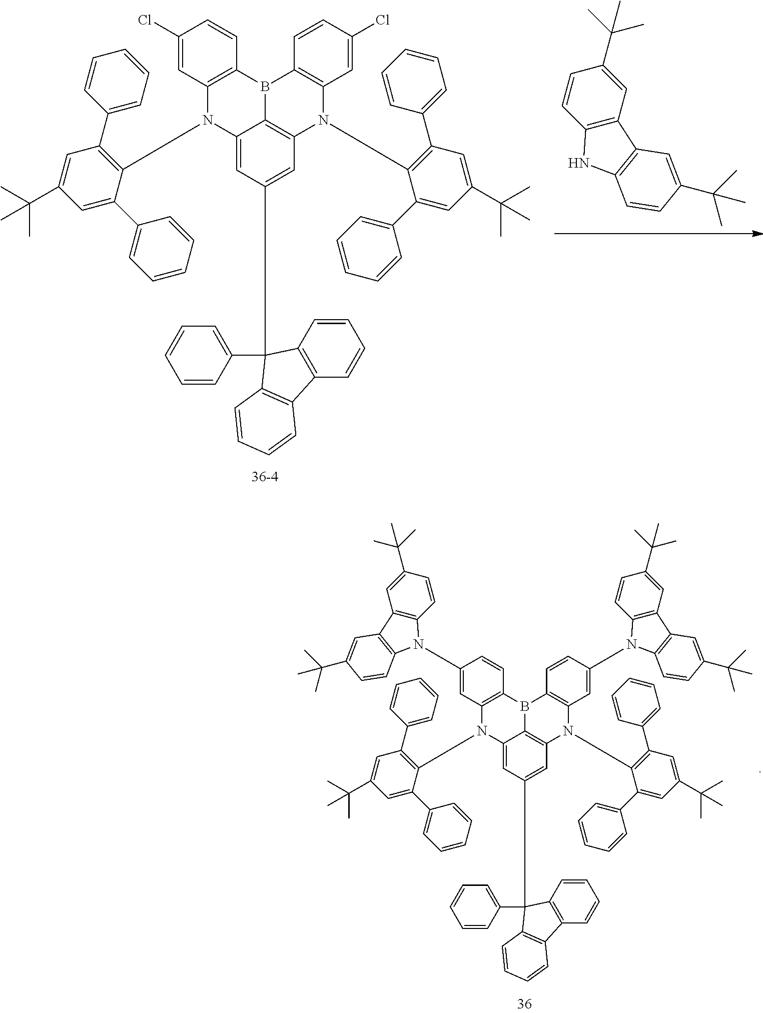

In an argon atmosphere, Intermediate Compound 36-4 (1 eq), 3,6-di-tert-butyl-9H-carbazole (2.1 eq), Pd₂dba₃ (0.05 eq), tris-tert-butyl phosphine (0.1 eq), and sodium tert-butoxide (3 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 36. (yield: 82%)

### (5) Synthesis of Compound 37

Fused polycyclic Compound 37 according to an embodiment may be synthesized, for example, by the reaction below:

### Synthesis of Intermediate Compound 37-1

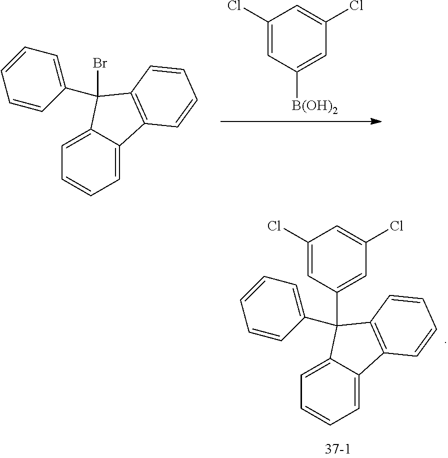 [SMILES: BrC1(c2ccccc2)c2ccccc2-c2ccccc21 ; OB(O)c1cc(Cl)cc(Cl)c1 ; Clc1cc(Cl)cc(C2(c3ccccc3)c3ccccc3-c3ccccc32)c1]

In an argon atmosphere, 9-bromo-9-phenyl-9H-fluorene (1 eq), (3,5-dichlorophenyl)boronic acid (1.5 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After being cooled, the resulting product was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate Compound 37-1. (yield: 82%)

### Synthesis of Intermediate Compound 37-2

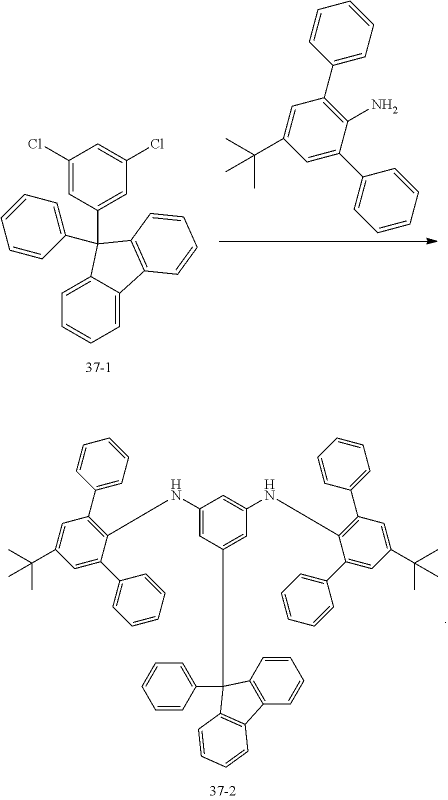 [SMILES: Clc1cc(Cl)cc(C2(c3ccccc3)c3ccccc3-c3ccccc32)c1 ; CC(C)(C)c1cc(-c2ccccc2)c(N)c(-c2ccccc2)c1 ; CC(C)(C)c1cc(-c2ccccc2)c(Nc2cc(Nc3c(-c4ccccc4)cc(C(C)(C)C)cc3-c3ccccc3)cc(C3(c4ccccc4)c4ccccc4-c4ccccc43)c2)c(-c2ccccc2)c1]

In an argon atmosphere, Intermediate Compound 37-1 (1 eq), 5′-(tert-butyl)-[1,1′:3′,1″-terphenyl]-2′-amine (1 eq), Pd₂dba₃ (0.05 eq), tris-tert-butyl phosphine (0.1 eq), and sodium tert-butoxide (2 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 37-2. (yield: 79%)

### Synthesis of Intermediate Compound 37-3

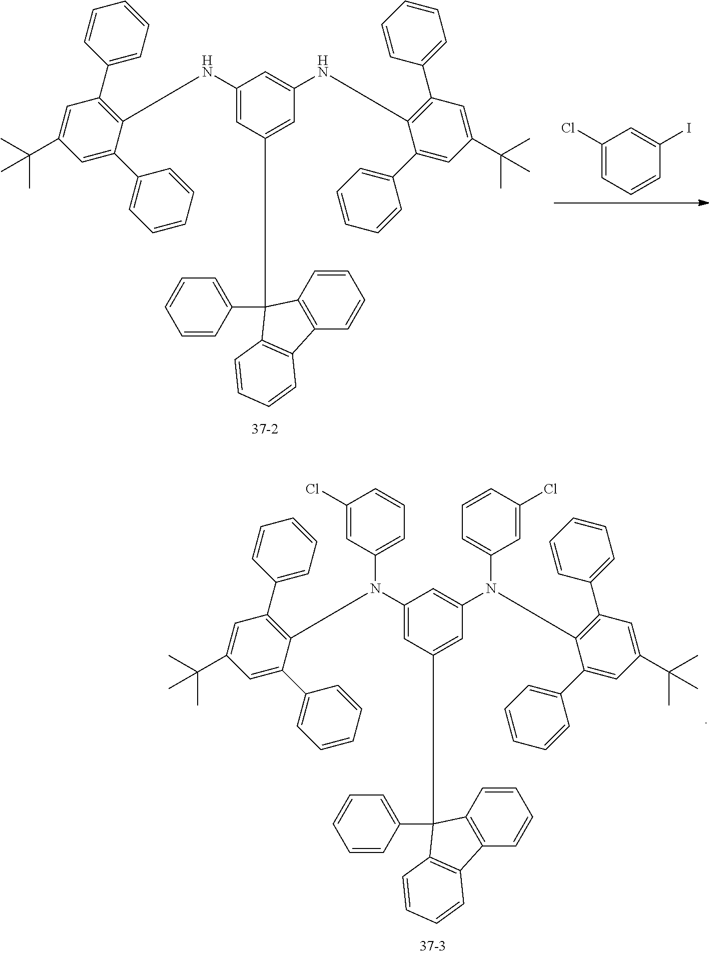

In an argon atmosphere, Intermediate Compound 37-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and then the reaction solution was stirred at about 160° C. for about 3 days. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 37-3. (yield: 62%)

### Synthesis of Intermediate Compound 37-4

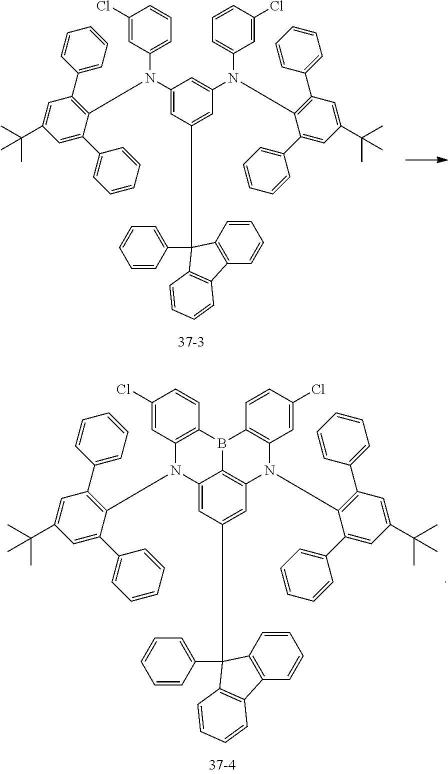

In an argon atmosphere, Intermediate Compound 37-3 (1 eq) was dissolved in o-dichlorobenzene, then cooled utilizing water and ice, and BBr₃ (5 equiv.) was slowly added dropwise thereto, and then the reaction solution was stirred at about 180° C. for about 12 hours. After the resulting product was cooled, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 37-4. (yield: 48%)

### Synthesis of Compound 37

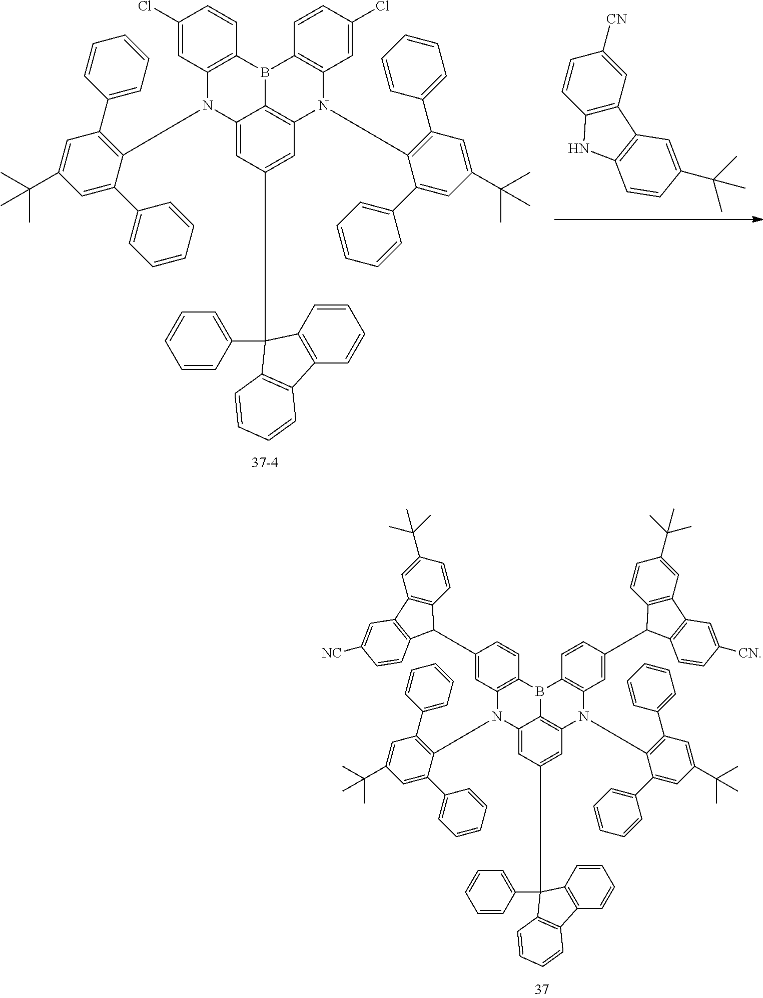 [SMILES: CC(C)(C)c1cc(-c2ccccc2)c(N2c3cc(Cl)ccc3B3c4ccc(Cl)cc4N(c4c(-c5ccccc5)cc(C(C)(C)C)cc4-c4ccccc4)c4cc(C5(c6ccccc6)c6ccccc6-c6ccccc65)cc2c43)c(-c2ccccc2)c1 ; CC(C)(C)c1ccc2[nH]c3ccc(C#N)cc3c2c1 ; CC(C)(C)c1ccc2c(c1)-c1cc(C#N)ccc1C2c1ccc2c(c1)N(c1c(-c3ccccc3)cc(C(C)(C)C)cc1-c1ccccc1)c1cc(C3(c4ccccc4)c4ccccc4-c4ccccc43)cc3c1B2c1ccc(C2c4ccc(C#N)cc4-c4cc(C(C)(C)C)ccc42)cc1N3c1c(-c2ccccc2)cc(C(C)(C)C)cc1-c1ccccc1]

In an argon atmosphere, Intermediate Compound 37-4 (1 eq), 6-(tert-butyl)-9H-carbazole-3-carbonitrile (2.1 eq), Pd₂dba₃ (0.05 eq), tris-tert-butyl phosphine (0.1 eq), and sodium tert-butoxide (3 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 37. (yield: 78%)

### (6) Synthesis of Compound 55

Fused polycyclic Compound 55 according to an embodiment may be synthesized by, for example, the reaction below:

### Synthesis of Intermediate Compound 55-1

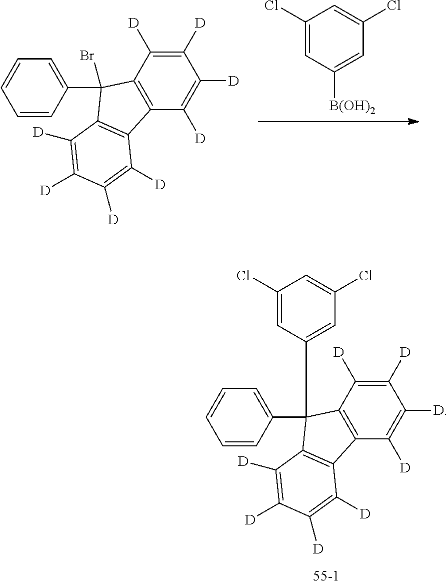

In an argon atmosphere, 9-bromo-9-phenyl-9H-fluorene-1,2,3,4,5,6,7,8-d8 (1 eq), (3,5-dichlorophenyl)boronic acid (1.5 eq), Pd(PPh₃)₄ (0.05 eq), and potassium carbonate (1.5 eq) were added and dissolved in a solvent of toluene:H₂O (3:1), and then the reaction solution was stirred at about 100° C. for about 12 hours. After being cooled, the resulting product was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate Compound 55-1. (yield: 68%)

### Synthesis of Intermediate Compound 55-2

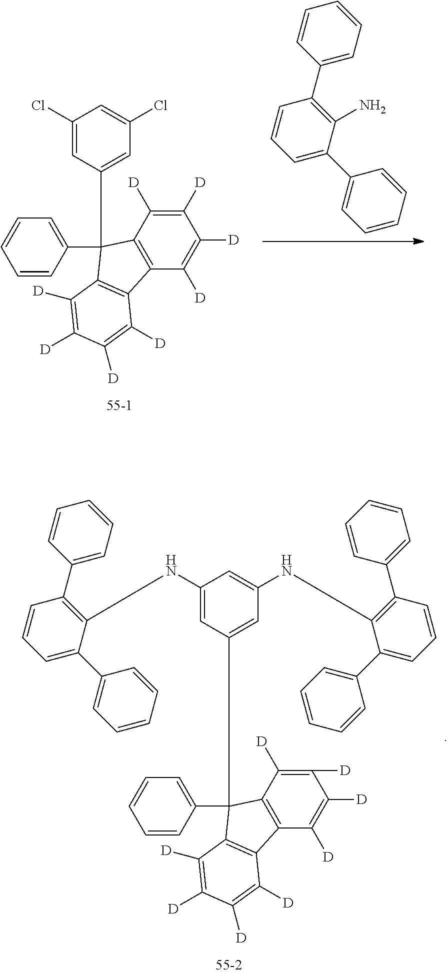 [SMILES: [2H]c1c([2H])c([2H])c2c(c1[2H])-c1c([2H])c([2H])c([2H])c([2H])c1C2(c1ccccc1)c1cc(Cl)cc(Cl)c1 ; Nc1c(-c2ccccc2)cccc1-c1ccccc1 ; [2H]c1c([2H])c([2H])c2c(c1[2H])-c1c([2H])c([2H])c([2H])c([2H])c1C2(c1ccccc1)c1cc(Nc2c(-c3ccccc3)cccc2-c2ccccc2)cc(Nc2c(-c3ccccc3)cccc2-c2ccccc2)c1]

In an argon atmosphere, Intermediate Compound 55-1 (1 eq), [1,1′:3′,1″-terphenyl]-2′-amine (1 eq), Pd₂dba₃ (0.05 eq), tris-tert-butyl phosphine (0.1 eq), and sodium tert-butoxide (2 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 55-2. (yield: 83%)

### Synthesis of Intermediate Compound 55-3

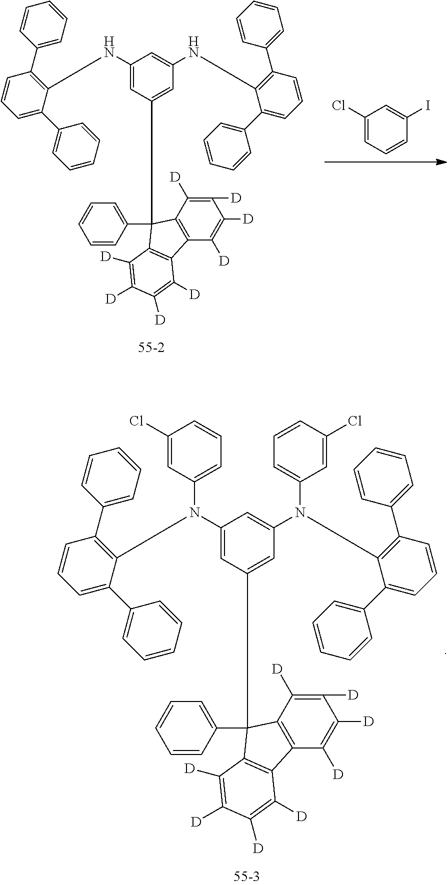

In an argon atmosphere, Intermediate Compound 55-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and then the reaction solution was stirred at about 160° C. for about 3 days. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 55-3. (yield: 64%)

### Synthesis of Intermediate Compound 55-4

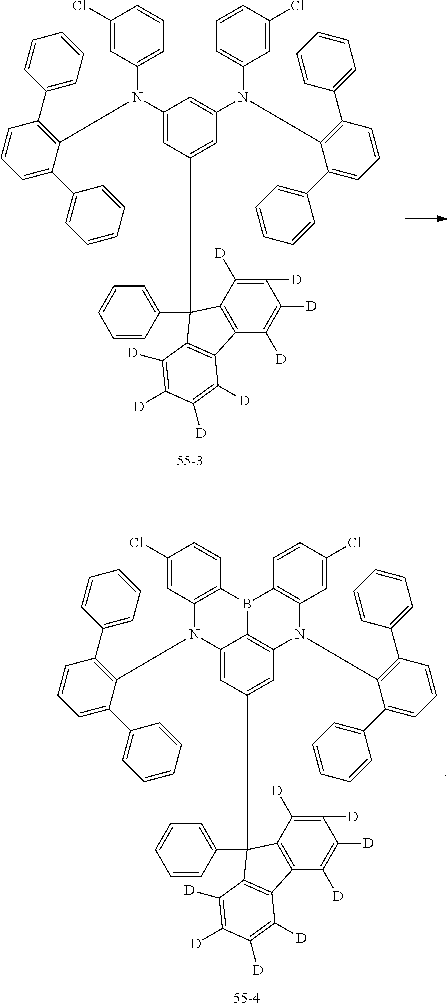 [SMILES: [2H]c1c([2H])c([2H])c2c(c1[2H])-c1c([2H])c([2H])c([2H])c([2H])c1C2(c1ccccc1)c1cc(N(c2cccc(Cl)c2)c2c(-c3ccccc3)cccc2-c2ccccc2)cc(N(c2cccc(Cl)c2)c2c(-c3ccccc3)cccc2-c2ccccc2)c1 ; [2H]c1c([2H])c([2H])c2c(c1[2H])-c1c([2H])c([2H])c([2H])c([2H])c1C2(c1ccccc1)c1cc2c3c(c1)N(c1c(-c4ccccc4)cccc1-c1ccccc1)c1cc(Cl)ccc1B3c1ccc(Cl)cc1N2c1c(-c2ccccc2)cccc1-c1ccccc1]

In an argon atmosphere, Intermediate Compound 55-3 (1 eq) was dissolved in o-dichlorobenzene, then cooled utilizing water and ice, and BBr₃ (5 equiv.) was slowly added dropwise thereto, and then the reaction solution was stirred at about 180° C. for about 12 hours. After the resulting product was cooled, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 55-4. (yield: 45%)

### Synthesis of Compound 55

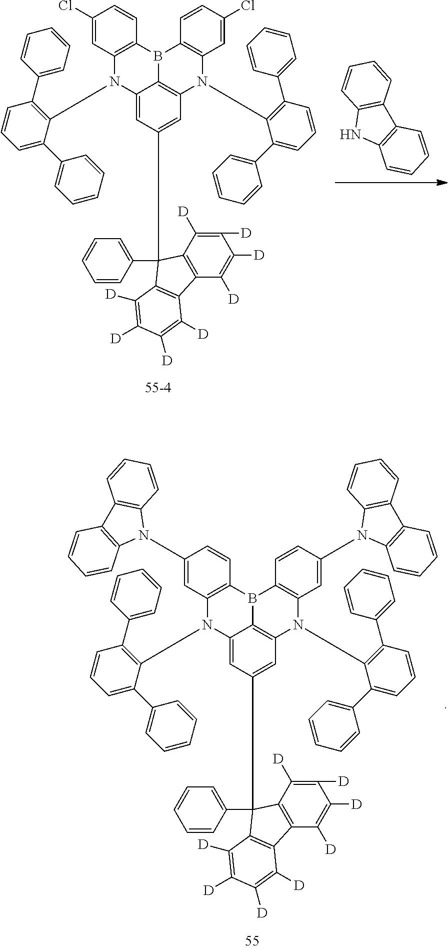 [SMILES: [2H]c1c([2H])c([2H])c2c(c1[2H])-c1c([2H])c([2H])c([2H])c([2H])c1C2(c1ccccc1)c1cc2c3c(c1)N(c1c(-c4ccccc4)cccc1-c1ccccc1)c1cc(Cl)ccc1B3c1ccc(Cl)cc1N2c1c(-c2ccccc2)cccc1-c1ccccc1 ; c1ccc2c(c1)[nH]c1ccccc12 ; [2H]c1c([2H])c([2H])c2c(c1[2H])-c1c([2H])c([2H])c([2H])c([2H])c1C2(c1ccccc1)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1N2c1c(-c2ccccc2)cccc1-c1ccccc1]

In an argon atmosphere, Intermediate Compound 55-4 (1 eq), 9H-carbazole (2.1 eq), Pd₂dba₃ (0.05 eq), tris-tert-butyl phosphine (0.1 eq), and sodium tert-butoxide (3 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 55. (yield: 80%)

### (7) Synthesis of Compound 60

Fused polycyclic Compound 60 according to an embodiment may be synthesized, for example, by the reaction below:

### Synthesis of Intermediate Compound 60-1

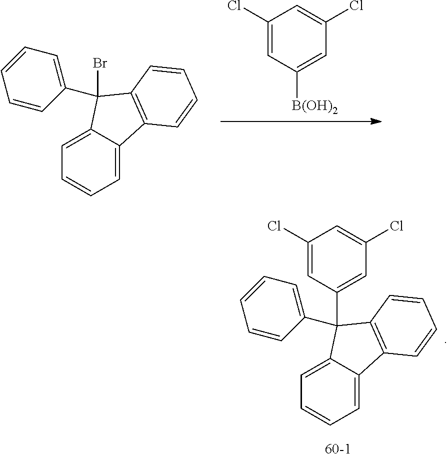 [SMILES: BrC1(c2ccccc2)c2ccccc2-c2ccccc21 ; OB(O)c1cc(Cl)cc(Cl)c1 ; Clc1cc(Cl)cc(C2(c3ccccc3)c3ccccc3-c3ccccc32)c1]

In an argon atmosphere, 9-bromo-9-phenyl-9H-fluorene (1 eq), (3,5-dichlorophenyl)boronic acid (1.5 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After being cooled, the resulting product was extracted by adding water (1 L) and ethyl acetate (300 mL) to collect organic layers, and the organic layers were dried over MgSO₄ and then filtered.

In the filtrate, the solvent was removed under reduced pressure to obtain a solid. The solid thus obtained was purified and separated by silica gel column chromatography utilizing CH₂Cl₂ and hexane as eluent to obtain Intermediate Compound 60-1. (yield: 82%)

### Synthesis of Intermediate Compound 60-2

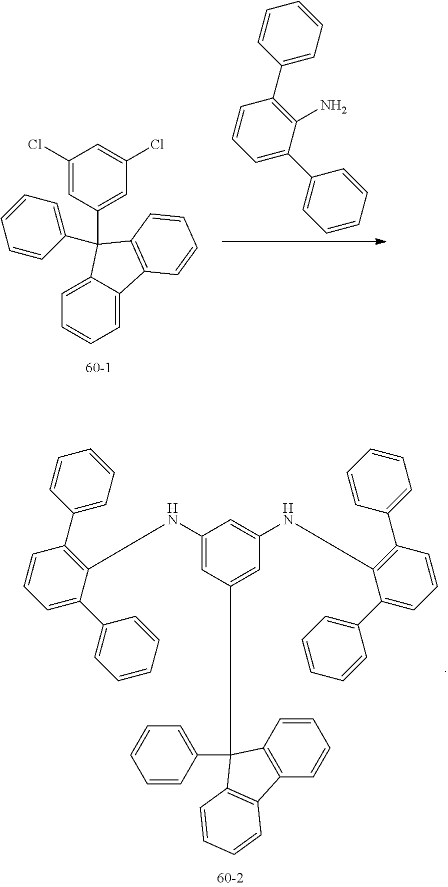 [SMILES: Clc1cc(Cl)cc(C2(c3ccccc3)c3ccccc3-c3ccccc32)c1 ; Nc1c(-c2ccccc2)cccc1-c1ccccc1 ; c1ccc(-c2cccc(-c3ccccc3)c2Nc2cc(Nc3c(-c4ccccc4)cccc3-c3ccccc3)cc(C3(c4ccccc4)c4ccccc4-c4ccccc43)c2)cc1]

In an argon atmosphere, Intermediate Compound 60-1 (1 eq), [1,1′:3′,1″-terphenyl]-2′-amin (1 eq), pd2dba3 (0.05 eq), tris-tert-butyl phosphine (0.1 eq), and sodium tert-butoxide (2 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 60-2. (yield: 82%)

### Synthesis of Intermediate Compound 60-3

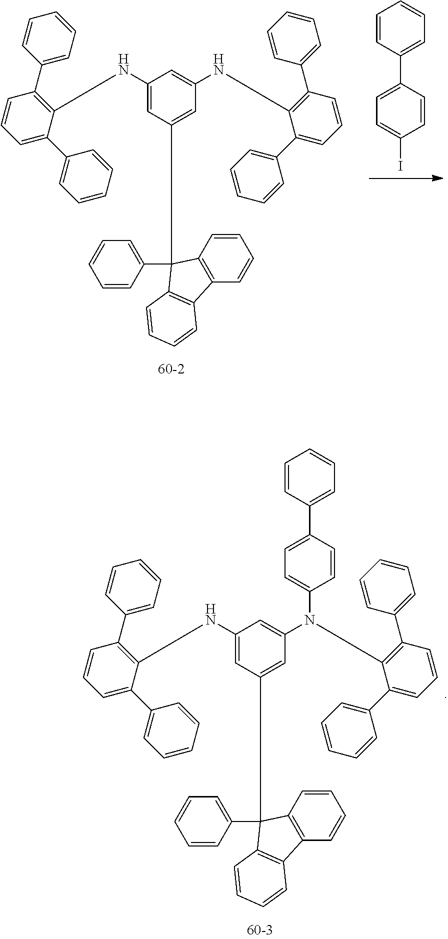

In an argon atmosphere, Intermediate Compound 60-2 (1 eq), 4-iodo-1,1′-biphenyl (5 eq), Pd₂dba₃ (0.5 eq), tris-tert-butyl phosphine (1 eq), and sodium tert-butoxide (4 eq) were added and dissolved in o-xylene, and then the reaction solution was stirred at about 140° C. for about 3 days. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 60-3. (yield: 42%)

### Synthesis of Intermediate Compound 60-4

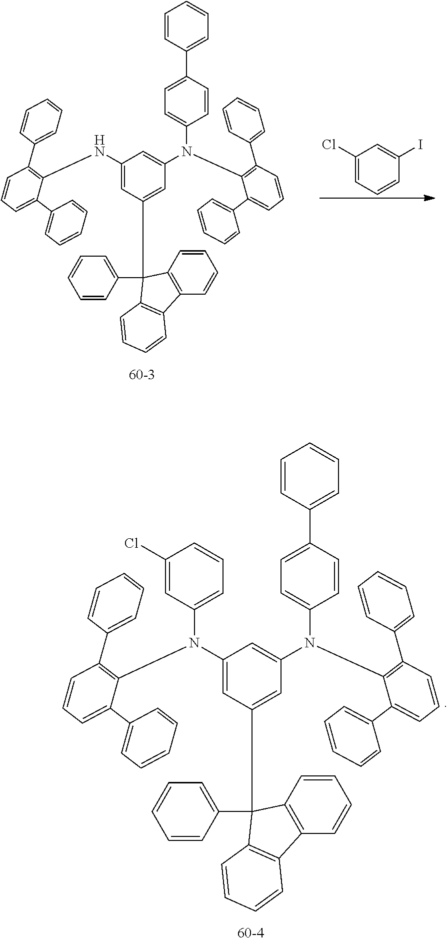 [SMILES: c1ccc(-c2ccc(N(c3cc(Nc4c(-c5ccccc5)cccc4-c4ccccc4)cc(C4(c5ccccc5)c5ccccc5-c5ccccc54)c3)c3c(-c4ccccc4)cccc3-c3ccccc3)cc2)cc1 ; Clc1cccc(I)c1 ; Clc1cccc(N(c2cc(N(c3ccc(-c4ccccc4)cc3)c3c(-c4ccccc4)cccc3-c3ccccc3)cc(C3(c4ccccc4)c4ccccc4-c4ccccc43)c2)c2c(-c3ccccc3)cccc2-c2ccccc2)c1]

In an argon atmosphere, Intermediate Compound 60-3 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and then the reaction solution was stirred at about 160° C. for about 3 days. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 60-4. (yield: 63%)

### Synthesis of Intermediate Compound 60-5

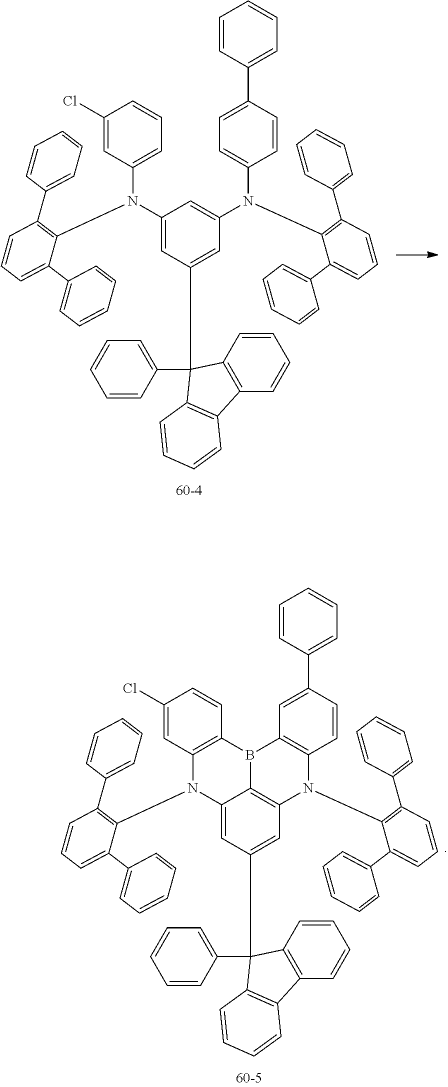 [SMILES: Clc1cccc(N(c2cc(N(c3ccc(-c4ccccc4)cc3)c3c(-c4ccccc4)cccc3-c3ccccc3)cc(C3(c4ccccc4)c4ccccc4-c4ccccc43)c2)c2c(-c3ccccc3)cccc2-c2ccccc2)c1 ; Clc1ccc2c(c1)N(c1c(-c3ccccc3)cccc1-c1ccccc1)c1cc(C3(c4ccccc4)c4ccccc4-c4ccccc43)cc3c1B2c1cc(-c2ccccc2)ccc1N3c1c(-c2ccccc2)cccc1-c1ccccc1]

In an argon atmosphere, Intermediate Compound 60-4 (1 eq) was dissolved in o-dichlorobenzene, then cooled utilizing water and ice, and BBr₃ (5 equiv.) was slowly added dropwise thereto, and then the reaction solution was stirred at about 180° C. for about 12 hours. After the resulting product was cooled, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 60-5. (yield: 42%)

### Synthesis of Compound 60

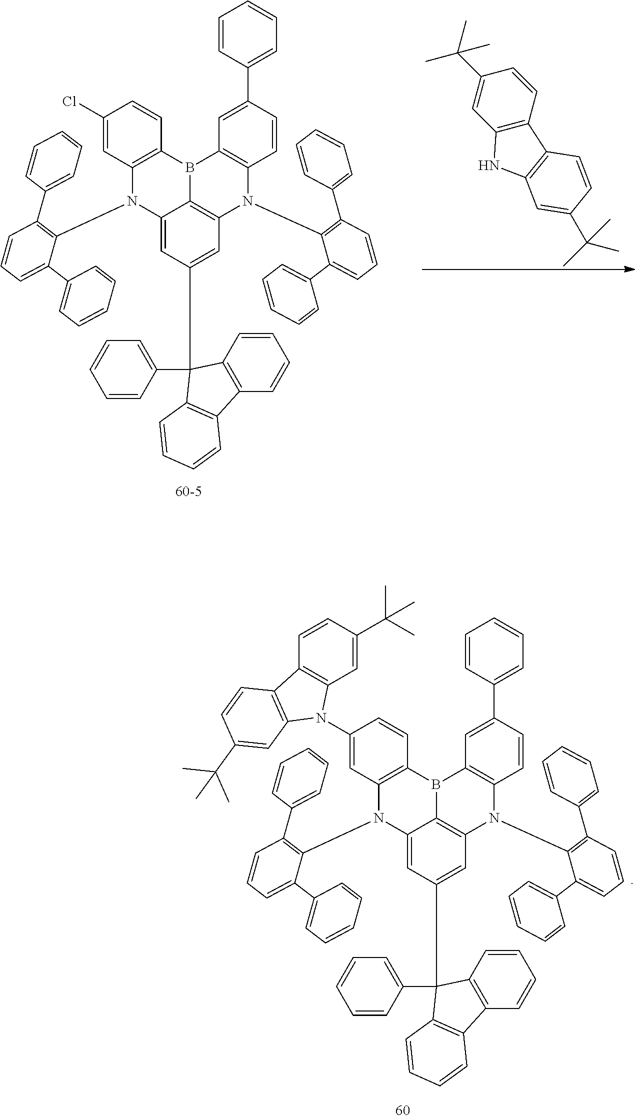 [SMILES: Clc1ccc2c(c1)N(c1c(-c3ccccc3)cccc1-c1ccccc1)c1cc(C3(c4ccccc4)c4ccccc4-c4ccccc43)cc3c1B2c1cc(-c2ccccc2)ccc1N3c1c(-c2ccccc2)cccc1-c1ccccc1 ; CC(C)(C)c1ccc2c(c1)[nH]c1cc(C(C)(C)C)ccc12 ; CC(C)(C)c1ccc2c3ccc(C(C)(C)C)cc3n(-c3ccc4c(c3)N(c3c(-c5ccccc5)cccc3-c3ccccc3)c3cc(C5(c6ccccc6)c6ccccc6-c6ccccc65)cc5c3B4c3cc(-c4ccccc4)ccc3N5c3c(-c4ccccc4)cccc3-c3ccccc3)c2c1]

In an argon atmosphere, Intermediate Compound 60-5 (1 eq), 2,7-di-tert-butyl-9H-carbazole (1.2 eq), Pd₂dba₃ (0.05 eq), tris-tert-butyl phosphine (0.1 eq), and sodium tert-butoxide (2 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 60. (yield: 73%)

### (8) Synthesis of Compound 81

Fused polycyclic Compound 81 according to an embodiment may be synthesized, for example, by the reaction below:

### Synthesis of Intermediate Compound 81-1

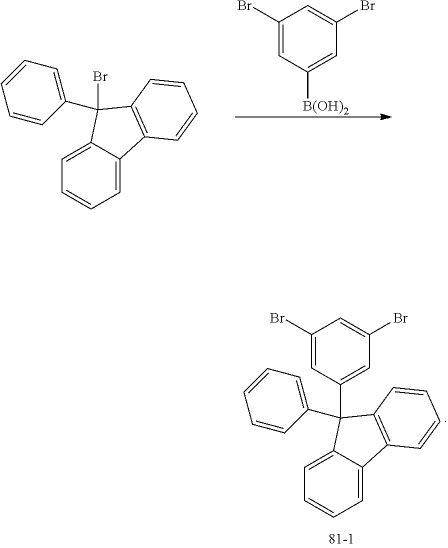 [SMILES: BrC1(c2ccccc2)c2ccccc2-c2ccccc21 ; OB(O)c1cc(Br)cc(Br)c1 ; Brc1cc(Br)cc(C2(c3ccccc3)c3ccccc3-c3ccccc32)c1]

In an argon atmosphere, 9-bromo-9-phenyl-9H-fluorene (1 eq), (3,5-dichlorophenyl)boronic acid (1.5 eq), Pd(PPh₃)₄ (0.05 eq), and potassium carbonate (1.5 eq) were added and dissolved in a solvent of toluene:H₂O (3:1), and then the reaction solution was stirred at about 100° C. for about 12 hours. After being cooled, the resulting product was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate Compound 81-1. (yield: 41%)

### Synthesis of Intermediate Compound 81-2

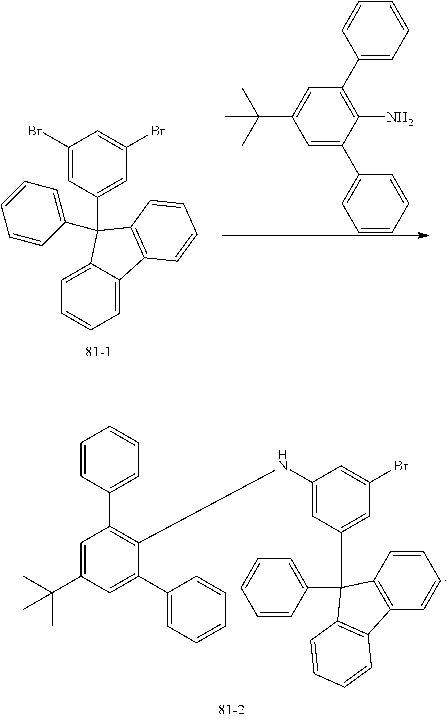 [SMILES: Brc1cc(Br)cc(C2(c3ccccc3)c3ccccc3-c3ccccc32)c1 ; CC(C)(C)c1cc(-c2ccccc2)c(N)c(-c2ccccc2)c1 ; CC(C)(C)c1cc(-c2ccccc2)c(Nc2cc(Br)cc(C3(c4ccccc4)c4ccccc4-c4ccccc43)c2)c(-c2ccccc2)c1]

In an argon atmosphere, Compound 81-1 (1 eq), 5′-(tert-butyl)-[1,1′:3′,1″-terphenyl]-2′-amine (1 eq), Pd₂dba₃ (0.05 eq), tris-tert-butyl phosphine (0.1 eq), and sodium tert-butoxide (2 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 81-2. (yield: 78%)

### Synthesis of Intermediate Compound 81-3

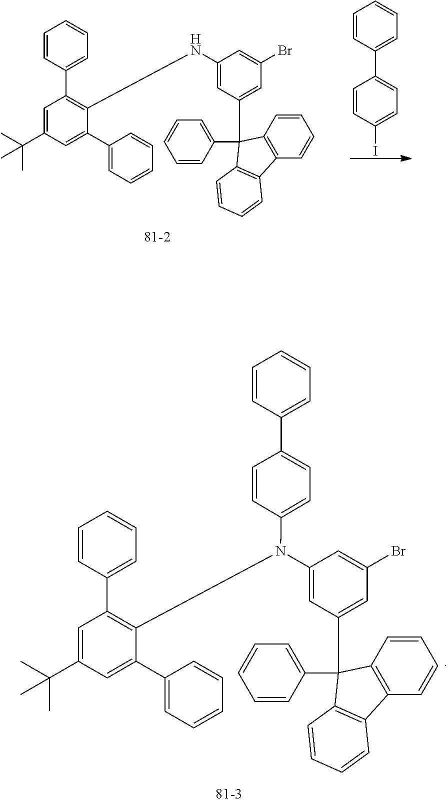

In an argon atmosphere, Compound 81-2 (1 eq), 4-iodo-1,1′-biphenyl (10 eq), Pd₂dba₃ (0.5 eq), tris-tert-butyl phosphine (1 eq), and sodium tert-butoxide (4 eq) were added and dissolved in o-xylene, and then the reaction solution was stirred at about 160° C. for about 3 days. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 81-3. (yield: 67%)

### Synthesis of Intermediate Compound 81-4

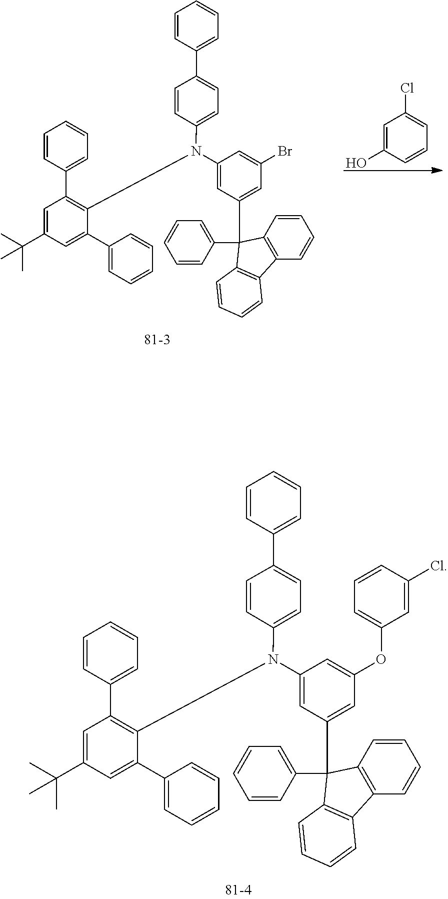 [SMILES: CC(C)(C)c1cc(-c2ccccc2)c(N(c2ccc(-c3ccccc3)cc2)c2cc(Br)cc(C3(c4ccccc4)c4ccccc4-c4ccccc43)c2)c(-c2ccccc2)c1 ; Oc1cccc(Cl)c1 ; CC(C)(C)c1cc(-c2ccccc2)c(N(c2ccc(-c3ccccc3)cc2)c2cc(Oc3cccc(Cl)c3)cc(C3(c4ccccc4)c4ccccc4-c4ccccc43)c2)c(-c2ccccc2)c1]

In an argon atmosphere, Intermediate Compound 81-3 (1 eq), 3-chlorophenol (1 eq), copper iodide (0.1 eq), 2-picolinic acid (0.2 eq), and K₃PO₄ (3 eq) were dissolved in DMF, and then the reaction solution was stirred at about 160° C. for about 12 hours in a nitrogen atmosphere. After being cooled, the resulting product was washed three times with ethyl acetate and water to obtain organic layers. The obtained organic layers were dried over MgSO₄, and then dried under reduced pressure. Intermediate Compound 81-4 was obtained by column chromatography. (yield: 59%)

### Synthesis of Intermediate Compound 81-5

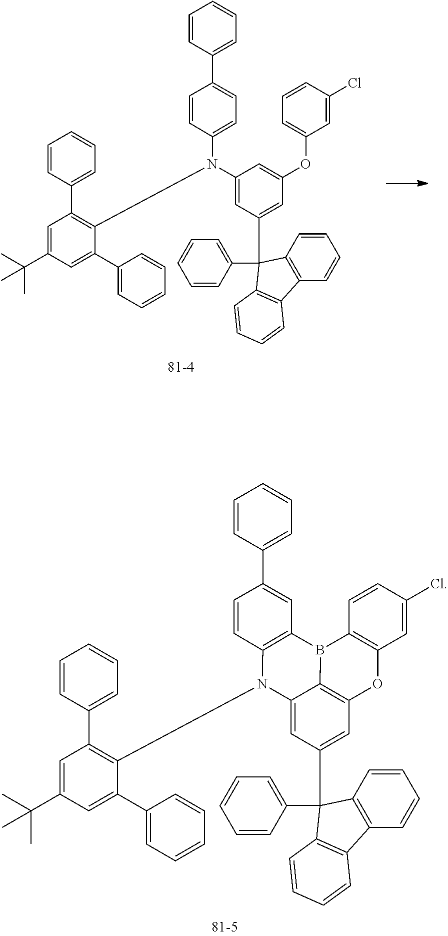 [SMILES: CC(C)(C)c1cc(-c2ccccc2)c(N(c2ccc(-c3ccccc3)cc2)c2cc(Oc3cccc(Cl)c3)cc(C3(c4ccccc4)c4ccccc4-c4ccccc43)c2)c(-c2ccccc2)c1 ; CC(C)(C)c1cc(-c2ccccc2)c(N2c3ccc(-c4ccccc4)cc3B3c4ccc(Cl)cc4Oc4cc(C5(c6ccccc6)c6ccccc6-c6ccccc65)cc2c43)c(-c2ccccc2)c1]

In an argon atmosphere, Intermediate Compound 81-4 (1 eq) was dissolved in o-dichlorobenzene, then cooled utilizing water and ice, and BBr₃ (5 equiv.) was slowly added dropwise thereto, and then the reaction solution was stirred at about 180° C. for about 12 hours. After the resulting product was cooled, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 81-5. (yield: 30%)

### Synthesis of Compound 81

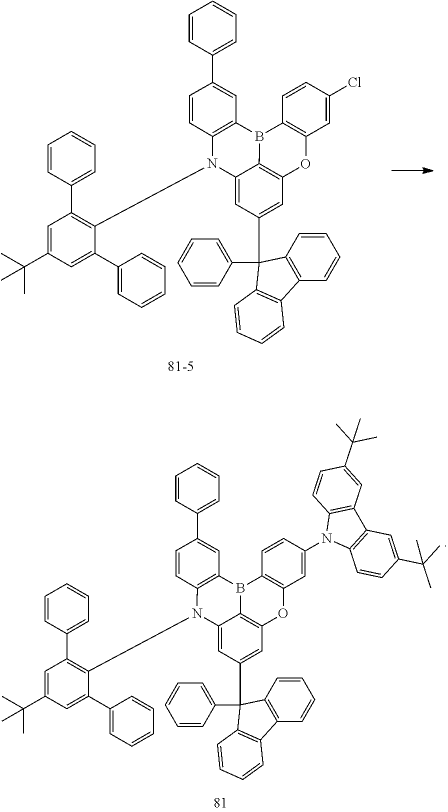 [SMILES: CC(C)(C)c1cc(-c2ccccc2)c(N2c3ccc(-c4ccccc4)cc3B3c4ccc(Cl)cc4Oc4cc(C5(c6ccccc6)c6ccccc6-c6ccccc65)cc2c43)c(-c2ccccc2)c1 ; CC(C)(C)c1cc(-c2ccccc2)c(N2c3ccc(-c4ccccc4)cc3B3c4ccc(-n5c6ccc(C(C)(C)C)cc6c6cc(C(C)(C)C)ccc65)cc4Oc4cc(C5(c6ccccc6)c6ccccc6-c6ccccc65)cc2c43)c(-c2ccccc2)c1]

In an argon atmosphere, Intermediate Compound 81-5 (1 eq), 3,6-di-tert-butyl-9H-carbazole (1.1 eq), Pd₂dba₃ (0.05 eq), tris-tert-butyl phosphine (0.1 eq), and sodium tert-butoxide (3 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 81. (yield: 75%)

### (9) Synthesis of Compound 102

Fused polycyclic Compound 102 according to an embodiment may be synthesized by, for example, the reaction below:

### Synthesis of Intermediate Compound 102-1

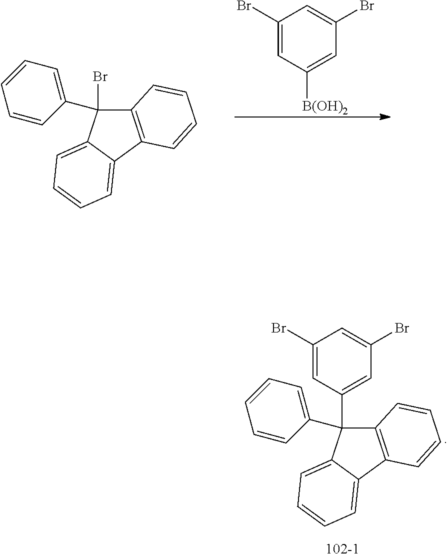 [SMILES: BrC1(c2ccccc2)c2ccccc2-c2ccccc21 ; OB(O)c1cc(Br)cc(Br)c1 ; Brc1cc(Br)cc(C2(c3ccccc3)c3ccccc3-c3ccccc32)c1]

In an argon atmosphere, 9-bromo-9-phenyl-9H-fluorene (1 eq), (3,5-dichlorophenyl)boronic acid (1.5 eq), Pd(PPh₃)₄ (0.05 eq), and potassium carbonate (1.5 eq) were added and dissolved in a solvent of toluene:H₂O (3:1), and the reaction solution was stirred at about 100° C. for about 12 hours. After cooling, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography utilizing CH₂Cl₂ and hexane as eluent to obtain Intermediate Compound 102-1. (yield: 45%)

### Synthesis of Intermediate Compound 102-2

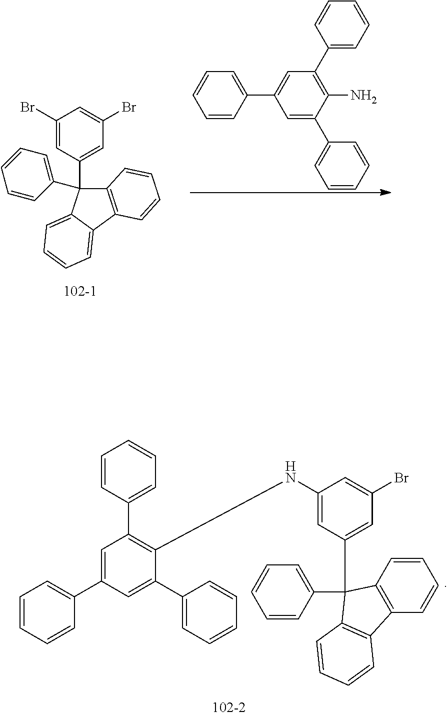 [SMILES: Brc1cc(Br)cc(C2(c3ccccc3)c3ccccc3-c3ccccc32)c1 ; Nc1c(-c2ccccc2)cc(-c2ccccc2)cc1-c1ccccc1 ; Brc1cc(Nc2c(-c3ccccc3)cc(-c3ccccc3)cc2-c2ccccc2)cc(C2(c3ccccc3)c3ccccc3-c3ccccc32)c1]

In an argon atmosphere, Compound 102-1 (1 eq), 5′-phenyl-[1,1′:3′,1″-terphenyl]-2′-amine (1 eq), pd2dba3 (0.05 eq), tris-tert-butyl phosphine (0.1 eq), and sodium tert-butoxide (2 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 102-2. (yield: 76%)

### Synthesis of Intermediate Compound 102-3

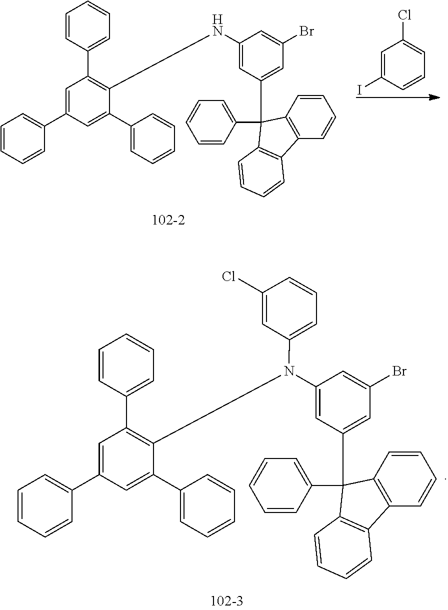

In an argon atmosphere, Intermediate Compound 102-2 (1 eq), 3-iodochlorobenzene (10 eq), Pd₂(dba)₃ (0.5 eq), tris-tert-butyl phosphine (1 eq), and sodium tert-butoxide (4 eq) were added and dissolved in o-xylene, and then the reaction solution was stirred at about 160° C. for about 3 days. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 102-3. (yield: 67%)

### Synthesis of Intermediate Compound 102-4

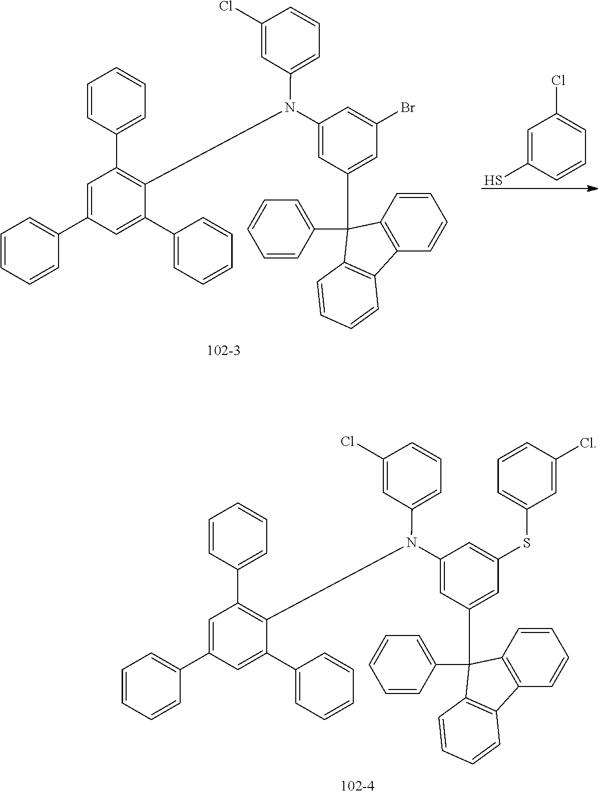 [SMILES: Clc1cccc(N(c2cc(Br)cc(C3(c4ccccc4)c4ccccc4-c4ccccc43)c2)c2c(-c3ccccc3)cc(-c3ccccc3)cc2-c2ccccc2)c1 ; Sc1cccc(Cl)c1 ; Clc1cccc(Sc2cc(N(c3cccc(Cl)c3)c3c(-c4ccccc4)cc(-c4ccccc4)cc3-c3ccccc3)cc(C3(c4ccccc4)c4ccccc4-c4ccccc43)c2)c1]

In an argon atmosphere, Intermediate Compound 102-3 (1 eq), 3-chlorobenzenethiol (1 eq), copper iodide (0.1 eq), 2-picolinic acid (0.2 eq), and K₃PO₄ (3 eq) were dissolved in DMF, and then the reaction solution was stirred at about 160° C. for about 12 hours in a nitrogen atmosphere. After being cooled, the resulting product was washed three times with ethyl acetate and water to obtain organic layers. The obtained organic layers were dried over MgSO₄, and then dried under reduced pressure. Intermediate Compound 102-4 was obtained by column chromatography. (yield: 48%)

### Synthesis of Intermediate Compound 102-5

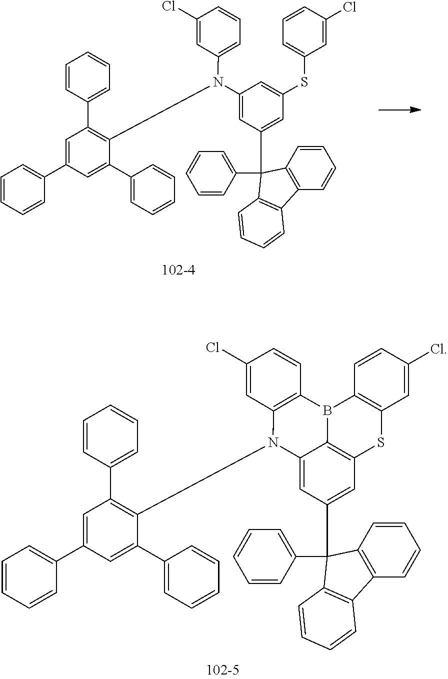 [SMILES: Clc1cccc(Sc2cc(N(c3cccc(Cl)c3)c3c(-c4ccccc4)cc(-c4ccccc4)cc3-c3ccccc3)cc(C3(c4ccccc4)c4ccccc4-c4ccccc43)c2)c1 ; Clc1ccc2c(c1)Sc1cc(C3(c4ccccc4)c4ccccc4-c4ccccc43)cc3c1B2c1ccc(Cl)cc1N3c1c(-c2ccccc2)cc(-c2ccccc2)cc1-c1ccccc1]

In an argon atmosphere, Compound 102-3 (1 eq) was dissolved in o-dichlorobenzene, then cooled utilizing water and ice, and BBr₃ (5 equiv.) was slowly added dropwise thereto, and then the reaction solution was stirred at about 180° C. for about 12 hours. After the resulting product was cooled, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography to obtain Intermediate Compound 102-5. (yield: 33%)

### Synthesis of Compound 102

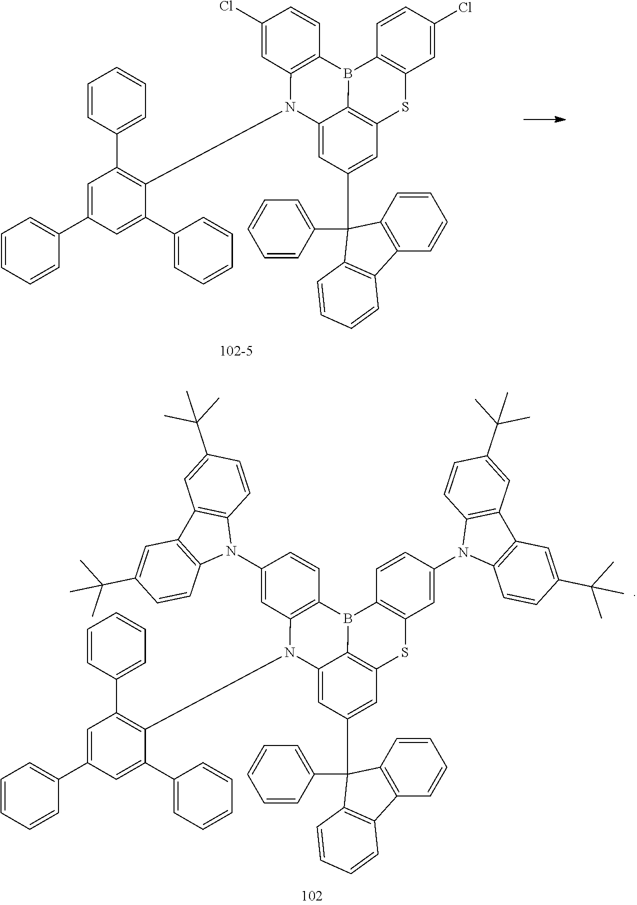 [SMILES: Clc1ccc2c(c1)Sc1cc(C3(c4ccccc4)c4ccccc4-c4ccccc43)cc3c1B2c1ccc(Cl)cc1N3c1c(-c2ccccc2)cc(-c2ccccc2)cc1-c1ccccc1 ; CC(C)(C)c1ccc2c(c1)c1cc(C(C)(C)C)ccc1n2-c1ccc2c(c1)Sc1cc(C3(c4ccccc4)c4ccccc4-c4ccccc43)cc3c1B2c1ccc(-n2c4ccc(C(C)(C)C)cc4c4cc(C(C)(C)C)ccc42)cc1N3c1c(-c2ccccc2)cc(-c2ccccc2)cc1-c1ccccc1]

In an argon atmosphere, Compound 102-5 (1 eq), 3,6-di-tert-butyl-9H-carbazole (2.1 eq), Pd₂dba₃ (0.05 eq), tris-tert-butyl phosphine (0.1 eq), and sodium tert-butoxide (3 eq) were added and dissolved in o-xylene, and then the reaction solution was stirred at about 140° C. for about 1 day. After being cooled, the resulting product was extracted by adding water and ethyl acetate to collect organic layers, and the organic layers were dried over MgSO₄ and then filtered. In the filtrate, the solvent was removed under reduced pressure to obtain a solid. The solid thus obtained was purified and separated by silica gel column chromatography to obtain Compound 102. (yield: 76%)

### 2. Evaluation of Physical Properties of Fused Polycyclic Compound

The results of MS/FAB and ¹H NMR of Example Compounds are listed in Table 1:

TABLE 1

| | | MS/FAB | |
|---|---|---|---|
| Compound | H NMR (δ) | Calc | Found |
| 18 | 1H-NMR (400 MHz, CDCl3): d = 9.05 (s, 2H), | 1188.65 | 1188.64 |
| | 8.03 (d, 2H), 7.95 (s, 2H), 7.65-7.43(m, 10H), | | |
| | 7.42-7.22 (m, 13H), 7.12-7.07 (m, 6H), 6.89 (s, | | |
| | 1H), 6.90 (s, 1H), 1.34 (ss, 18H), 1.20 (ss, 18H). | | |
| 20 | 1H-NMR (400 MHz, CDCl3): d = 8.99 (d, 2H), | 1340.71 | 1340.70 |
| | 7.97 (d, 2H), 7.83 (s, 4H), 7.60-7.43(m, 18H), | | |
| | 7.41-7.28 (m, 14H), 7.27-7.10 (m, 11H), 6.79 | | |
| | (ss, 2H), 1.32 (ss, 36H). | | |
| 27 | 1H-NMR (400 MHz, CDCl3): d = 9.01 (s, 2H), | 1248.71 | 1248.69 |
| | 7.99 (d, 2H), 7.89 (s, 4H), 7.75-7.41(m, 9H), | | |
| | 7.37-7.26 (m, 12H), 7.25-7.10 (m, 4H), 6.89 (s, | | |
| | 1H), 6.93 (s, 2H), 1.32 (s, 18H). | | |
| 36 | 1H-NMR (400 MHz, CDCl3): d = 9.03 (d, 2H), | 1630.89 | 1630.88 |
| | 8.13 (s, 4H), 7.97 (d, 2H), 7.97 (s, 4H), 7.62- | | |
| | 7.43(m, 17H), 7.42-7.27 (m, 18H), 7.26-7.18 | | |
| | (m, 8H), 6.93 (s, 2H), 1.34 (ss, 36H), 1.28 (s, | | |
| | 18H). | | |
| 37 | 1H-NMR (400 MHz, CDCl3): d = 9.11 (d, 2H), | 1568.76 | 1568.75 |
| | 8.01 (s, 2H), 7.88 (d, 2H), 7.79 (s, 4H), 7.67- | | |
| | 7.45(m, 19H), 7.44-7.25 (m, 17H), 7.24-7.07 | | |
| | (m, 9H), 7.03 (s, 2H), 1.38 (s, 18H), 1.30 (s, | | |
| | 18H). | | |
| 55 | 1H-NMR (400 MHz, CDCl3): d = 9.08 (s, 2H), | 1318.60 | 1318.59 |
| | 8.19 (d, 2H), 8.13 (d, 2H) 7.94 (d, 2H), 7.58- | | |
| | 7.42(m, 19H), 7.41-7.22 (m, 19H), 7.21-7.08 | | |
| | (m, 11H), 6.93 (s, 1H). | | |
| 60 | 1H-NMR (400 MHz, CDCl3): d = 9.02 (d, 1H), | 1333.64 | 1333.64 |
| | 9.00 (s, 1H), 8.04 (d, 2H), 7.93 (dd, 4H), 7.67- | | |
| | 7.43(m, 14H), 7.42-7.39 (m, 22H), 7.38-7.18 | | |
| | (m, 16H), 6.93 (s, 1H), 6.90 (s, 1H), 1.38 (s, | | |
| | 18H). | | |
| 81 | 1H-NMR (400 MHz, CDCl3): d = 8.97 (d, 1H), | 1146.57 | 1146.56 |
| | 8.95 (s, 1H), 8.21 (s, 2H), 7.95 (s, 2H), 7.62- | | |
| | 7.45(m, 14H), 7.44-7.26 (m, 15H), 7.25-7.10 | | |
| | (m, 7H), 6.83 (s, 1H), 6.77 (s, 1H), 1.42 (ss, | | |
| | 18H), 1.33 (s, 9H). | | |
| 102 | 1H-NMR (400 MHz, CDCl3): d = 9.01 (s, 1H), | 1383.66 | 1383.65 |
| | 8.98 (s, 1H), 8.12 (dd, 4H), 8.00 (d, 2H), 7.76 (s, | | |
| | 2H), 7.61-7.43(m, 12H), 7.42-7.23 (m, 17H), | | |
| | 7.22-7.11 (m, 9H), 6.89 (s, 1H), 6.81 (s, 1H), | | |
| | 1.38 (s, 18H), 1.32 (s, 18H). | | |

### 3. Manufacture and Evaluation of Light Emitting Device Including Fused Polycyclic Compound

The light emitting device of an embodiment including the fused polycyclic compound of an embodiment in an emission layer was manufactured as follows. Fused polycyclic compounds of Compounds 18, 20, 27, 36, 37, 55, 60, 81, and 102, which are Example Compounds as described above, were utilized as dopant materials for the emission layers to manufacture the light emitting devices of Examples 1 to 7, respectively. Comparative Examples 1 to 6 correspond to the light emitting devices manufactured by utilizing Comparative Example Compounds C1 to C6 as dopant materials for the emission layers, respectively.

### Example Compounds

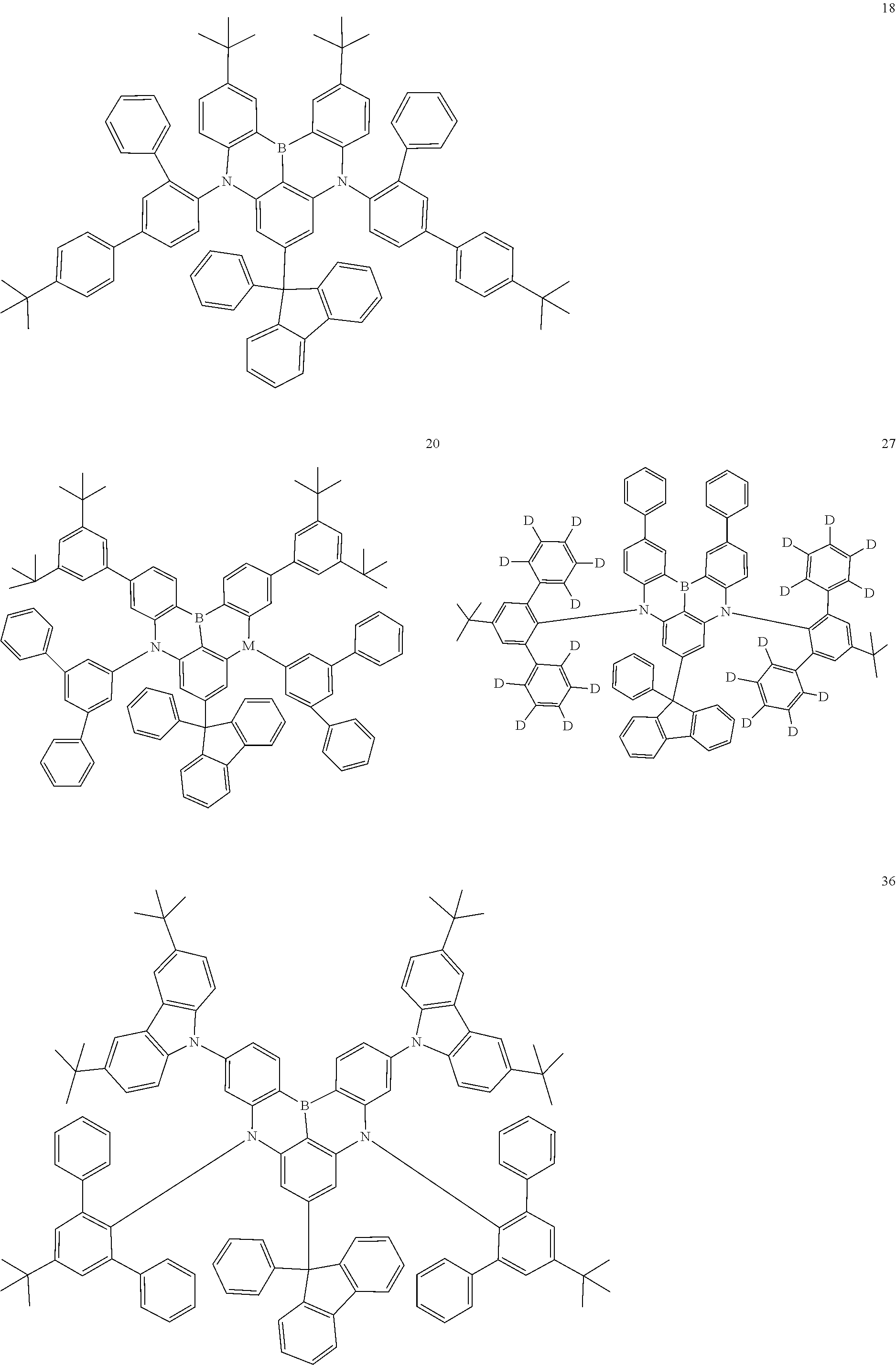

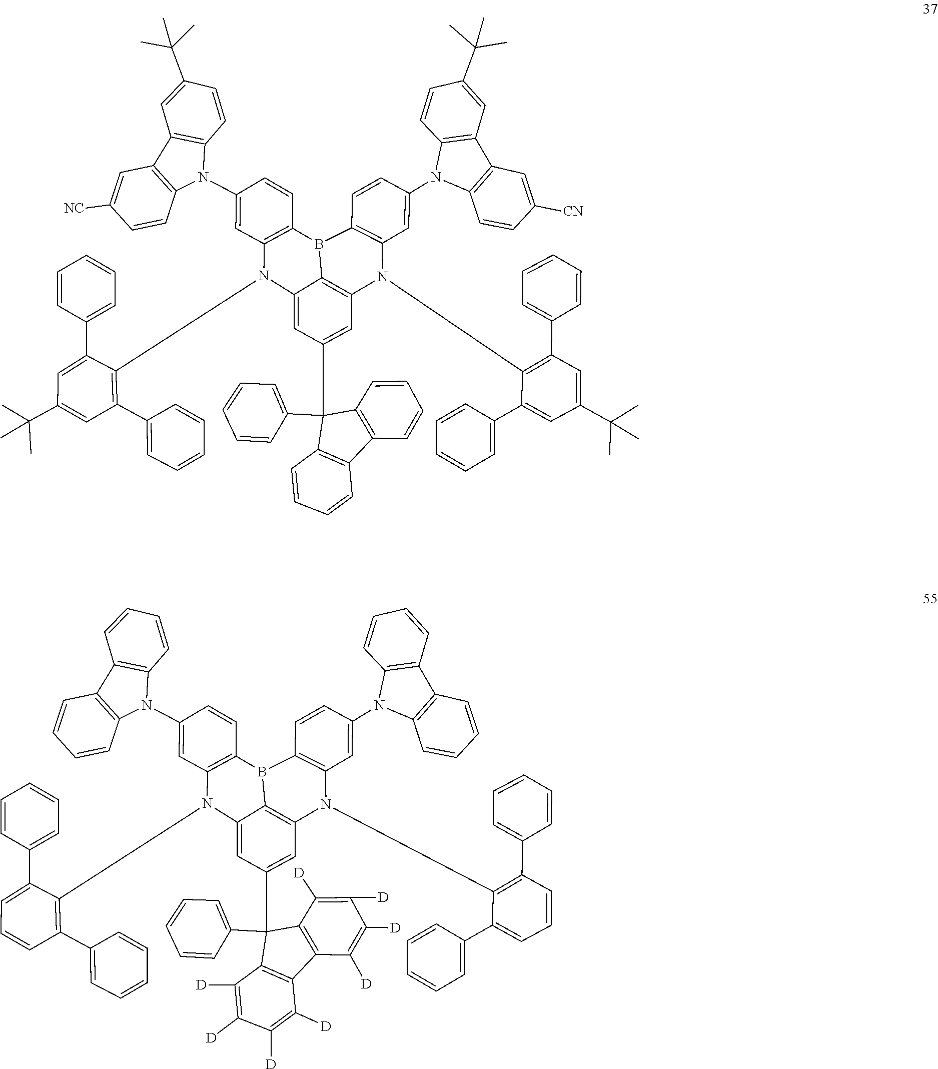 [SMILES: CC(C)(C)c1ccc2c(c1)-c1cc(C#N)ccc1N(c1ccc3c(c1)N(c1c(-c4ccccc4)cc(C(C)(C)C)cc1-c1ccccc1)c1cc(C4(c5ccccc5)c5ccccc5-c5ccccc54)cc4c1B3c1ccc(-n3c5ccc(C#N)cc5c5cc(C(C)(C)C)ccc53)cc1N4c1c(-c3ccccc3)cc(C(C)(C)C)cc1-c1ccccc1)C2 ; [2H]c1c([2H])c([2H])c2c(c1[2H])-c1c([2H])c([2H])c([2H])c([2H])c1C2(c1ccccc1)c1cc2c3c(c1)N(c1c(-c4ccccc4)cccc1-c1ccccc1)c1cc(-n4c5ccccc5c5ccccc54)ccc1B3c1ccc(N3Cc4ccccc4-c4ccccc43)cc1N2c1c(-c2ccccc2)cccc1-c1ccccc1]

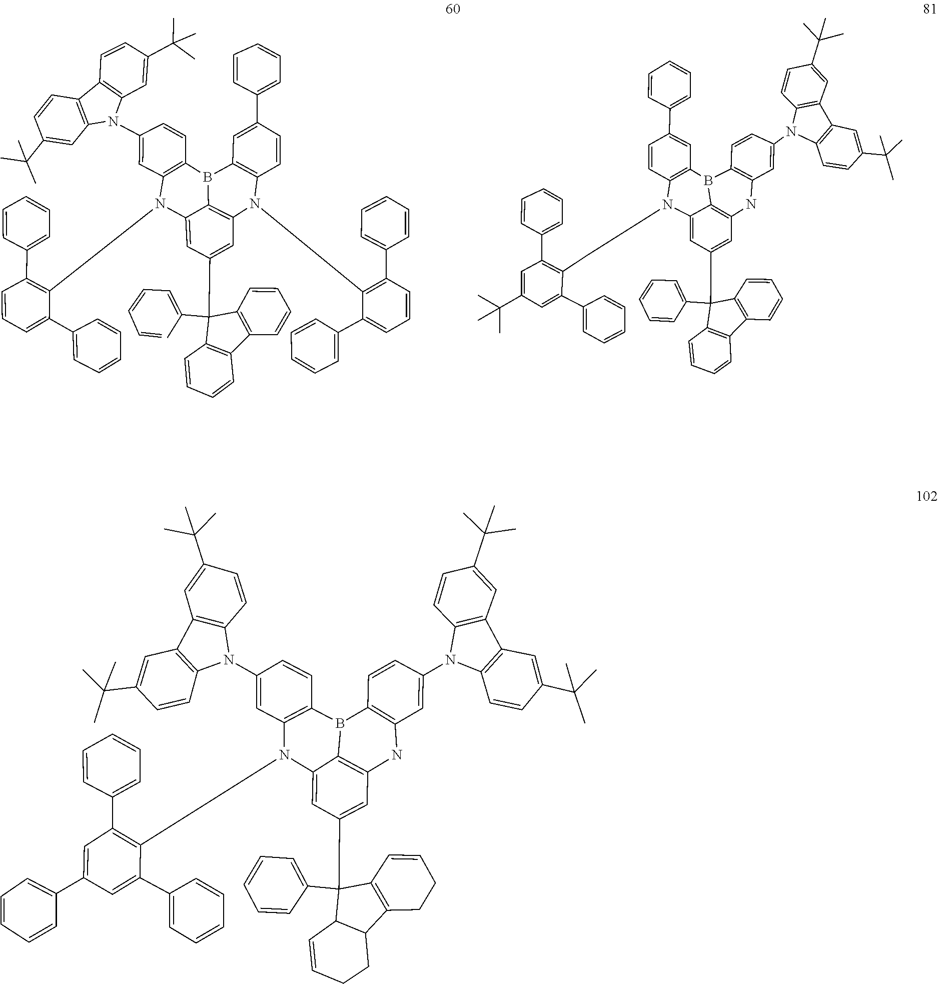

### Comparative Example Compounds

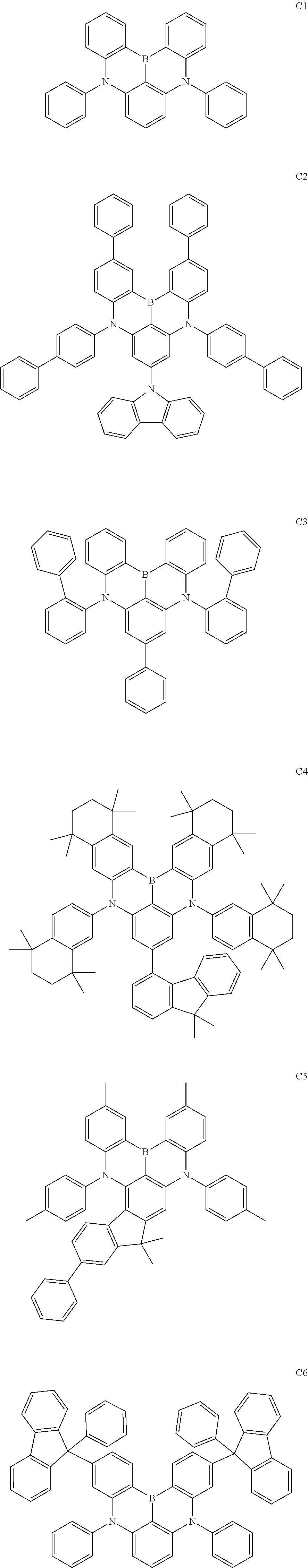

### Manufacture of Light Emitting Device

With respect to the light emitting devices of Examples and Comparative Examples, an ITO glass substrate was cut to a size of about 50 mm×50 mm×0.7 mm, washed by ultrasonic waves utilizing isopropyl alcohol and distilled water for about 5 minutes each, and then irradiated with ultraviolet rays for about 30 minutes and cleansed by exposing to ozone, and then installed on a vacuum deposition apparatus. Then, NPD was utilized to form a 300 Å-thick hole injection layer HIL, HT-1-19 was utilized to form a 200 Å-thick hole transport layer HTL, and then CzSi was utilized to form a 100 Å-thick emission auxiliary layer. Then, a host compound in which the first host and the second host according to an embodiment were mixed in a weight ratio of about 1:1, the second dopant, and a respective Example Compound or Comparative Example Compound were co-deposited in a weight ratio of about 82:15:3 to form a 200 Å-thick emission layer EML, and TSPO1 was utilized to form a 200 Å-thick electron transport layer ETL. Next, TPBi, a buffer electron transporting compound, was utilized to form a 300 Å-thick buffer layer, and LiF was utilized to form 10 Å-thick electron injection layer EIL. Al was then utilized to form a 3,000 Å-thick second electrode EL2 to form a LiF/Al electrode. Then, on the upper portion of the second electrode, P4 was utilized to form a 700 Å-thick capping layer. Each layer was formed by a vacuum deposition method. Meanwhile, HTH29 from among the compounds in Compound Group 2 as described above was utilized as the first host, ETH66 from among the compounds in Compound Group 3 as described above was utilized as the second host, and AD-37 from among the compounds in Compound Group 4 as described above was utilized as the second dopant (sensitizer).

Compounds utilized for manufacturing the light emitting devices of Examples and Comparative Examples are disclosed below. The materials below were utilized to manufacture the elements by subjecting commercial products to sublimation purification.

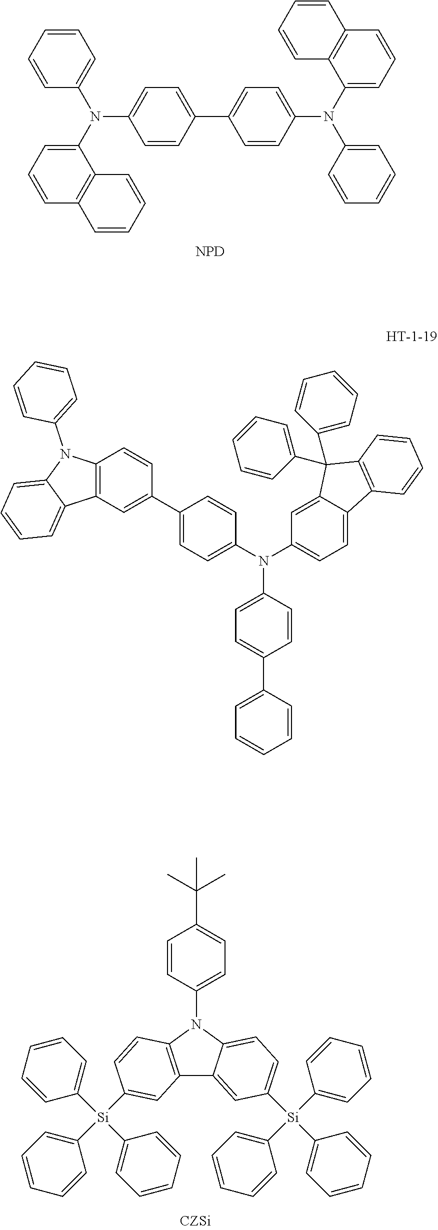

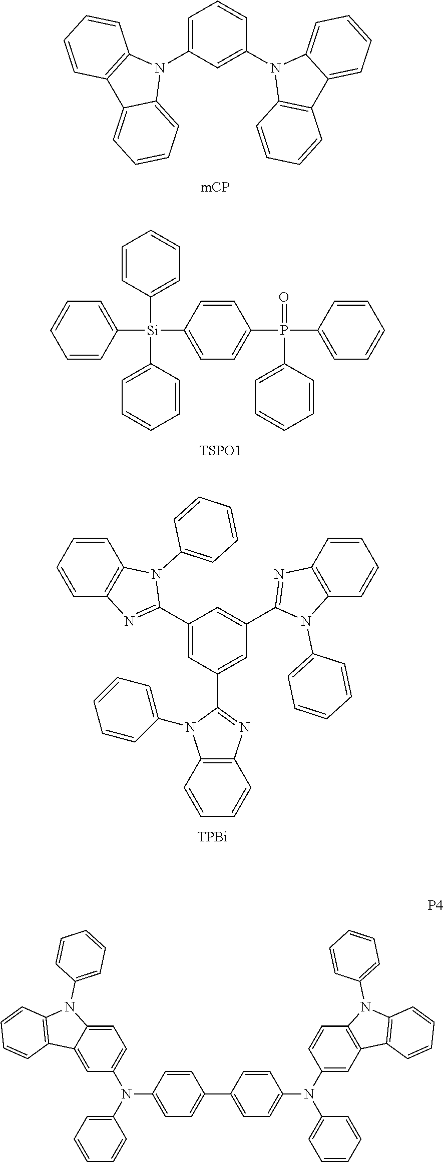

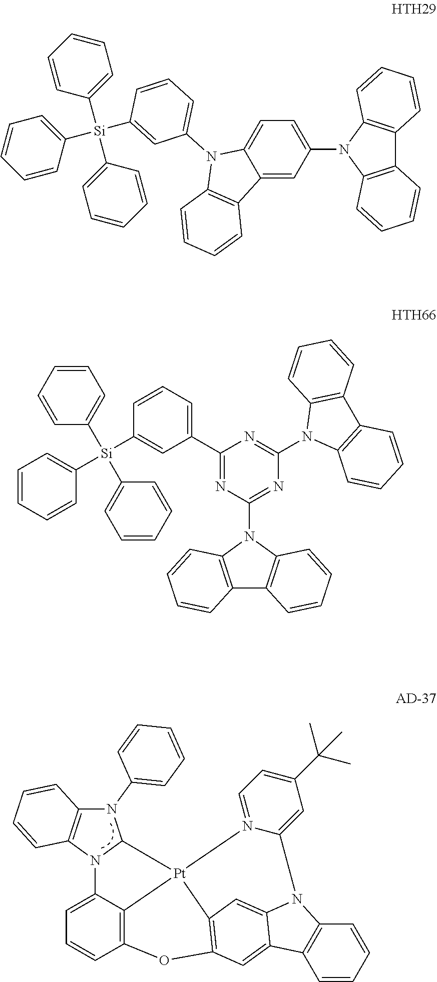

### Evaluation of Light Emitting Device Characteristics

Device efficiencies and device service lives of the light emitting devices manufactured with Experimental Example Compounds 18, 20, 27, 36, 37, 55, 60, 81 and 102, and Comparative Example Compounds C1 to C6 as described above were evaluated. Evaluation results of the light emitting devices of Examples 1 to 9 and Comparative Examples 1 to 6 are listed in Table 2. In the characteristic evaluation results of Examples and Comparative Examples listed in Table 1, driving voltages and current densities were measured by utilizing V7000 OLED IVL Test System (Polaronix). To evaluate the characteristics of the light emitting devices manufactured in Examples 1 to 9 and Comparative Examples 1 to 6, driving voltages and efficiencies (cd/A) at a current density of 10 mA/cm² were measured, and the relative device service life was set as a numerical value with the service life of Comparative Example 1 set as 1. Each service life was measured as the time it took for the brightness to deteriorate from an initial value to 50% of the initial brightness value when the device was continuously operated at a current density of 10 mA/cm².

TABLE 2

| | Second | | | | | | |
|---|---|---|---|---|---|---|---|
| | compound:Third | | | Driving | | Luminescence | Service |
| | compound | Fourth | First | voltage | Efficiency | wavelength | life ratio |
| | (HT:ET = 5:5) | compound | compound | (V) | (cd/A) | (nm) | (T95) |
| Example 1 | HTH29/ETH66 | AD-37 | 18 | 4.3 | 28 | 455 | 4.0 |
| Example 2 | HTH29/ETH66 | AD-37 | 20 | 4.2 | 30.1 | 460 | 4.6 |
| Example 3 | HTH29/ETH66 | AD-37 | 27 | 4.1 | 29.4 | 458 | 4.9 |
| Example 4 | HTH29/ETH66 | AD-37 | 36 | 4.1 | 30.3 | 456 | 5.1 |
| Example 5 | HTH29/ETH66 | AD-37 | 37 | 4.2 | 28.9 | 457 | 4.2 |
| Example 6 | HTH29/ETH66 | AD-37 | 55 | 4.1 | 29.7 | 456 | 4.5 |
| Example 7 | HTH29/ETH66 | AD-37 | 60 | 4.2 | 29.3 | 458 | 4.9 |
| Example 8 | HTH29/ETH66 | AD-37 | 81 | 4.3 | 27.9 | 454 | 3.9 |
| Example 9 | HTH29/ETH66 | AD-37 | 102 | 4.3 | 28.1 | 457 | 4.1 |
| Comparative | HTH29/ETH66 | AD-37 | C1 | 4.8 | 19.2 | 462 | 1 |
| Example 1 | | | | | | | |
| Comparative | HTH29/ETH66 | AD-37 | C2 | 4.5 | 26.8 | 463 | 2.5 |
| Example 2 | | | | | | | |
| Comparative | HTH29/ETH66 | AD-37 | C3 | 4.6 | 24.1 | 458 | 1.4 |
| Example 3 | | | | | | | |
| Comparative | HTH29/ETH66 | AD-37 | C4 | 5.1 | 16.2 | 461 | 0.6 |
| Example 4 | | | | | | | |
| Comparative | HTH29/ETH66 | AD-37 | C5 | 5.0 | 18.7 | 464 | 0.8 |
| Example 5 | | | | | | | |
| Comparative | HTH29/ETH66 | AD-37 | C6 | 4.7 | 20.1 | 462 | 2.3 |
| Example 6 | | | | | | | |

Referring to the results of Table 1, it may be confirmed that Examples of the light emitting devices in which the fused polycyclic compounds according to embodiments of the present disclosure are utilized as a luminescent material exhibit lower driving voltage and higher luminous efficiency, and particularly have significantly improved service life characteristics as compared with Comparative Examples. Example Compounds each include the first substituent bonded at the para-position of the boron atom constituting the fused ring, thereby may effectively maintain a trigonal planar structure of the boron atom through a steric hindrance effect by the first substituent, and thus high efficiency and long service life of the light emitting device including Example Compounds may be exhibited. Example Compounds may have an increase in the luminous efficiency and may suppress or reduce the red shift of luminescence wavelength because the intermolecular interaction may be suppressed or reduced by the introduction of the first substituent, thereby controlling the formation of excimer or exciplex. In addition, Example Compounds have an increase in the distance between adjacent molecules due to the large steric hindrance structure to thereby suppress or reduce the Dexter energy transfer, and thus may suppress or reduce the deterioration of service life due to the increase of triplet concentration.

The light emitting device of an embodiment may exhibit improved device characteristics with high efficiency and a long service life.

The fused polycyclic compound of an embodiment may be included in the emission layer of the light emitting device to contribute to high efficiency and a long service life of the light emitting device.

As used herein, the term “and/or” includes any and all combinations of one or more of the associated listed items. Throughout the disclosure, the expression “at least one of a, b or c”, “at least one selected from a, b, and c”, “at least one selected from the group consisting of a, b, and c”, “at least one from among a, b, and c”, etc., indicates only a, only b, only c, both (e.g., simultaneously) a and b, both (e.g., simultaneously) a and c, both (e.g., simultaneously) b and c, all of a, b, and c, or variations thereof.

The use of “may” when describing embodiments of the present disclosure refers to “one or more embodiments of the present disclosure”.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to a preferred embodiment of the present disclosure, it will be understood that the present disclosure should not be limited to these preferred embodiments but one or more suitable changes and modifications can be made by those skilled in the art without departing from the spirit and scope of the present disclosure.

Accordingly, the technical scope of the present disclosure is not intended to be limited to the contents set forth in the detailed description of the present disclosure, but is intended to be defined by the appended claims, and equivalents thereof.

What is claimed is:

1. A light emitting device comprising:
a first electrode;
a second electrode facing the first electrode; and
an emission layer between the first electrode and the second electrode,
wherein the emission layer comprises a first compound represented by Formula 1: 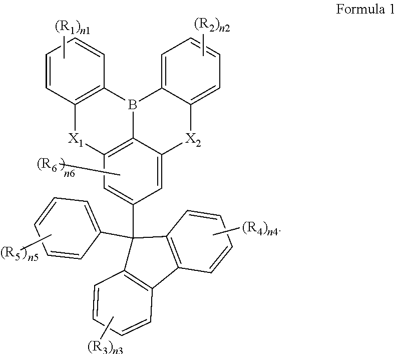
wherein, in Formula 1,
X₁ and X₂ are each independently NA_{R7}, O or S,
R₁ to R₇ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
n1 to n4 are each independently an integer of 0 to 4,
n5 is an integer of 0 to 5, and
n6 is an integer of 0 to 2.

2. The light emitting device of claim 1, wherein in Formula 1, R₁ to R₇ are each independently a hydrogen atom, a deuterium atom, a fluorine atom, a cyano group, a substituted or unsubstituted amine group, a substituted or unsubstituted oxy group, a substituted or unsubstituted t-butyl group, a substituted or unsubstituted phenyl group, a substituted or unsubstituted biphenyl group, a substituted or unsubstituted terphenyl group, a substituted or unsubstituted naphthyl group, a substituted or unsubstituted carbazole group, a substituted or unsubstituted dibenzofuran group, or a substituted or unsubstituted dibenzothiophene group, and/or bonded to an adjacent group to form a ring.

3. The light emitting device of claim 1, wherein the first compound represented by Formula 1 is represented by any one selected from among Formula 2a to Formula 2c: 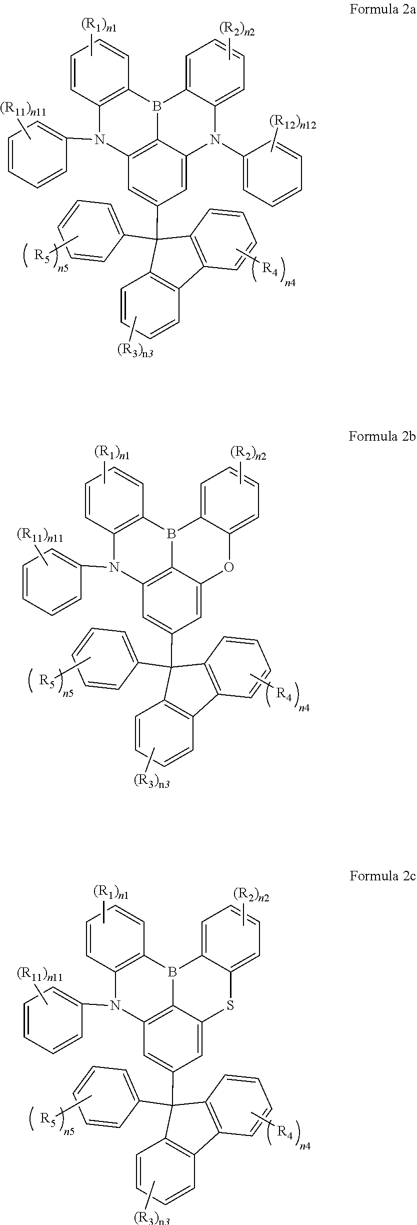
wherein, in Formula 2a to Formula 2c,
R₁₁ and R₁₂ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
n11 and n12 are each independently an integer of 0 to 5, and
R₁ to R₅, and n1 to n5 are the same as respectively defined in Formula 1.

4. The light emitting device of claim 3, wherein the first compound represented by Formula 2a is represented by any one selected from among Formula 2-1 to Formula 2-5: 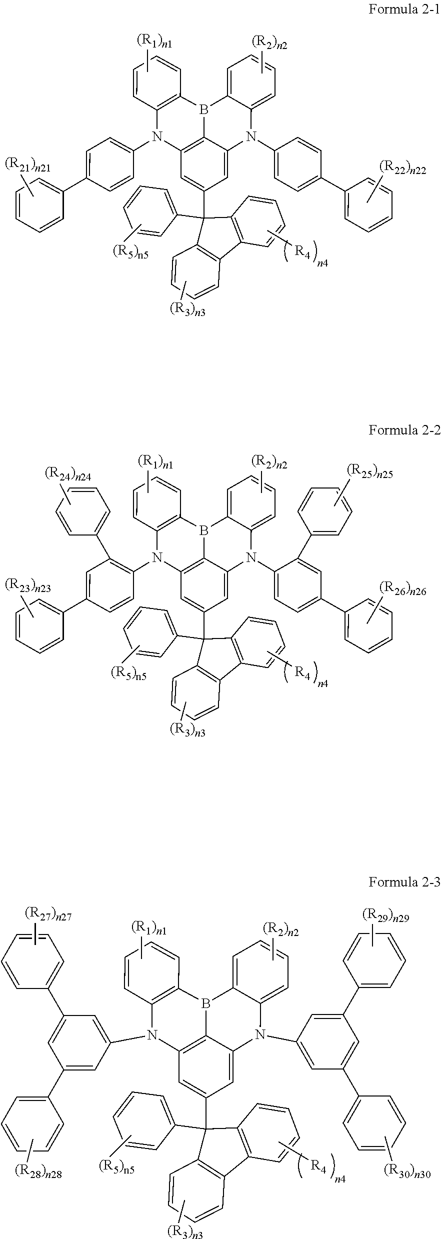 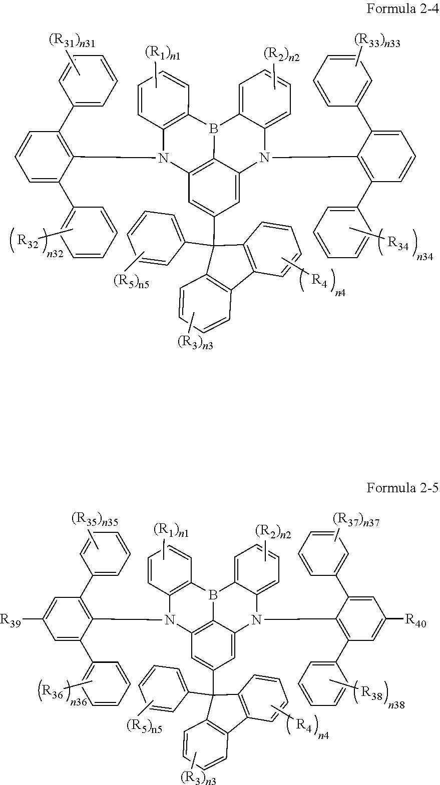
wherein, in Formula 2-1 to Formula 2-5,
R₂₁ to R₃₈ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
R₃₉ and R₄₀ are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n21 to n38 are each independently an integer of 0 to 5, and
R₁ to R₅, and n1 to n5 are the same as respectively defined in Formula 1.

5. The light emitting device of claim 4, wherein, in Formula 2-1 to Formula 2-5,
R₂₁ to R₃₈ are each independently a hydrogen atom, a deuterium atom, a cyano group, a substituted or unsubstituted oxy group, a substituted or unsubstituted methyl group, a substituted or unsubstituted vinyl group, a substituted or unsubstituted t-butyl group, or a substituted or unsubstituted phenyl group, and/or bonded to an adjacent group to form a ring, and
R₃₉ and R₄₀ are each independently a deuterium atom, a cyano group, a substituted or unsubstituted methyl group, a substituted or unsubstituted t-butyl, or a substituted or unsubstituted phenyl group.

6. The light emitting device of claim 1, wherein the first compound represented by Formula 1 is represented by any one selected from among Formula 3-1 to Formula 3-4: 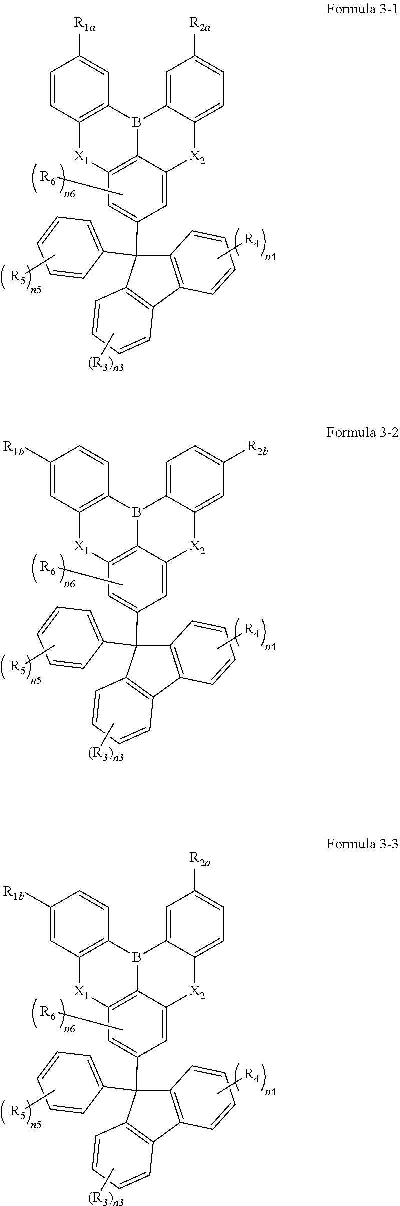 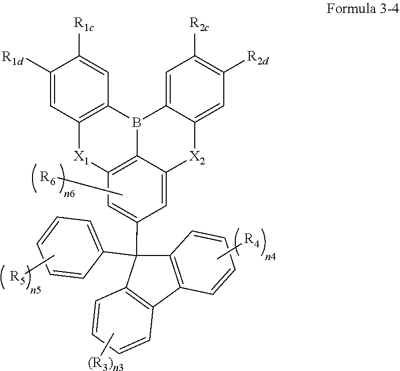
wherein, in Formula 3-1 to Formula 3-4,
R₁ₐ, R_{1b}, R₂ₐ, and R_{2b} are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{1c}, R_{1d}, R_{2c}, and R_{2d} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and
X₁, X₂, R₃ to R₆, and n3 to n6 are the same as respectively defined in Formula 1.

7. The light emitting device of claim 1, wherein the first compound represented by Formula 1 is represented by any one selected from among Formula 4-1 to Formula 4-5: 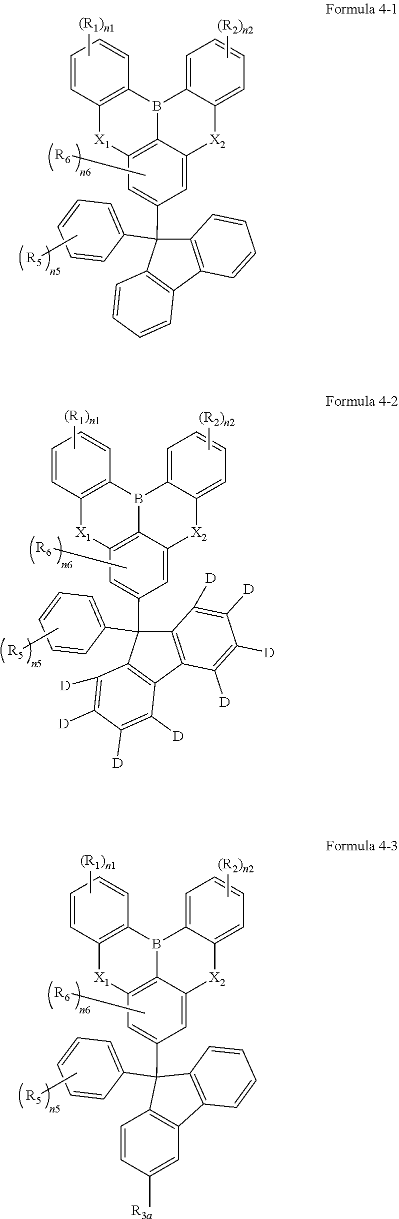 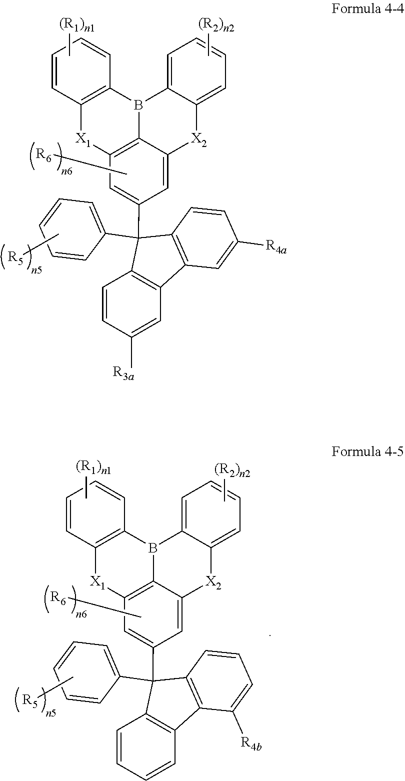
wherein, in Formula 4-1 to Formula 4-5,
R₃ₐ, R₄ₐ, and R_{4b} are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
D represents a deuterium atom, and
X₁, X₂, R₁, R₂, R₅, R₆, n1, n2, n5, and n6 are the same as respectively defined in Formula 1.

8. The light emitting device of claim 1, wherein the first compound represented by Formula 1 is represented by any one selected from among Formula 5-1 to Formula 5-6: 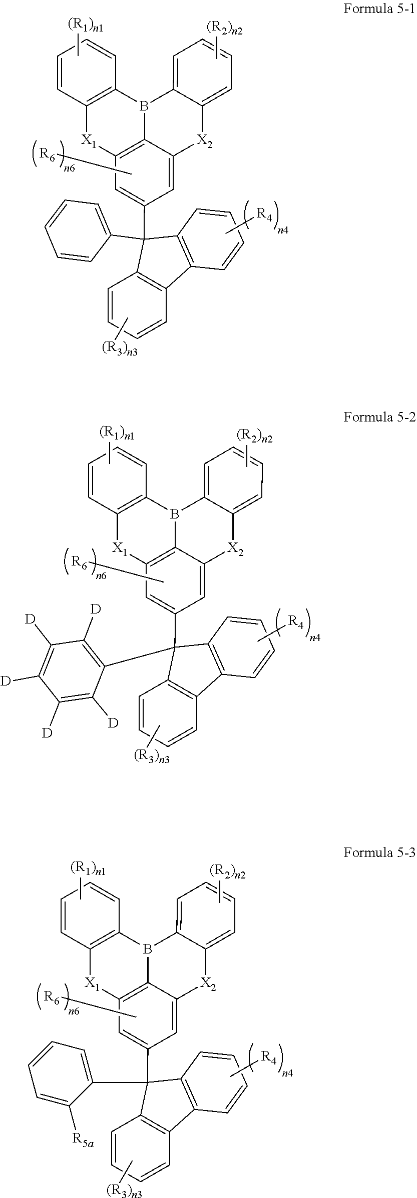 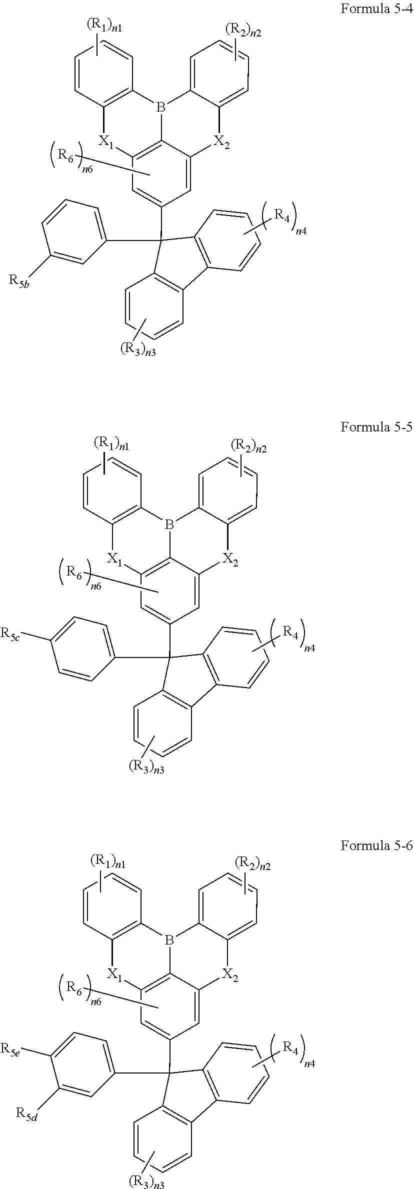
wherein, in Formula 5-1 to Formula 5-6,
R₅ₐ, R_{5b}, and R_{5c} are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{5d} and R₅ₑ are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
D represents a deuterium atom, and
X₁, X₂, R₁ to R₄, R₆, n1 to n4, and n6 are the same as respectively defined in Formula 1.

9. The light emitting device of claim 1, wherein the first compound represented by Formula 1 comprises at least one from among compounds in Compound Group 1:

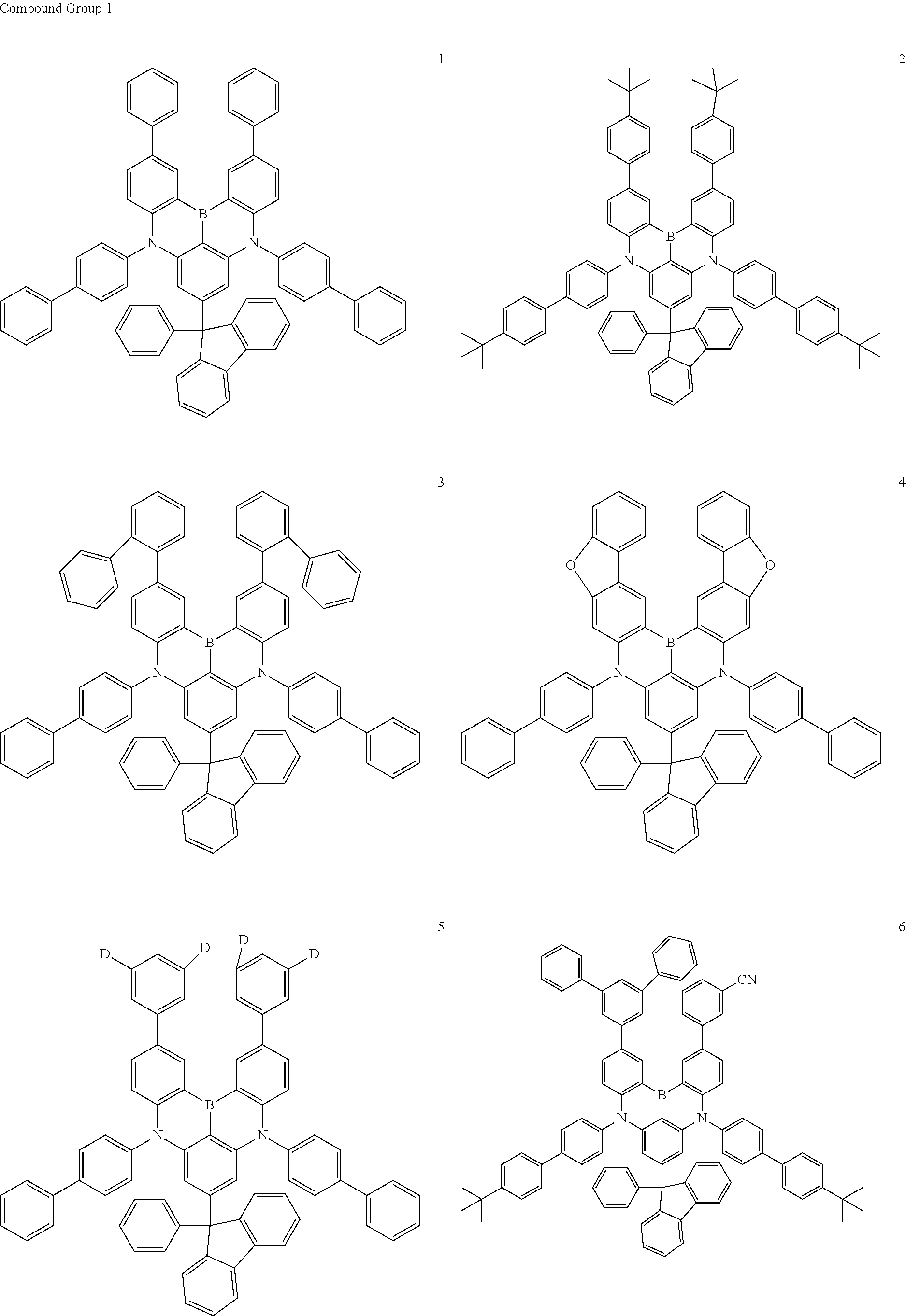

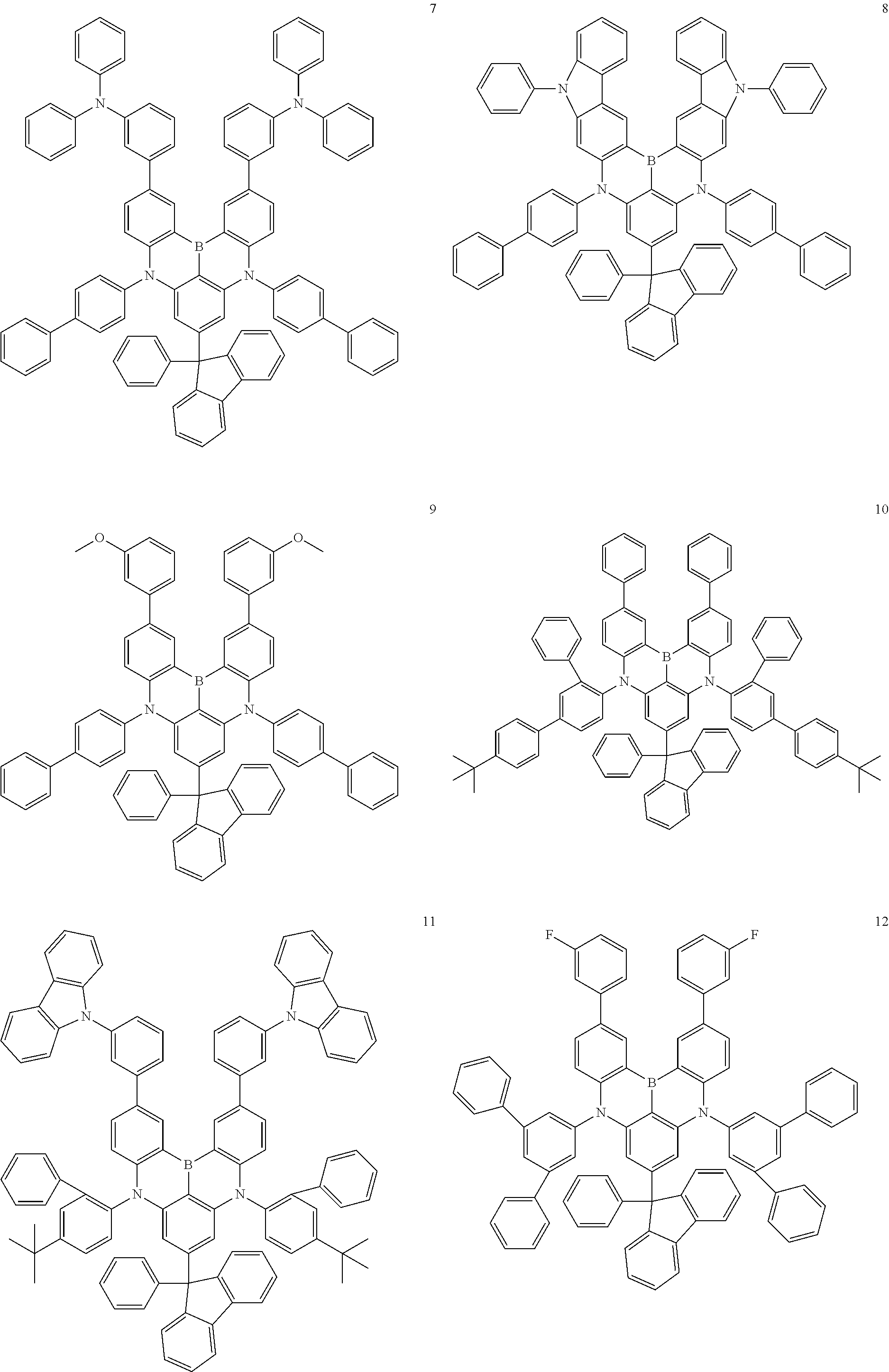

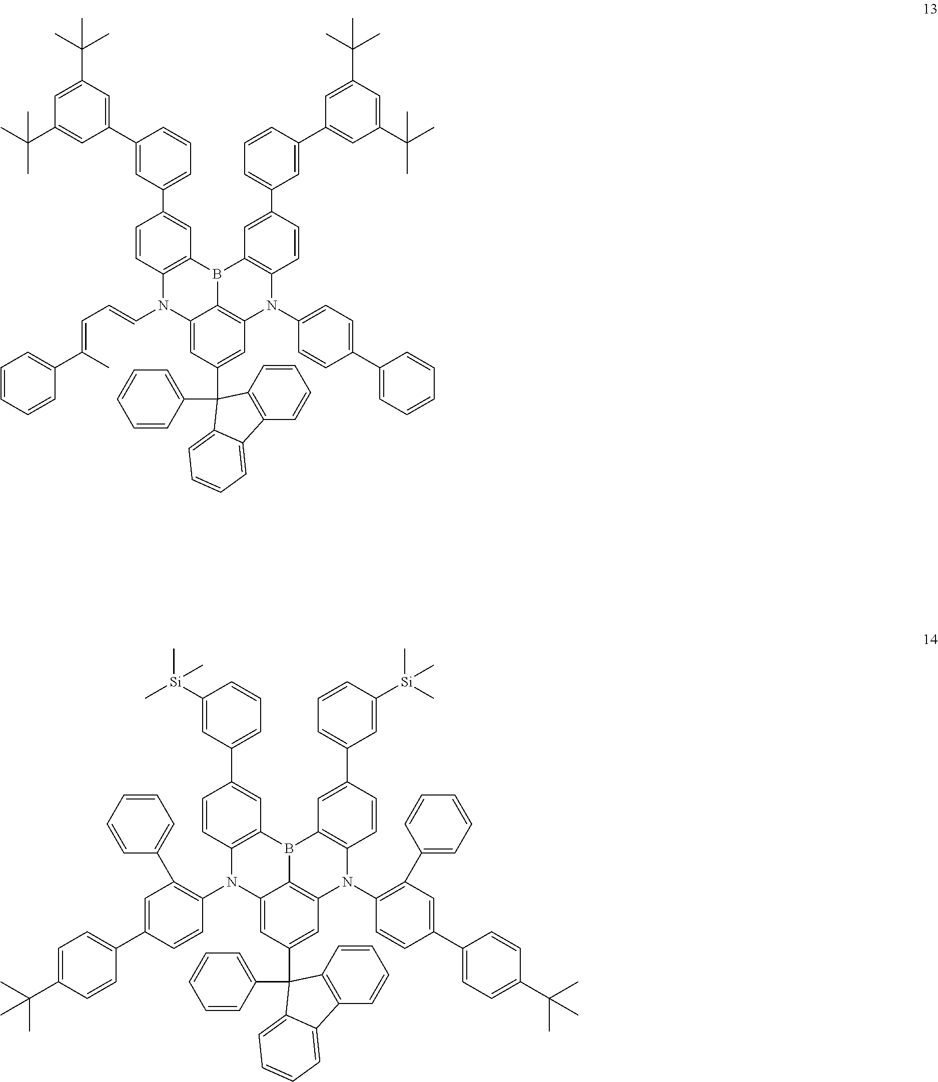 [SMILES: C/C(=C\C=C\N1c2ccc(-c3cccc(-c4cc(C(C)(C)C)cc(C(C)(C)C)c4)c3)cc2B2c3cc(-c4cccc(-c5cc(C(C)(C)C)cc(C(C)(C)C)c5)c4)ccc3N(c3ccc(-c4ccccc4)cc3)c3cc(C4(c5ccccc5)c5ccccc5-c5ccccc54)cc1c32)c1ccccc1 ; CC(C)(C)c1ccc(-c2ccc(N3c4ccc(-c5cccc([Si](C)(C)C)c5)cc4B4c5cc(-c6cccc([Si](C)(C)C)c6)ccc5N(c5ccc(-c6ccc(C(C)(C)C)cc6)cc5-c5ccccc5)c5cc(C6(c7ccccc7)c7ccccc7-c7ccccc76)cc3c54)c(-c3ccccc3)c2)cc1]

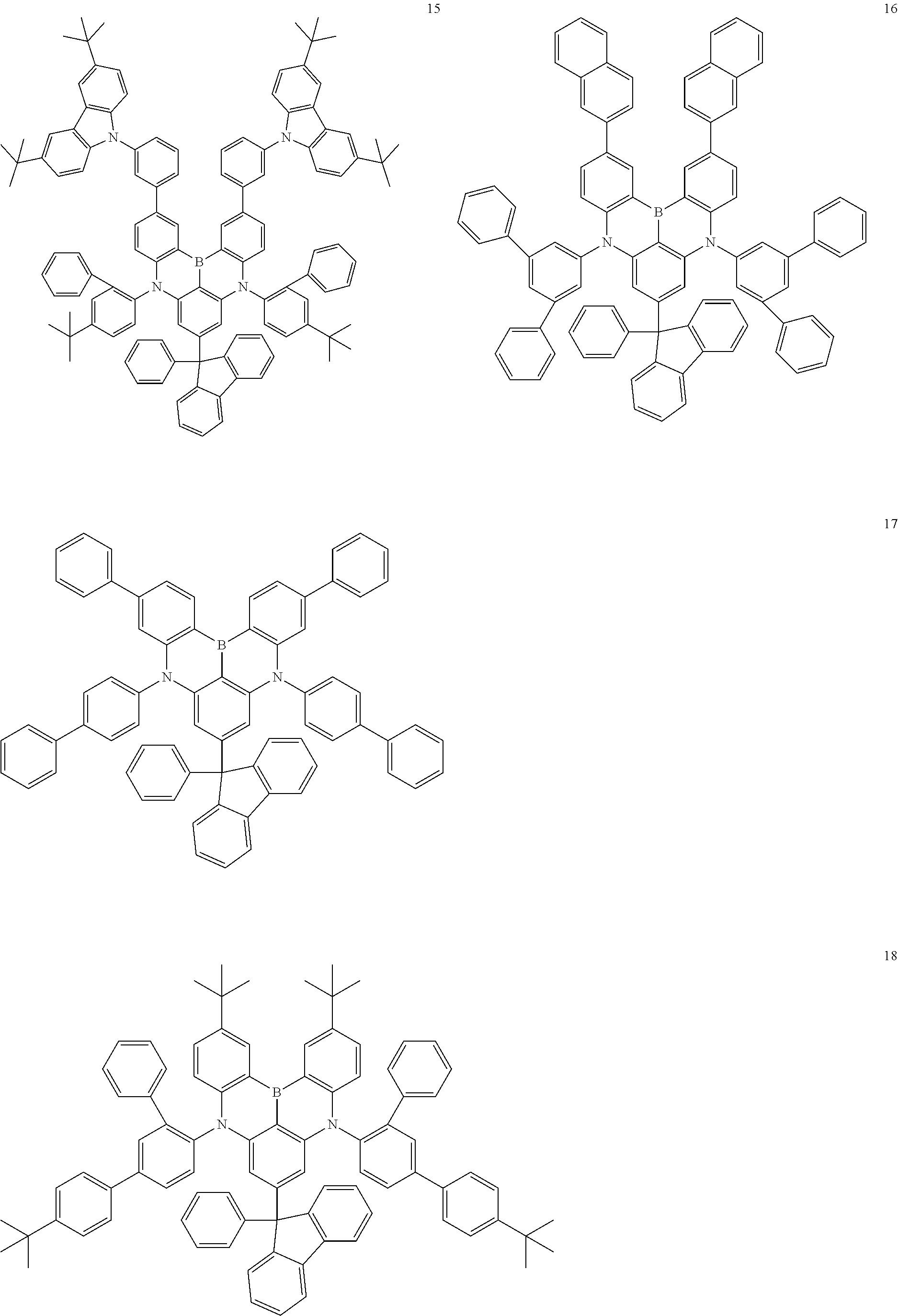

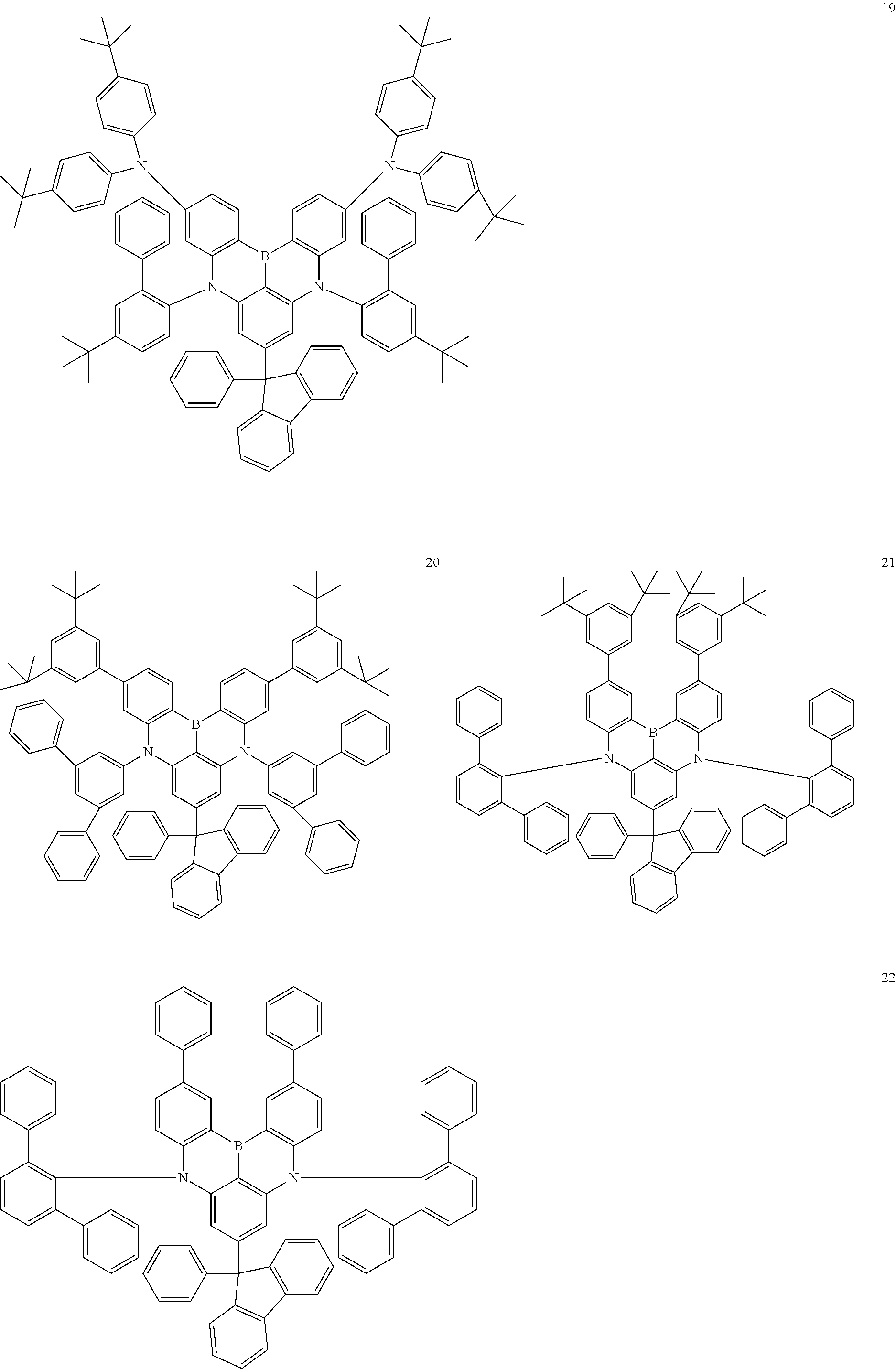

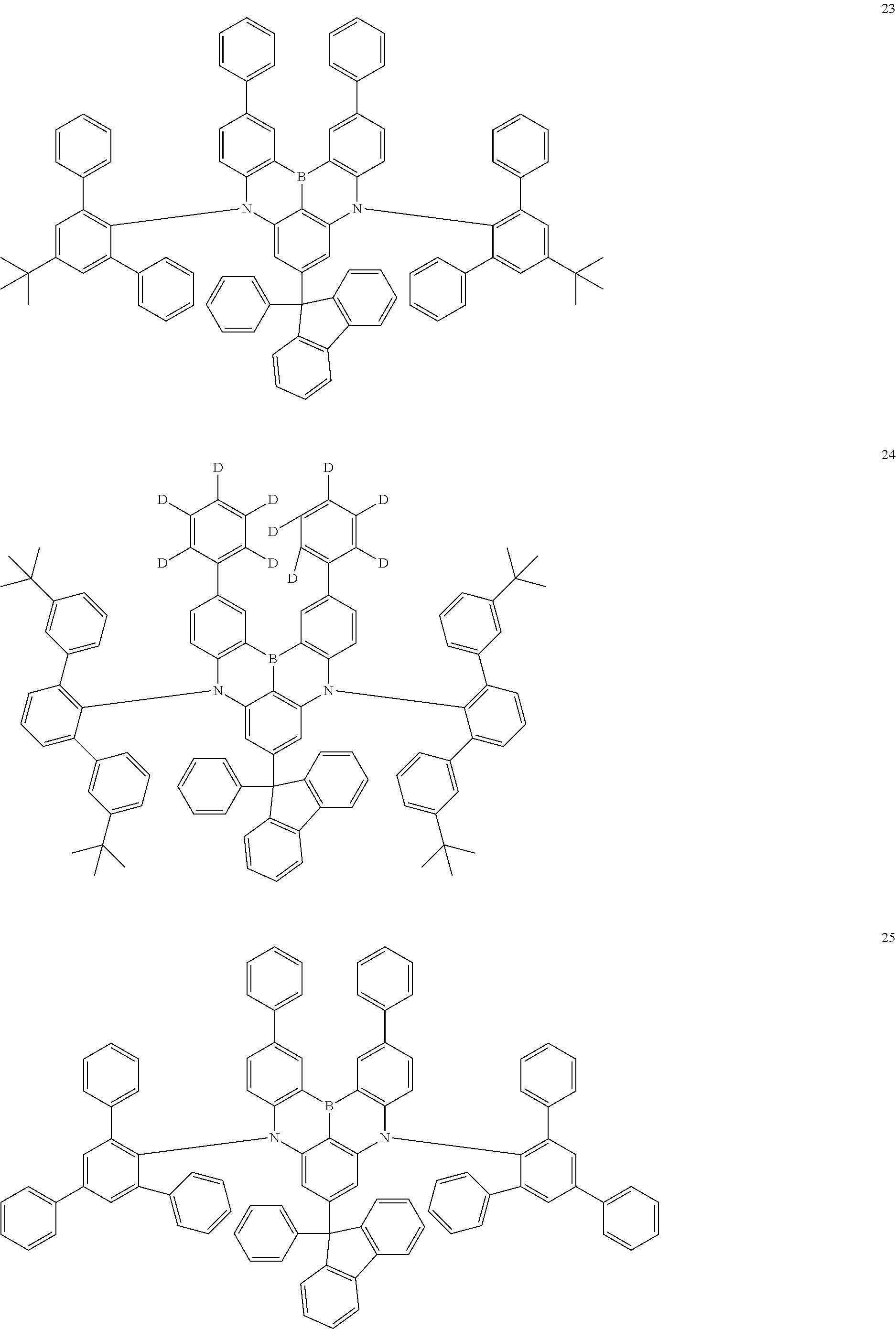

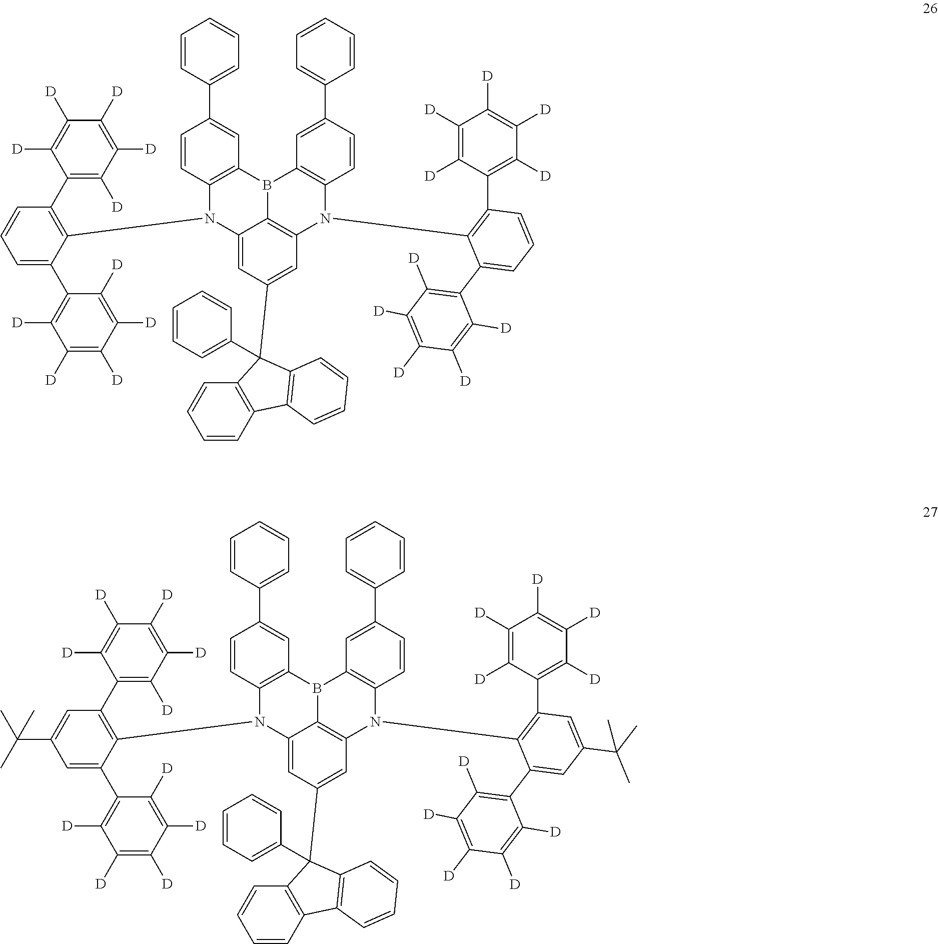

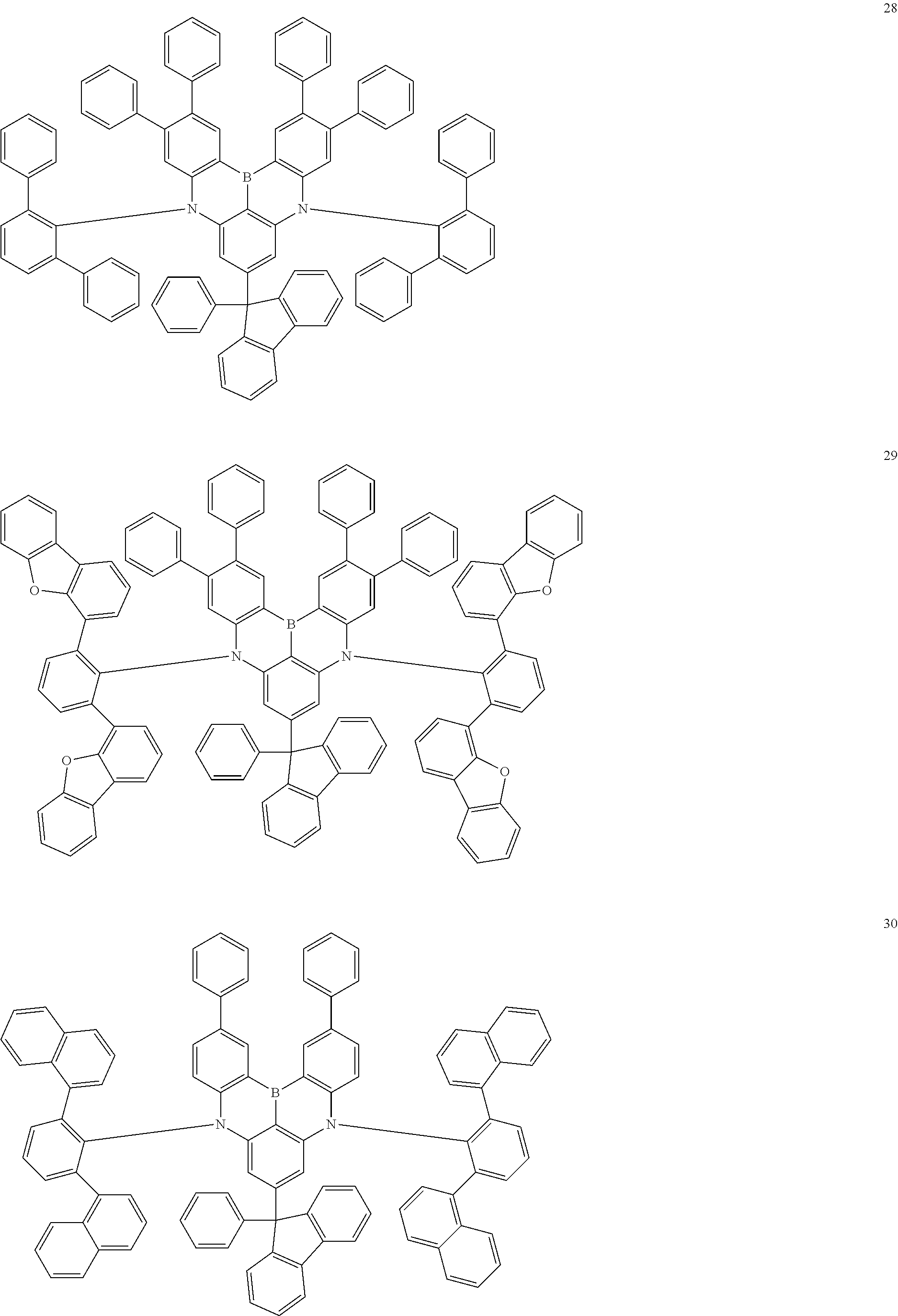

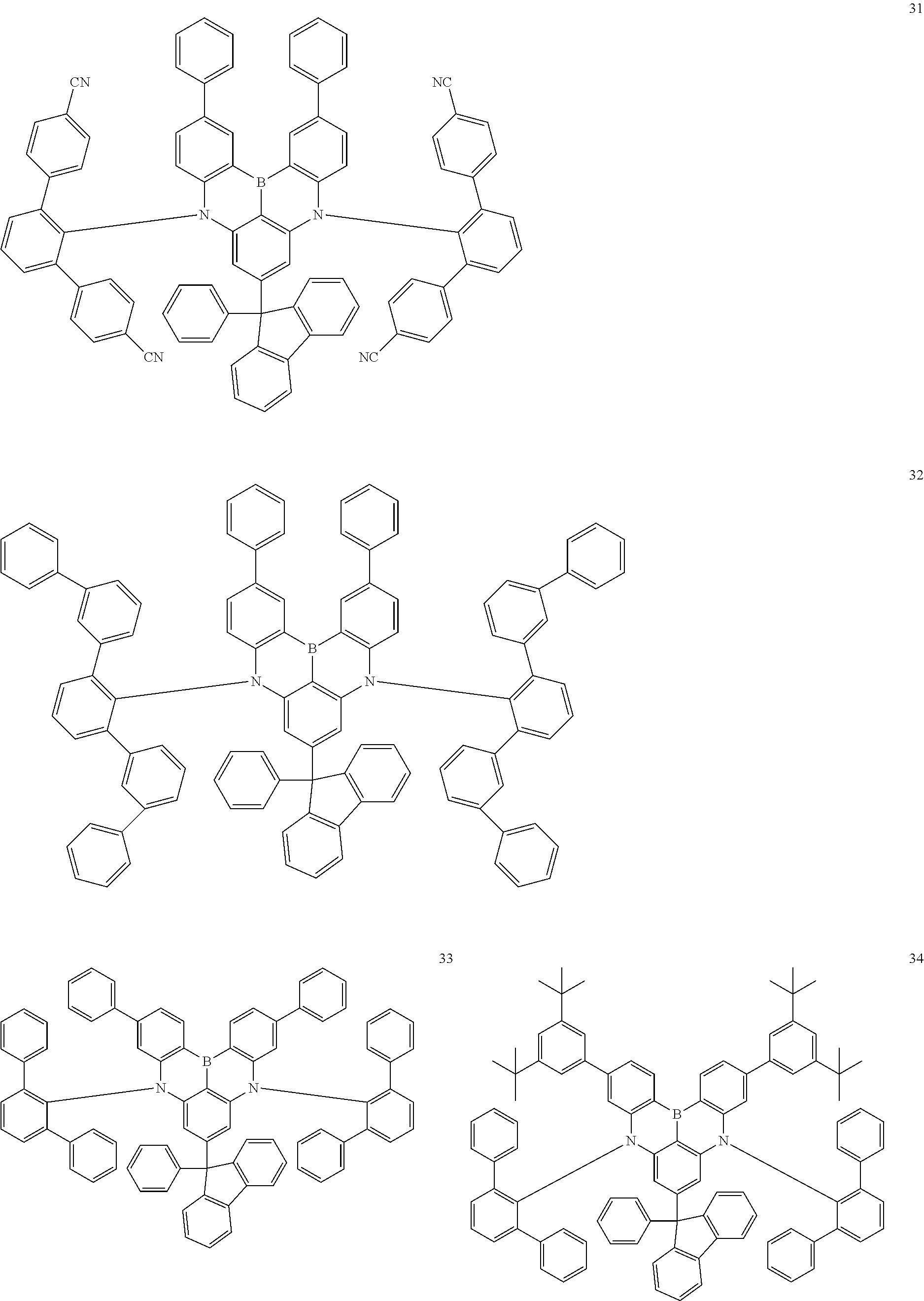

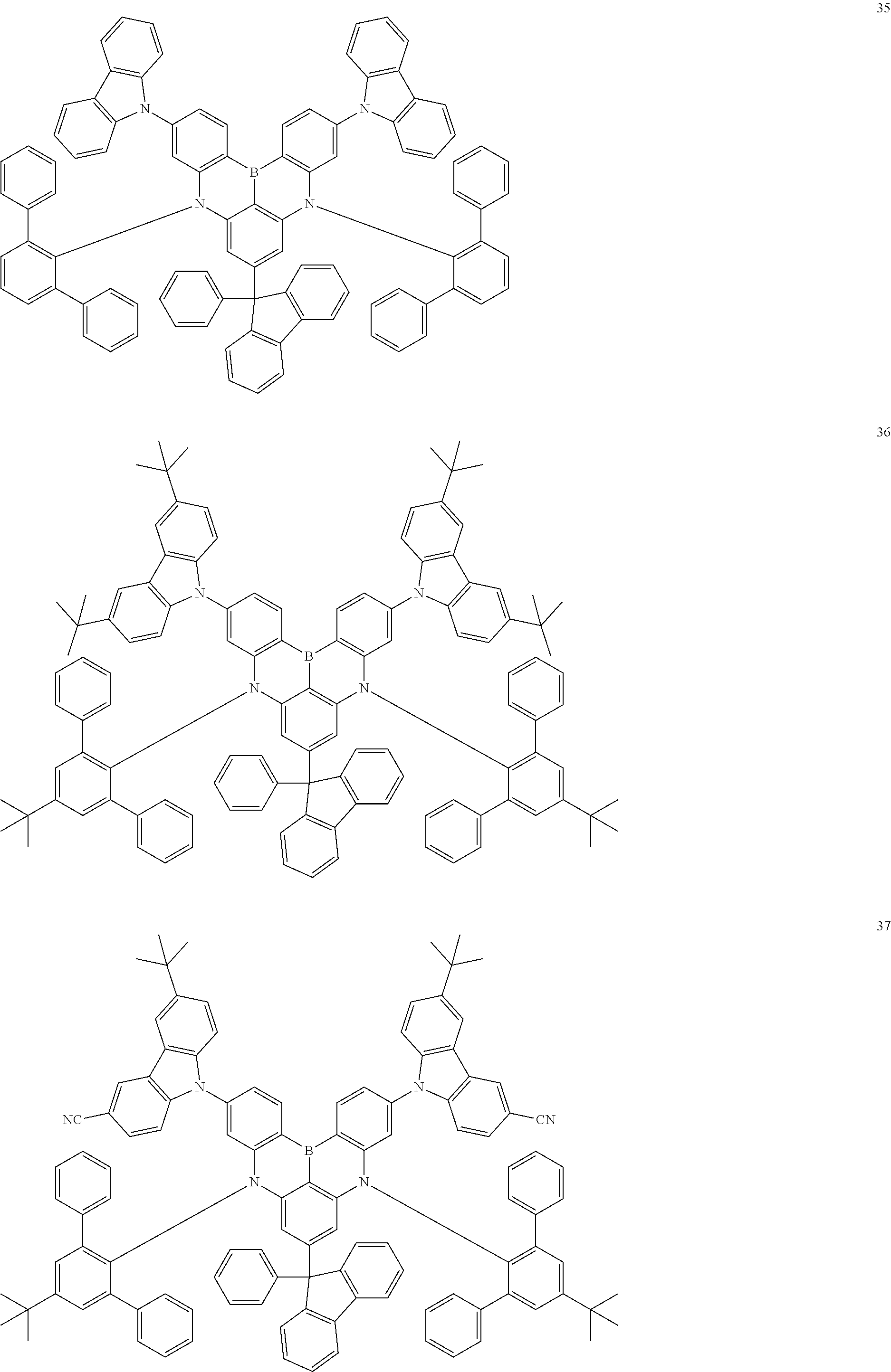

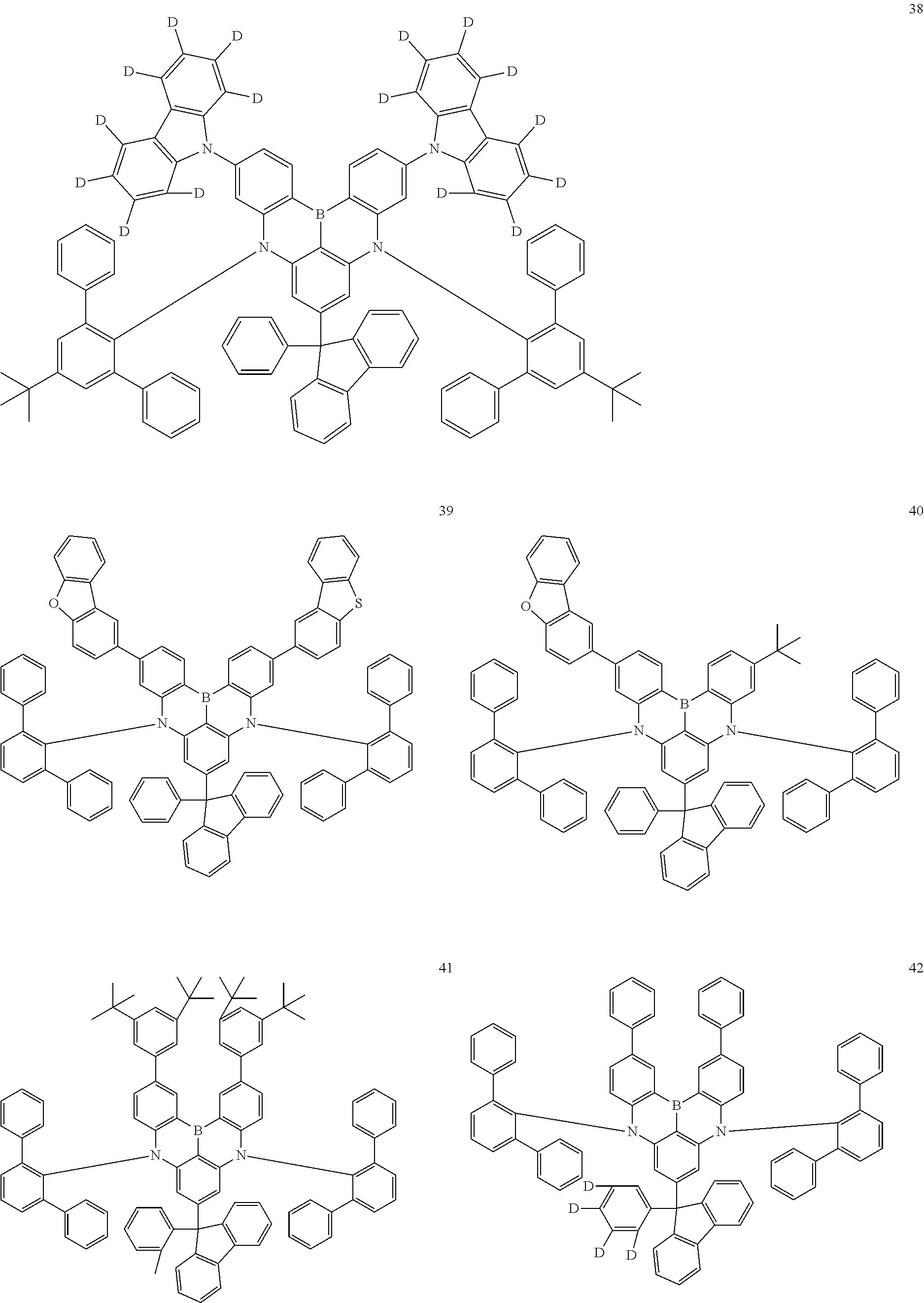

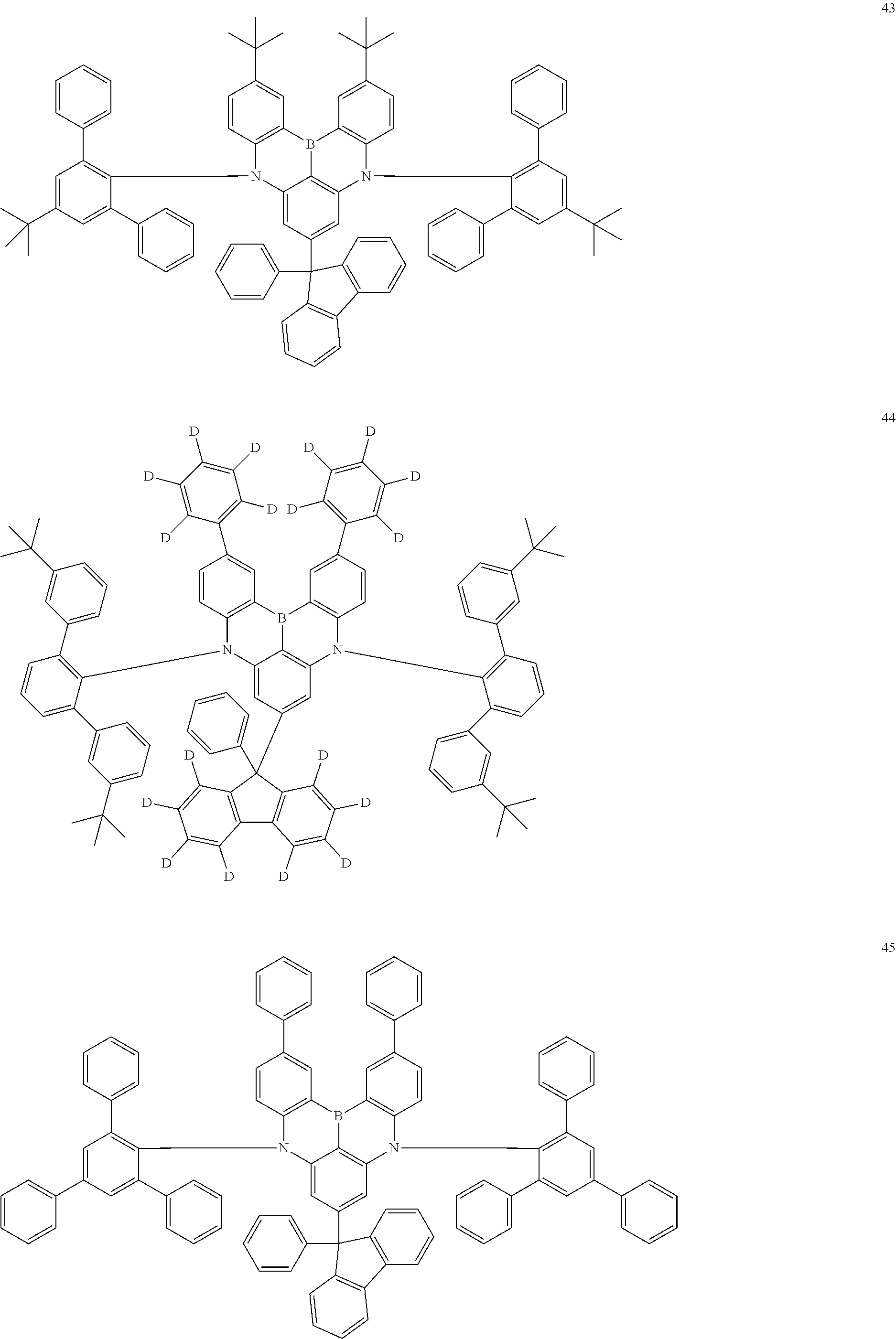

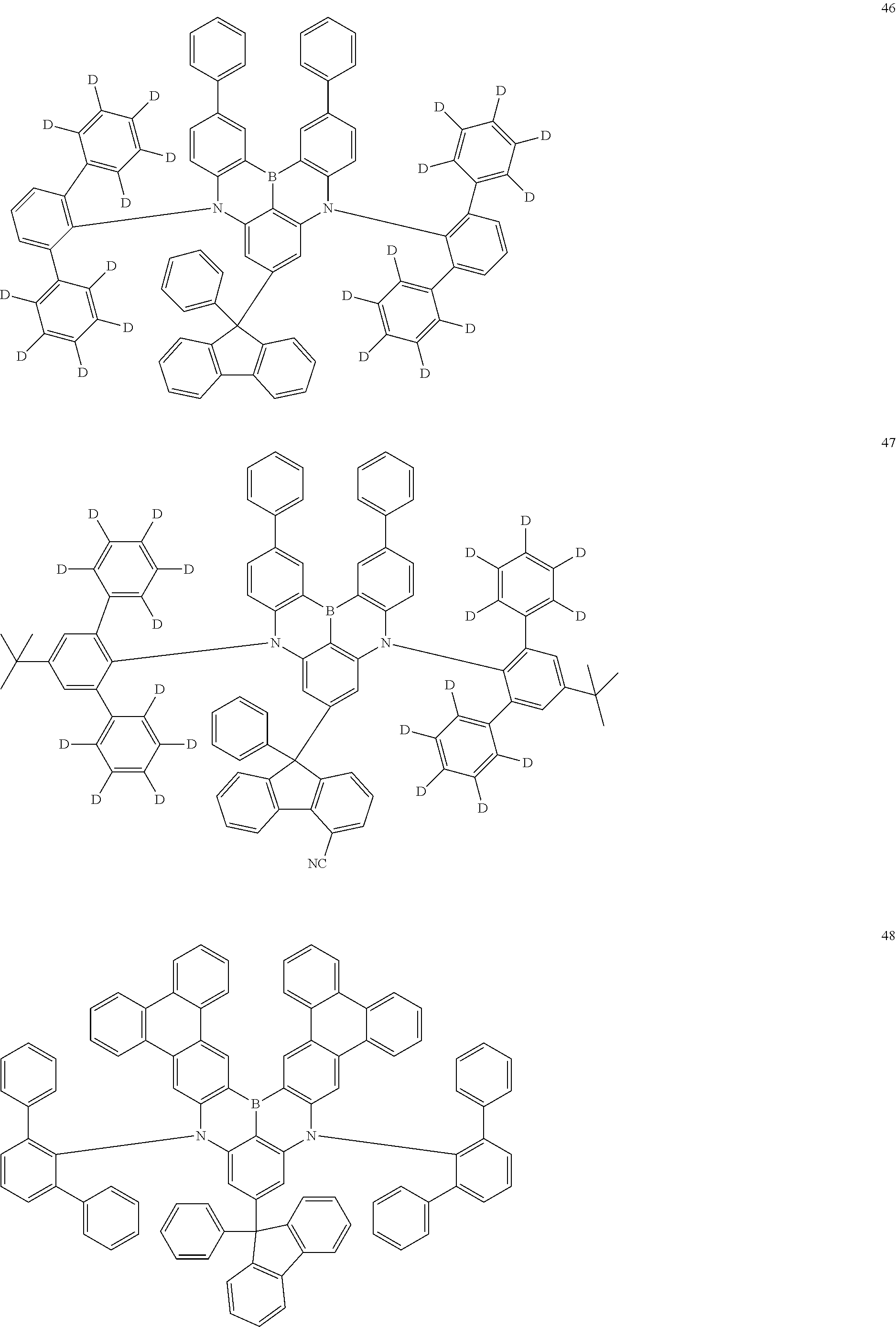

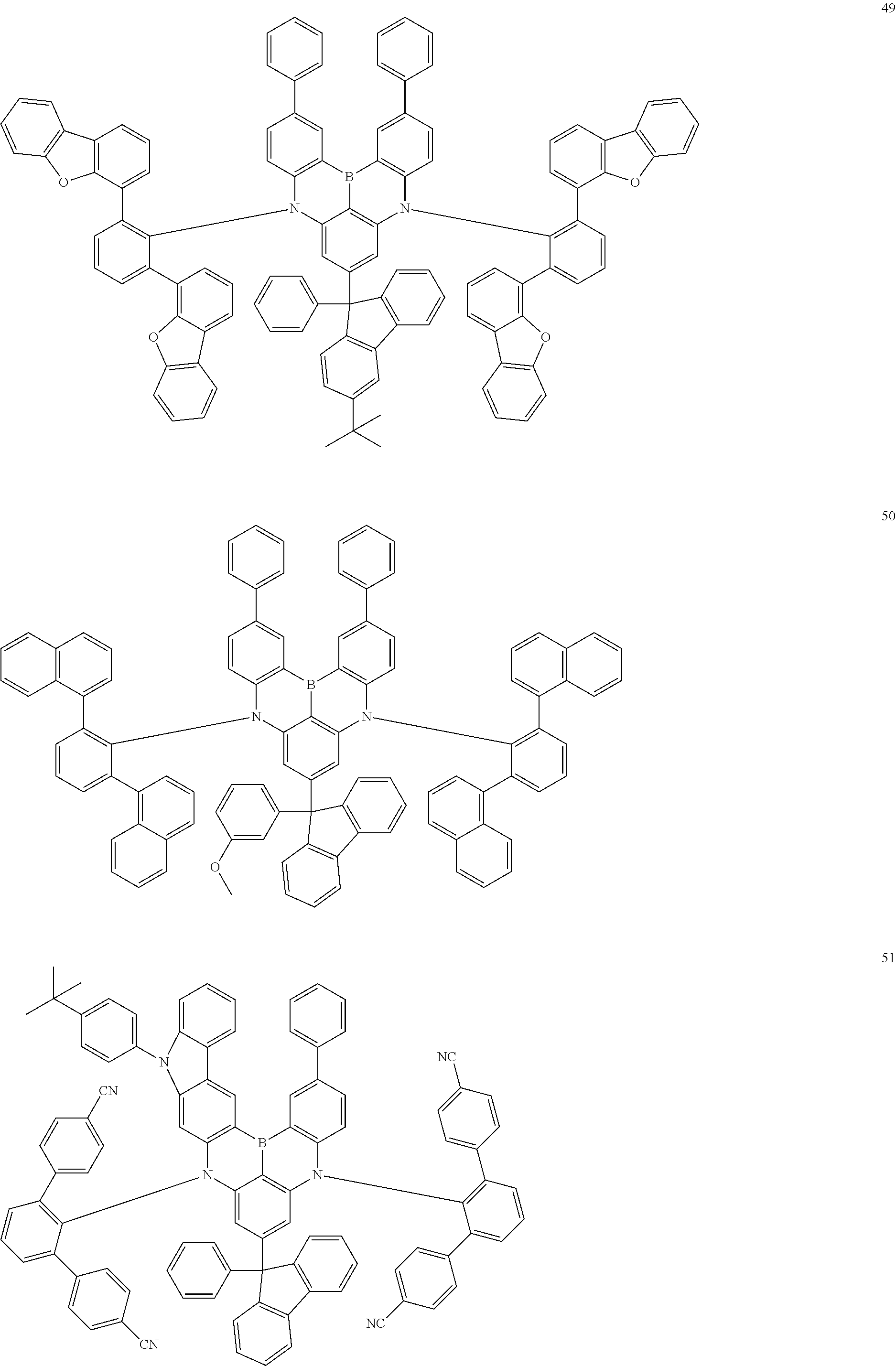

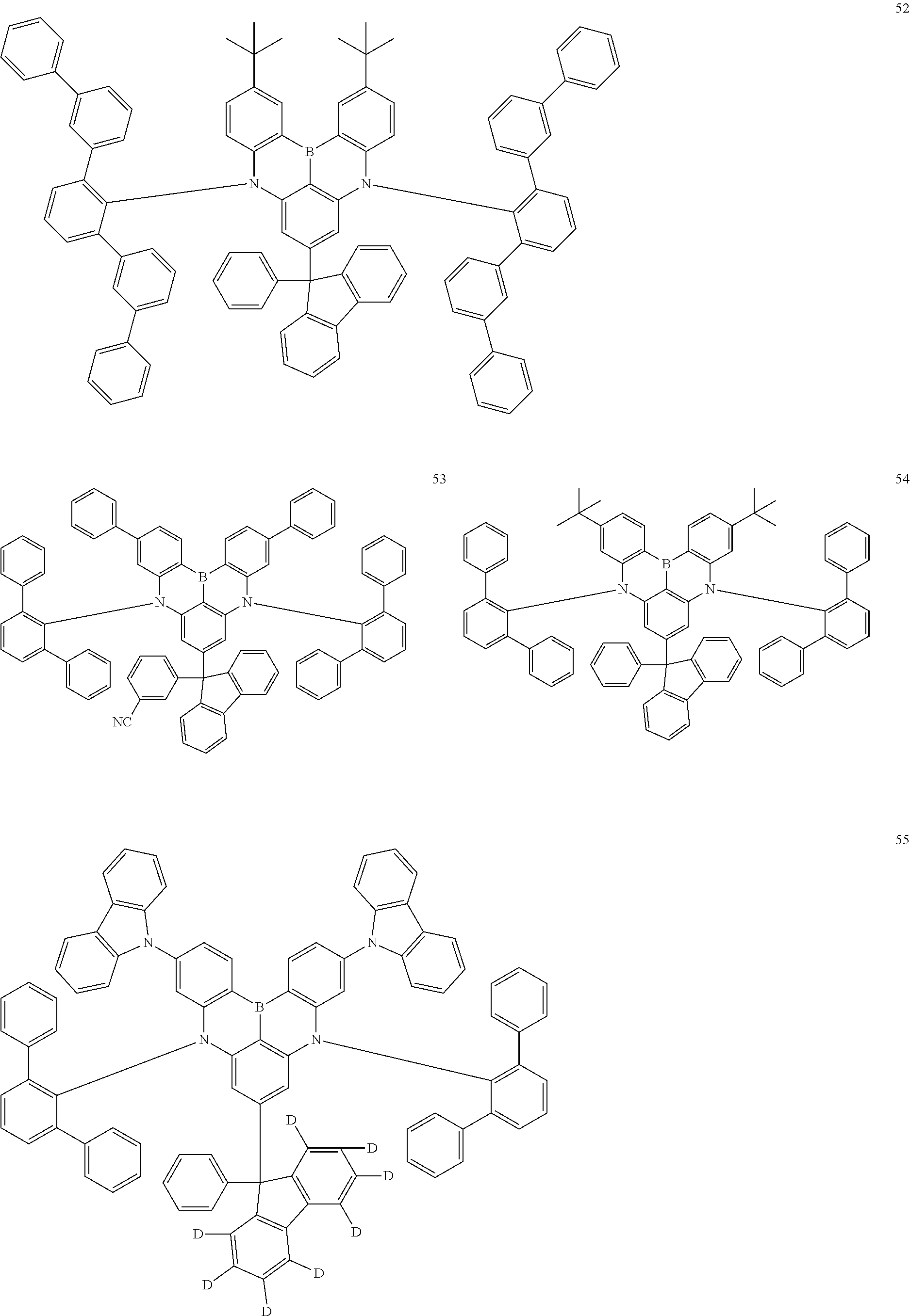

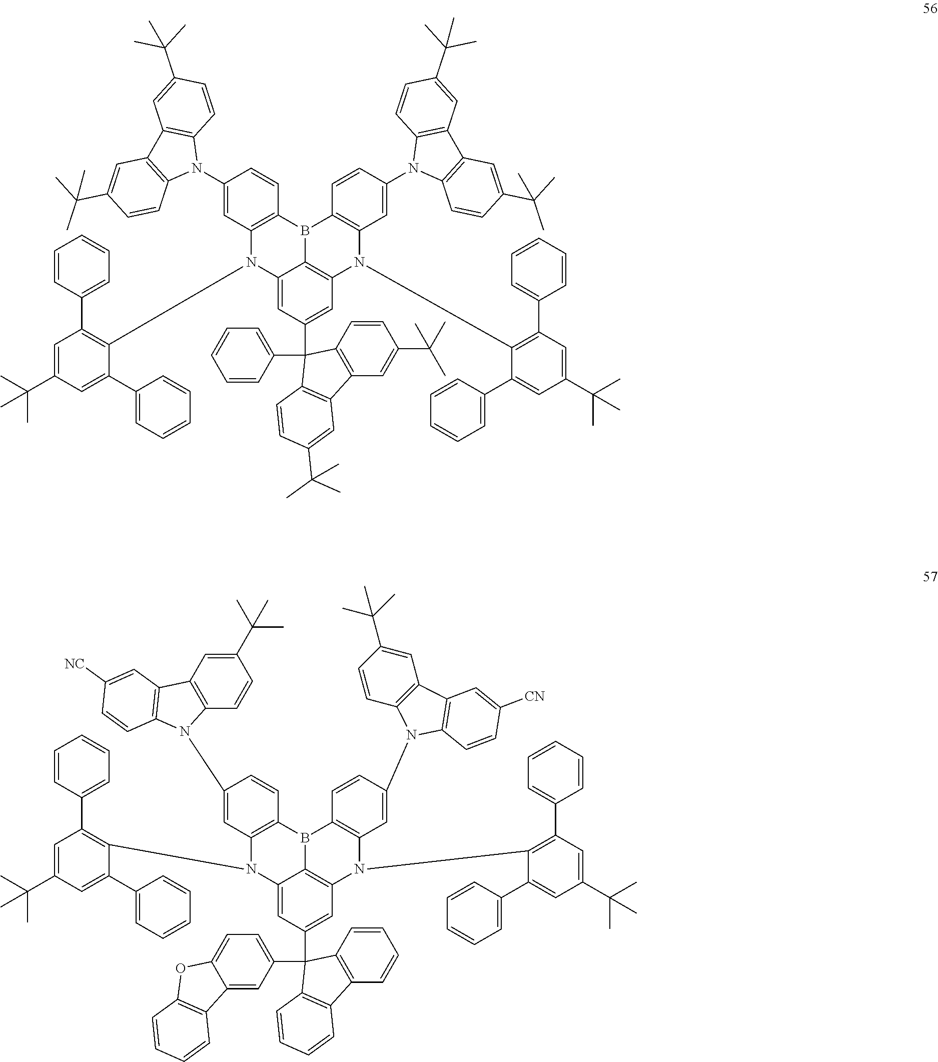

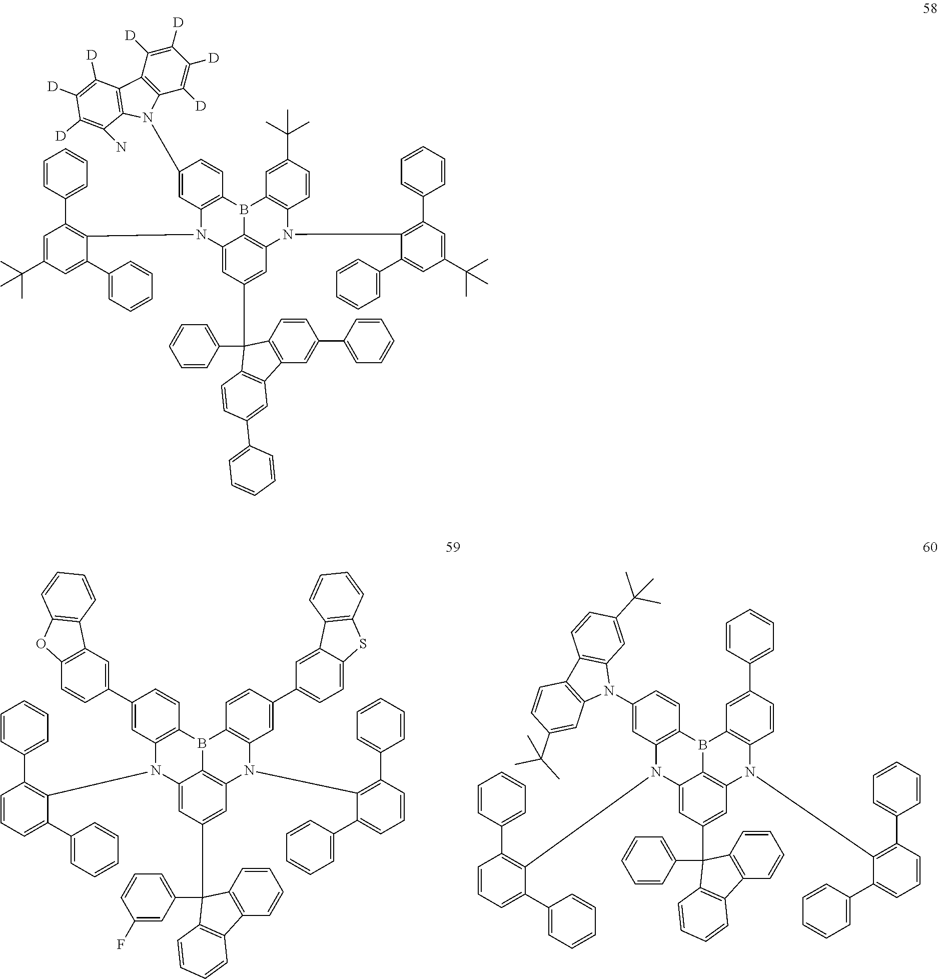

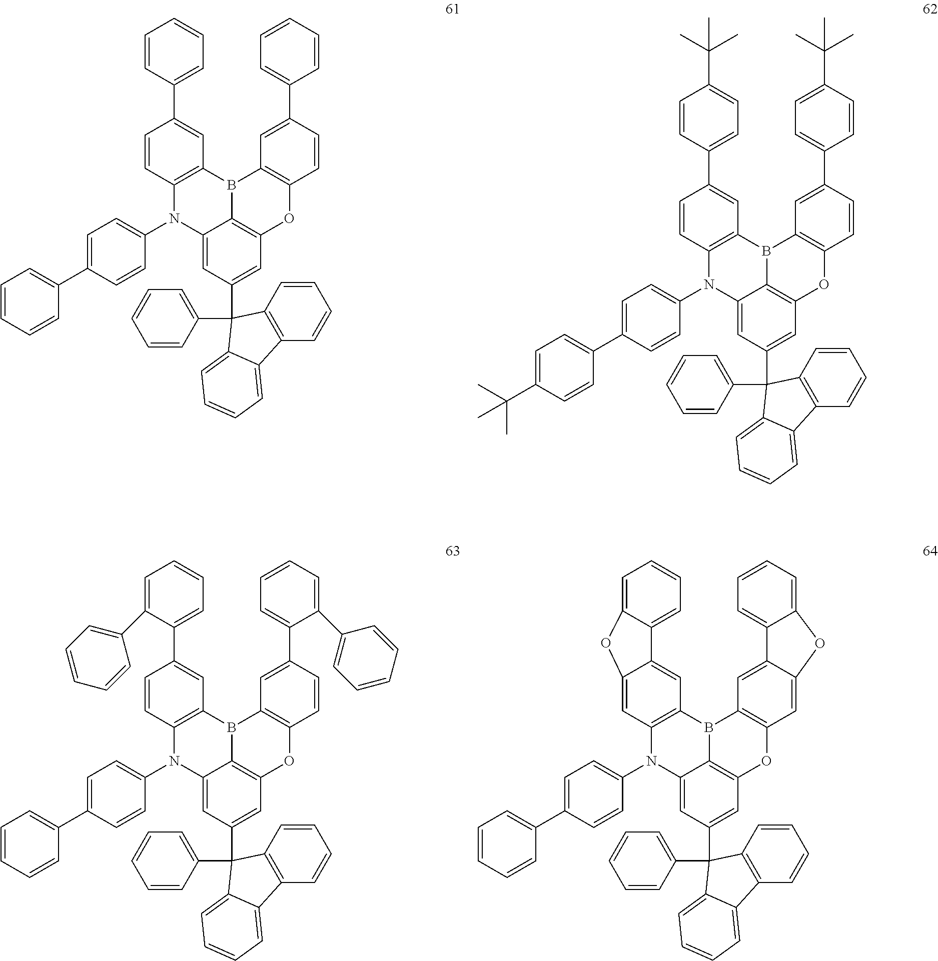 [SMILES: c1ccc(-c2ccc(N3c4ccc(-c5ccccc5)cc4B4c5cc(-c6ccccc6)ccc5Oc5cc(C6(c7ccccc7)c7ccccc7-c7ccccc76)cc3c54)cc2)cc1 ; CC(C)(C)c1ccc(-c2ccc(N3c4ccc(-c5ccc(C(C)(C)C)cc5)cc4B4c5cc(-c6ccc(C(C)(C)C)cc6)ccc5Oc5cc(C6(c7ccccc7)c7ccccc7-c7ccccc76)cc3c54)cc2)cc1 ; c1ccc(-c2ccc(N3c4ccc(-c5ccccc5-c5ccccc5)cc4B4c5cc(-c6ccccc6-c6ccccc6)ccc5Oc5cc(C6(c7ccccc7)c7ccccc7-c7ccccc76)cc3c54)cc2)cc1 ; c1ccc(-c2ccc(N3c4cc5oc6ccccc6c5cc4B4c5cc6c(cc5Oc5cc(C7(c8ccccc8)c8ccccc8-c8ccccc87)cc3c54)oc3ccccc36)cc2)cc1]

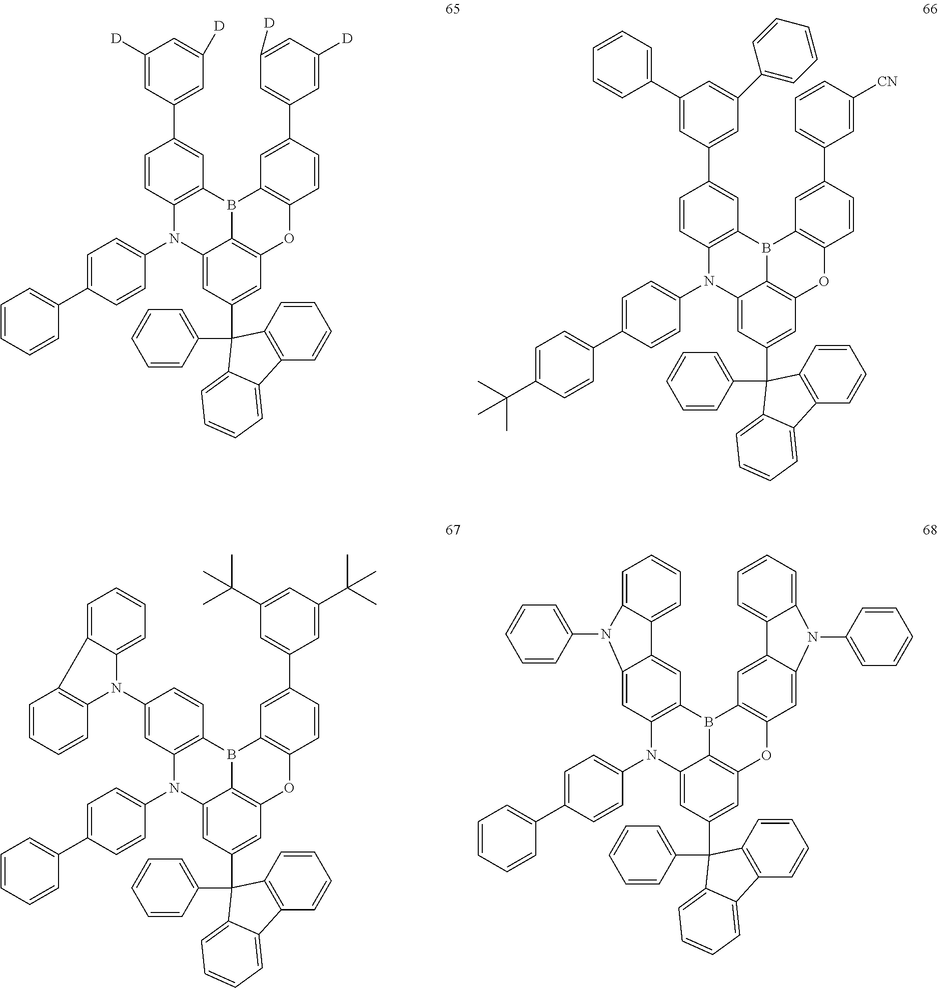

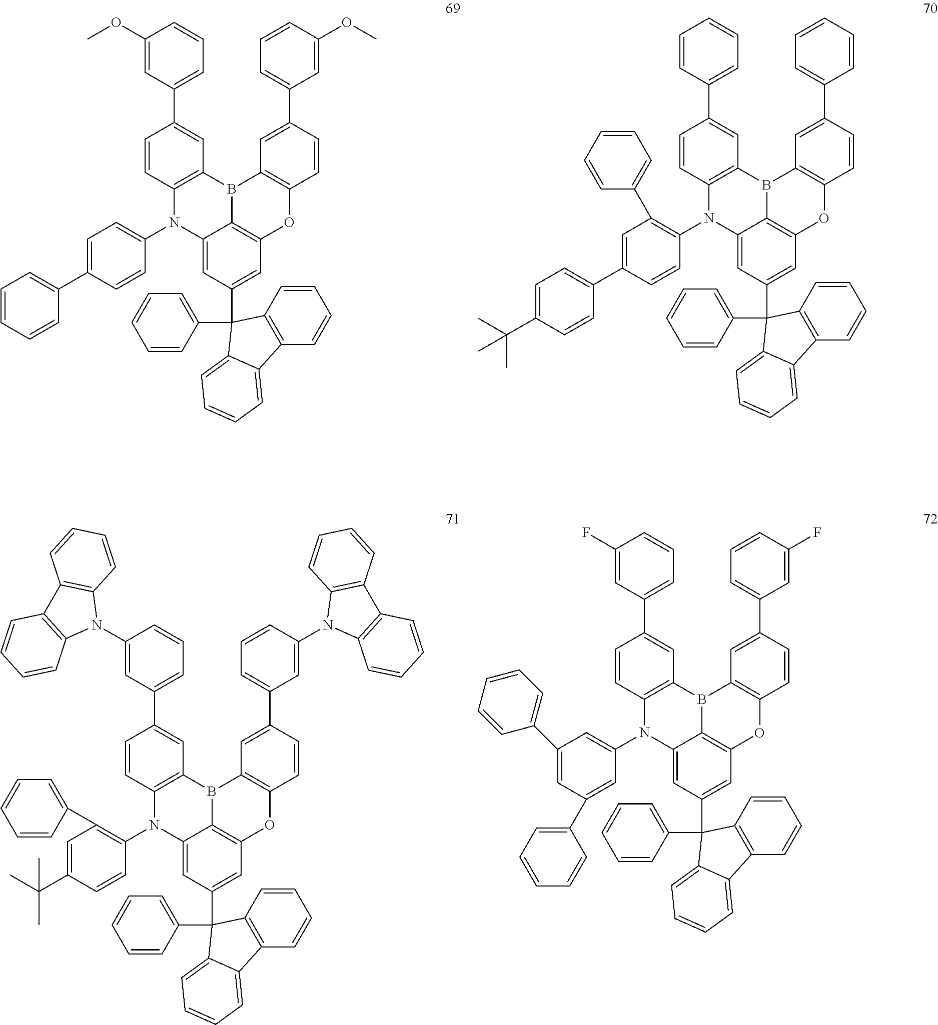

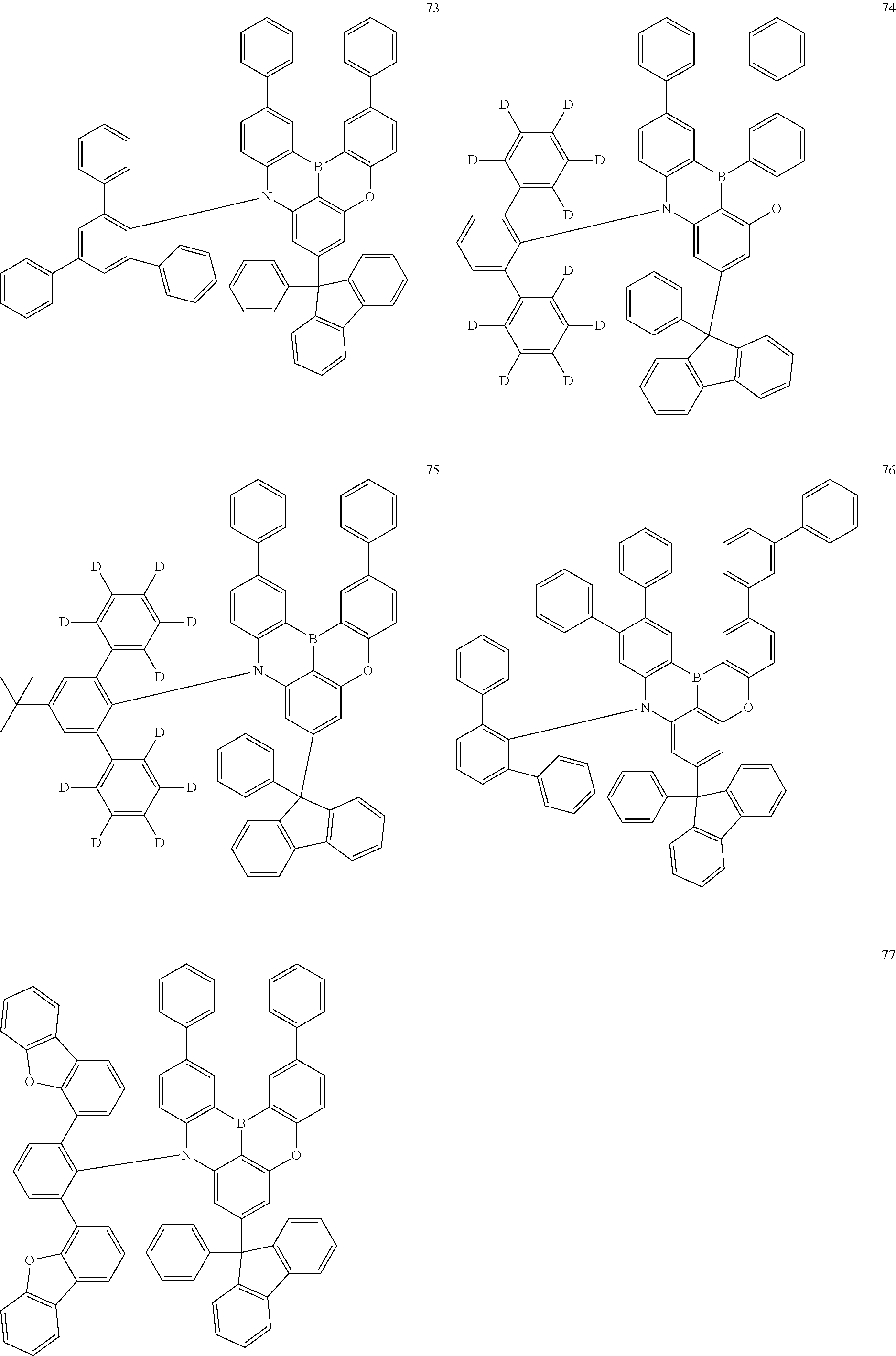

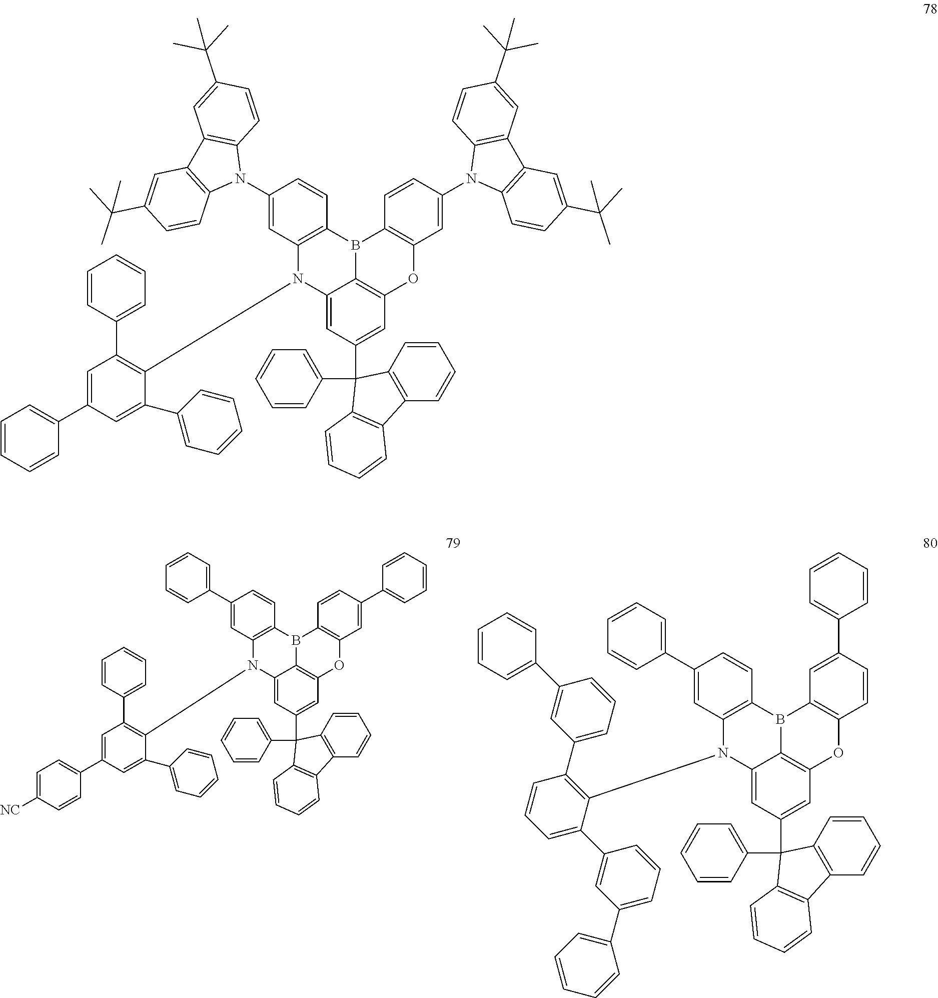 [SMILES: CC(C)(C)c1ccc2c(c1)c1cc(C(C)(C)C)ccc1n2-c1ccc2c(c1)Oc1cc(C3(c4ccccc4)c4ccccc4-c4ccccc43)cc3c1B2c1ccc(-n2c4ccc(C(C)(C)C)cc4c4cc(C(C)(C)C)ccc42)cc1N3c1c(-c2ccccc2)cc(-c2ccccc2)cc1-c1ccccc1 ; N#Cc1ccc(-c2cc(-c3ccccc3)c(N3c4cc(-c5ccccc5)ccc4B4c5ccc(-c6ccccc6)cc5Oc5cc(C6(c7ccccc7)c7ccccc7-c7ccccc76)cc3c54)c(-c3ccccc3)c2)cc1 ; c1ccc(-c2cccc(-c3cccc(-c4cccc(-c5ccccc5)c4)c3N3c4cc(-c5ccccc5)ccc4B4c5cc(-c6ccccc6)ccc5Oc5cc(C6(c7ccccc7)c7ccccc7-c7ccccc76)cc3c54)c2)cc1]

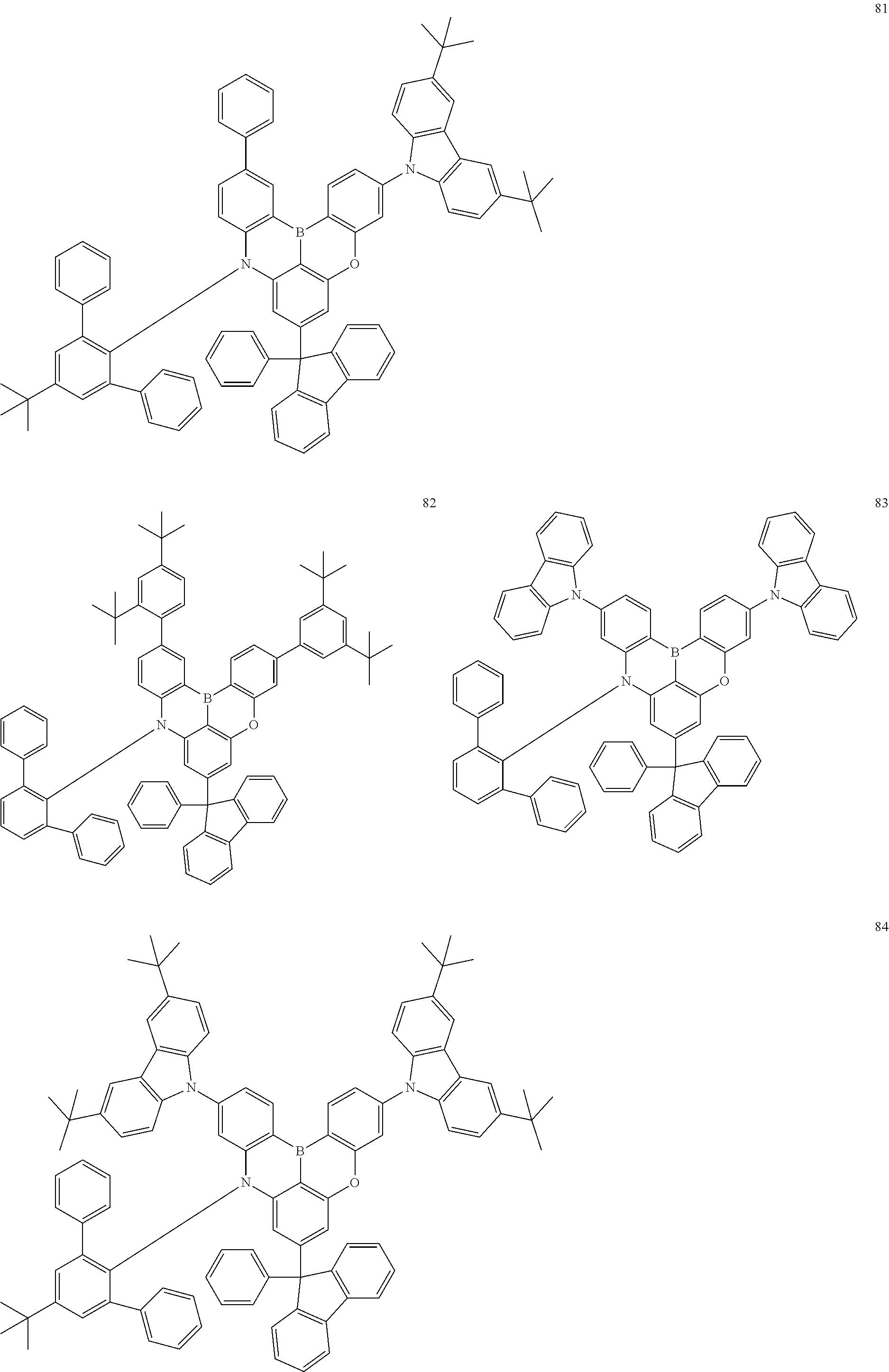

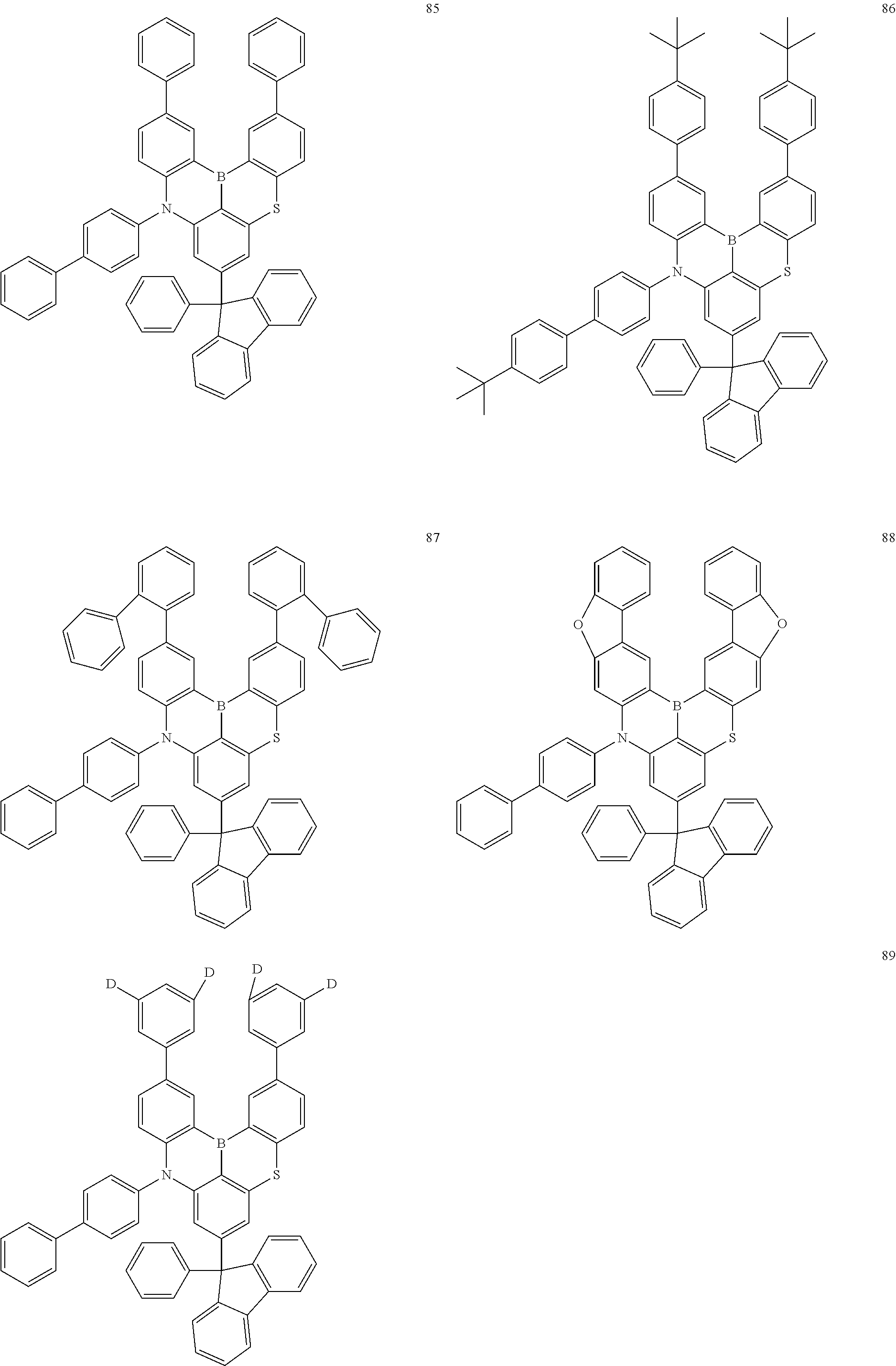

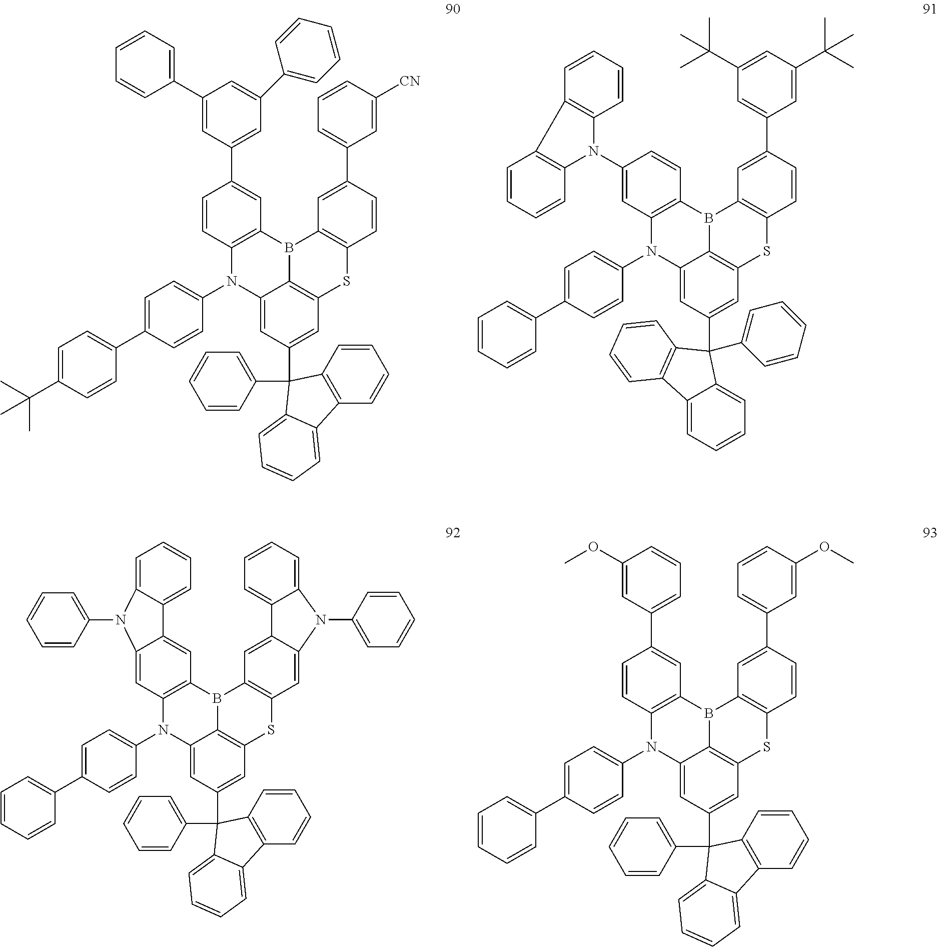

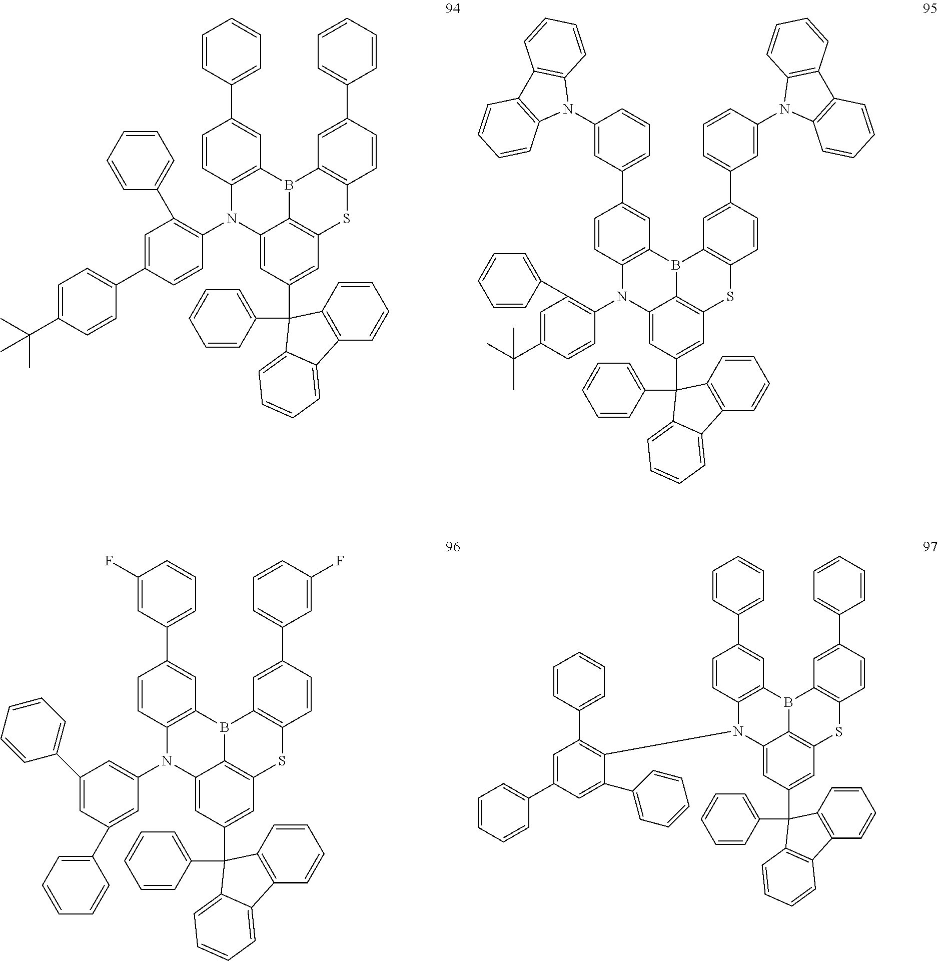

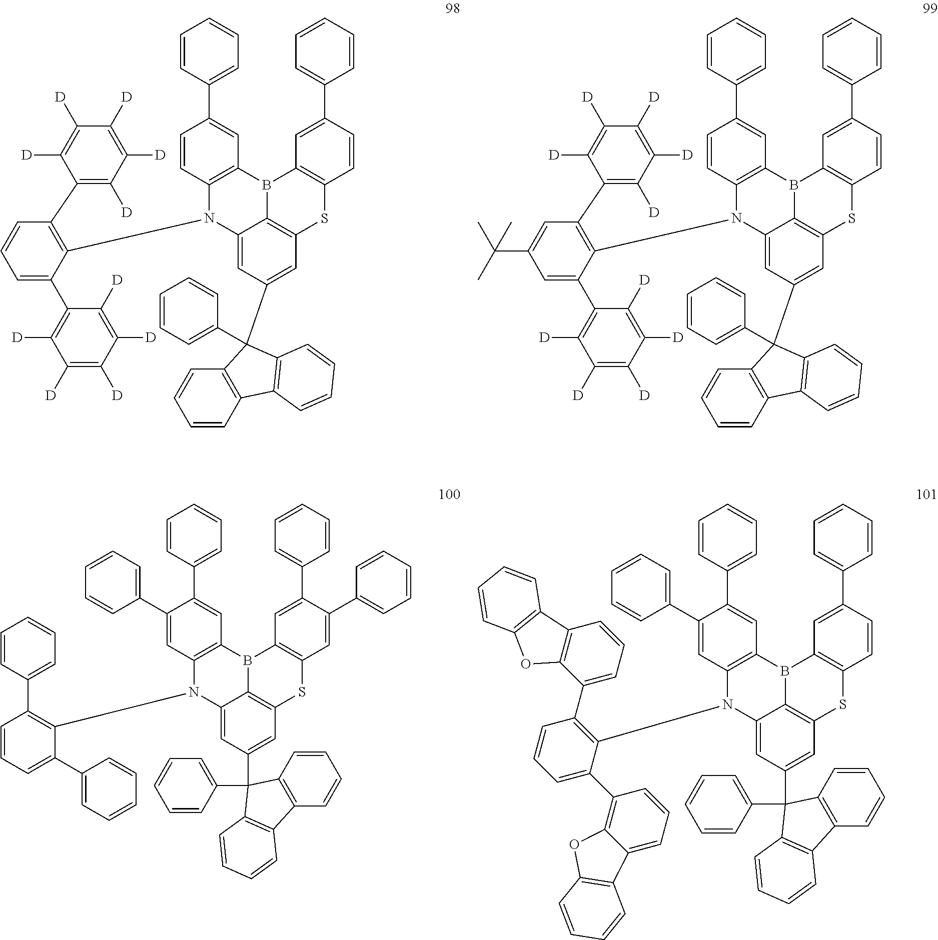

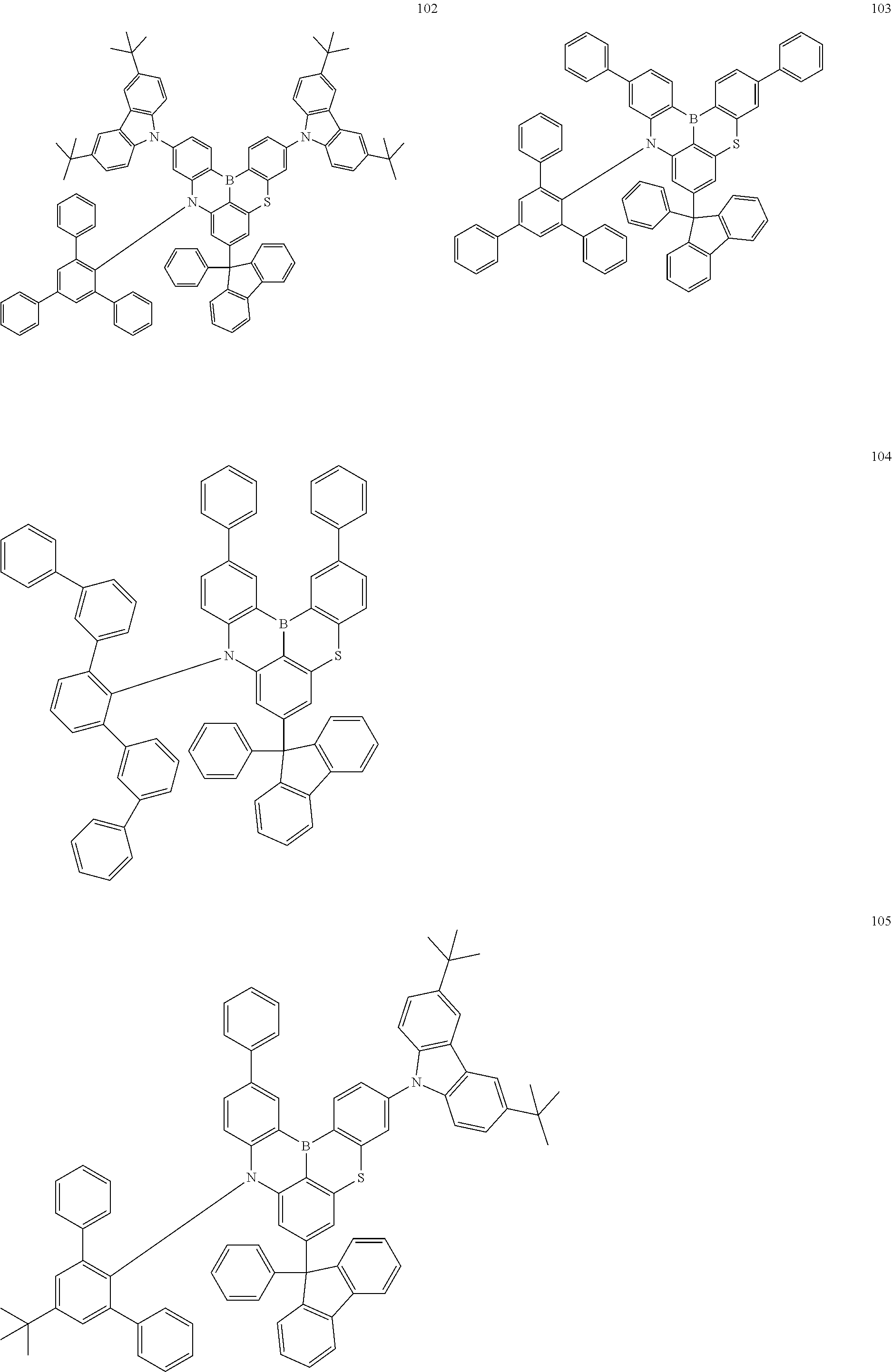

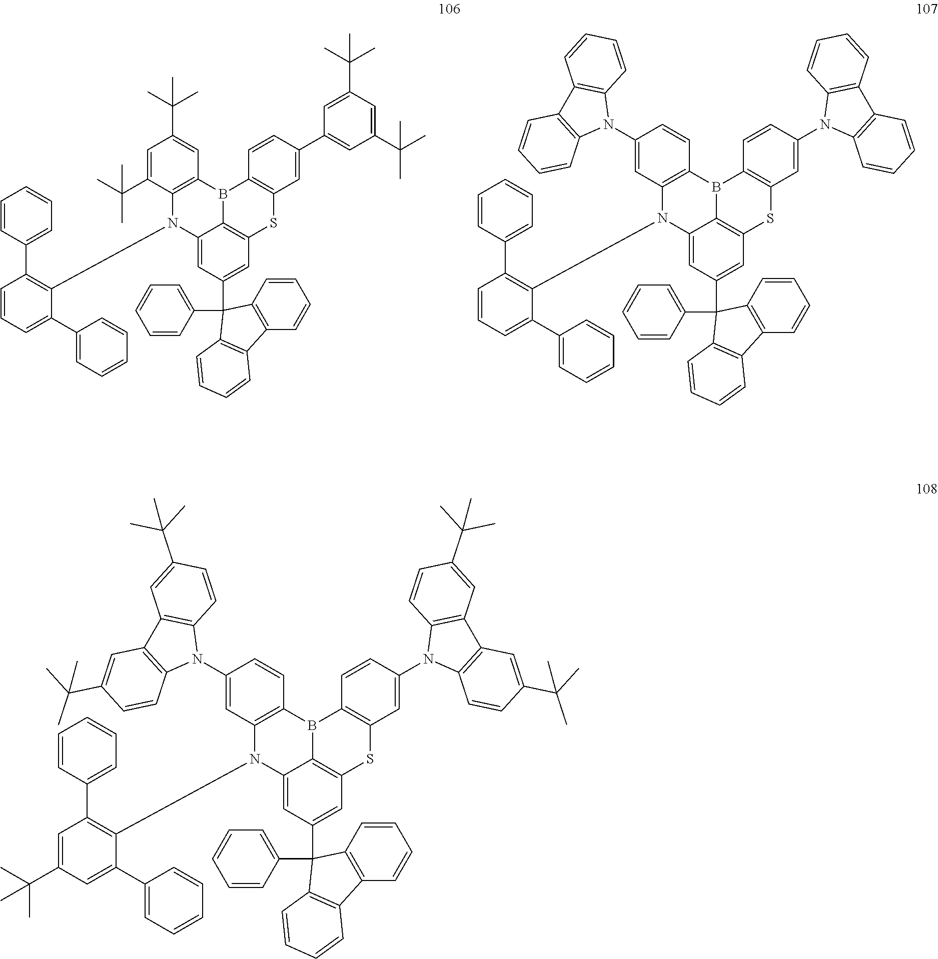 [SMILES: CC(C)(C)c1cc(-c2ccc3c(c2)Sc2cc(C4(c5ccccc5)c5ccccc5-c5ccccc54)cc4c2B3c2cc(C(C)(C)C)cc(C(C)(C)C)c2N4c2c(-c3ccccc3)cccc2-c2ccccc2)cc(C(C)(C)C)c1 ; c1ccc(-c2cccc(-c3ccccc3)c2N2c3cc(-n4c5ccccc5c5ccccc54)ccc3B3c4ccc(-n5c6ccccc6c6ccccc65)cc4Sc4cc(C5(c6ccccc6)c6ccccc6-c6ccccc65)cc2c43)cc1 ; CC(C)(C)c1cc(-c2ccccc2)c(N2c3cc(-n4c5ccc(C(C)(C)C)cc5c5cc(C(C)(C)C)ccc54)ccc3B3c4ccc(-n5c6ccc(C(C)(C)C)cc6c6cc(C(C)(C)C)ccc65)cc4Sc4cc(C5(c6ccccc6)c6ccccc6-c6ccccc65)cc2c43)c(-c2ccccc2)c1]

10. The light emitting device of claim 1, wherein the emission layer further comprises a second compound represented by Formula H-1: 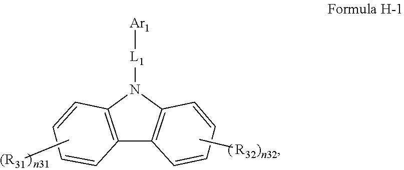
wherein, in Formula H-1
L₁ is a direct linkage, a substituted or unsubstituted arylene group having 6 to 30 ring-forming carbon atoms, or a substituted or unsubstituted heteroarylene group having 2 to 30 ring-forming carbon atoms,
Ar₁ is a substituted or unsubstituted aryl group having 6 to 30 ring-forming carbon atoms, or a substituted or unsubstituted heteroaryl group having 2 to 30 ring-forming carbon atoms,
R₃₁ and R₃₂ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and
n31 and n32 are each independently an integer of 0 to 4.

11. The light emitting device of claim 1, wherein the emission layer further comprises a third compound represented by Formula H-2: 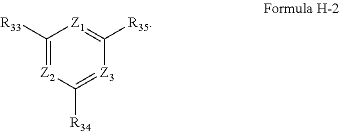
wherein, in Formula H-2,
Z₁ to Z₃ are each independently N or CR₃₆,
at least one selected from among Z₁ to Z₃ is N, and
R₃₃ to R₃₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

12. The light emitting device of claim 1, wherein the emission layer further comprises a fourth compound represented by Formula D-1: 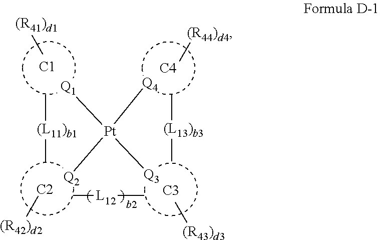
wherein, in Formula D-1,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, 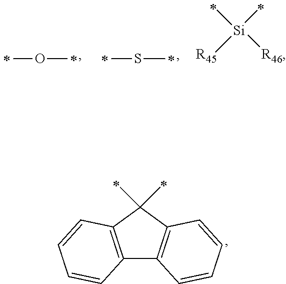
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b1 to b3 are each independently 0 or 1,
R₄₁ to R₄₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and
d1 to d4 are each independently an integer of 0 to 4.

13. A fused polycyclic compound represented by Formula 1: 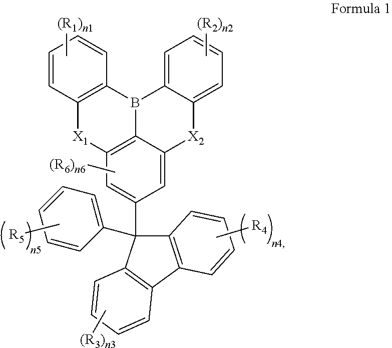
wherein, in Formula 1,
X₁ and X₂ are each independently NR₇, O or S,
R₁ to R₇ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
n1 to n4 are each independently an integer of 0 to 4,
n5 is an integer of 0 to 5, and
n6 is an integer of 0 to 2.

14. The fused polycyclic compound of claim 13, wherein the fused polycyclic compound represented by Formula 1 is represented by any one selected from among Formula 2a to Formula 2c: 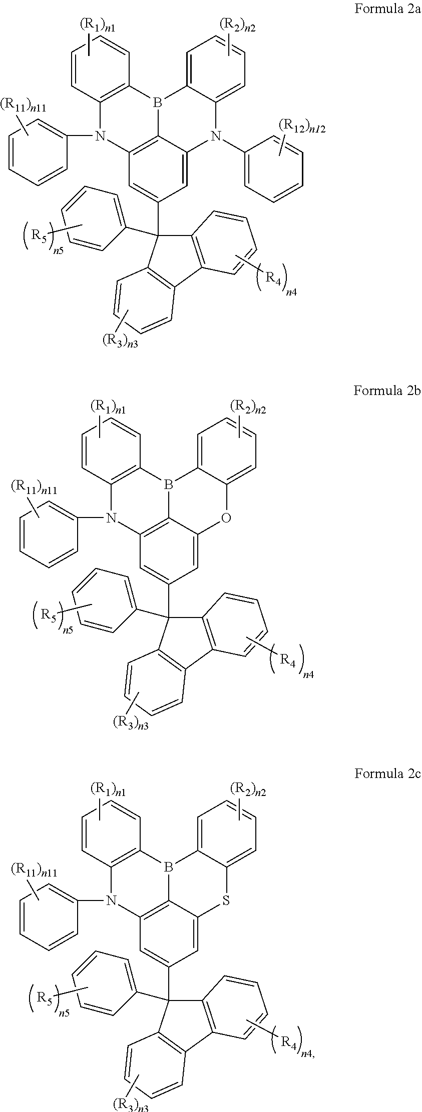
wherein, in Formula 2a to Formula 2c,
R₁₁ and R₁₂ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
n11 and n12 are each independently an integer of 0 to 5, and
R₁ to R₅, and n1 to n5 are the same as respectively defined in Formula 1.

15. The fused polycyclic compound of claim 14, wherein the fused polycyclic compound represented by Formula 2a is represented by any one selected from among Formula 2-1 to Formula 2-5: 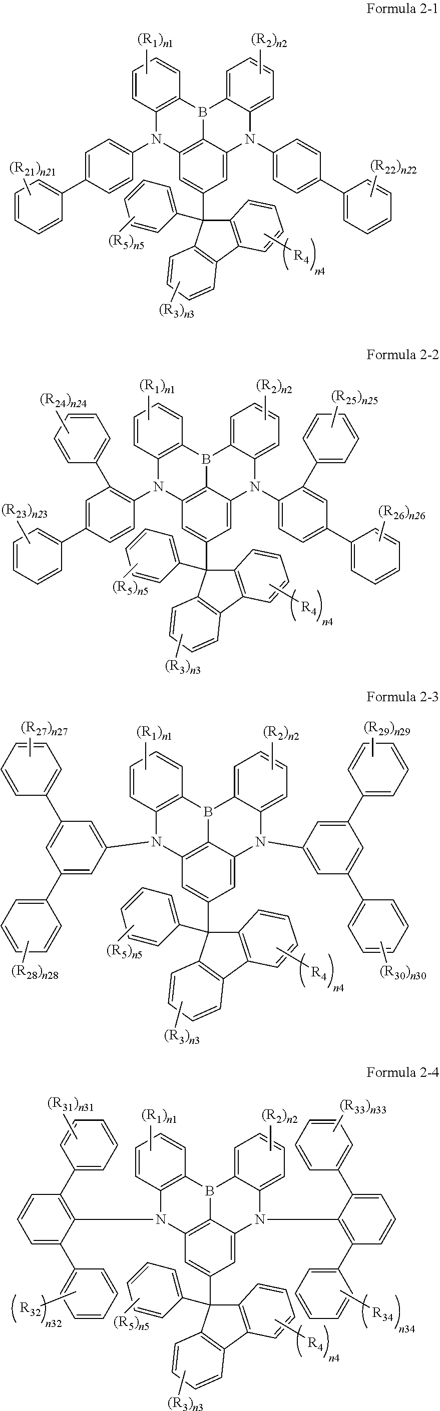 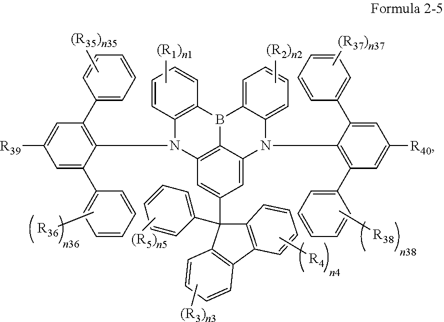
wherein, in Formula 2-1 to Formula 2-5,
R₂₁ to R₃₈ are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
R₃₉ and R₄₀ are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n21 to n38 are each independently an integer of 0 to 5, and
R₁ to R₅, and n1 to n5 are the same as respectively defined in Formula 1.

16. The fused polycyclic compound of claim 15, wherein, in Formula 2-1 to Formula 2-5,
R₂₁ to R₃₈ are each independently a hydrogen atom, a deuterium atom, a cyano group, a substituted or unsubstituted oxy group, a substituted or unsubstituted methyl group, a substituted or unsubstituted vinyl group, a substituted or unsubstituted t-butyl group, or a substituted or unsubstituted phenyl group, and/or bonded to an adjacent group to form a ring, and
R₃₉ and R₄₀ are each independently a deuterium atom, a cyano group, a substituted or unsubstituted methyl group, a substituted or unsubstituted t-butyl, or a substituted or unsubstituted phenyl group.

17. The fused polycyclic compound of claim 13, wherein the fused polycyclic compound represented by Formula 1 is represented by any one selected from among Formula 3-1 to Formula 3-4: 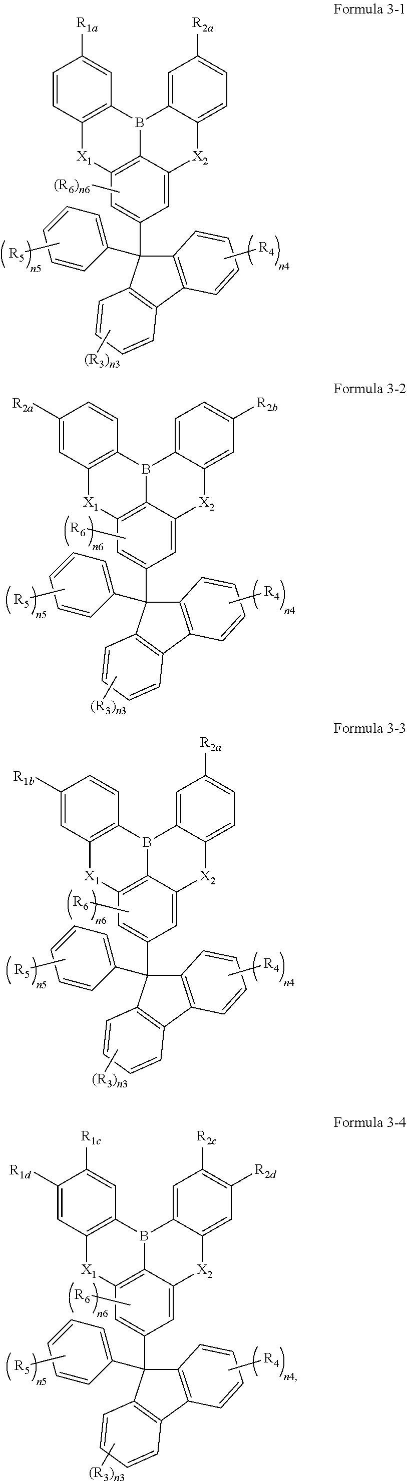
wherein, in Formula 3-1 to Formula 3-4,
R₁ₐ, R_{1b}, R₂ₐ, and R_{2b} are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{1c}, R_{1d}, R_{2c}, and R_{2d} are each independently a hydrogen atom, a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring, and
X₁, X₂, R₃ to R₆, and n3 to n6 are the same as respectively defined in Formula 1.

18. The fused polycyclic compound of claim 13, wherein the fused polycyclic compound represented by Formula 1 is represented by any one selected from among Formula 4-1 to Formula 4-5: 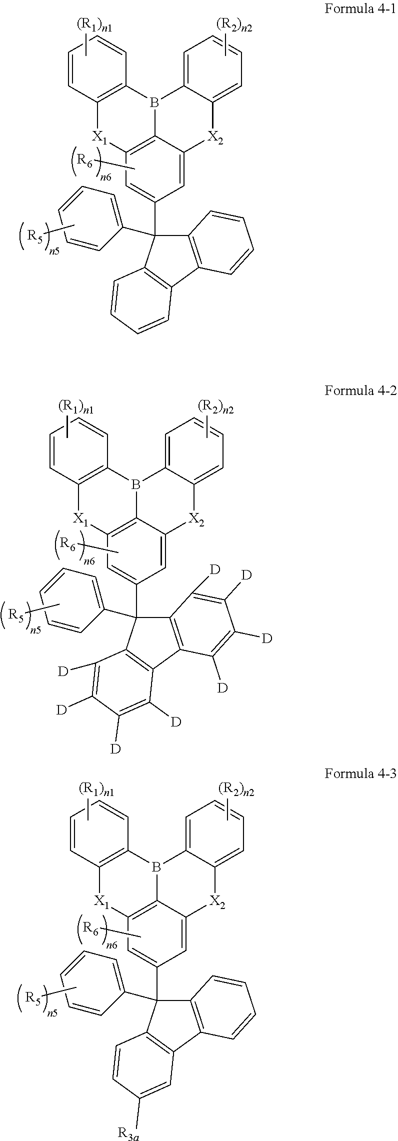 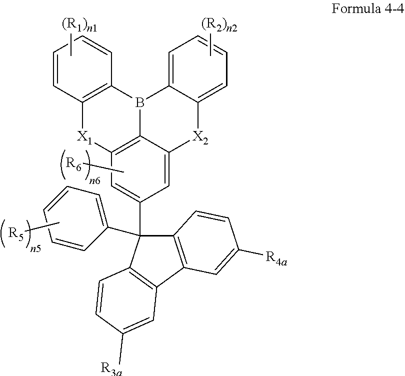
wherein, in Formula 4-1 to Formula 4-5,
R₃ₐ, R₄ₐ, and R_{4b} are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
D represents a deuterium atom, and
X₁, X₂, R₁, R₂, R₅, R₆, n1, n2, n5, and n6 are the same as respectively defined in Formula 1.

19. The fused polycyclic compound of claim 13, wherein the fused polycyclic compound represented by Formula 1 is represented by any one selected from among Formula 5-1 to Formula 5-6: 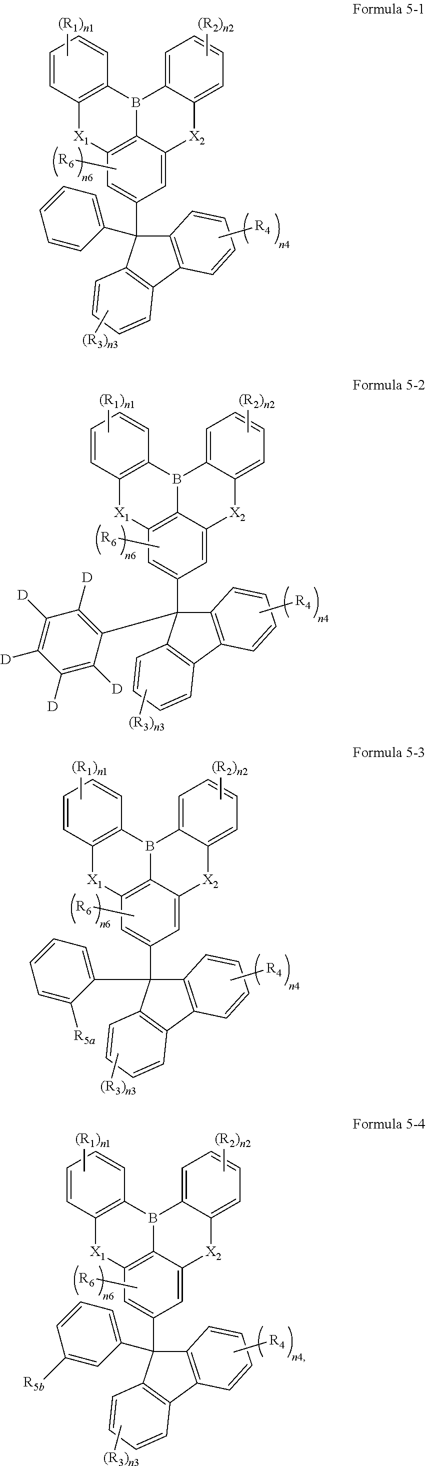 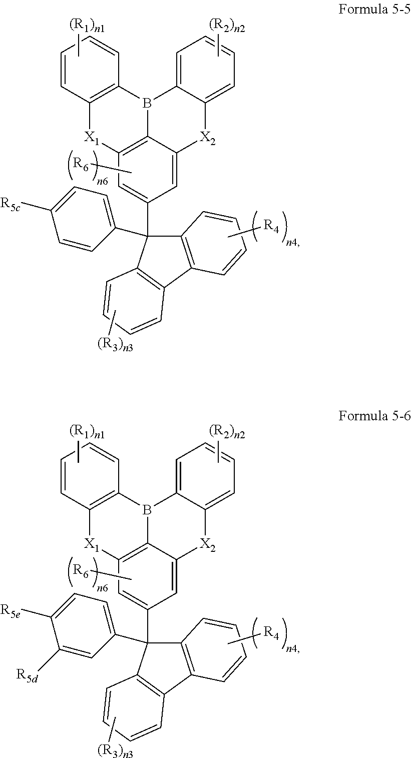
wherein, in Formula 5-1 to Formula 5-6,
R₅ₐ, R_{5b}, and R_{5c} are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R_{5d} and R₅ₑ are each independently a deuterium atom, a halogen atom, a cyano group, a substituted or unsubstituted silyl group, a substituted or unsubstituted amine group, a substituted or unsubstituted oxy group, a substituted or unsubstituted alkyl group having 1 to 20 carbon atoms, a substituted or unsubstituted alkenyl group having 2 to 30 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring,
D represents a deuterium atom, and
X₁, X₂, R₁ to R₄, R₆, n1 to n4, and n6 are the same as respectively defined in Formula 1.

20. The fused polycyclic compound of claim 13, wherein the fused polycyclic compound represented by Formula 1 comprises at least one selected from among compounds represented by Compound Group 1: 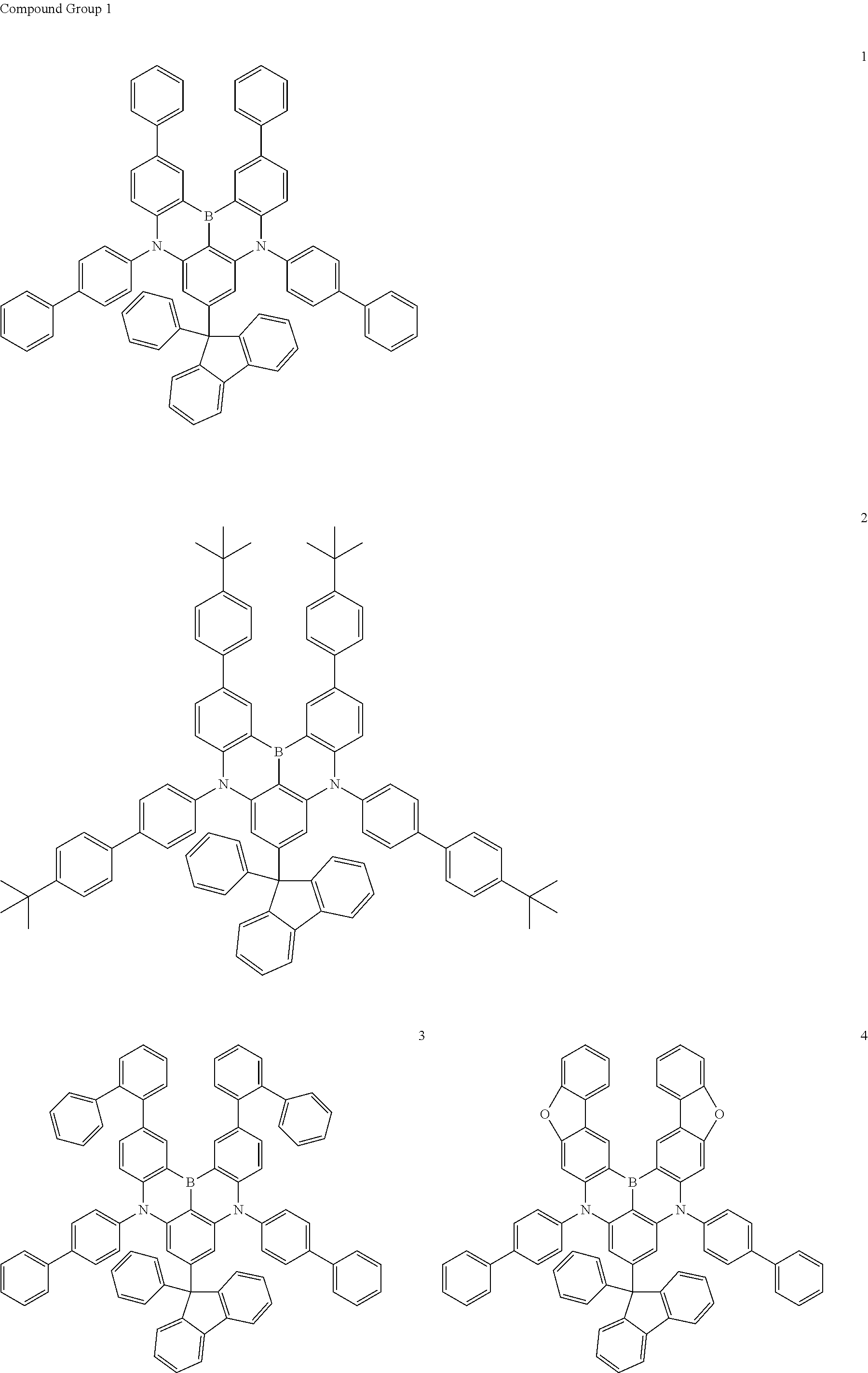 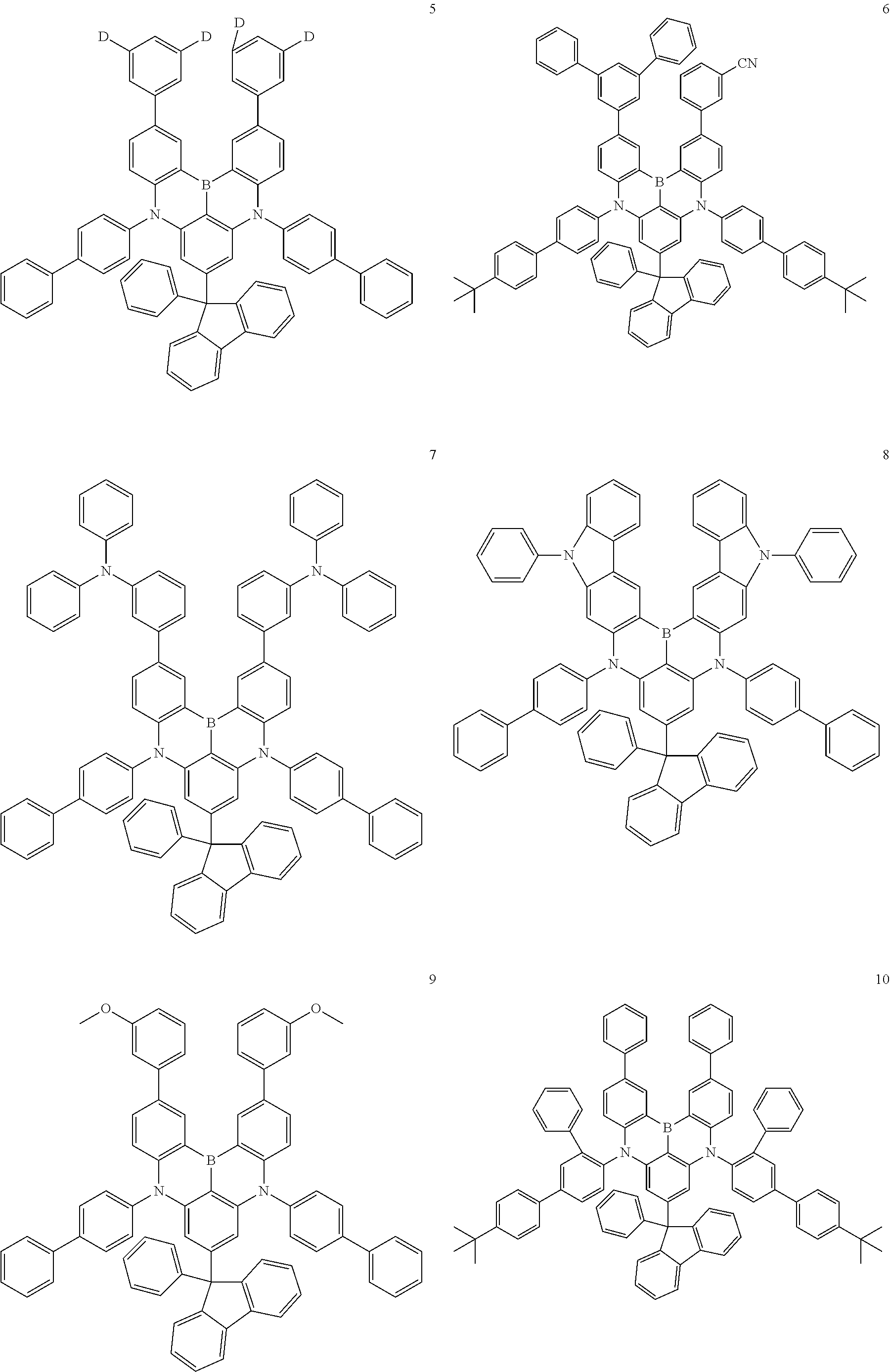 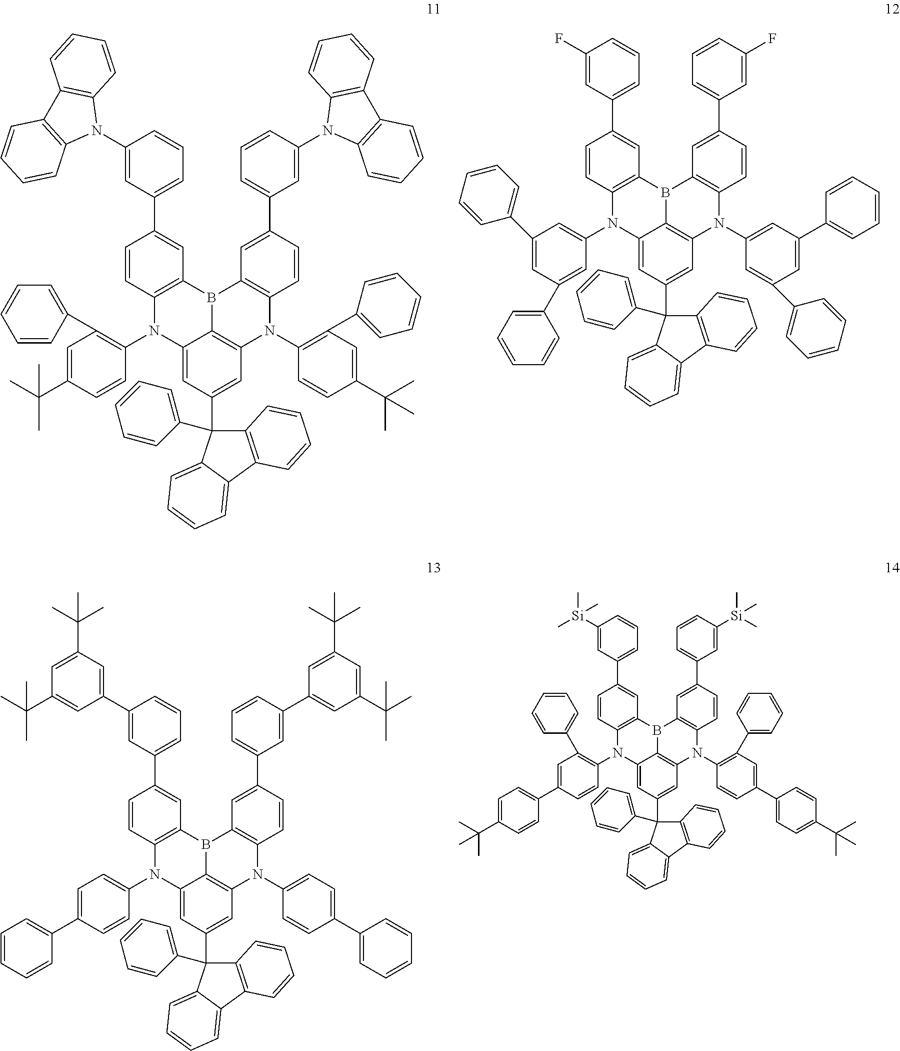 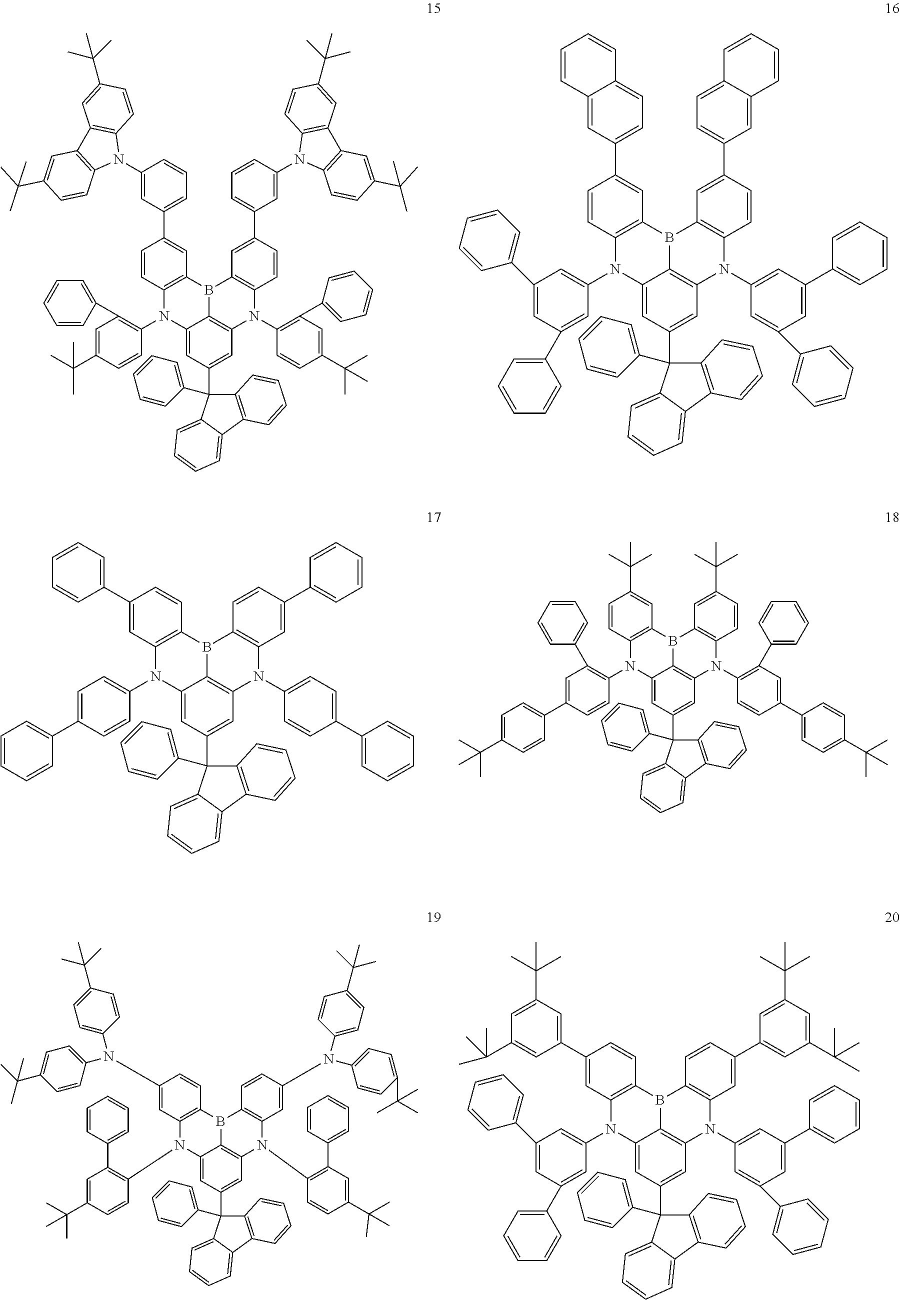 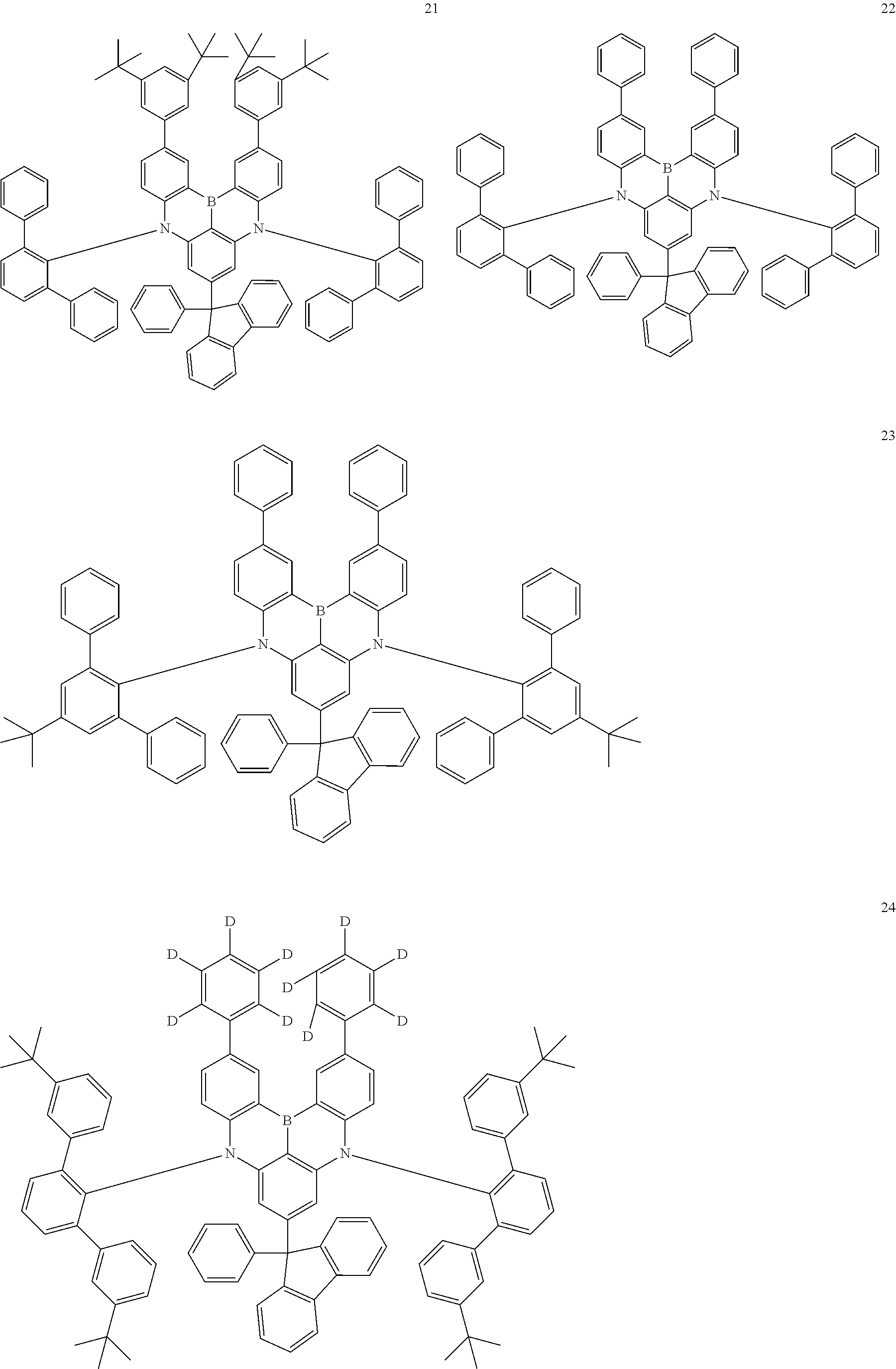 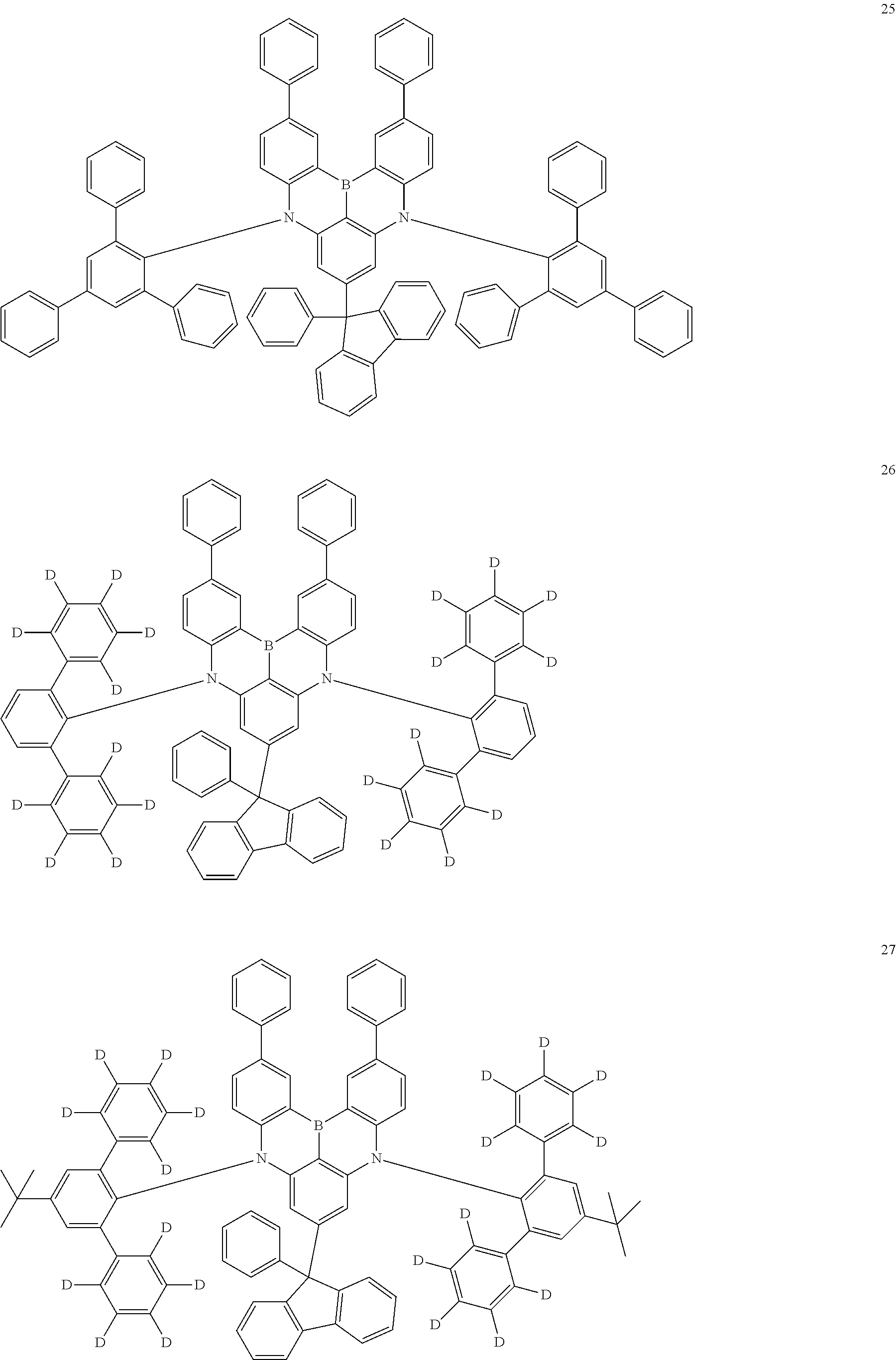 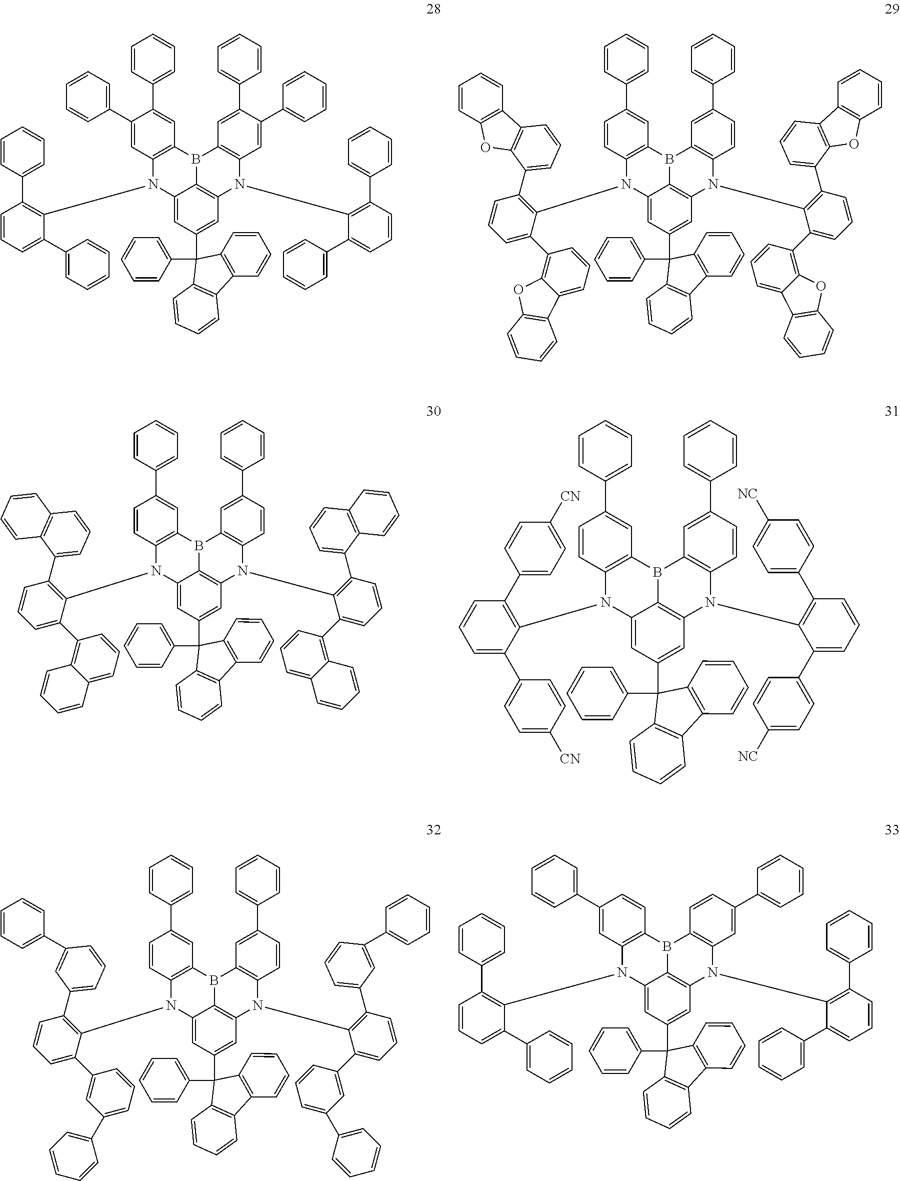 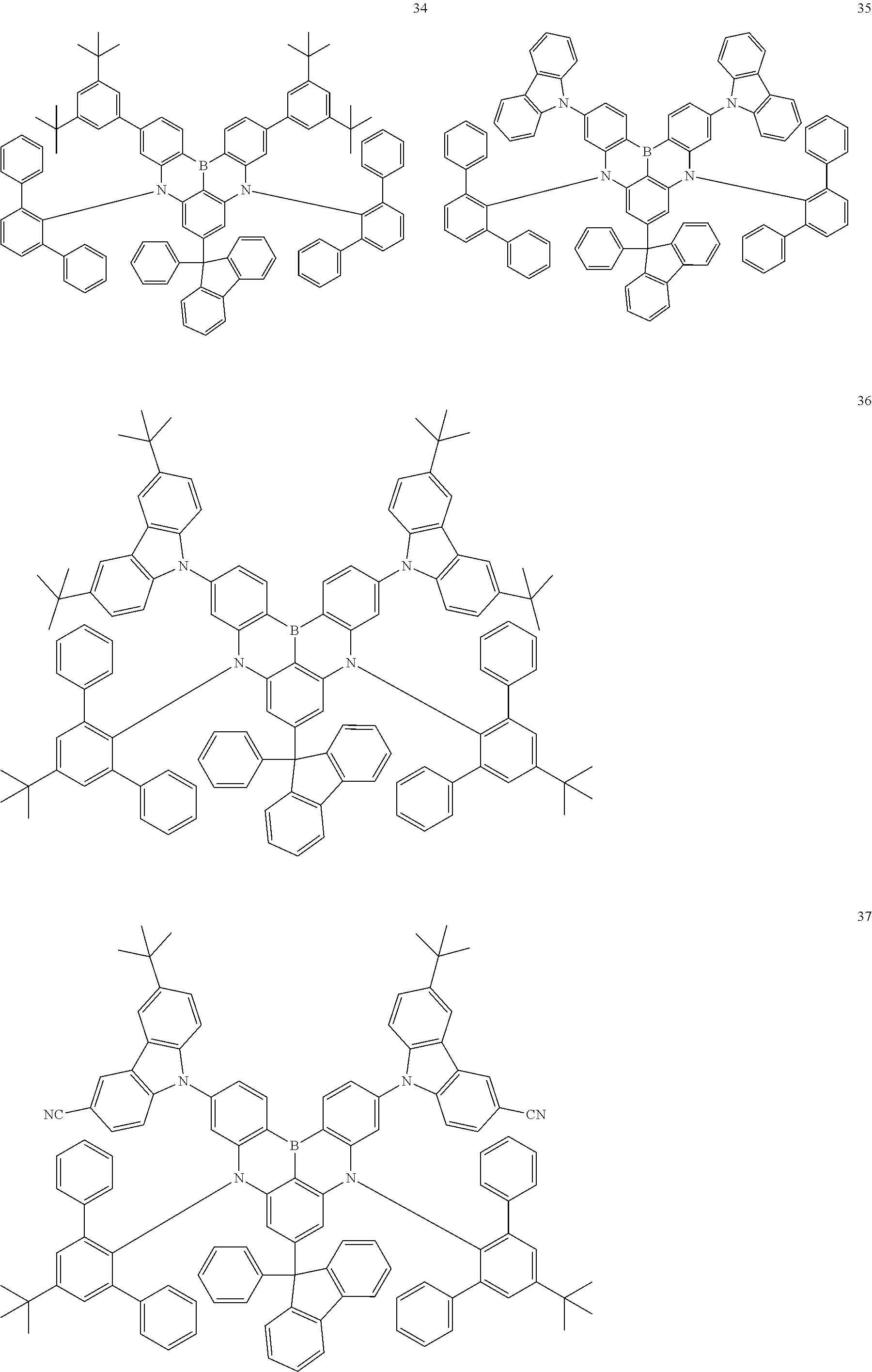 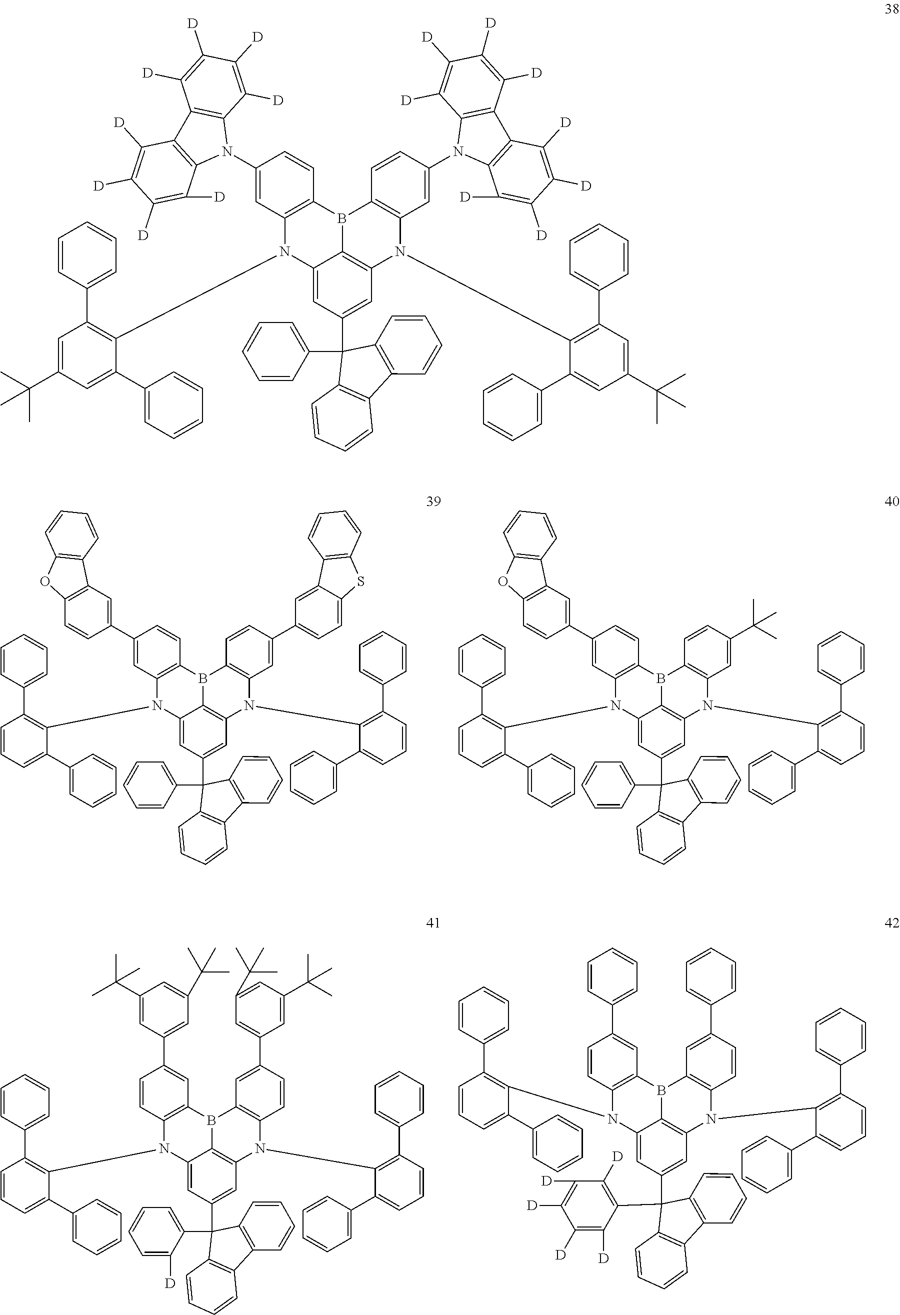 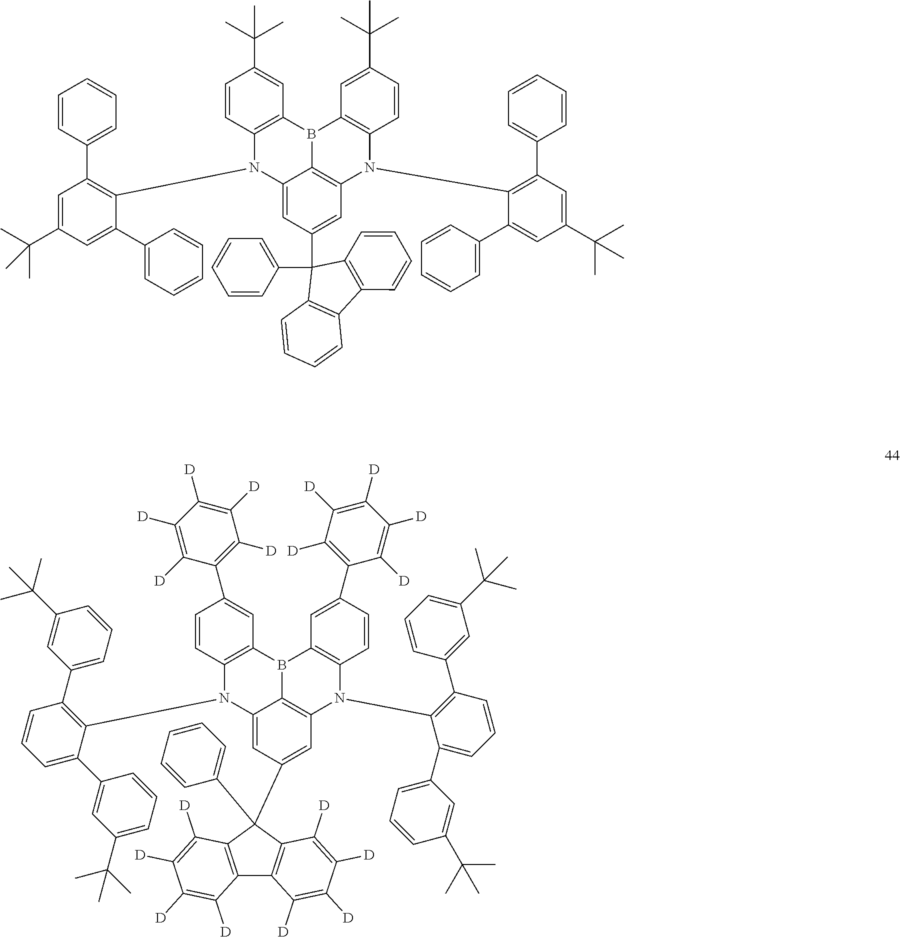 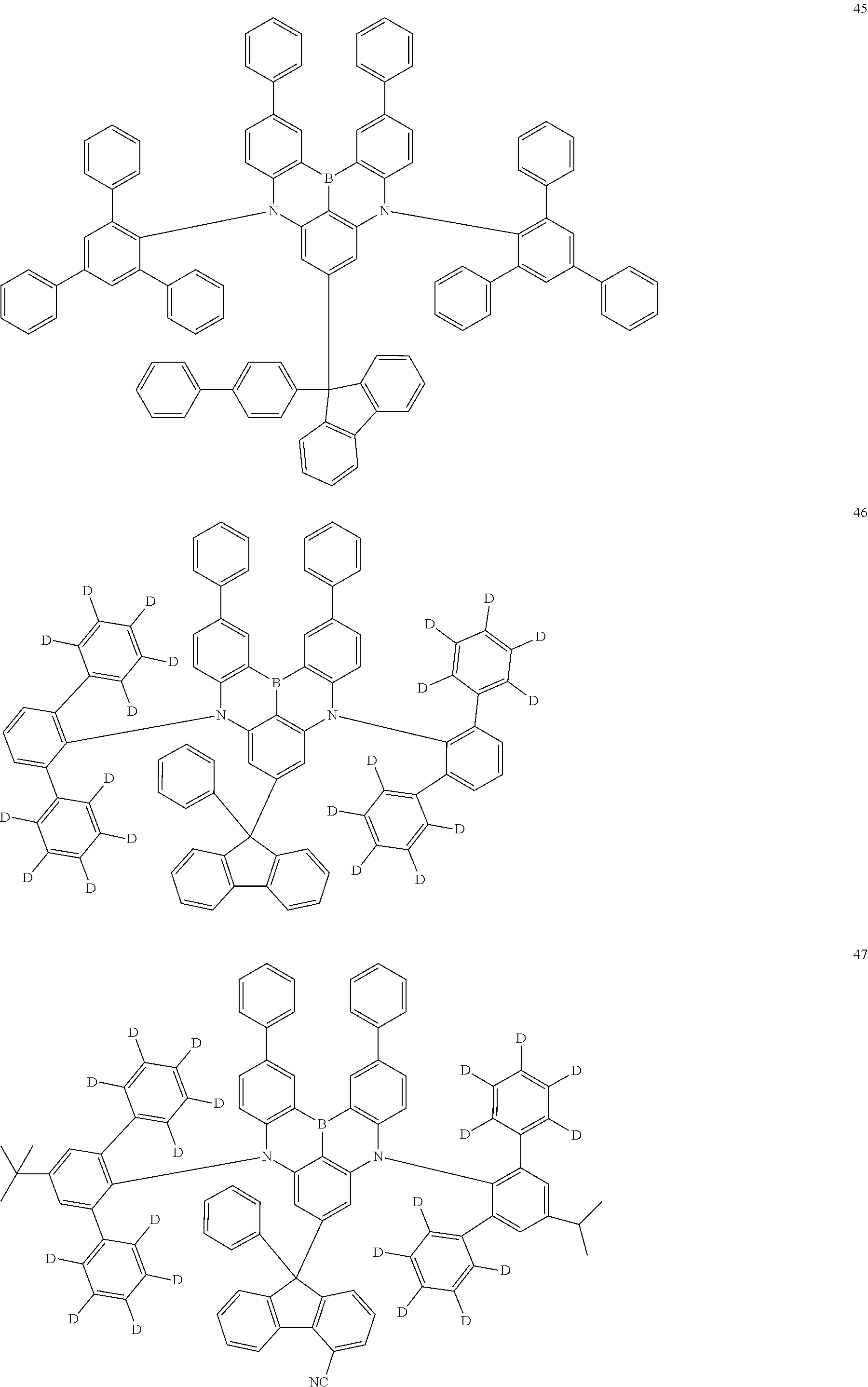 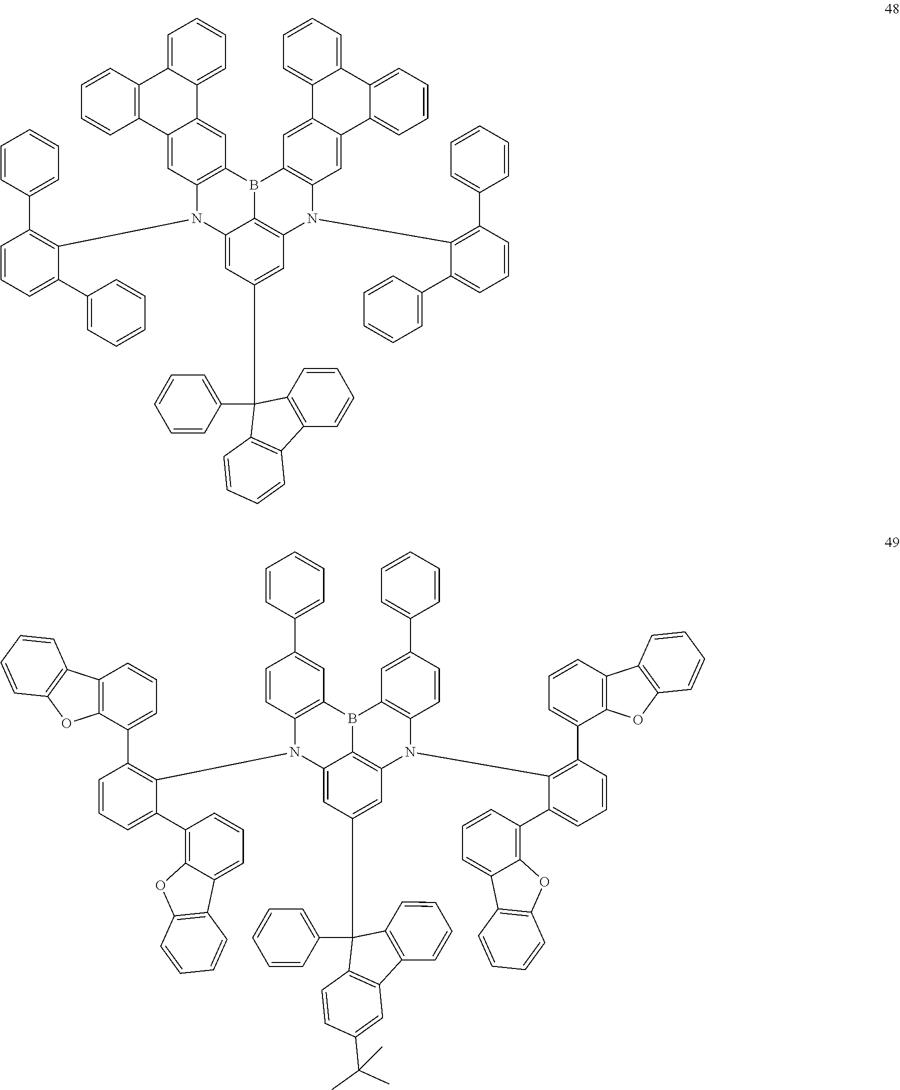 [SMILES: c1ccc(-c2cccc(-c3ccccc3)c2N2c3cc4c5ccccc5c5ccccc5c4cc3B3c4cc5c6ccccc6c6ccccc6c5cc4N(c4c(-c5ccccc5)cccc4-c4ccccc4)c4cc(C5(c6ccccc6)c6ccccc6-c6ccccc65)cc2c43)cc1 ; CC(C)(C)c1ccc2c(c1)-c1ccccc1C2(c1ccccc1)c1cc2c3c(c1)N(c1c(-c4cccc5c4oc4ccccc45)cccc1-c1cccc4c1oc1ccccc14)c1ccc(-c4ccccc4)cc1B3c1cc(-c3ccccc3)ccc1N2c1c(-c2cccc3c2oc2ccccc23)cccc1-c1cccc2c1oc1ccccc12] 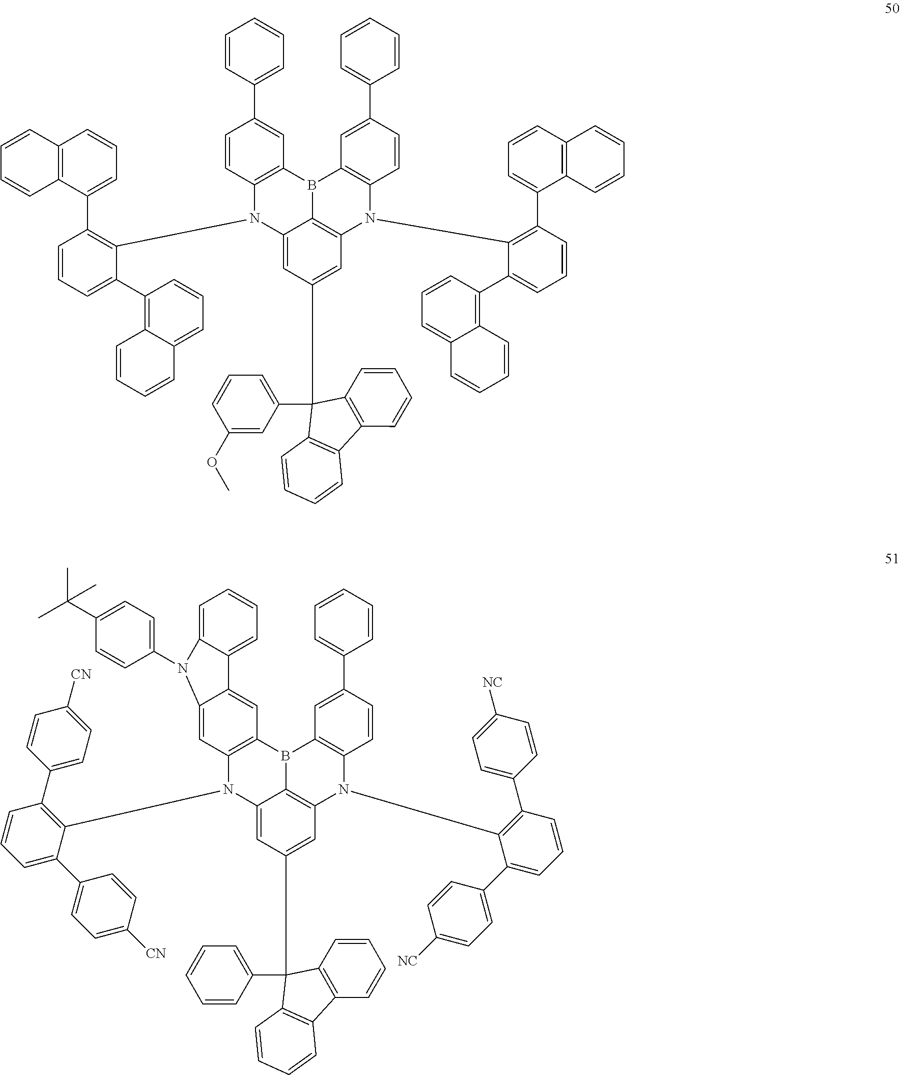 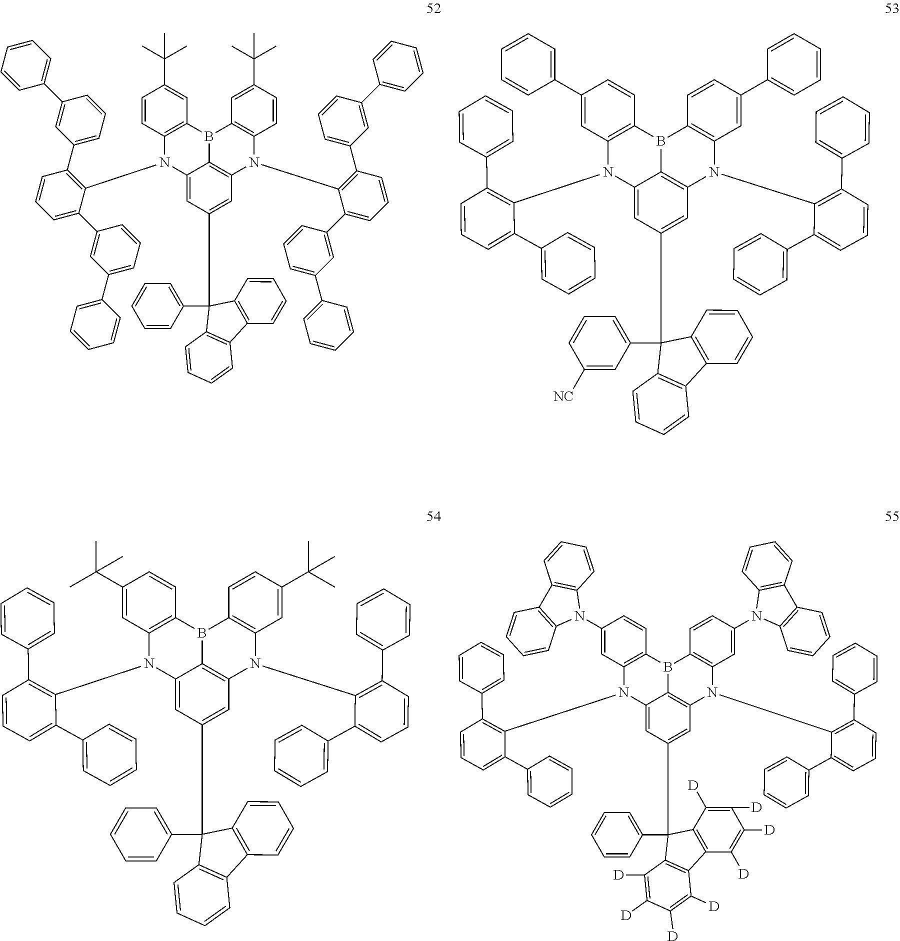 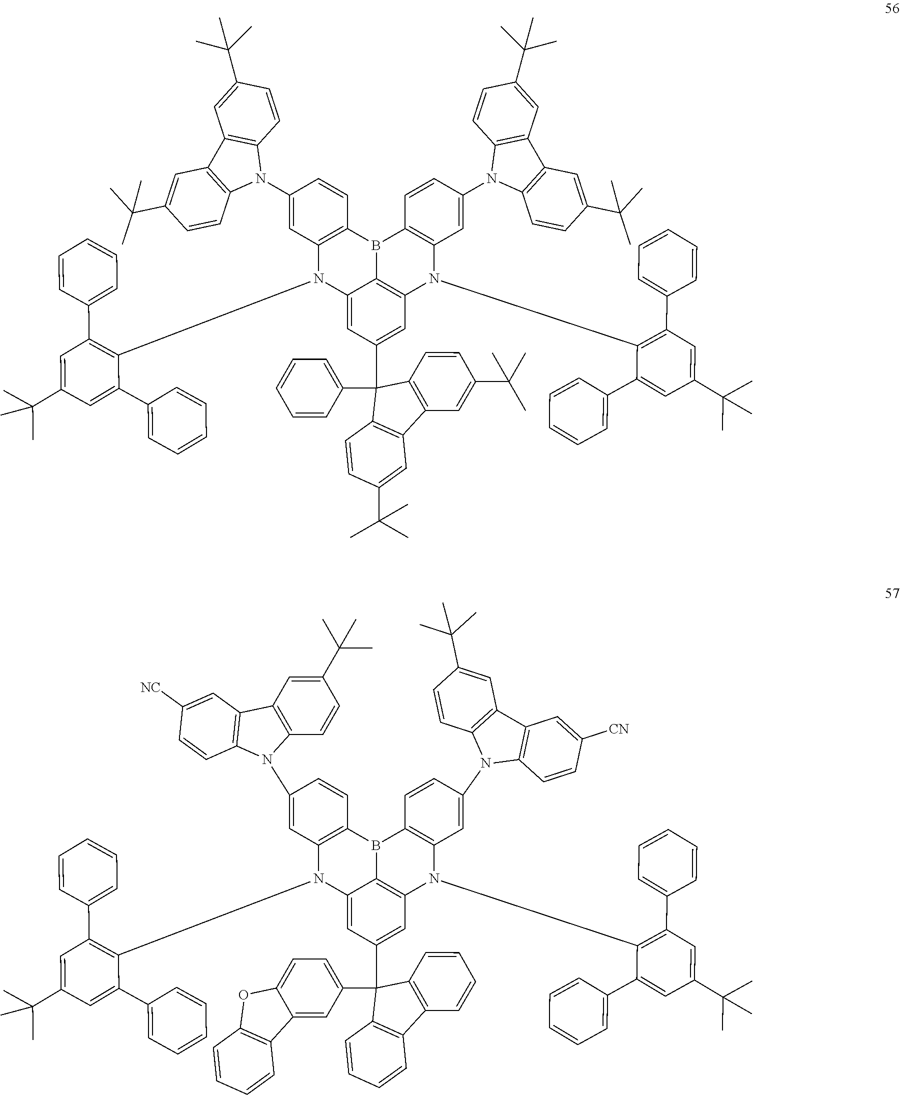 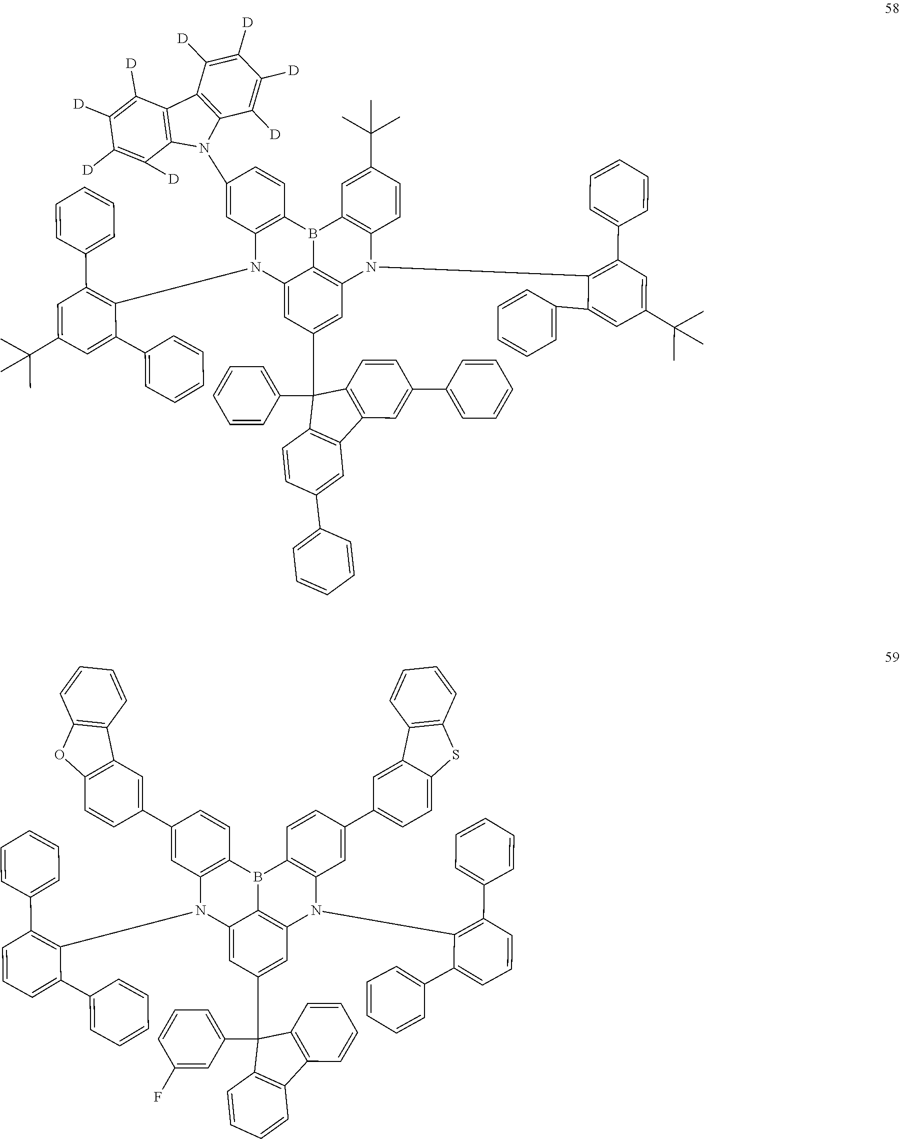 [SMILES: [2H]c1c([2H])c([2H])c2c(c1[2H])c1c([2H])c([2H])c([2H])c([2H])c1n2-c1ccc2c(c1)N(c1c(-c3ccccc3)cc(C(C)(C)C)cc1-c1ccccc1)c1cc(C3(c4ccccc4)c4ccc(-c5ccccc5)cc4-c4cc(-c5ccccc5)ccc43)cc3c1B2c1cc(C(C)(C)C)ccc1N3c1c(-c2ccccc2)cc(C(C)(C)C)cc1-c1ccccc1 ; Fc1cccc(C2(c3cc4c5c(c3)N(c3c(-c6ccccc6)cccc3-c3ccccc3)c3cc(-c6ccc7sc8ccccc8c7c6)ccc3B5c3ccc(-c5ccc6oc7ccccc7c6c5)cc3N4c3c(-c4ccccc4)cccc3-c3ccccc3)c3ccccc3-c3ccccc32)c1] 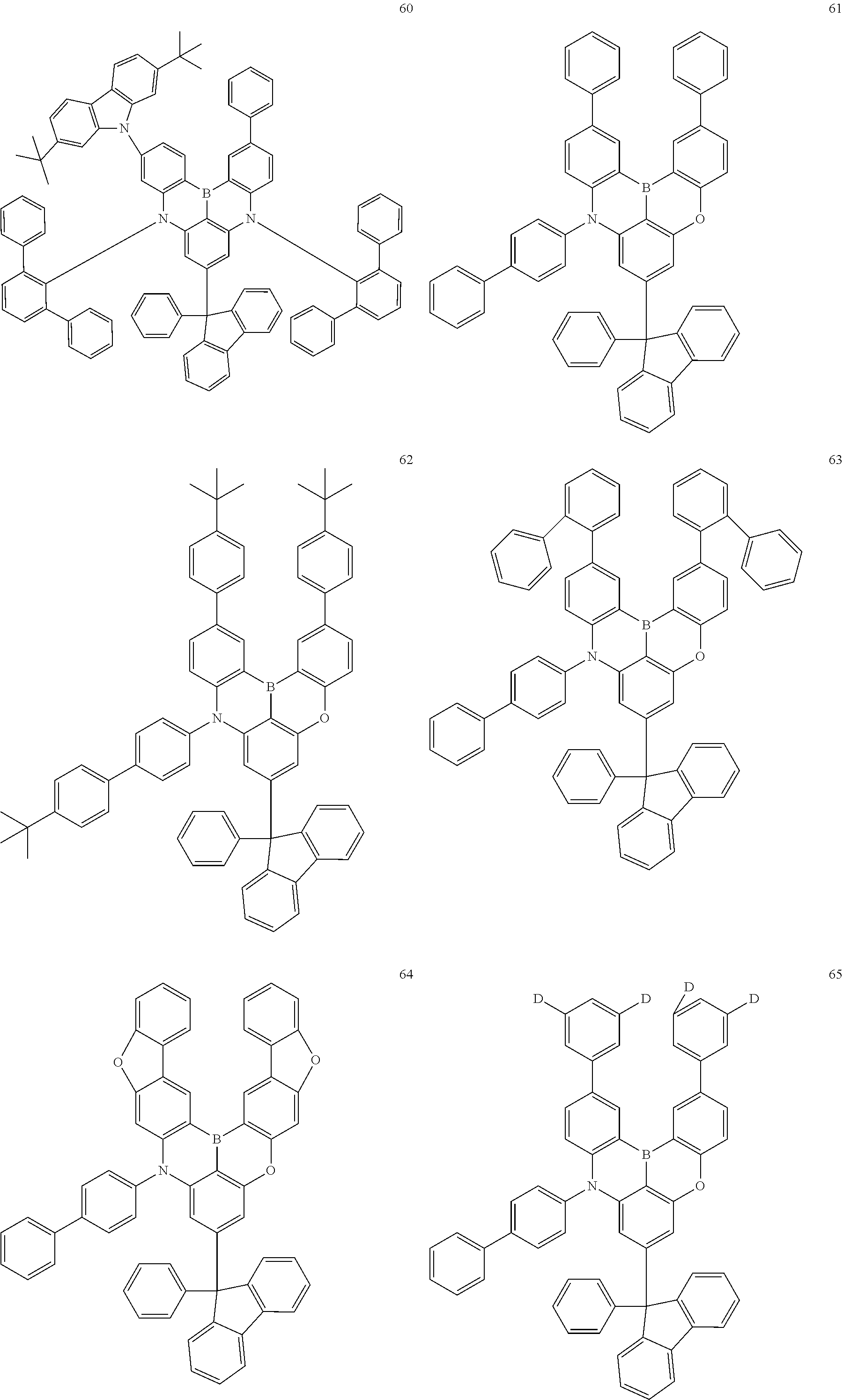 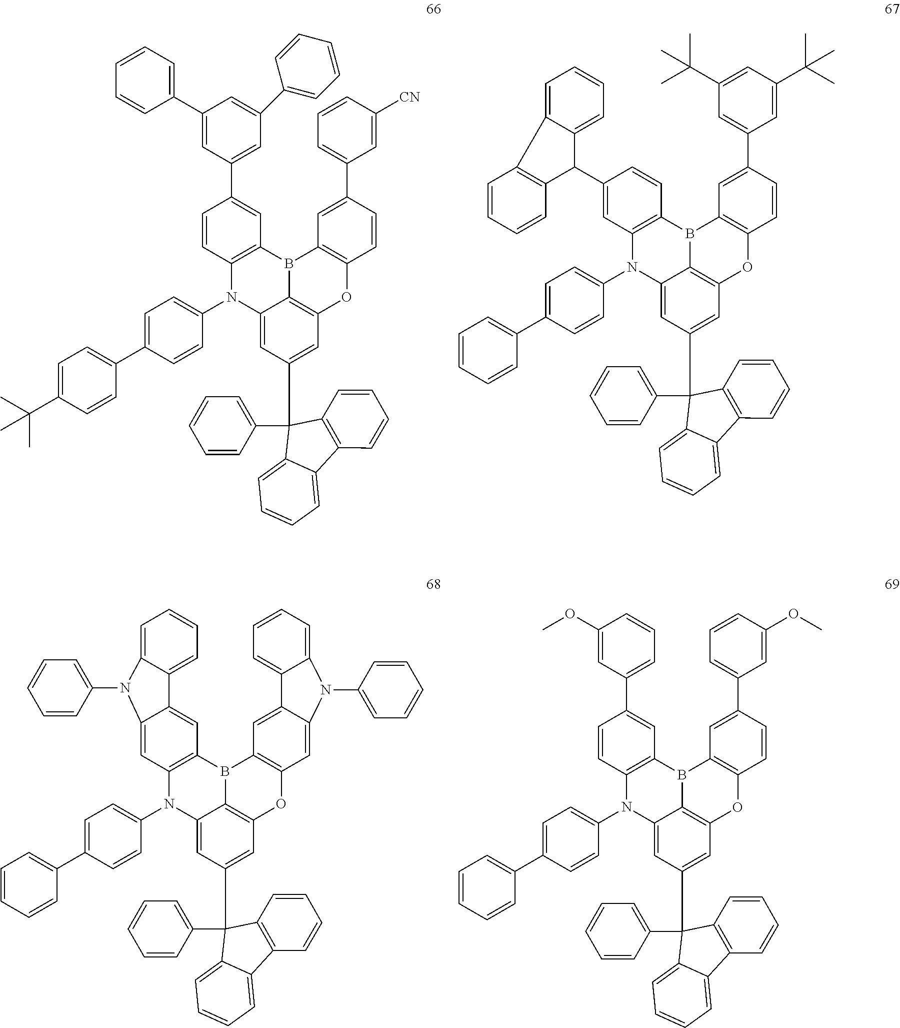 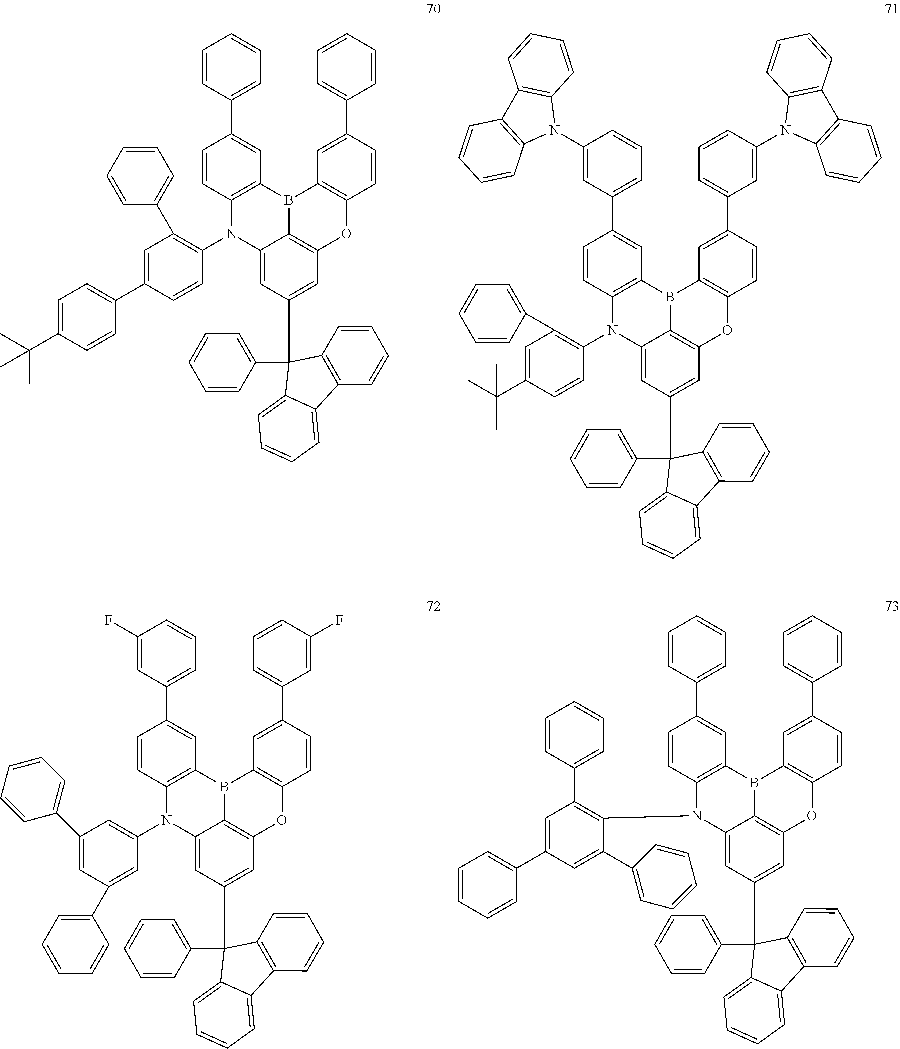 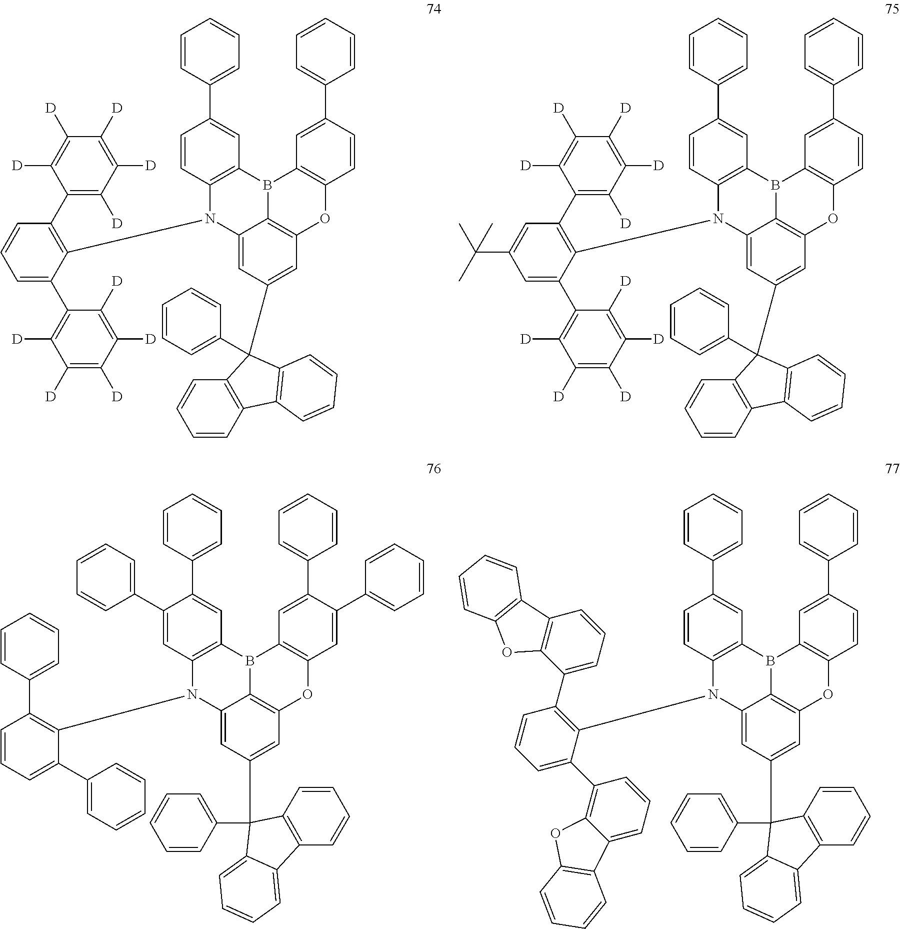 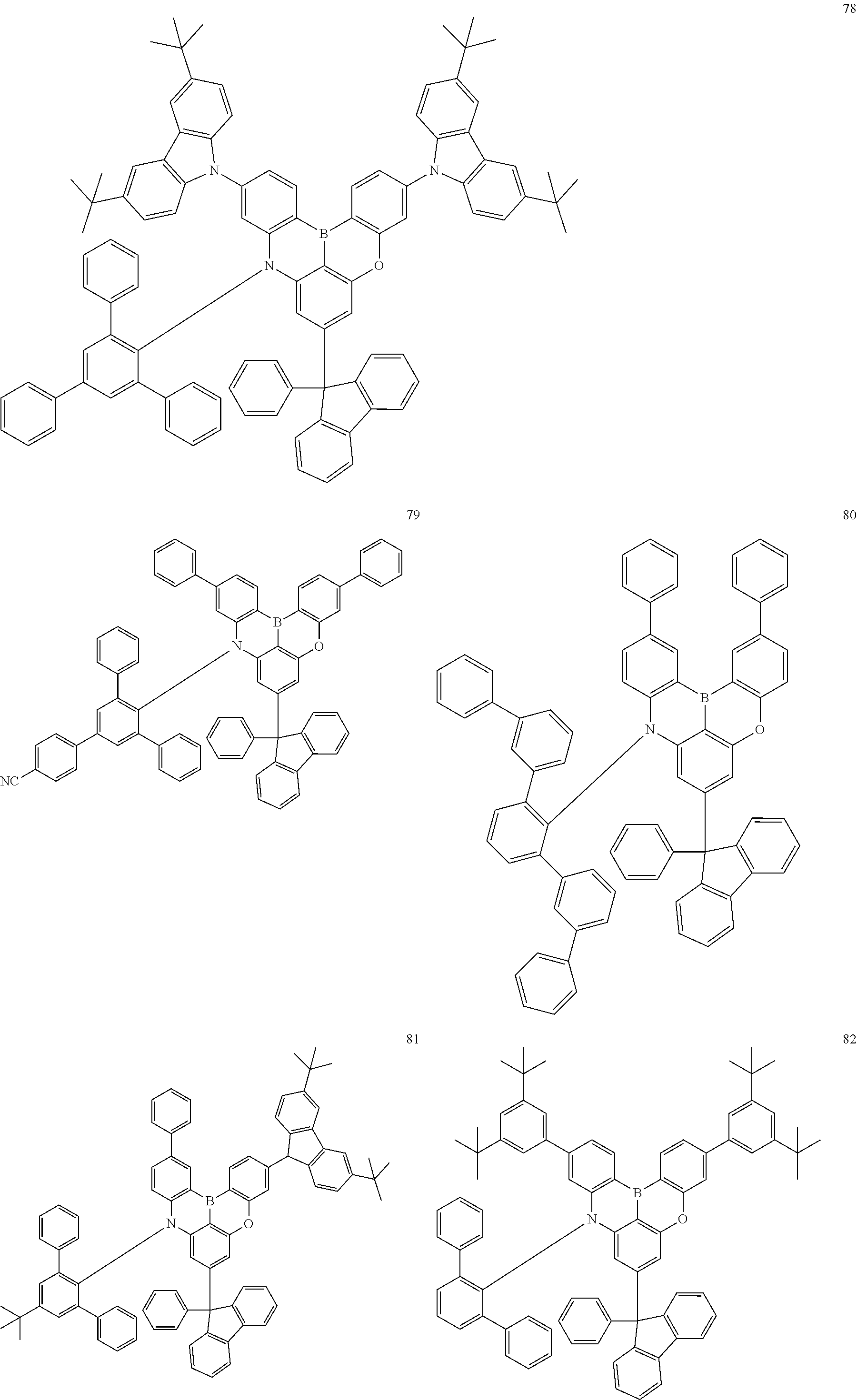 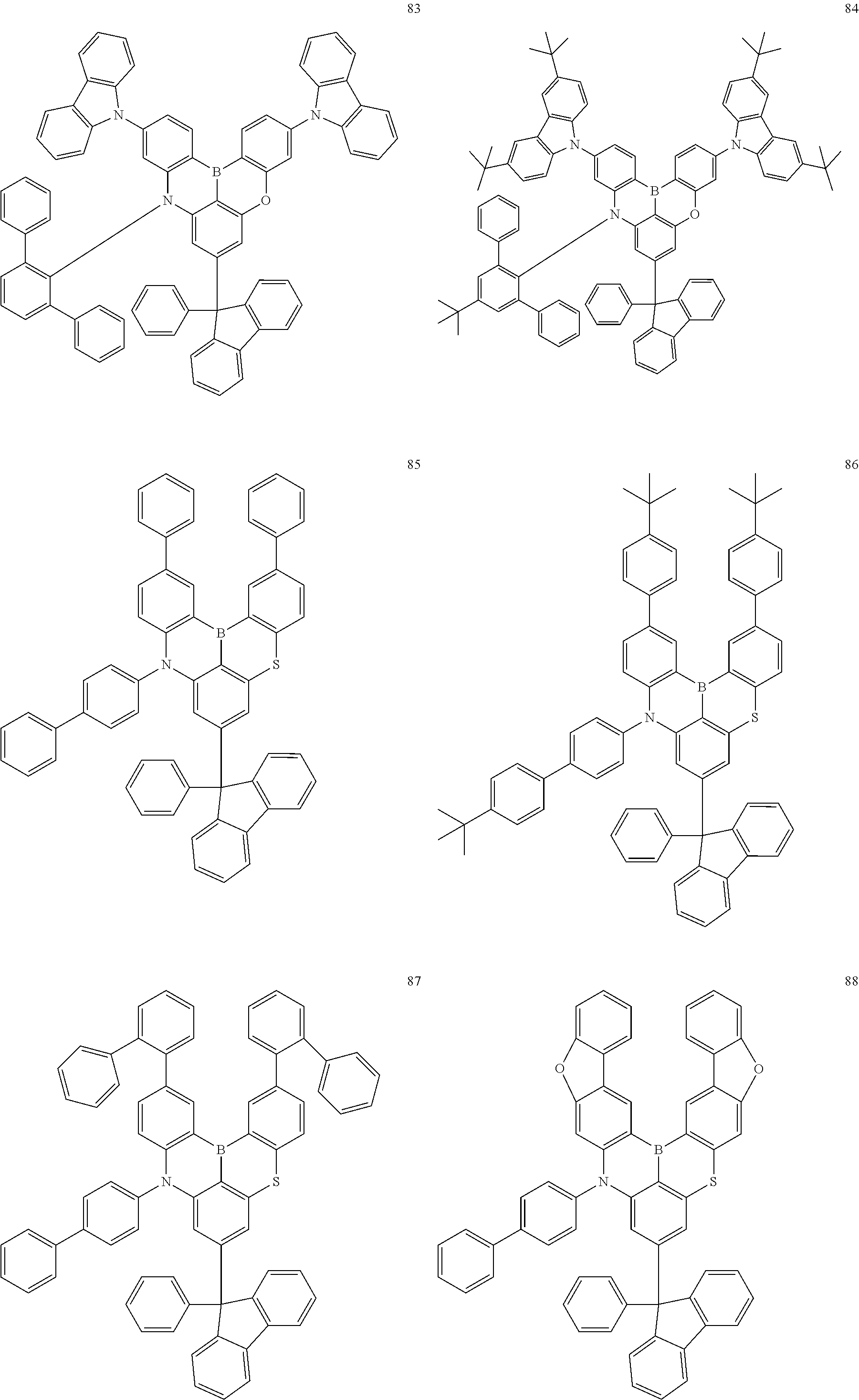 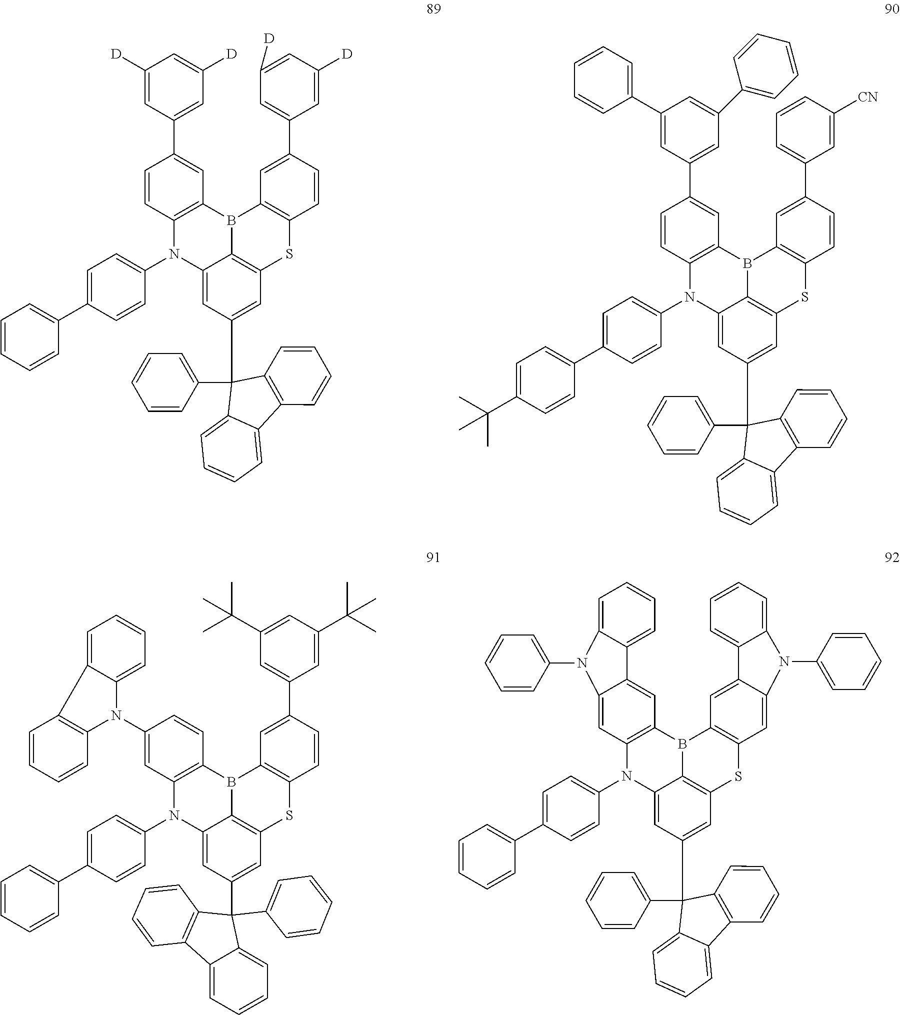 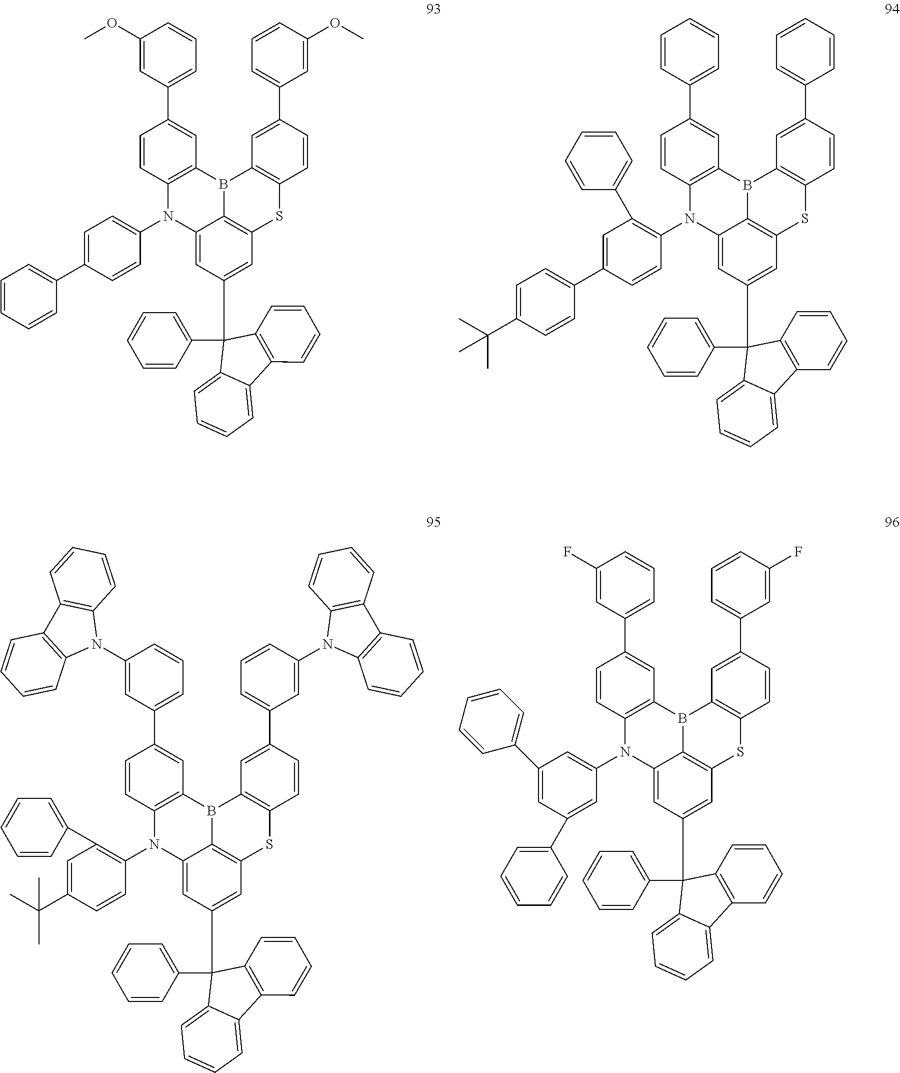 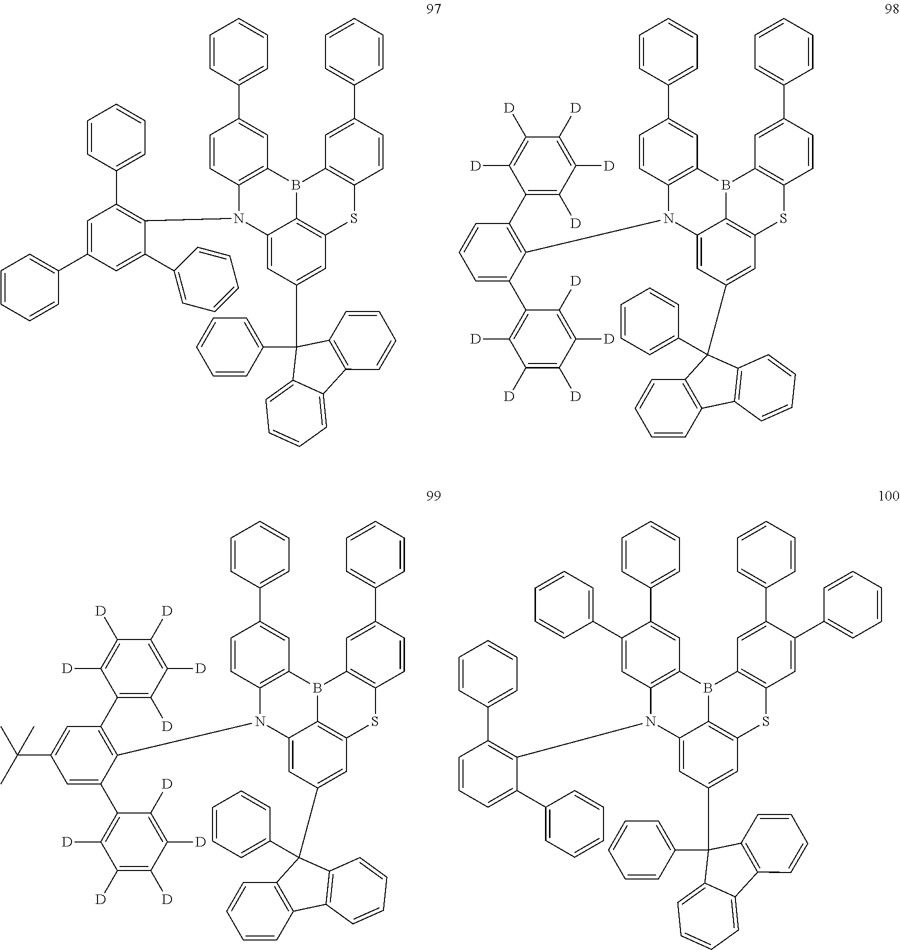 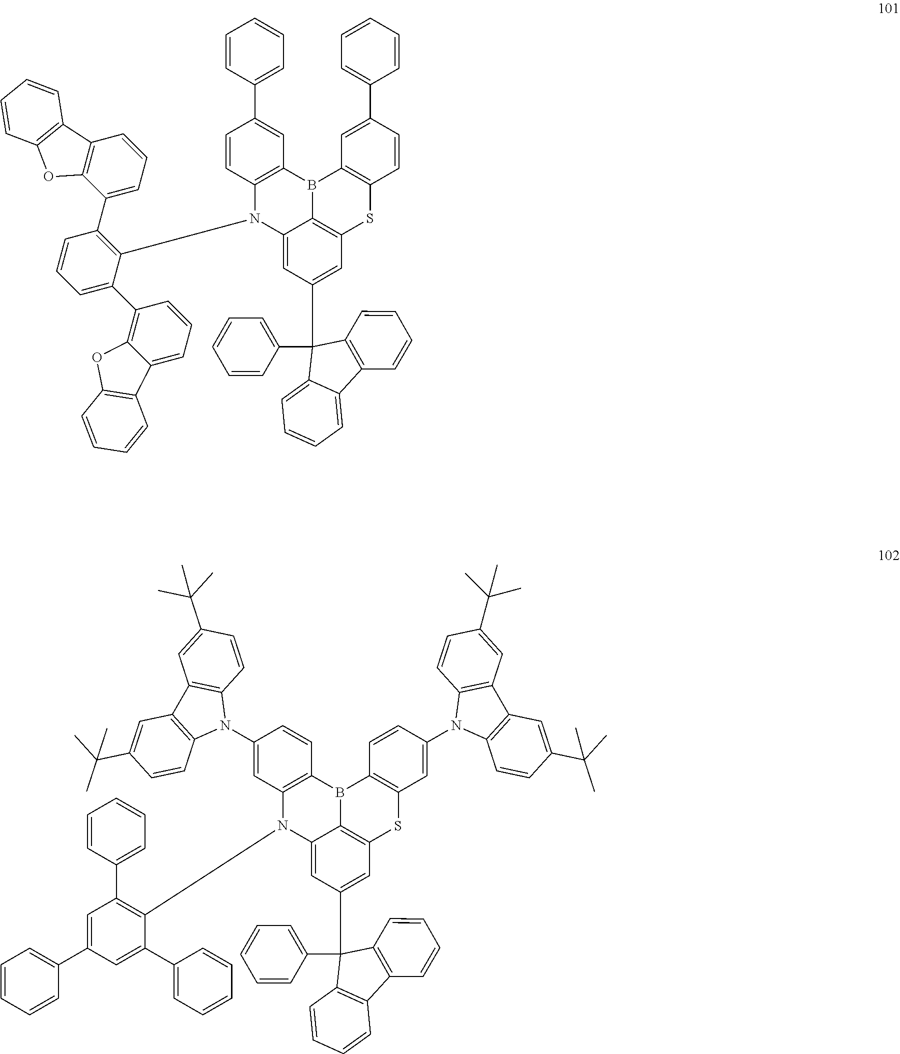 [SMILES: c1ccc(-c2ccc3c(c2)B2c4cc(-c5ccccc5)ccc4N(c4c(-c5cccc6c5oc5ccccc56)cccc4-c4cccc5c4oc4ccccc45)c4cc(C5(c6ccccc6)c6ccccc6-c6ccccc65)cc(c42)S3)cc1 ; CC(C)(C)c1ccc2c(c1)c1cc(C(C)(C)C)ccc1n2-c1ccc2c(c1)Sc1cc(C3(c4ccccc4)c4ccccc4-c4ccccc43)cc3c1B2c1ccc(-n2c4ccc(C(C)(C)C)cc4c4cc(C(C)(C)C)ccc42)cc1N3c1c(-c2ccccc2)cc(-c2ccccc2)cc1-c1ccccc1] [chemical structure]
